(19) United States
(12) Patent Application Publication
(10) Pub. No.: US 2015/0303390 A1
(43) Pub. Date: Oct. 22, 2015

(54) SEQUENCE DEPENDENT ASSEMBLY TO CONTROL MOLECULAR INTERFACE PROPERTIES FOR MEMORY DEVICES, SOLAR CELLS AND MOLECULAR DIODES

(71) Applicant: YEDA RESEARCH AND DEVELOPMENT CO. LTD, Rehovot (IL)

(72) Inventors: Milko E. VAN DER BOOM, Rishon Lezion (IL); Graham DE RUITER, Rehove (IL); Michal LAHAV, Rehove (IL); Hodaya KEISAR, Rehovot (IL); Renata BALGLEY, Rehovot (IL)

(21) Appl. No.: 14/436,092

(22) PCT Filed: Oct. 16, 2013
(86) PCT No.: PCT/IL2013/050834

§ 371 Date: Apr. 16, 2015

Related U.S. Application Data
(60) Provisional application No. 61/715,041, filed on Oct. 17, 2012.

(51) Int. Cl. H01L 51/00; G11C 13/00; G11C 11/56

(52) U.S. Cl. CPC H01L 51/0098; H01L 51/0096; G11C 11/5664; G11C 13/0016; H01L 2251/308; H01L 51/0088; H01L 51/0086; H01L 51/0083; H01L 51/0067

(57) ABSTRACT

The present invention relates to a device having an electrically conductive surface and carrying a molecular assembly, preferably composed of two or more redox-active based molecular components arranged in a specific order or sequence, such that the sequence of the components and their thickness dictate the assembly properties and consequently the uses of the device. Such a device can be used in fabrication of a multistate memory, electrochromic window, smart window, electrochromic display, binary memory, solar cell, molecular diode, charge storage device, capacitor, or transistor.

### TECHNICAL FIELD

The present invention relates to a device having an electrically conductive surface and carrying a molecular assembly, preferably composed of two or more redox-active based molecular components arranged in a specific order or sequence, such that the sequence of the components and their thickness dictate the assembly properties and consequently the uses of the device.

Abbreviations: AFM, atomic force microscopy; BPEB, 1,4-bis[2-(4-pyridyl)ethenyl]benzene; CV, cyclic voltammogram; DCM, dichloromethane; DMF, dimethylformamide; FTIR, fourier-transform infrared; ITO, indium tin oxide; MLCT, metal-to-ligand charge-transfer; RT, room temperature; SDA, sequence dependent assembly; SPMA, self-propagating molecule-based assembly; TBAPF₆, tetrabutylammonium hexafluorophosphate; THF, tetrahydrofuran; XPS, X-ray photoelectron spectroscopy; XRR, X-ray reflectivity.

### BACKGROUND ART

Multi-component materials might display synergistic effects and possess functions not attainable with single-component systems. The composition, structure, and phase segregation of multi-component materials is difficult to control. The controlled layer-by-layer assembly of metal complexes can induce systematic changes in the physicochemical properties of the materials. However, the use of a layer-by-layer assembly technique inherently brings about a certain assembly sequence. For instance, for mono-metallic molecular assemblies, the sequence follows a simple order where each deposition of a metal complex is followed by the deposition of the cross linker. In fact most systems follow such straightforward deposition sequence. However, what sequence does one follow if multiple metal and/or functionalities are incorporated into a single molecular assembly, and how does the assembly sequence affect the molecular properties. These are critical questions, with important implications in the field of multistate memory, electrochromic windows, smart windows, binary memory, electrochromic displays, bulk-hetero-junction solar cells, inverted type solar cells, dye sensitized solar cells, molecular diodes, charge storage devices, capacitors, or transistors. There is thus a great need to answer these questions and to study the effect of the assembly sequence on the molecular properties.

International Publication No. WO 2011/141913 discloses a solid-state, multi-valued, molecular random access memory device, comprising an electrically, optically and/or magnetically addressable unit, a memory reader, and a memory writer. The addressable unit comprises a conductive substrate; one or more layers of electrochromic, magnetic, redox-active, and/or photochromic materials deposited on the conductive substrate; and a conductive top layer deposited on top the one or more layers. The memory writer applies a plurality of predetermined values of potential biases or optical signals or magnetic fields to the unit, wherein each predetermined value applied results in a uniquely distinguishable optical, magnetic and/or electrical state of the unit, thus corresponding to a unique logical value. The memory reader reads the optical, magnetic and/or electrical state of the unit.

International Application No. PCT/IL2013/050584 discloses a logic circuit for performing a logic operation comprising a plurality of predetermined solid-state molecular chips, each molecular chip having multiple states obtained after application of a corresponding input. After applying predetermined inputs on the molecular chips, reading the states of the molecular chips produces a logical output according to the logic operation.

The aforesaid patent publications are herewith incorporated by reference in their entirety as if fully disclosed herein.

### SUMMARY OF INVENTION

In one aspect, the present invention provides a device comprising a substrate having an electrically conductive surface and carrying an assembly of one or more molecular components, each molecular component having a thickness and an oxidative or reductive peak potential, and comprising one or more entities each independently is a redox-active compound,

provided that:
(i) wherein said device comprises one molecular component, said component comprises more than one of said entities, and the difference between the oxidative- and/or reductive peak potentials of each one of said entities is larger than 100 mV; and
(ii) wherein said device comprises more than one molecular components, said components are assembled on said electrically conductive surface in a random, alternate or successive order, each one of said components comprises one or more of said entities, and the difference between the oxidative- and/or reductive peak potentials of two of said entities comprised within said components is larger than 100 mV,

wherein exposure of said device, when comprising one molecular component, to a potential change, causes electron transfer, which results in an electrochemical signature which can be read out electrically, optically, magnetically, or by conductivity measurements; and exposure of said device, when comprising more than one molecular components, to a potential change, causes (a) reversible electron transfer; (b) oxidative catalytic electron transfer with charge trapping; (c) reductive catalytic electron transfer; or (d) blocking of the electron transfer, dependent on the order of said components and the thickness of each one of said components, which results in an electrochemical signature which can be read out electrically, optically, magnetically, or by conductivity measurements.

In certain embodiments, the redox-active compounds composing the molecular components of the device of the present invention each independently is a metal, preferably a transition metal, complex, e.g., a tris-bipyridyl complex of said transition metal. Particular such tris-bipyridyl complexes exemplified herein are those of the general formula I:

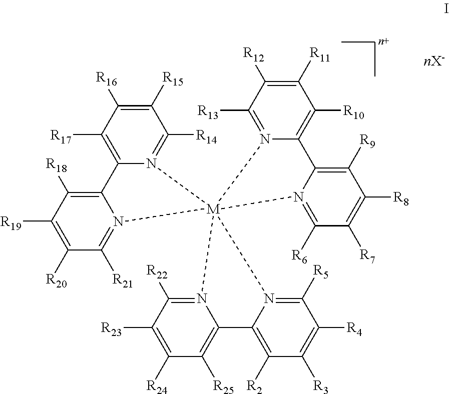

wherein

M is said transition metal;
n is the formal oxidation state of the transition metal, wherein n is 0-4;

X is a counter anion selected from Br⁻, Cl⁻, F⁻, I⁻, PF₆⁻, BF₄⁻, OH⁻, ClO₄⁻, SO₃⁻, SO₄⁻, CF₃COO⁻, CN⁻, alkylCOO⁻, arylCOO⁻, or a combination thereof;

R₂ to R₂₅ each independently is selected from hydrogen, halogen, hydroxyl, azido, nitro, cyano, amino, substituted amino, thiol, C₁-C₁₀ alkyl, cycloalkyl, heterocycloalkyl, haloalkyl, aryl, heteroaryl, alkoxy, alkenyl, alkynyl, carboxamido, substituted carboxamido, carboxyl, protected carboxyl, protected amino, sulfonyl, substituted aryl, substituted cycloalkyl, substituted heterocycloalkyl, or group A, wherein at least two, preferably three, of said R₂ to R₂₅ each independently is a group A:

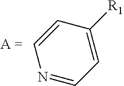

wherein A is linked to the ring structure of the compound of general formula II via R₁; and R₁ is selected from cis/trans C═C, C≡C, N═N, C═N, N═C, C—N, N—C, alkylene, arylene or a combination thereof; and any two vicinal R₂-R₂₅ substituents, together with the carbon atoms to which they are attached, may form a fused ring system selected from cycloalkyl, heterocycloalkyl, heteroaryl or aryl, wherein said fused system may be substituted by one or more groups selected from C₁-C₁₀ alkyl, aryl, azido, cycloalkyl, halogen, heterocycloalkyl, alkoxy, hydroxyl, haloalkyl, heteroaryl, alkenyl, alkynyl, nitro, cyano, amino, substituted amino, carboxamido, substituted carboxamido, carboxyl, protected carboxyl, protected amino, thiol, sulfonyl or substituted aryl; and said fused ring system may also contain at least one heteroatom selected from N, O or S.

In other embodiments, the redox-active compounds composing the molecular components of the device of the present invention each independently is an organic molecule. Particular such organic molecules exemplified herein are 1,3,5-tris(4-ethenyl pyridyl)benzene, 1,3,5-tris(2-(pyridin-4-yl)ethyl)benzene, and 1,4-bis[2-(4-pyridyl)ethenyl]benzene.

In certain embodiments, the device of the present invention comprises a substrate having an electrically conductive surface and carrying an assembly of one molecular component, e.g., such devices wherein the molecular component comprises two or more, preferably two, entities. Such devices can be used in fabrication of a multistate memory, electrochromic window, smart window, electrochromic display, or binary memory.

In other embodiments, the device of the present invention comprises a substrate having an electrically conductive surface and carrying an assembly of more than one molecular component, e.g., two molecular components wherein each component preferably comprises one entity and the components are preferably assembled in any alternate or successive order; or three or more molecular components wherein each component preferably comprises one entity and the components are preferably assembled in any random, alternate or successive order. Particular such devices, when comprising an assembly of more than one molecular component assembled in an alternate order, can be used in fabrication of a multistate memory, electrochromic window, smart window, binary memory, electrochromic display, bulk-hetero-junction solar cell, inverted type solar cell, dye sensitized solar cell, molecular diode, charge storage device, capacitor, or transistor. Other such devices, when comprising an assembly of more than one molecular component assembled in a successive order, can be used in fabrication of a smart window, electrochromic display, bulk-hetero-junction solar cell, inverted type solar cell, dye sensitized solar cell, molecular diode, charge storage devices capacitor, or transistor.

### BRIEF DESCRIPTION OF DRAWINGS

FIG. 1 shows a SDA method of preparing SPMAs I-IV. The interfaces are formed by immersion of a pyridine-terminated template layer on quartz, silicon and no-coated glass substrates (Kaminker et al., 2010) in a 1.0 mm THF solution of [Pd(PhCN)₂Cl₂] and subsequent immersion in 0.2 mm solutions of complexes 1 or 2 in THF/DMF (9:1 v/v) followed by immersion. The different SPMAs were created by alternate repetition of steps x and y (I and IV) or successive repetition of steps x and y (II and III). The photograph on the right shows the coloration of the SPMA-functionalized ITO-coated glass substrates (7.5×0.8 cm) as a function of the number of deposition steps.

FIG. 2 shows electron transfer mechanism of SDA I, in which molecular components A and B are assembled alternatingly. The thickness of each “layer” (that is composed of a single component) should not exceed a certain threshold limit, so conductivity is still maintained. In this case, the electron transfer from each molecular component inside the molecular assembly is possible and both oxidation/reduction wave of each molecular component is observed in the CV. The kind of electrochemical behavior is specific for this assembly order, and merits application in molecular memory and electrochromic windows (conditions: wherein E_{oxA}−E_{oxB}≧100 mV so that E_{oxA}>E_{oxB}).

FIG. 3 shows electron transfer mechanism of SDA II, in which molecular components A and B are assembled sequentially. When component A is below the surface-interface threshold thickness in which it does not insulate component B, the electron results in direct oxidation of the molecular components A and B (left). However when component A does exceed the threshold thickness, the electron transfer results in the oxidation component B, that is catalytically mediated by the molecular component A (right). These electrochemical characteristics are specific for assembly method II and are important for, solar cells, memory and battery technology (conditions: wherein E_{oxA}−E_{oxB}≧100 mV so that E_{oxA}>E_{oxB}).

FIG. 4 shows electron transfer mechanism of SDA III, in which molecular components A and B are assembled sequentially. When component B is below a certain surface-interface thickness, direct reduction of the molecular components A and B by the ITO electrode occurs (left). At intermediate thickness of component B, two distinct reduction pathways are observed: pathway (i)—direct electron transfer from the ITO electrode to molecular component A; and pathway (ii)—catalytically mediated electron transfer by the molecular component B (right). At higher thicknesses, complete isolation of the molecular component A is observed (not shown). These electrochemical characteristics are specific for assembly method III and might be important battery technology and electrochromic materials (conditions: wherein E_{oxA}−E_{oxB}≧100 mV so that E_{oxA}>E_{oxB}).

FIGS. 5A-5E show comparison of the thickness (5A), ¹MLCT band at λ≈500 nm (5B), and the π-π* band at λ≈317 nm (2C) for SPMA I | Ru₄—Os₄ (black circles), SPMA II | Ru₄—Os₄ (red circles), SPMA III | Os₄—Ru₄ (blue circles) and SPMA IV | (Ru—Os)₈ (green circles). All SPMAs show an exponential correlation between the number of deposition steps vs. the thickness and the absorption of the ¹MLCT or π-π* band, with R²>0.99. 5D and 5E show the linear correlation between the thickness of SPMA I | Ru₄—Os₄ (black circles), SPMA II | Ru₄—Os₄ (red circles), SPMA III | Os₄—Ru₄ (blue circles), and SPMA IV | (Ru—Os)₈ (green circles), with respect to their absorption; for the MLCT band at λ≈500 nm (5D) and the π-π* band λ≈317 nm (5E), with R²>0.97. The exponential growth of the thickness and absorption, and the linear correlation between the thickness and absorption indicate that all SPMAs exhibit identical growth behavior, with a regular and homogeneous deposition of the molecular components 1 and 2.

FIGS. 6A-6D show CVs of SPMAs constructed by SDA. The CVs of SPMAs, on ITO, were recorded at a scan rate of 200 mVs⁻¹, with thicknesses of 11.4 nm (SPMA I | Ru₂—Os₂) (6A); 12.1 nm (SPMA II | Ru₃—Os₁) (6B; 11.4 nm (SPMA III | Os₃—Ru₂) (6C); and 12.5 nm (SPMA IV | (Ru—Os)₄) (6D). The oxidation/reduction processes in the SPMAs are indicated by the lettered potentials and are defined as follows: Os²⁺→Os³⁺ (a); catalytic Os²⁺→Os³⁺ (a′); Ru²⁺→Ru³⁺ (b); Ru³⁺→Ru²⁺ (c); catalytic Ru³⁺→Ru²⁺ (c′); and Os³⁺→Os²⁺ (d).

FIGS. 7A-7D show oxidative (7A and 7B) and reductive (7C and 7D) peak currents for the Os^{2+/3+} (7A and 7C) and Ru^{2+/3+} (7B and 7D) redox-couples vs. the scan rate, for SPMAs with thicknesses of 5.4 (yellow circles), 11.4 (green circles), 22.7 (violet circles), 36.7 (blue circles), and 54.3 nm (black circles), with R²>0.98 for all thicknesses. Thicknesses of 5.4, 11.4, 22.7, 36.7 and 54.3 nm correspond to deposition steps 2, 4, 6, 8 and 10. The linear correlation (R²>0.98) between the peak current and scan rate, for the Os^{2+/3+} and Ru^{2+/3+} redox-couples, indicate a reversible surface-confined process that is not limited by diffusion (Bard and Faulkner, 2001).

FIGS. 8A-8B show peak-to-peak separation for the Os^{2+/3+} (8A) and Ru^{2+/3+} (8B) redox-couples. (8A) Peak-to-peak separation for the Os^{2+/3+} redox-couple in the SPMAs as a function of the scan rate, for the following thicknesses: 5.4 (yellow circles), 11.4 (green circles), 22.7 (violet circles), 36.7 (blue circles), and 54.3 (black circles) nm. (8B) Peak-to-peak separation for the Ru^{2+/3+} redox-couple in SPMAs as a function of the scan rate, for the following thicknesses: 5.4 (yellow circles), 11.4 (green circles), 22.7 (violet circles), 36.7 (blue circles), and 54.3 (black circles) nm. The thicknesses of 5.4, 11.4, 22.7, 36.7, and 54.3 nm, as estimated by spectroscopic ellipsometry of SPMAs grown simultaneously on silicon substrates, corresponds to deposition steps 2, 4, 6 8 and 10, respectively.

FIG. 9 shows Os/Ru ratio, as determined by the charges of the Os^{2+/3+} and Ru^{2+/3+} redox couples in the CVs of SPMA I | Ru₁—Os₁, SPMA I | Ru₂—Os₂, SPMA I | Ru₃—Os₃, and SPMA I | Ru₄—Os₄ (blue circles). For comparison the charges of the Os^{2+/3+} and Ru^{2+/3+} redox couples in the CVs of SPMA IV | (Ru—Os)_{1→8} (red circles) are also shown. For SDA I, only the even number of deposition steps are shown where 1 and 2 have been deposited an equal number of times. The dotted grey line indicates the unity ratio of the osmium and ratio complexes.

FIG. 10 shows representative CV of an acetonitrile solution of complexes 1 and 2 (0.5 mM each) at a scan rate of 100 mVs⁻¹. The CVs were recorded at RT in acetonitrile with 0.1 M TBAPF₆ as the supporting electrolyte. Pt- and Ag-wires were used as counter and reference electrodes respectively, with ferrocene as the internal standard.

FIGS. 11A-11B show CVs of SPMAs constructed by SDA. CV of SPMAs on ITO at 200 mVs⁻¹ with a Ru thickness of 5.7 nm and an Os thickness of 6.8 nm (SPMA II | Ru₂—Os₂; blue trace) and with a Ru thickness of 8.0 nm and an Os thickness of 4.1 nm (SPMA II | Ru₃—Os₁; red trace) showing the generation of the oxidative pre-wave at approximately 1.08 V upon increasing the Ru thickness (11A). CV of SPMAs on ITO at 200 mVs⁻¹ with increasing thicknesses of the Os layer from 4.1 nm (red trace; SPMA II | Ru₃—Os₁) to 9.3 nm (blue trace; SPMA II | Ru₃—Os₂), and finally to 17.6 nm (green trace; SPMA II | Ru₃—Os₃). The black trace shows the CV of an SPMA with only Ru (SPMA II | Ru₃—Os₀) (11B).

FIGS. 12A-12B show electron transfer in SPMAs created by SDA II and III. 12A) Oxidative mechanism of electron transfer observed for SPMAs created by SDA II. For SPMAs with a Ru surface-interface thickness under 5.7 nm, direct oxidation of the Os and Ru metal centers by the ITO electrode is possible (left). At higher Ru surface-interface thicknesses over 8.0 nm, the oxidation the Os²⁺ metal centers is catalytically mediated by the Ru³⁺ metal centers (right). 12B) Reductive mechanism of electron transfer observed for SPMAs created by SDA III. For SPMAs with an Os surface-interface thickness under 2.6 nm, direct reduction of the Os and Ru metal centers by the ITO electrode occurs (left). At intermediate Os surface-interface thicknesses 3.8-6.1 nm, two distinct reduction pathways are observed. Pathway A: direct electron transfer from the ITO electrode to the Ru³⁺ centers, and Pathway B: catalytically mediated electron transfer by the Os²⁺ metal centers (right). At higher thicknesses (over 6.1 nm) complete isolation of the metal centers is observed (not shown).

FIG. 13 shows CV of SPMA II | Ru₃—Os₁ at 200 mVs⁻¹ for the 1^{st} scan (blue trace) and the 2^{nd} scan (red trace) between 0.4 and 1.6 V, clearly indicating a significant drop in the intensity of the catalytic prewave at −1.08 V in the 2^{nd} scan cycle.

FIGS. 14A-14B show oxidative (14A) and reductive (14B) peak currents for SPMA II | Ru₂—Os₂ as a function of the scan rate. The linear correlation (R²>0.96) between the peak current and scan rate, for the Os^{2+/3+} (green circles) and Ru^{2+/3+} (blue circles) redox-couples indicate a reversible surface-confined process that is not limited by diffusion (Bard and Faulkner, 2001).

FIGS. 15A-15C show CVs of SPMAs constructed by SDA III. 15A) CV of SPMA III | Os₁—Ru₁ on ITO, with an Os thickness of 2.6 nm and a Ru thickness of 1.3 nm, at a scan rate of 100 mVs⁻¹ (red trace), 400 mVs⁻¹ (blue trace), and 700 mVs⁻¹ (green trace). 15B) CV of SPMA III | Os₂—Ru₂ on ITO, with an Os thickness of 3.8 nm and a Ru thickness of 5.0 nm, at a scan rate of 100 mVs⁻¹ (red trace), 400 mVs⁻¹ (blue trace) and 700 mVs⁻¹ (green trace), demonstrating the evolution of a reductive catalytic pre-wave at approximately 1.00 V. 15C) CV of SPMA III | Os₃—Ru₂ on ITO, with an Os thickness of 6.1 nm and a Ru thickness of 5.3 nm, at a scan rate of a 100 mVs⁻¹ (red trace), 400 mVs⁻¹ (blue trace), and 700 mVs⁻¹ (green trace), demonstrating the permanent presence and evolution of a reductive catalytic pre-wave at ≈1.00 V.

FIGS. 16A-16B show (16A) current response of SPMA III | Os₁—Ru₁ (black trace) and SPMA III | Os₂—Ru₁ (red trace), following a potential step between 1.60-1.00 V. (16B) Current response of SPMA III | Os₃—Ru₁ (green trace) and SPMA III | Os₄—Ru₁ (brown trace), following a potential step between 1.60-1.00 V. The pink trace shows the current response of a bare ITO-electrode following a potential step between 1.60-0.40 V. The decay of the current could not be analyzed by a simple exponential or bi-exponential method as introduced by Katz and Willner (1997).

FIG. 17 shows CV of an SPMA on ITO at scan rates between 25 and 700 mVs⁻¹, with an Os thickness of 11.0 nm and a Ru thickness of 28.8 nm (SPMA III | Ru₄—Os₄), showing the isolation of the Ru layer from the ITO electrode. The thickness was estimated by spectroscopic ellipsometry of the SPMA grown simultaneously on a silicon substrate.

FIGS. 18A-18D show oxidative and reductive peak currents for SPMA IV | (Ru—Os)₁ (orange circles), SPMA IV | (Ru—Os)₂ (red circles), SPMA IV | (Os—Ru)₃ (light blue circles), SPMA IV | (Ru—Os)₄ (dark blue), SPMA IV | (Ru—Os)₅ (violet circles), SPMA IV | (Ru—Os)₆ (green circles), SPMA IV | (Ru—Os)₇ (navy blue circles), and SPMA IV | (Ru—Os)₈ (brown circles), as a function of the scan rate. The linear correlation (R²>0.93) between the peak current and scan rate, for the Os^{2+/3+} (18A, 18C) and Ru^{2+/3+} (18B, 18D) redox-couples, indicate a reversible surface-confined process that is not limited by diffusion (Bard and Faulkner, 2001).

FIGS. 19A-19B show CVs of SPMAs constructed by SDA IV. 19A) CVs of SPMA IV | (Os—Ru)₅ on ITO at scan rates between 25 and 700 mVs⁻¹, with a thickness of 12.5 nm demonstrating the reversible and surface-confined oxidation/reduction of the Os^{2+/3+} and Ru^{2+/3+} redox-couples. 19B) Increase in the Os/Ru ratio, as determined by the charges in the CVs of the corresponding redox couples, upon increasing the number of deposition steps; SPMA IV | (Os—Ru)_{1→8}.

FIG. 20 shows CVs of SPMA IV | (Ru—Os)₂ (red trace), SPMA IV | (Ru—Os)₄ (black trace), SPMA IV | (Ru—Os)₆ (green trace), and SPMA IV | (Ru—Os)₈ (blue trace), on ITO at a scan rate of 100 mVs⁻¹, demonstrating the increase in the Os/Ru ratio upon increasing the number of deposition steps.

FIG. 21 shows CV of a 54 nm thick SPMA on ITO (10 deposition steps), at a scan rate of 100 mVs⁻¹. State I: Os²⁺|Ru²⁺, State II: Os³⁺|Ru²⁺ and State III: Os³⁺|Ru³⁺. CVs were recorded at RT with 0.1 M TBAPF₆ in acetonitrile or dry propylene carbonate as supporting electrolyte, with the SPMA functionalized ITO, Pt- and Ag-wires were used as working, counter and reference electrode respectively. Thicknesses of the ITO samples were estimated according to SPMAs grown simultaneously on silicon substrates.

FIG. 22 shows a representative CV of a acetonitrile solution of complexes 1 and 2 (0.5 mM each) at a scan rate of 100 mVs⁻¹. The CVs were recorded at RT in acetonitrile with 0.1 M TBAPF₆ as supporting electrolyte. Pt- and Ag-wires were used as counter and reference electrodes respectively, with ferrocene as internal standard.

FIGS. 23A-23B show optical response of the SPMAs on ITO, with a thickness of 29 nm (7 deposition steps), upon applying potential biases (vs. Ag/Ag⁺) of 0.40 V (blue trace), 0.95 V (green trace) and 1.60 V (red trace) (23A); and a representative CV of the 29 nm thick SPMA at 100 mVs⁻¹ (23B). This thickness corresponds to deposition step 7 and was estimated by spectroscopic ellipsometry of SPMAs grown simultaneously on silicon substrates. CVs were recorded as described in FIG. 21.

FIG. 24 shows optical response of the ¹MLCT at λ=495 nm of a 29 nm thick SPMA on ITO (7 deposition steps), as a function of time upon applying multiple potential steps. Double-potential steps between 0.40-1.60 V (panel A); double-potential steps between 0.40-0.95 V (blue trace) and between 0.95-1.60 V (red trace) (Panel B); and triple-potential steps between 0.40, 0.95 and 1.60 V (panel C). CVs were recorded as described in FIG. 21.

FIGS. 25A-25B show (25A) optical response of the ¹MLCT band, at λ=495 nm, of a SPMA (46 nm; 9 deposition steps), as a function of the voltage. The dashed red line is a sigmoidal fit (R²=0.99), with inflection points at 0.84 V (Os^{2+/3+}) and at 1.27 V (Ru^{2+/3+}) that corresponds to the half-wave potentials of complexes 1 and 2 in the SPMA. (25B) Derivative of the sigmoidal fit and the resulting full-width at half-maximum (fwhm). CVs were recorded as described in FIG. 21.

FIG. 26 shows representative CVs of SPMAs on ITO created according to SDA I, at various scan rates (25-700 mVs⁻¹) with thicknesses of 5.4 (panel A), 11.4 (panel B), 22.7 (panel C), 36.7 (panel D) and 54.3 (panel E) nm, and differential pulse voltammograms (DPVs) of the SPMAs with thicknesses of 5.4 (panel F), 11.4 (panel G), 22.7 (panel H), 36.7 (panel I) and 54.3 (panel J) nm, with ferrocene as internal standard. The thicknesses of 5.4, 11.4, 22.7, 36.7 and 54.3 nm, as estimated by spectroscopic ellipsometry of SPMAs grown simultaneously on silicon substrates, correspond to deposition steps 2, 4, 6, 8 and 10, respectively.

FIG. 27 shows CVs of SPMAs on ITO, created according to SDA I, at scan rates between 25-700 mVs⁻¹, with a thickness of 5.4 nm (panel A) and 54 nm (panel B); Linear dependence of the oxidative peak-current for the Os^{2+/3+} (panel C) and Ru^{2+/3+} (panel D) redox-couples vs. the scan rate, for SPMAs with thicknesses of 5.4 (yellow circles), 11.4 (green circles), 22.7 (violet circles), 36.7 (blue circles) and 54.3 nm (black circles), with R²>0.98 for all thicknesses. Thicknesses of 5.4, 11.4, 22.7, 36.7 and 54.3 nm correspond to deposition steps 2, 4, 6, 8 and 10. CVs were recorded as described in FIG. 21.

FIG. 28 shows (panel A) CVs of the SPMAs on ITO, created according to SDA I, terminated with a layer of complex 2 at a scan rate of 100 mVs⁻¹. The data are shown for assemblies having the following thicknesses: 5.4 (black trace), 11.4 (red trace), 24.7 (blue trace), 36.7 (green trace), and 54.3 nm (pink trace); and (panel B) exponential growth of the peak current vs. the number of deposition steps for Os-metal center (red circles, R²=0.988) and Ru-metal center (green circles, R²=0.994). The thicknesses of 5.4, 11.4, 22.7, 36.7 and 54.3 nm, as estimated by spectroscopic ellipsometry of SPMAs grown simultaneously on silicon substrates, corresponds to deposition steps 2, 4, 6, 8 and 10, respectively.

FIG. 29 shows peak-to-peak separation for the Os^{2+/3+} redox-couple in SPMAs created according to SDA I, as a function of the scan rate, for the following thicknesses: 5.4 (yellow circles), 11.4 (green circles), 22.7 (violet circles), 36.7 (blue circles), and 54.3 (black circles) nm (panel A); and peak-to-peak separation for the Ru^{2+/3+} redox-couple in SPMAs as a function of the scan rate, for the following thicknesses: 5.4 (yellow circles), 11.4 (green circles), 22.7 (violet circles), 36.7 (blue circles) and 54.3 (black circles) nm (panel B). The thicknesses of 5.4, 11.4, 22.7, 36.7 and 54.3 nm, as estimated by spectroscopic ellipsometry of SPMAs grown simultaneously on silicon substrates, corresponds to deposition steps 2, 4, 6, 8 and 10, respectively.

FIG. 30 shows optical absorption spectra of the SPMAs on quartz, created according to SDA I, with increasing numbers of deposition steps (panel A); and exponential growth and exponential fits of the absorption intensity of the π-π* band (black circles) at λ=317 nm vs. the number of deposition steps (R²=0.99), and dependence of the ¹MLCT band (blue circles) at λ=495 (Ru) and 510 nm (Os) vs. the number of deposition steps (R²=0.99) (panel B).

FIG. 31 shows exponential dependence of the thickness of SPMAs, created according to SDA I on silicon, measured my spectroscopic ellipsometry, vs. the number of deposition steps of complexes 1 and 2. The dotted red line is an exponential fit of the data (R²=0.994).

FIG. 32 shows (panel A) linear dependence of the thickness vs. the absorbance of the π-π* band (red circles) at λ=317 nm (R²=0.994), and ¹MLCT band (blue circles) at λ=495 (Ru) and 510 nm (Os) (R²=0.996), of SPMAs created according to SDA I. (Panel B) Linear dependence of the thickness vs. the peak current of the Os metal center (R²=0.985). The thickness of the SPMAs was estimated by spectroscopic ellipsometry of SPMAs grown simultaneously on silicon substrates.

FIG. 33 shows UV/vis spectra of the self-propagating molecular assemblies (SPMAs) on ITO, created according to SDA I with a thickness of 11 nm (panel A) and 54 nm (panel B), upon applying potential biases (vs. Ag/Ag⁺) of 0.40 V (blue trace), 0.95 V (green trace) and 1.60 V (red trace). The thicknesses of 11 and 54 nm, as estimated spectroscopic ellipsometry of SPMAs grown simultaneously on silicon substrates, corresponds to deposition steps 4 and 10, respectively.

FIG. 34 shows absorption intensity of the ³MLCT band at λ≈700 nm vs. the number of deposition steps of Os (blue circles) and Ru (red circles) for SPMAs created according to SDA I. The increase of the ³MLCT only occurs when the osmium-based complex 2 is deposited, indicated by the stepwise increase of the absorption. The dotted line is an exponential fit of the data (red circles; R²=0.987 and blue circles; R²=0.98; fit not shown).

FIG. 35 shows proof-of-principle that the optical response of the ³MLCT at λ=700 nm of the multi-component SPMAs (29 nm)—created according to SDA I—could be used for the formation of binary memory, upon applying potential biases at 0.40 and 0.95 V. The optical modulation results in the binary switching of the SPMA as the Ru complex (1) lacks a ³MLCT band. Therefore, the switching of the SPMA is solely contributed to the Os complex (2). The thicknesses of 29 nm, as estimated by spectroscopic ellipsometry of SPMAs grown simultaneously on silicon substrates, corresponds to deposition step 7.

FIG. 36 shows optical response of the ¹MLCT at λ=495 nm of the multi-component SPMA (11 nm)—created according to SDA I—as a function of time upon applying multiple potential steps. Double-potential steps between 1.00-1.60 V (blue trace) and between 0.40-1.60 V (red trace) (panel A); and triple-potential steps between 0.40, 1.00 and 1.60 V (panel B). The thickness of 11 nm, as estimated by spectroscopic ellipsometry of SPMAs grown simultaneously on silicon substrates, corresponds to deposition step 4.

FIG. 37 shows optical response of the ¹MLCT at λ=495 nm of the multi-component SPMA (54 nm)—created according to SDA I—as a function of time upon applying multiple potential steps. Double-potential steps between 1.00-1.60 V (blue trace) and between 0.40-1.60 V (red trace) (panel A); and triple-potential steps between 0.40, 1.00 and 1.60 V (panel B). The thickness of 54 nm, as estimated by spectroscopic ellipsometry of SPMAs grown simultaneously on silicon substrates, corresponds to deposition step 10.

FIG. 38 shows absorbance of the ¹MLCT at λ=495 nm of the SPMA created according to SDA I (22.7 nm; 6 deposition steps), as a function of time upon applying a triple-potential step between 0.4, 0.95 and 1.6 V, with 5-s intervals, with subsequent monitoring of the optical response under open circuit conditions (t>20 s) after a final pulse of 1.6 V (blue trace), 0.95 V (red trace) and 0.40 V (black trace) (panel A); and operability is best under DRAM conditions with refresh times of −60 s. Adventitious amounts of H₂O might reduce the retention times (Gupta and van der Boom, 2006) (panel B).

FIG. 39 shows a representative CV of a 46 nm thick SPMAs on ITO, created according to SDA I, at 100 mVs⁻¹. The ratio of the area under the peaks (1.6×10⁻⁴ C vs. 7.7×10⁻⁵ C) corresponds to the ratio observed in FIG. 25B. The thickness of 46 nm, as estimated by spectroscopic ellipsometry of SPMAs grown simultaneously on silicon substrates, corresponds to deposition step 9.

FIG. 40 shows optical response of the ¹MLCT at λ=495 nm of the SPMA created according to SDA I (29 nm; 7 deposition steps) as a function of time upon applying double potential steps between 0.40-0.95V, for 10 (blue trace) and 1000 cycles (red trace), where each cycle is 10 seconds.

FIG. 41 shows a representative CV of a 19 nm thick SPMAs, created according to SDA I, on ITO, at 100 mVs⁻¹, after heating at 130° C. for 2 hours (red trace), 3 hours (green trace) and 4 hours (blue trace). The thickness of 19 nm, as estimated by spectroscopic ellipsometry of SPMAs grown simultaneously on silicon substrates, corresponds to deposition step 5.

FIG. 42 shows optical absorption spectra of SPMAs on quartz formed by SDA II-III. The red and blue traces correspond to SPMA II | Ru₁—Os₀, and SPMA III | Os₁—Ru₀, with thicknesses of 3.4 and 4.4 nm, respectively. The green spectrum represents the template layer.

FIG. 43 shows optical absorption spectra of SPMAs on quartz formed by SDA I-III. (panel A) SPMA I | Ru₃—Os₃, (panel B) SPMA II | Ru₃—Os₃, and (panel C) SPMA III | Os₃—Ru₃, with thicknesses of 20.3, 24.6 and 17.9 nm. The red and blue traces correspond to UV-vis spectra taken after the deposition steps that contained metal complexes 1 or 2, respectively. The green trace represents the template layer.

FIG. 44 shows absorption intensity of the ³MLCT band at λ≈700 nm vs. the number of deposition steps of Os (blue circles) and Ru (red circles) for of SPMAs created according to SDA I. The increase of the ³MLCT only occurs when the osmium-based complex 2 is deposited, indicated by the stepwise increase of the absorption. The dotted line is an exponential fit of the data (red circles; R²=0.987 and blue circles; R²=0.98; fit not shown).

FIG. 45 shows optical absorbance and ellipsometry data of SPMA I | Ru₃—Os₃ (green circles), SPMA II | Ru₃—Os₃ (red circles), and SPMA III | Os₃—Ru₃ (blue circles) on quartz and silicon substrates. Comparison of the ¹MLCT band at λ=500 nm (panel A), and the π-π* band at λ=319 nm (panel B) as a function of the number of deposition steps; and a comparison of spectroscopic ellipsometry derived thickness vs. optical absorption of the ¹MLCT band at λ=500 nm (panel C), and the π-π* band at λ=319 nm (panel D). All SPMAs show an exponential correlation (panels A and B) between the number of deposition steps and the thickness; or a linear correlation (C and D) between the thickness and the absorption of the ¹MLCT or π-π* band, respectively. All R²>0.99.

FIG. 46 shows spectroscopic-derived thicknesses of SPMAs formed by SDA I-III. Exponential dependence of the thickness vs. the number of deposition steps for SPMA I | Ru₃—Os₃ (yellow circles), SPMA II | Ru₃—Os₃ (red circles), and SPMA III | Os₃—Ru₃ (blue circles) with final thicknesses of 20.3, 24.7 and 17.8 nm. All R²>0.99.

FIG. 47 shows representative synchrotron specular XRR data of SPMA I | Ru₆—Os₆ (panel A), SPMA II | Ru₄—Os₄ (panel B), and SPMA III | Os₄—Ru₄ (panel C), with XRR-derived thicknesses of 64.2, 40.4 and 46.4 nm. The reflectivity R is normalized to the Fresnel reflectivity R_{F}. The insets show an enlargement of the Kiessig Fringes observed in all SPMAs. Panels D-F show the electron density profiles for (panel D) SPMA I | Ru₁—Os₁ (red trace), SPMA I | Ru₂—Os₂ (green trace), SPMA I | Ru₃—Os₃ (blue trace), and template layer (black trace) as a function of the film thickness; (panel E) for SPMA II | Ru₂—Os₀ (black trace), SPMA II | Ru₄—Os₀ (red trace), SPMA II | Ru₄—Os₂ (green trace), and SPMA II | Ru₄—Os₄ (blue trace) as a function of the film thickness; and (panel F) for SPMA III | Os₂—Ru₀ (black trace), SPMA III | Os₄—Ru₀ (red trace), SPMA III | Os₄—Ru₁ (green trace), SPMA III | Os₄—Ru₂ (blue trace), SPMA III | Os₄—Ru₃ (magenta trace), and SPMA III | Os₄—Ru₄ (purple trace) as a function of the film thickness.

FIG. 48 shows XRR-derived Patterson plot for SPMA II | Ru₄—Os₄, with a thickness of 40.2 nm. The local maxima at 1.5, 5.6, 8.6, 12.5, 16.0, 27.1, 29.9 and 38.9 nm, seem to correspond with spectroscopic ellisometry-derived thicknesses of 2.6, 5.2, 7.3, 10.6, 15.5, 22.8, 33.3 and 43.6 nm, for deposition steps 0, 2, 3, 4, 5, 6, 7 and 8, respectively.

FIG. 49 shows XRR-derived Patterson plot for SPMA III | Os₄—Ru₄, with a thickness of 46.4 nm. For this SPMA, the local maxima are absent, and no correlation was found.

FIG. 50 shows XRR-derived thicknesses of SPMAs formed by SDA I-III. Exponential dependence of the thickness vs. the number of deposition steps for SPMA I | Ru₄—Os₄ (yellow circles), SPMA II | Ru₄—Os₄ (red circles), and SPMA III | Os₄—Ru₄ (blue circles) with thicknesses of 40.7, 40.4, and 46.4 nm. All R²>0.94.

FIG. 51 shows XRR-derived Patterson plot for SPMA I | Ru_{b}—Os₆, with a thickness of 64.2 nm. The local maxima at 1.4, 6.0, 11.0, 17.0, 23.0, 29.0, 38.0, 44.0 and 65.0 nm, seem to correspond with spectroscopic ellisometry-derived thicknesses of 2.4, 5.4, 11.4, 16.7, 23.7, 29.2, 36.7, 46.8 and 62.5 nm for deposition steps 0, 2, 4, 5, 6, 7, 8, 9 and 11, respectively.

FIG. 52 shows CVs of SPMAs on ITO, at various thicknesses. (Panel A) CVs at 100 mVs⁻¹ of SPMA I | Ru₁—Os₁ (blue trace), SPMA I | Ru₂—Os₂ (red trace), SPMA I | Ru₃—Os₃ (green trace), and SPMA I | Ru₄—Os₄ (purple trace), with thicknesses of 5.4, 11.4, 23.8 and 36.7 nm, respectively. (Panel B) CVs at 200 mVs⁻¹ of SPMA II | Ru₁—Os₁ (blue trace), SPMA II | Ru₂—Os₂ (red trace), SPMA II | Ru₃—Os₃ (green trace), and SPMA II | Ru₄—Os₄ (purple trace), with thicknesses of 5.8, 12.4, 25.6 and 43.6 nm, respectively. (Panel C) CVs at 200 mVs⁻¹ of SPMA III | Os₁—Ru₁ (blue trace), SPMA III | Os₂—Ru₂ (red trace), SPMA III | Os₃—Ru₃ (green trace), and SPMA III | Os₄—Ru₄ (purple trace), with thicknesses of 3.8, 8.7, 15.7 and 38.9 nm, respectively. The SPMAs were constructed according to SDA I (panel A), SDA II (panel B), or SDA III (panel C).

FIGS. 53A-53B show a schematic representation of the electron transfer in SPMAs constructed according to SDA II or III. (53A, panels A and B) Oxidative catalytic electron transfer in SPMA II | Ru₃—Os₃ (25 mVs⁻¹). At potentials of 0.40 V (a) or 1.60 V (d) the SPMAs are entirely reduced or oxidized, respectively. At an intermediate potential of 1.00 V (c) small amounts of Ru²⁺ are oxidized to Ru³⁺. Since the Ru³⁺ is able to oxidize Os²⁺ a sharp increase in the current is observed in which the ruthenium layer act as a catalytic gate for the oxidation of the osmium layer. However at the half-wave potential (0.75V) of the Os^{2+|+} redox-couple (b), no oxidation/reduction is observed due to the insulating nature of the 8.0 nm thick ruthenium layer and charge trapping occurs. (53B, panels A and B) Reductive catalytic electron transfer in SPMA III | Os₃—Ru₃ (25 mVs⁻¹). At potentials of 0.40 V (a) or 1.60 V (d) the SPMAs are entirely reduced or oxidized, respectively. At intermediated potentials the electron has two possibilities in reaching the outer ruthenium layer: (i) at 1.20 V (c) the electron transfer is reversible but hampered by the osmium layer and (ii) at 1.00 V (b) a catalytic transfer is observed due oxidation of the newly formed Os²⁺ metal centers by the remaining Ru³⁺ centers.

FIG. 54 shows CV of SPMA II | Ru₄—Os₁—with a thickness of the ruthenium layer of 11.4 nm, and a thickness of the osmium layer of 5.3 nm—at 200 mVs⁻¹ for the 1^{st} scan (blue trace) and the 2^{nd} scan (red trace) between 0.4 and 1.6 V, clearly indicating a significant drop in the intensity of the catalytic pre-wave at −1.08 V in the 2^{nd} scan cycle.

FIG. 55 shows optical absorption of SPMAs formed according SDAs I-III, after applying various potential biases. (Panel A) UV-vis spectra of SPMA I | Ru₄—Os₃, after applying a potential bias of 0.40 V (blue), 0.95 V (green trace), and 1.60 V (red trace) for 60 s. (Panel B) UV-vis spectra of SPMA II | Ru₃—Os₃, after applying a potential bias of −0.70 V (blue trace), 1.10 V (green trace), and 1.60 V (red trace) for 60 s. (Panel C) UV-vis spectra of SPMA III | Os₃—Ru₃, after applying a potential bias of 0.40 V (blue trace), 1.00 V (green trace), and 1.60 V (red trace) for 60 s. The black trace represents the baseline.

FIG. 56 shows (panel A) optical transmission of the ¹MLCT band, at λ=495 nm, of a SPMA I | Ru₅—Os₄ (49 nm), as a function of the voltage. The dashed red line is a sigmoidal fit (R²=0.99), with inflection points at 0.84 V (Os^{2+/3+}) and at 1.27 V (Ru^{2+/3+}) that corresponds to the half-wave potentials of complexes 1 and 2 in the SPMA. (Panel B) Derivative of the sigmoidal fit and the resulting full-width at half-maximum (fwhm).

FIG. 57 shows spectroelectrochemistry of SPMA I | Ru₄—Os₃ formed by SDA I. Optical transmission (T) of the ¹MLCT band at λ=495 nm, with a thickness of the SPMA of 29.3 nm, upon (panel A) applying double potential steps between 0.40-0.95 V (blue traces) and between 0.95-1.60 V (red traces), or (panel B) upon applying triple potential steps between 0.40, 0.95, and 1.60 V, followed by double potential steps between 0.4-1.60 V (green traces).

FIG. 58 shows spectroelectrochemistry of SPMA I | Ru₂—Os₂ formed by SDA I. Optical transmission (T) of the ¹MLCT at λ=495 nm, with a thickness of the SPMA of 11.4 nm, upon applying double potential steps between 0.40-1.60 V (blue traces) and between 0.95-1.60 V (red traces). The red trace shows the oxidation/reduction of the ruthenium centers only.

FIG. 59 shows spectroelectrochemistry of SPMAs formed by SDA II. Optical transmission of the ¹MLCT at λ=495 nm of SPMAs with (panel A) a thickness of the ruthenium layer of 5.7 nm and a thickness of the osmium layer of 6.8 nm (SPMA II | Ru₂—Os₂) and with (panel B) a thickness of the ruthenium layer of 8.0 nm and a thickness of the osmium layer of 17.6 nm (SPMA II | Ru₃—Os₃) as a function of time upon applying triple-potential steps (5 s) between 0.40, 1.00, and 1.60 V (red traces) or applying triple potential steps (5 s) between −0.70, 1.10, and 1.60 V (blue traces). Panel C shows the time dependence of the reduction of the osmium content in an SPMA with a thickness of the ruthenium layer of 8.0 nm and a thickness of the osmium layer of 17.6 nm (SPMA II | Ru₃—Os₃), upon applying triple-potential steps between −0.70, 1.10, and 1.60 V for 5 s (black traces), 10 s (red traces) and 30 s (blue traces).

FIG. 60 shows spectroelectrochemistry of SPMA II | Ru₄—Os₄. Optical transmission of the ¹MLCT at λ=495 nm of the SPMA with a thickness of the ruthenium layer of 10.7 nm and a thickness of the osmium layer of 33.0 nm upon applying triple-potential steps between −0.70, 1.10, and 1.60 V for 5 s (black traces), 10 s (red traces) and 30 s (blue traces).

FIG. 61 shows spectroelectrochemistry of SPMAs formed by SDA III. Optical transmission of ¹MLCT at λ=495 nm of SPMAs (panel A) with a thickness of the osmium layer of 3.8 nm and a thickness of the ruthenium layer of 5.0 nm (SPMA III | Os₂—Ru₂), (panel B) with a thickness of the osmium layer of 6.1 nm and a thickness of the ruthenium layer of 9.5 nm (SPMA III | Os₃—Ru₃), and (panel C) with a thickness of the osmium layer of 11.0 nm and a thickness of the ruthenium layer of 27.8 nm (SPMA III | Os₄—Ru₄), upon applying triple-potential steps at intervals of −0.70, 1.10, and 1.60 V for 5 s (black traces), 10 s (red traces), and 30 s (blue traces).

FIG. 62 shows CV of SPMA III | Os₂—Ru₂, with a thickness of the osmium layer of 3.8 nm and a thickness of the ruthenium layer of 5.0 nm, on ITO. The CVs are recorded at different scan rates: 25 (black trace), 50 (red trace), 100 (blue trace), 200 (dark cyan trace), 300 (magenta trace), 400 (dark yellow trace), 500 (navy blue trace), 600 (wine red trace), and 700 (pink trace) mVs⁻¹ (de Ruiter et al., 2013).

FIG. 63 shows a schematic representation of the stepwise coordination-based assembly. 1-based template layer on quartz, silicon, or ITO-coated glass is used for iterative solution depositions in 0.2 mM solutions of complexes 1 or 2 in THF/DMF (9:1 v/v) and in 1 mM solution of BPEB in THF. Each pyridyl-terminated interface is immersed in a 1 mM THF solution of PdCl₂(PhCN)₂ prior to the deposition of the next interface. The deposition sequence is as follows: (a) Single deposition of complex 1; (b) 0-20 depositions of BPEB; (c) Two depositions of complex 2.

FIGS. 64A-64C show (64A) UV/vis absorption spectra of a multi-component assembly on quartz. The bottom and the top grey traces are the absorption spectra of complexes 1 and 2, respectively. The black traces are the absorption spectra of BPEB, measured at each even deposition cycle. The grey arrows represent the increase in the π-π* transition and the MLCT bands at λ≈320 nm and λ≈510 nm, respectively, of complexes 1 and 2. The black arrow represents the increase in the BPEB absorption band at λ=380 nm. Inset: Absorption intensity at λ≈380 nm versus the number of BPEB deposition cycles (linear fit; R²=0.992). (64B) Ellipsometry-derived thickness versus the number of deposition cycles, measured on silicon. The grey dots represent depositions of complexes 1 and 2 (the 0^{th} deposition cycle refers to the 1-based template layer) and are not included in the fit. The black dots represent BPEB depositions (linear fit; R²=0.994). (64C) Representative XRR electron density plots as a function of the distance from the substrate surface for the following assemblies on silicon: (a) Ru₂-BPEB₄-Os₂; (b) Ru₂-BPEB₈-Os₂; (c) Ru₂-BPEB₁₂-Os₂; (d) Ru₂-BPEB₁₈-Os₂.

FIG. 65 shows absorption intensity at λ=380 nm vs. the ellipsometry-derived thickness, measured on silicon (linear fit; R²=0.994). The thickness of the 1-based domain (41.98 nm) has been subtracted from the measured thickness values to obtain the BPEB thickness.

FIG. 66 shows ellipsometry-derived thickness (▴) and XRR-derived thickness () of the following representative assemblies on silicon: Ru₂-BPEB₄-Os₂, Ru₂-BPEB₈-Os₂, Ru₂-BPEB₁₂-Os₂, and Ru₂-BPEB₁₈-Os₂.

FIG. 67 shows representative synchrotron specular XRR spectrum of the Ru₂-BPEB₄-Os₂ assembly, with a XRR-derived thickness of 8.6 nm. The red trace is a fit to the experimental data.

FIG. 68 shows representative AFM image of a 500×500 nm² scan area of the Ru₂-BPEB₁₈-Os₂ assembly (13.1 nm) on silicon with a root-mean-square roughness (Rᵣₘₛ) of 0.8 nm.

FIG. 69 shows log(I) versus V plots of the following multi-component assemblies on silicon with a homogeneous 8.6 Å oxide layer: Ru₂-BPEB₀-Os₂ (blue); Ru₂-BPEB₆-Os₂ (red); and Ru₂-BPEB₂₀-Os₂ (green). The data are averaged over 4 traces for each assembly.

FIG. 70 shows CVs of the multi-component assemblies on ITO, recorded at a scan rate of 100 mVs⁻¹, with thicknesses of: (panel A) 4.8 nm (Ru₂-BPEB₂-Os₂); (panel B) 5.9 nm (Ru₂-BPEB₄-Os₂); (panel C) 7.0 nm (Ru₂-BPEB₆-Os₂); (panel D) 10.0 nm (Ru₂—BPEB₁₂-Os₂). The redox processes are as follows: (a) Os²⁺→Os³⁺; (a′) catalytic Os²⁺→Os³⁺; (b) Ru²⁺→Ru³⁺; (c) Ru³⁺→Ru²⁺; and (d) Os³⁺→Os²⁺.

FIG. 71 shows representative CVs of a 7.0 nm-thick assembly (Ru₂-BPEB₆-Os₂) with scan rates of 50-700 mVs⁻¹ (panel A); and osmium catalytic pre-wave current (blue circles) and ruthenium anodic peak current (red circles) dependence on the scan rate (linear fits; R²=0.998 and R²=0.997, respectively) (panel B).

FIG. 72 shows CVs of the multi-component assemblies on ITO, recorded at a scan rate of 100 mVs⁻¹, with thicknesses of 9.1 nm (Ru₂-BPEB₁₀-Os₂) (panel A) and 17.6 nm (Ru₂-BPEB₂₀-Os₂) (panel B). The redox processes are the same as in FIG. 70.

FIG. 73 shows spectroelectrochemistry (SEC): in situ transmittance monitored at λ=510 nm during multiple triple-potential steps with 3 s intervals for the following assemblies on ITO: Ru₂-BPEB₀-Os₂ (panel A); Ru₂-BPEB₁₂-Os₂ (panel B). The dashed lines represent the applied potential values.

FIG. 74 shows temperature dependence of the CV of a representative assembly, Ru₂-BPEB₆-Os₂, on ITO. (Panel A) CVs recorded at a scan rate of 100 mVs⁻¹ at 20° C. (grey traces) and 40° C. (black traces). (Panel B) Os^{2+/3+} catalytic oxidative pre-wave (red circles) potential difference and (blue circles) current difference during heating-cooling cycles.

FIG. 75 shows temperature-dependent CVs of the Ru₂-BPEB₆-Os₂ assembly on ITO. (Panel A) Recorded during heating at 20° C. (light gray), 40° C. (gray), and 60° C. (black). (Panel B) Recorded during cooling at 60° C. (black), 40° C. (gray), and 20° C. (light gray). The blue arrows indicate the direction of the changes in the peak's current and potential when heated or cooled. The voltammograms were recorded at a scan rate of 100 mVs⁻¹.

FIG. 76 shows CVs of a representative assembly, Ru₂-BPEB₆-Os₂, on ITO at 20° C. without any treatment (a) and at 20° C. after heating the slide in an electrolyte solution at 60° C. for 5 minutes and immediately cooling down by transferring the slide to an electrolyte solution, kept at 20° C. (b). The voltammograms were recorded at a scan rate of 100 mVs⁻¹.

FIG. 77 shows CVs of a representative assembly, Ru₂-BPEB₆-Os₂, on ITO at given temperatures, after the following treatments: 20° C., without any treatment (black); 20° C., after heating the slide in an electrolyte solution at 60° C. for 5 minutes and immediately cooling it down by transferring the slide to an electrolyte solution, kept at 20° C. (red); 60° C., immediately after the previous measurement (blue); 20° C., immediately after the previous measurement (violet); 60° C., immediately after the previous measurement (green). The voltammograms were recorded at a scan rate of 100 mVs⁻¹.

FIG. 78 shows CVs of a representative assembly, Ru₂-BPEB₆-Os₂, on ITO using the following electrolyte concentrations (TBAPF₆ in acetonitrile): 0.02 M (green); 0.1 M (red); 0.5 M (violet). The voltammograms were recorded at a constant scan rate of 100 mVs⁻¹.

FIGS. 79A-79D show the effect of UV irradiation on the UV/vis absorption spectra of the following multi-component assemblies on ITO before (solid trace) and after (dashed trace) irradiating the slides for 40 min using Hg lamp (254 nm): Ru₂-BPEB₀-Os₂ (79A); Ru₂-BPEB₆-Os₂ (79B); Ru₂-BPEB₁₀-Os₂ (79C); and Ru₂-BPEB₁₈-Os₂ (79D). The bands at λ≈338 nm and λ2513 nm correspond to π-π* transition and the MLCT bands, respectively, of complexes 1 and 2. The band at λ=390 nm corresponds to the absorption of BPEB. Insets: CVs of the corresponding assemblies before (solid trace) and after (dashed trace) irradiation, recorded at a scan rate of 100 mVs⁻¹.

FIG. 80 shows ATR-FTIR spectra of the Ru₂-BPEB₆-Os₂ assembly on silicon before (a) and after (b) irradiating the slide for 40 min using Hg lamp (254 nm).

FIG. 81 shows UV/Vis spectra of different template layers generated on quartz. Blue, brown, black, green and orange curves correspond to TL1, TL2, TL3, TL4 and TL5, respectively.

FIG. 82 shows UV/Vis spectra of SPMA TL-[Os/Ru] grown on TL1 (panel A), TL2 (panel B), TL3 (panel C), TL4 (panel D) and TL5 (panel E) after 8 deposition steps; and Exponential correlation between the deposition steps and absorption of MLCT band at λₘₐₓ=500 nm for SPMA TL-[Os/Ru] grown upon TL1 (Δ), TL2 (∘), TL3 (□), TL4 (∇) and TL5 (⋄) (panel F).

FIG. 83 shows assembly thickness as a function of the deposition steps for SPMA TL-[Os/Ru] grown on TL1 (panel A), TL2 (panel B), TL3 (panel C) and TL5 (panel D). The film thickness was recorded by ellipsometry during film formation (Δ). In addition, slides were measured by XRR (□). Before XRR measurements, the same slides were also measured by ellipsometry (∘).

FIG. 84 shows linear correlation between the film thickness and absorption of MLCT band at λₘₐₓ=500 nm (∘) and π-π* band at λₘₐₓ=317 nm (□) for SPMA TL-[Os/Ru] grown on TL1 (panel A), TL2 (panel B), TL3 (panel C), and TL5 (panel D).

FIG. 85 shows XRR-derived electron density profile for SPMA TL-[Os/Ru] grown upon TL1 (panel A), TL2 (panel B) and TL3 (panel C) for all deposition steps. The minima around 0.8 nm correspond to the coupling layer.

FIG. 86 shows CVs on ITO of SPMA TL-[Os/Ru] recorded at 100 mV. The films were grown upon TL1 (4.1 nm), TL2 (5.4 nm), TL3 (4.3 nm), TL4, and TL5 (2.5 nm) which correspond to blue, brown, gray, orange and green voltamograms, respectively.

FIG. 87 shows oxidative peak current as a function of different scan rates of SPMA TL-[Os/Ru] grown upon TL1 (Δ), TL2 (∘), TL3 (□), TL4 (⋄), and TL5 (∇) for Os^{+2/+3} (panel A) and Ru^{+2/+3} (panel B) redox couples. The films thicknesses are 6.8 nm, 6.8 nm, 7.1 nm, and 7.5 nm for TL1, TL2, TL3 and TL5, respectively.

FIG. 88 shows ratios between osmium and ruthenium complexes as a function of deposition steps on TL1 (panel A); and fraction (%) of osmium (brown) and ruthenium (green) complexes in each deposition step (panel B). The ratios and fractions (%) are calculated in an accumulative manner for all the deposition steps.

FIG. 89 shows ratios between osmium and ruthenium complexes as a function of deposition steps grown on TL3. The ratios are calculated for each individual deposition step.

FIG. 90 shows XPS analysis of osmium and ruthenium atomic ratio for odd numbered deposition steps.

FIGS. 91A-91D show ratios between osmium and ruthenium complexes as a function of deposition steps (left panels), and fraction (%) of osmium (brown) and ruthenium (green) complexes in each deposition step (right panels), on TL1 (91A), TL2 (91B), TL4 (91C), and TL5 (91D). The ratios and fractions (%) are calculated in an accumulative manner for all the deposition steps. Os:Ru ratio on TL4 after 8 deposition steps could not be derived due to poor defined oxidation peaks.

FIG. 92 shows fractions (%) of osmium (brown) and ruthenium (green) complexes of SPMA 1-[Os/Ru] without (A) and with a blocking layer consisting of 1, 2 and 4 (B, C and D, respectively).

### DETAILED DESCRIPTION OF THE INVENTION

The device of the present invention can be described as a molecular assembly composed of two or more molecular components, e.g., the molecular components A, B and C, each composed of one or more redox active entities such as metal complexes, inorganics, organics, polymers etc., wherein the molecular components are arranged in a specific order or sequence, i.e., in a SDA. Together with the surface-interface thickness, i.e., the thickness of each layer (or molecular component) during the deposition process (usually consisting of one redox active entity), the SDA dictates the multi-component material, i.e., the overall assembly, properties, which in turn dictates the functionality of the device (solar cell, memory, battery, diode, electrochromic window etc.).

The material properties result from the SDA of molecular components A, B, and C, wherein A, B, and C are chosen from a family of redox active entities such that the separation of the oxidative peak potential between any of the molecular entities in molecular components A, B, or C, e.g., E_{oxA}−E_{oxB} or E_{oxB}−E_{oxC}, is larger than 100 mV, i.e. for any of the molecular components DEₒₓ≧100 mV. This separation simultaneously applies for the separation of the reductive peak potentials so DE_{red}≧100 mV. The total requirement therefore for a successful device is that: DEₒₓ and DE_{red}≧100 mV, wherein E_{oxA}>E_{oxB}>E_{oxC}> . . . E_{oxZ} and E_{redA}<E_{redB}<E_{redC}< . . . E_{redZ}, so that E_{1/2A}>E_{1/2B}>E_{1/2C}> . . . E_{1/2Z} (the labels A, B, C etc. are, of course, arbitrarily assigned to fulfill those conditions, so that A always has the highest oxidation potential and Z has the lowest oxidation potential).

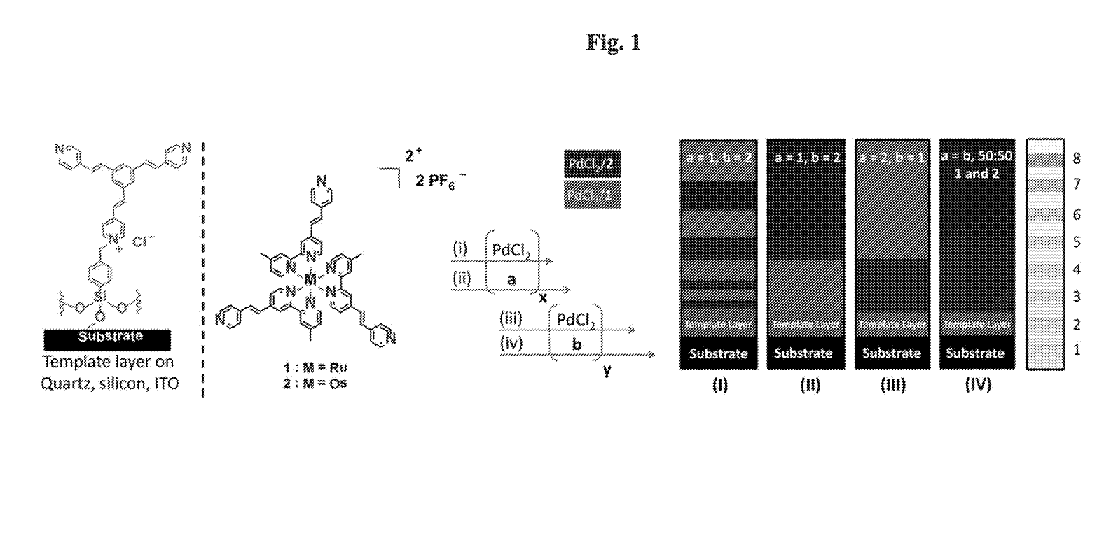

However, upon assembly of two molecular components, comprising of one or more entities, for instance, there are different possibilities in which the components can be arranged (see, e.g., FIG. 1), i.e., (I) alternating assembly of A and B; (II) successive assembly of molecular component A, followed by component B; (III) successive assembly of molecular component B, followed by A; and (IV) assembly of the molecular components from a mixture of A and B (random order of A and B in the assembly).

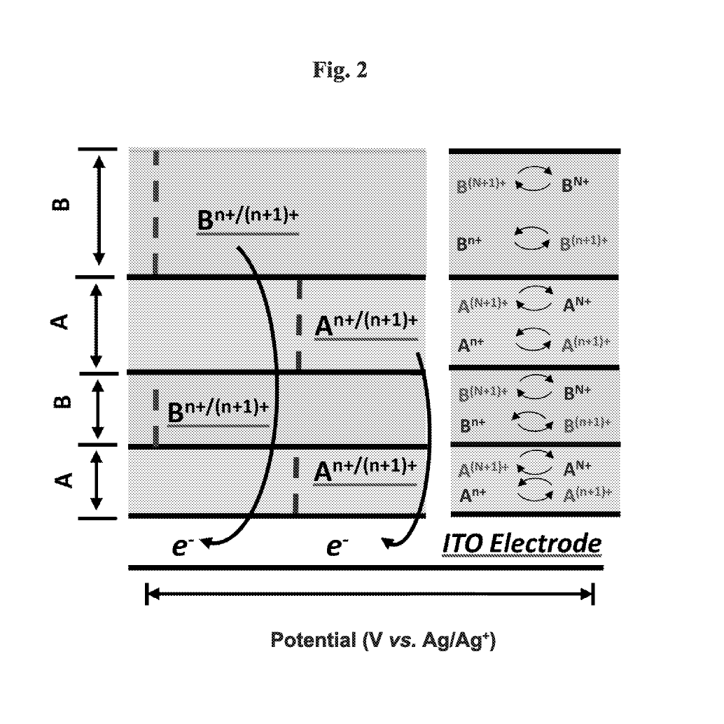

In cases wherein molecular components A and B are arranged in an alternating fashion (I), wherein the electrochemical differences of said entities in molecular components A and B is E_{oxA}−E_{oxB}≧100 mV so that E_{oxA}>E_{oxB} as defined above, the electron transfer of each one of the individual entities is not affected by the presence of the other entity, and the oxidation/reduction waves of both entities are thus visible in the CV. The order in which components A and B are alternating (ABABAB or BABABA) is not important, and can also include a third component (C) or fourth component (D) until the amount of desirable components, as long as the abovementioned requirements (alternating order; electrochemical requirements for said entities) are met. It is important to note that the thickness of the components (layer thickness) in the alternating assembly cannot exceed a certain thickness, i.e., the thickness of the molecular components once assembled in the molecular assembly cannot exceed a threshold limit, so that they become insulating (e.g., 8 nm in the case of Os and Ru system exemplified herein). The electrochemical properties in such this specific kind of assembly order (alternating; I) allow for individual addressing of the molecular component and therefore direct towards the fabrication of multi-state memory and electrochromic windows (as discussed in Study 2 hereinafter). The mechanism of electron transfer described above is shown in the FIG. 2.

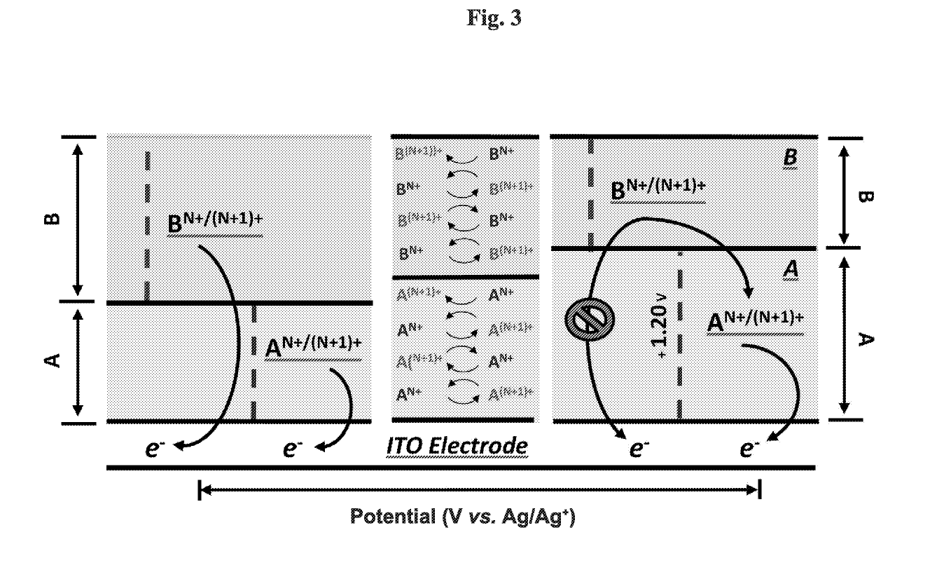

In contrast, in cases wherein molecular components A and B are arranged in a sequential order (II or III); A followed by B or alternatively B followed by A, wherein the electrochemical differences of said entities in molecular components A and B is E_{oxA}−E_{oxB}≧100 mV so that E_{oxA}≧E_{oxB} as defined above, a different electrochemical behavior is observed. If component A is assembled first followed by component B, where the thickness of component A exceeds a certain threshold (8.0 nm in case A is Ru), the electrochemical behavior is controlled solely by component A. In particular, since the entity comprising component A has an oxidation potential higher than the entity that comprises component B, and the thickness is such that component A is insulating component B from the surface, the molecular entity in component B is insulated from the surface such that no oxidation occurs when a potential of E_{oxB} is applied. However, when E_{oxA} is approached, small amounts of the entity in component A are oxidized, which in turn are able to catalytically oxidize the entire entities of component B. In such a way, the molecular entities in component A behaves as a catalytic gate for the oxidation of the entities in component B and the electron transfer occurs unidirectional. Moreover, when applying a reducing potential, since now entities in component A is reduced first, the catalytic gate is closed, such that there is no way for the entities in component B to be reduced (note: component A insulates component B from the surface). This results in charge trapping of component B on the outside. This type of behavior is of course preserved if a component C is added, as long as the entities in component C has a lower oxidation potential than that of those component A, and the assembly follows the order ABC or ACB. In short, any additional component can be added as long as the oxidation potential of the entities in the component added is lower than that of A, and the assembly order after component A has been deposited is irrelevant (e.g., ABCD or ACDB or ADBC etc. . . . should all give identical electrochemical behavior). This electrochemical behavior is specific for SDA II, results in uni-molecular current flow with charge trapping, and is good for molecular diodes, solar cells, and battery technology. The mechanism is shown in FIG. 3. It should be noted that in cases component A is below the threshold thickness (e.g., <8.0 nm in case A is Os or Ru), electron transfer occurs as in SDA I. A more thorough investigation in which an organic spacer is used to investigate the electron transfer between the metal centers is described in Study 4 hereinafter.

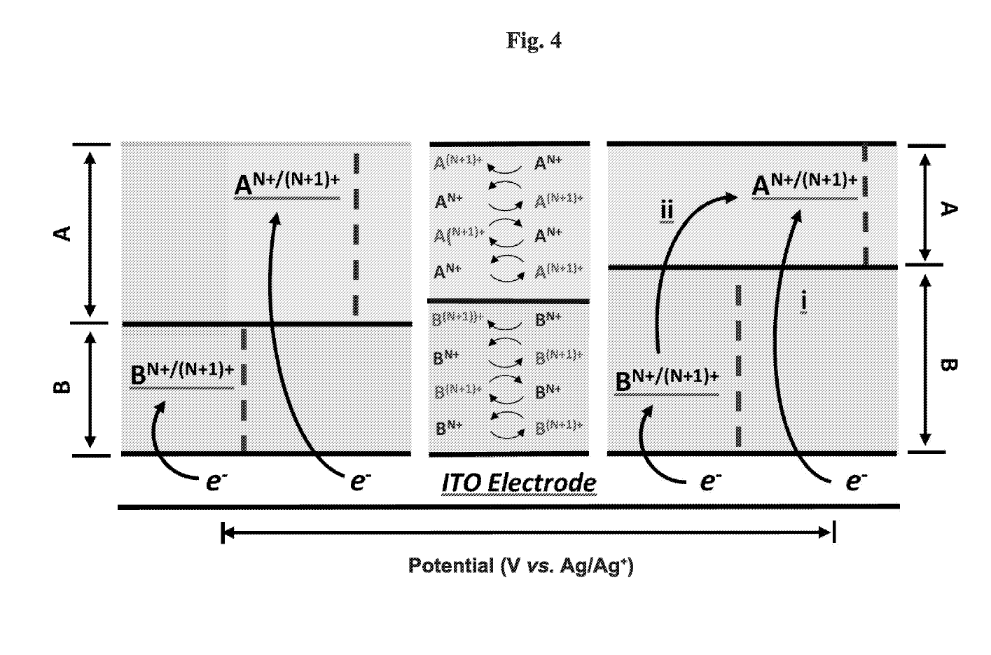

However, in cases molecular component B is first assembled followed by molecular component A, two distinct electron-transfer pathways (i and ii) are observed depending on the surface-interface thickness of molecular component B. When the thickness of component B is sufficiently low (e.g., <2.6 nm in the case of Os and Ru), the electron transfer occurs exactly as described for an alternating assembly, and direct oxidation of the entities in components A and B by the electrode is possible. At intermediate thickness of component B (e.g., 3.6-6.1 nm in the case of Os and Ru), the oxidation of the molecular component A is more difficult due to the interference (insulating nature) of molecular component B and is directly attributed to the fact that electron transfer from the entities in components A and B; A_{red} to Bₒₓ is thermodynamically unfavourable. The thermodynamic and kinetic effects of electron transfer at the interface of molecular components A and B is even more pronounced, when the molecular assembly is reduced. Scanning in the negative direction, two distinct pathways (i and ii) are observed, in which the electrode is able to reduce the molecular entities in component A. For pathway (i), at low scan rates (<100 mVs⁻¹) the electron transfer occurs similarly in assembly sequence I. When the scan rate is increased, a second pathway (ii) is preferred. A typical characteristic of pathway (ii) is that at the onset of the reduction of the molecular entities in component B, the reduction from Bₒₓ→*B_{red} starts to occur, which forms a conductive path to catalytically reduce the remaining entities in component A; Aₒₓ→A_{red}, i.e., the Aₒₓ that has not yet been reduced by means of pathway (i). Since the reduction by pathway (i) occurs at a higher potential than that of pathway (ii), there is a temporary charge trapping. In the last stage, the surface-interface thickness of component B exceeds a certain threshold (e.g., 11 nm in case of Os and Ru), and at this thickness, molecular component A is completely isolated from the surface, and its electrochemical oxidation/reduction wave are completely absent in the CV. These electrochemical properties are specific for SDA III, and might be useful for electrochromic materials and battery technology. Although more than two molecular components can be used, it is predicted that similar results are obtained as long as molecular entities in component C or D have a higher oxidation potential than B, although the exact behavior of such multi-component films is difficult to estimate for this specific assembly technique. The mechanism underlying electron transfer in SDA III is shown in FIG. 4 (note that for SDA II and SDA III, the thickness of the outer components A and B are irrelevant and are unlimited).

In the last assembly technique (SDA IV), molecular components A and B are homogeneously mixed in a solution (50:50), and deposited from this solution. In this case there is a random distribution throughout the assembly of the entities that comprises components A and B, and not unlike previous examples more distinct “layers”. The electrochemical behavior is such that both molecular entities in components A and B are electrochemically addressable in the assembly. The behavior is identical to that as described in FIG. 2, besides that the distribution the entities in components A and B is random. Similarly, these compounds are useful for electrochromic materials. Interestingly, in these assemblies, the ratio between entities in components A and B in the final assembly is a function of the number of deposition steps, i.e., upon each deposition step, the ratio between entities in components A and B increases linearly (this effect is also called the template layer effect) as discussed in detail in Study 5 hereinafter.

As shown in the various studies described herein, the SDA of the device of the present invention can be addressed optically, magnetically, electrochemically, etc.

In one aspect, the present invention thus provides a device comprising a substrate having an electrically conductive surface and carrying an assembly of one or more molecular components, each molecular component having a thickness and an oxidative or reductive peak potential, and comprising one or more entities each independently is a redox-active compound,

provided that:
(i) wherein said device comprises one molecular component, said component comprises more than one of said entities, and the difference between the oxidative- and/or reductive peak potentials of each one of said entities is larger than 100 mV; and
(ii) wherein said device comprises more than one molecular components, said components are assembled on said electrically conductive surface in a random, alternate or successive order, each one of said components comprises one or more of said entities, and the difference between the oxidative- and/or reductive peak potentials of two of said entities comprised within said components is larger than 100 mV,

wherein exposure of said device, when comprising one molecular component, to a potential change, causes electron transfer, which results in an electrochemical signature which can be read out electrically, optically, magnetically, or by conductivity measurements; and exposure of said device, when comprising more than one molecular components, to a potential change, causes (a) reversible electron transfer; (b) oxidative catalytic electron transfer with charge trapping; (c) reductive catalytic electron transfer; or (d) blocking of the electron transfer, dependent on the order of said components and the thickness of each one of said components, which results in an electrochemical signature which can be read out electrically, optically, magnetically, or by conductivity measurements.

As defined above, in devices according to the present invention, when comprising one molecular component comprising more than one, e.g., two, redox-active compounds, i.e., entities, the difference between the oxidative- and/or reductive peak potentials of each one of said entities is larger than 100 mV. It should also be understood that in devices according to the present invention, when comprising more than one molecular components each comprising a sole entity, i.e., redox-active compound, a difference as defined above between the oxidative- and/or reductive peak potentials of two of said redox-active compounds, in fact, reflects the difference between the oxidative- and/or reductive peak potentials of two of the molecular components. Similarly, in such devices when comprising more than one molecular components each comprising more than one redox-active compounds, the redox-active compounds whose oxidative- and/or reductive peak potentials are compared can be any couple of redox-active compounds no matter whether both of these compounds are comprised within the same molecular component or one of them is comprised within one of the molecular components and the other one is comprised within another one of the molecular components, and the difference between the oxidative- and/or reductive peak potentials of those redox-active compounds causes a difference between the oxidative- and/or reductive peak potentials of two of the molecular components.

In certain embodiments, the substrate comprised within the device of the invention is hydrophilic, hydrophobic or a combination thereof.

In particular such embodiments, the substrate includes a material selected from glass, a doped glass, ITO-coated glass, silicon, a doped silicon, Si(100), Si(111), SiO₂, SiH, silicon carbide mirror, quartz, a metal, metal oxide, a mixture of metal and metal oxide, group IV elements, mica, a polymer such as polyacrylamide and polystyrene, a plastic, a zeolite, a clay, wood, a membrane, an optical fiber, a ceramic, a metalized ceramic, an alumina, an electrically-conductive material, a semiconductor, steel or a stainless steel. In more particular such embodiments, the substrate is in the form of beads, microparticles, nanoparticles, quantum dots or nanotubes, preferably wherein the substrate is optically transparent to the ultraviolet (UV), infrared (IR), near-IR (NIR) and/or visible spectral ranges.

In certain embodiments, the redox-active compounds composing the molecular components of the device of the present invention each independently is a metal, modified nanoparticle or quantum dot, organometallic compound, metal-organic, organic or polymeric material, inorganic material, metal complex, organic molecule, or a mixture thereof.

Specific examples of such metals include, without being limited to, transition metals such as Os, Ru, Fe, Pt, Pd, Ni, Ir, Rh, Co, Cu, Re, Tc, Mn, V, Nb, Ta, Hf, Zr, Cr, Mo, W, Ti, Sc, Ag, Au or Y; lanthanides such as La, Ce, Pr, Nd, Pm, Sm, Eu, Gd, Tb, Dy, Ho, Er, Tm, Yb or Lu; actinides such as Ac, Th, Pa, U, Np, Pu, Am, Cm, Bk, Cf, Es, Fm, Md, No or Lr; or main group element metals such as Zn, Ga, Ge, Al, Cd, In, Sn, Sb, Hg, Tl or Pb.

In certain particular such embodiments, the redox-active compounds composing the molecular components of the device each independently is a tris-bipyridyl complex or terpyridyl complex of said transition metal, e.g., a tris-bipyridyl complex or terpyridyl complex of ruthenium, osmium, iron or cobalt, a complex of a porphyrin, corrole, or chlorophyll with said transition metal. The term “pyridyl complex”, as used, herein, refers to a metal having one or more, e.g., two, three, or four, pyridyl ligands coordinated therewith.

More particular such embodiments are those wherein the redox-active compounds composing the molecular components of the device each independently is a tris-bipyridyl complex of the general formula I:

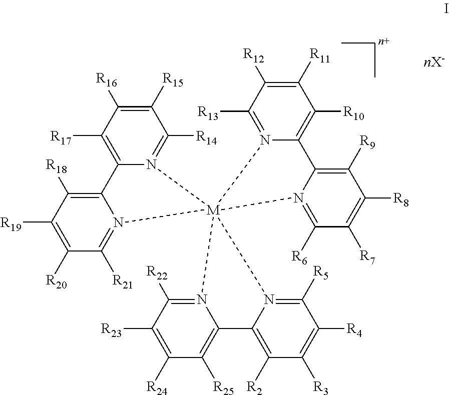

wherein

M is a transition metal as defined above;

n is the formal oxidation state of the transition metal, wherein n is 0-4;

X is a counter anion selected from Br⁻, Cl⁻, F⁻, I⁻, PF₆⁻, BF₄⁻, OH⁻, ClO₄⁻, SO₃⁻, SO₄⁻, CF₃COO⁻, CN⁻, alkylCOO⁻, arylCOO⁻, or a combination thereof;

R₂ to R₂₅ each independently is selected from hydrogen, halogen, hydroxyl, azido, nitro, cyano, amino, substituted amino, thiol, C₁-C₁₀ alkyl, cycloalkyl, heterocycloalkyl, haloalkyl, aryl, heteroaryl, alkoxy, alkenyl, alkynyl, carboxamido, substituted carboxamido, carboxyl, protected carboxyl, protected amino, sulfonyl, substituted aryl, substituted cycloalkyl, substituted heterocycloalkyl, or group A, wherein at least two, i.e., two, three, four, five or six, preferably three, of said R₂ to R₂₅ each independently is a group A:

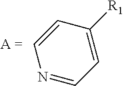

wherein A is linked to the ring structure of the compound of general formula II via R₁; and R₁ is selected from cis/trans C═C, C≡C, N═N, C═N, N═C, C—N, N—C, alkylene, arylene or a combination thereof; and any two vicinal R₂-R₂₅ substituents, together with the carbon atoms to which they are attached, may form a fused ring system selected from cycloalkyl, heterocycloalkyl, heteroaryl or aryl, wherein said fused system may be substituted by one or more groups selected from C₁-C₁₀ alkyl, aryl, azido, cycloalkyl, halogen, heterocycloalkyl, alkoxy, hydroxyl, haloalkyl, heteroaryl, alkenyl, alkynyl, nitro, cyano, amino, substituted amino, carboxamido, substituted carboxamido, carboxyl, protected carboxyl, protected amino, thiol, sulfonyl or substituted aryl; and said fused ring system may also contain at least one heteroatom selected from N, O or S.

The term “oxidation state”, as used herein, refers to the electrically neutral state or to the state produced by the gain or loss of electrons to an element, compound or chemical substituent/subunit. In a preferred embodiment, this term refers to states including the neutral state and any state other than a neutral state caused by the gain or loss of electrons (reduction or oxidation).

The term “alkyl”, as used herein, typically means a straight or branched hydrocarbon radical having preferably 1-10 carbon atoms, and includes, e.g., methyl, ethyl, n-propyl, isopropyl, n-butyl, isobutyl, sec-butyl, tert-butyl, n-pentyl, isopentyl, 2,2-dimethylpropyl, n-hexyl, n-heptyl, n-octyl, n-nonyl, n-decyl and the like. The alkyl may further be substituted. The term “alkylene” refers to a linear divalent hydrocarbon chain having preferably 1-10 carbon atoms and includes, e.g., methylene, ethylene, propylene, butylene, pentylene, hexylene, octylene and the like.

The terms “alkenyl” and “alkynyl” refer to a straight or branched hydrocarbon radical having preferably 2-10 carbon atoms and containing one or more double or triple bond, respectively. Non-limiting examples of such alkenyls are ethenyl, 3-buten-1-yl, 2-ethenylbutyl, 3-octen-1-yl, and the like.

The term “cycloalkyl” typically means a saturated aliphatic hydrocarbon in a cyclic form (ring) having preferably 3-10 carbon atoms. Non-limiting examples of such cycloalkyl ring systems include cyclopropyl, cyclobutyl, cyclopentyl, cyclohexyl, cyclodecyl and the like. The cycloalkyl may be fused to other cycloalkyls, such in the case of cis/trans decalin. The term “heterocycloalkyl” refers to a cycloalkyl, in which at least one of the carbon atoms of the ring is replaced by a heteroatom selected from N, O or S.

The term “alkylCOO” refers to an alkyl group substituted by a carboxyl group (—COO—) on any one of its carbon atoms. Preferably, the alkyl has 1-10 carbon atoms, more preferably CH₃COO⁻.

The term “aryl” typically means any aromatic group, preferably having 6-14 carbon atoms such as phenyl and naphtyl. The aryl group may be substituted by any known substituents. The term “arylCOO” refers to such a substituted aryl, in this case being substituted by a carboxylate group.

The term “heteroaryl” refers to an aromatic ring system in which at least one of the carbon atoms is replaced by a heteroatom selected from N, O or S. Non-limiting examples of heteroaryl include pyrrolyl, furyl, thienyl, pyrazolyl, imidazolyl, oxazolyl, isoxazolyl thiazolyl, isothiazolyl, pyridyl, 1,3-benzodioxinyl, pyrazinyl, pyrimidinyl, 1,3,4-triazinyl, 1,2,3-triazinyl, 1,3,5-triazinyl, thiazinyl, quinolinyl, isoquinolinyl, benzofuryl, isobenzofuryl, indolyl, imidazo[1,2-a]pyridyl, pyrido[1,2-a]pyrimidinyl, benz-imidazolyl, benzthiazolyl and benzoxazolyl.

The term “halogen” includes fluoro, chloro, bromo, and iodo. The term “haloalkyl” refers to an alkyl substituted by at least one halogen.

The term “alkoxy” refers to the group —OR, wherein R is an alkyl group. The term “azido” refers to —N₃. The term “nitro” refers to —NO₂ and the term “cyano” refers to —CN. The term “amino” refers to the group —NH₂ or to substituted amino including secondary, tertiary and quaternary substitutions wherein the substituents are alkyl or aryl. The term “protected amino” refers to such groups which may be converted to the amino group. The term “carboxamido” refers to the group —CONH₂ or to such a group substituted, in which one or both of the hydrogen atoms is/are replaced by a group independently selected from an alkyl or aryl.

The term “carboxyl” refers to the group —COOH. The term “protected carboxyl” refers to such groups which may be converted into the carboxyl group, e.g., esters such as —COOR, wherein R is an alkyl group or an equivalent thereof, and others which may be known to a person skilled in the art of organic chemistry.

The expression “any two vicinal R₂-R₂₅ substituents” refers to any two substituents on the pyridine rings, being ortho to one another. The expression “fused ring system” refers to at least two rings sharing one bond, such as in the case of quinolone, isoquinoline, 5,6,7,8-tetrahydroisoquinoline, 6,7-dihydro-5H-cyclopenta[c]pyridine, 1,3-dihydrothieno[3,4-c]pyridine, 1,3-dihydro furo[3,4-c] pyridine, and others. The fused ring system contains at least one pyridine ring, being the ring of the compound of general formula I and another ring being formed by the ring closure of said any two vicinal R₂-R₂₅ substituents. The said another ring may be saturated or unsaturated, substituted or unsubstituted and may be heterocylic.

Specific examples of tris-bipyridyl complexes of the general formula I are those wherein n is 2; X is a counter anion as defined above, i.e., Br⁻, Cl⁻, F⁻, I⁻, PF₆⁻, BF₄⁻, OH⁻, ClO₄⁻, SO₃⁻, SO₄⁻, CF₃COO⁻, CN⁻, alkylCOO⁻, arylCOO⁻, or a combination thereof; R₂, R₄ to R₇, R₉, R₁₀, R₁₂ to R₁₅, R₁₇, R₁₈, R₂₀ to R₂₃ and R₂₅ each is hydrogen; R₃, R₁₁ and R₁₉ each is methyl; and R₈, R₁₆ and R₂₄ each is A, wherein R₁ is C═C. Particular such complexes exemplified herein are those wherein M is Ru, Os or Co; and X is PF₆⁻, i.e., tris[4′-methyl-4-(2-(4-pyridyl)ethenyl)-2,2′-bipyridine]ruthenium(II)[bis(hexafluorophosphate)], tris[4′-methyl-4-(2-(4-pyridyl)ethenyl)-2,2′-bipyridine]osmium(II)[bis(hexafluorophosphate)], tris[4′-methyl-4-(2-(4-pyridyl)ethenyl)-2,2′-bipyridine]cobalt(II)[bis(hexafluorophosphate)], herein identified compounds (or complexes) 1, 2 and 4, respectively, of the formulas:

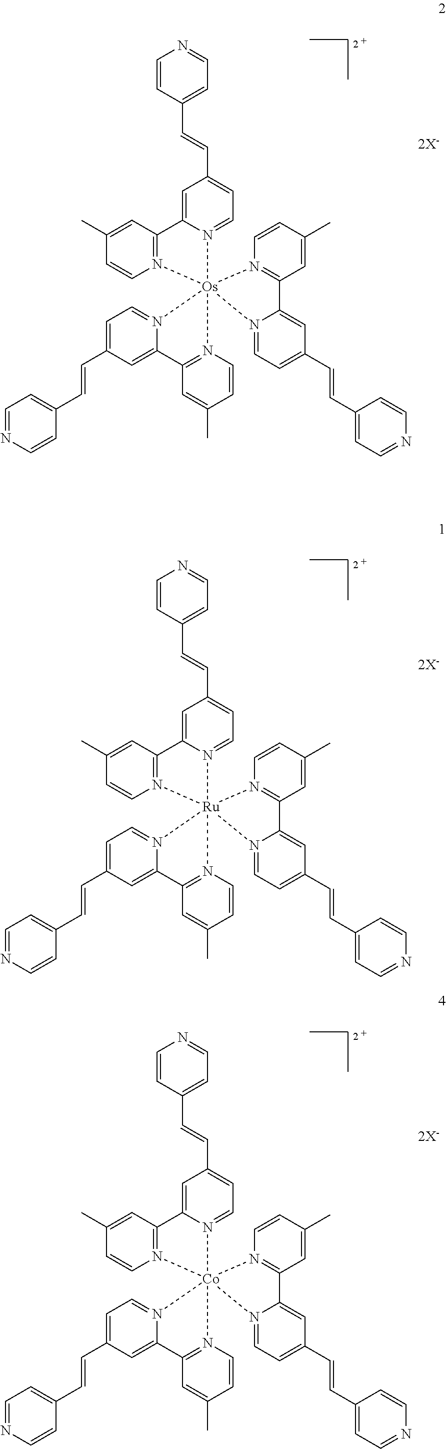

The various tris-bipyridyl complexes of the general formula I described herein can be prepared by any suitable method or technique known in the art, e.g., as described in Study 1 hereinafter (additional data may be found in Mentes and Singh, 2013).

In other particular such embodiments, the redox-active compounds composing the molecular components of the device each independently is an organic molecule, and said organic molecule is a thiophene, quinone, porphyrin such as those described in detail in International Patent Application No. PCT/IL2013/050584, corrole, chlorophyll, a vinylpyridine derivative such as 1,3,5-tris(4-ethenylpyridyl)benzene (herein identified compound 3) and 1,4-bis[2-(4-pyridyl)ethenyl]benzene (herein identified BPEB or compound 6), a pyridylethylbenzene derivative such as 1,3,5-tris(2-(pyridin-4-yl)ethyl)benzene (herein identified compound 5), or a combination thereof.

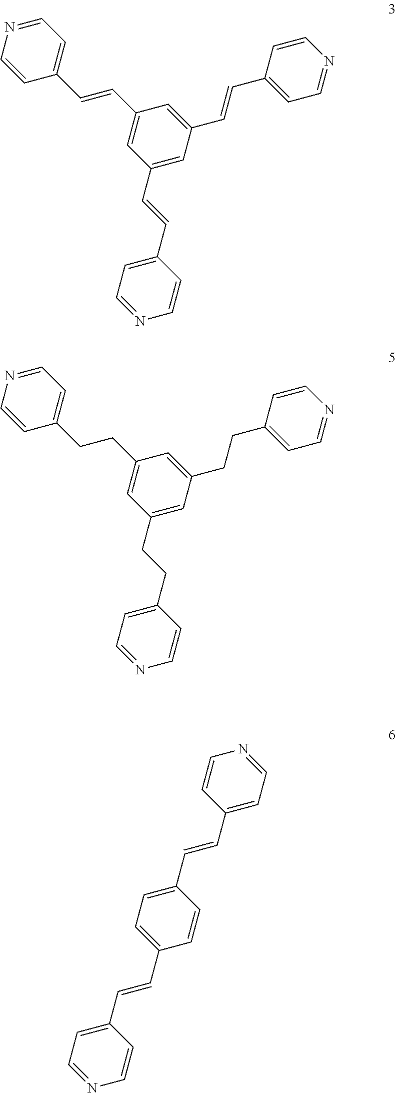 [SMILES: C(=C\c1cc(/C=C/c2ccncc2)cc(/C=C/c2ccncc2)c1)/c1ccncc1 ; c1cc(CCc2cc(CCc3ccncc3)cc(CCc3ccncc3)c2)ccn1 ; C(=C\c1ccc(/C=C/c2ccncc2)cc1)/c1ccncc1]

Compounds such as compounds 3, 5 and 6 can be prepared by any suitable method or technique known in the art, e.g., as described in Studies 1 and 4 hereinafter.

In further particular such embodiments, the redox-active compounds composing the molecular components of the device each independently is an organic or metal-organic material, and said organic or metal-organic material is selected from (i) viologen (4,4′-bipyridylium salts) or its derivatives such as, without being limited to, methyl viologen (MV); (ii) azol compounds such as, without limiting, 4,4′-(1E,1′E)-4,4′-sulfonylbis(4,1-phenylene)bis(diazene-2,1-diyl)-bis(N,N-dimethylaniline); (iii) aromatic amines; (iv) carbazoles; (v) cyanines; (vi) methoxybiphenyls; (vii) quinones; (viii) thiazines; (ix) pyrazolines; (x) tetracyanoquinodimethanes (TCNQs); (xi) tetrathiafulvalene (TTF); (xii) metal coordination complex wherein said complex is [M^{II}(2,2′-bipyridine)₃]²⁺ or [M^{II}(2,2′-bipyridine)₂(4-methyl-2,2′-bipyridine-pyridine]²⁺, wherein said M is iron, ruthenium, osmium, nickel, chromium, copper, rhodium, iridium or cobalt; or a polypyridyl metal complex selected from tris(4-[2-(4-pyridyl)ethenyl]-4′-methyl-2,2′-bipyridine osmium(II) bis(hexafluorophosphate), tris 4-[2-(4-pyridyl)ethenyl]-4′-methyl-2,2′-bipyridine cobalt(II) bis(hexafluorophosphate), tris(4-[2-(4-pyridyl)ethenyl]-4′-methyl-2,2′-bipyridine)ruthenium(II)bis-(hexafluorophosphate), bis(2,2′-bipyridine)[4′-methyl-4-(2-(4-pyridyl)ethenyl)-2,2′-bipyridine]osmium(II) [bis(hexafluorophosphate)/di-iodide], bis(2,2′-bipyridine)[4′-methyl-4-(2-(4-pyridyl)ethenyl)-2,2′-bipyridine]ruthenium(II) [bis(hexafluorophosphate)/di-iodide], bis(2,2′-bipyridine) [4′-methyl-4-(2-(4-(3-propyl trimethoxysilane)pyridinium)ethenyl)-2,2′-bipyridine]osmium(II) [tris(hexafluorophosphate)/tri-iodide], or bis(2,2′-bipyridine) [4′-methyl-4-(2-(4-(3-propyl trimethoxysilane)pyridinium)ethenyl)-2,2′-bipyridine]ruthenium(II)[tris(hexafluorophosphate)/tri-iodide]; (xiii) metallophthalocyanines or porphyrins in mono, sandwich or polymeric forms; (xiv) metal hexacyanometallates; (xv) dithiolene complexes of nickel, palladium or platinum; (xvi) dioxylene complexes of osmium or ruthenium; (xvii) mixed-valence complexes of ruthenium, osmium or iron; or (xviii) derivatives thereof.

In still further particular such embodiments, the redox-active compounds composing the molecular components of the device each independently is an inorganic material, and said inorganic material is tungsten oxide, iridium oxide, vanadium oxide, nickel oxide, molybdenum oxide, titanium oxide, manganese oxide, niobium oxide, copper oxide, tantalum oxide, rhenium oxide, rhodium oxide, ruthenium oxide, iron oxide, chromium oxide, cobalt oxide, cerium oxide, bismuth oxide, tin oxide, praseodymium, bismuth, lead, silver, lanthanide hydrides (LaH₂/LaH₃), nickel doped SrTiO₃, indium nitride, ruthenium dithiolene, phosphotungstic acid, ferrocene-naphthalimides dyads, organic ruthenium complexes, or any mixture thereof.

In yet further particular such embodiments, the redox-active compounds composing the molecular components of the device each independently is a polymeric material, and said polymeric material is a conducting polymer such as a polypyrrole, a polydioxypyrrole, a polythiophene, a polyselenophene, a polyfuran, poly(3,4-ethylenedioxythiophene), a polyaniline, a poly(acetylene), a poly(p-phenylene sulfide), a poly(p-phenylene vinylene) (PPV), a polyindole, a polypyrene, a polycarbazole, a polyazulene, a polyazepine, a poly(fluorene), a polynaphthalene, a polyfuran, a metallopolymeric film based on a polypyridyl complex or polymeric viologen system comprising pyrrole-substituted viologen pyrrole, a disubstituted viologen, N,N′-bis(3-pyrrol-1-ylpropyl)-4,4′-bipyridilium, or a derivative thereof.

In still further particular such embodiments, the redox-active compounds composing the molecular components of the device each independently is an electrochromic compound.

The molecular components of the device of the present invention may be formed, e.g., deposited, on the electrically conductive surface by any suitable technique known in the art, e.g., by the layer-by-layer deposition technique exemplified herein, which enables incorporation of multiple components in one assembly by depositing different type of molecules in each deposition step. Other suitable techniques may include, without being limited to, physical/chemical vapor deposition (PVD/CVD), halogen bonding, spin coating, dip coating, and spray coating (Shirman et al., 2008; Decher, Gero, 2012, Multilayer thin films—sequential assembly of nanocomposite materials, vol 2. Weinheim, Germany: Wiley-VCH).

According to the present invention, exposure of a device as defined above, when comprising one molecular component, to a potential change, causes electron transfer, which results in an electrochemical signature which can be read out electrically, optically, magnetically, or by conductivity measurements; and exposure of a device as defined above, when comprising more than one molecular components, to a potential change, causes (a) reversible electron transfer; (b) oxidative catalytic electron transfer with charge trapping; (c) reductive catalytic electron transfer; or (d) blocking of the electron transfer, dependent on the order of said components and the thickness of each one of said components, which results in an electrochemical signature which can be read out electrically, optically, magnetically, or by conductivity measurements.

In certain embodiments, said electrical read-out is carried out by an electrochemical technique such as cyclic voltammetry (CV), differential pulse voltammetry (DPV), current-voltage changes, and conductivity changes; and said optical read-out is carried out in the UV, IR, NIR, or visible region or by fluorescence spectroscopy.

In Study 1 hereinafter, four different types of interfaces were demonstrated with two molecular entities, 1 and 2. As a result of the applied SDA, different electrochemical behavior was observed for all four SPMAs. Successive deposition of the molecular entities 1 and 2, resulted in the occurrence of catalytic pre-waves that oxidized/reduced the outer layer of the SPMA, depending on which entity was deposited first. If Ru was deposited first (SPMA II | Ruₓ—Os_{y}), catalytic oxidation of the outer Os layer was observed, provided that the thickness of the Ru layer exceeded 8.0 nm. However, instead of this thermodynamic effect, a kinetic effect was observed when the Os was deposited first (SPMA III | Osₓ—Ru_{y}). The two observed pathways for electron transfer to the outer Ru layer were strongly dependent on the scan rate and the thickness of the Os layer. Assembling the molecular entities in an alternating fashion (SPMA I | Ruₓ—Os_{y}), or from a mixture of 1 and 2 (SPMA IV | Ru—Os)_{x+y}), however, resulted in a reversible oxidation/reduction process of both metal centers independent of the SPMA thickness. This study unequivocally demonstrates that upon changing the SDA strategy and assembly thickness, the electrochemical properties of SPMAs can be controlled. To this end, the SDA concept is unlikely to be limited only to interfaces; it might also be applied in multi-component systems in solution, including self-sorting assemblies and molecular networking (Campbell et al., 2010; Deng et al., 2010; Northrop et al., 2009; Sknepnek et al., 2008; Lehn, 2002).

In Study 2, functional SPMAs incorporating two different, yet very similar, entities 1 and 2 were constructed using a bi-molecular assembly protocol. The well-separated half-wave potentials between the Os and Ru complexes allowed three well-defined oxidation states of the SPMA. The optical properties of the SPMA can be controlled by applying different potential biases and allowed us to address these states for the formation of binary and ternary memory. Since three physical distinguishable states are demonstrated, our ternary memory set-up is not dependent on the assembly thickness, as similar switching behavior is demonstrated for various thicknesses. In addition, two different types of memory can be read-out in a dual way; resulting in the simultaneous operation of binary and ternary memory. Moreover, these materials can also find applications in related areas, especially in the field of molecular logic (Avellini et al., 2012; Remón et al., 2011; Andréasson et al., 2011; de Ruiter and van der Boom, 2011a; de Ruiter and van der Boom, 2011b; de Silva, 2011; Amelia et al., 2010; Andreasson and Pischel, 2010). With retention times of several minutes, the SPMAs are within the needed requirements for mimicking the output behavior of flip-flops and related logic circuits operating on base 3 (e.g., flip-flap-flops) (Lee et al., 2011). Therefore, this molecular approach, based on the separate addressing of molecular entities in a SPMA, unequivocally demonstrates the exciting possibilities of information processing and storage in a ternary platform.

In Study 3, three different SPMAs were obtained according to the SDA shown in FIG. 1. All the SPMAs displayed an exponential growth in their film thickness and in the optical properties of the π-π* and MLCT bands. Even though the three SPMAs were formed using different SDAs, their optical and structural properties are nearly identical. XRR analysis of the SPMAs revealed a similar electron density and surface roughness. The main difference between the SPMAs is in the internal composition, e.g., the distribution of the Os and Ru entities 1 and 2. The SPMAs demonstrate homogeneous layers that consist only of one type of entity (e.g. the metal complexes). The formation of these layers is a direct result of SDA in combination with a high stability of said entities (no lateral diffusion upon incorporation) and a low surface roughness. Only at the Os|Ru or Ru|Os interface, some intermixing of the said molecular entities might occur. For an alternating assembly sequence (SDA I), XPS revealed alternating layers comprising of the Os and Ru entities, according to the assembly sequence. Since for SDA I, the individual components do not exceed the threshold thickness of 8.0 nm, reversible electrochemical behavior is observed for both entities. The well-separated oxidation potentials of the Ru and Os entities 1 and 2 allow for individual addressing of both type of entities, which is beneficial for multi-state memory (de Ruiter et al., 2010a; de Ruiter et al., 2010b). For SDA II and III this is not the case due to communication among the entities that comprises the molecular components. XPS analysis showed two distinct layers of components containing either the Os or Ru entity. The presence of a sufficiently thick initial layer of Ru (8.0 nm) or Os (6.0 nm) results in catalytic electron transfer. The profound changes in the electrochemistry and spectroelectrochemistry upon changing the thickness of Ru and Os layers, together with the applied SDA highlights the importance of this work. These obtained results unequivocally demonstrated that the sequence in which molecular components comprising of single entities (Os or Ru) are assembled can have important consequences for the material properties or other emerging systems where SDA is of critical importance (Deng et al., 2010; Lehn, 2002; Sknepnek et al., 2008).

In Study 4, sandwich-like multi-component assemblies were generated. The lengthwise increasing intermediate component containing the BPEB entity displayed a linear growth in its optical properties and thickness during formation. XRR analysis provided an insight about the internal structure and sequence, which confirmed the sandwich-like structure with a low electron density organic chromophore component confined by two high electron density redox-active components containing the Os or Ru entity. Additionally, gradual transitions between the different components at the Ru|BPEB and BPEB|Os interfaces were observed. The electrochemical properties of the assemblies are governed by a number of variables. The primary route to control these properties was by changing the thickness of the component containing the BPEB entity. Since each BPEB deposition cycle contributes 1.1 nm on average, a delicate tuning of the electrochemical profile was achieved. At low thickness of the BPEB containing component thicknesses both the Os and Ru entities could be addressed individually by the ITO electrode, which is applicable for multi-state memory devices. Upon increasing the thickness, the 2-based top domain became less and less electrochemically accessible due to its distance from the electrode. At the same time, an alternative two-step pathway for electron transfer from the top Os containing component was generated. In this pathway, catalytic amounts of the surface-adjacent Ru entities play an active role in the electron transfer process. This metal-mediated electron transfer restricts the current flow directionality, which results in current rectification. And finally, above a certain threshold thickness, an isolation of the Os entities was achieved. An additional degree of control over the electrochemical properties of our assemblies was demonstrated by subjecting the already-formed assemblies to different environmental conditions. Electrochemical reversibility could be partially to fully restored by heating the assemblies and by increasing the supporting electrolyte concentration. The importance of the internal structure in determining the electrochemical properties and the dynamic nature of the assemblies was demonstrated by two individual methods. First, a prolonged heating of the assemblies resulted in structural changes that have led to a more electrochemically reversible system, and second, a prolonged UV irradiation of the assemblies resulted in a photochemical reaction of the BPEB entities, producing substantially different assemblies in terms of the molecular structure, which had a pronounced effect on their electrochemical properties. Such photoreactions in monolayers have been studied extensively. The ability to carry out this type of a reaction in our multilayered architectures implies on a high degree of internal order since a proper alignment and specific distances between the reacting species are of mandatory importance.

Study 5 demonstrates that molecular composition of binary assemblies consisting of polypyridyl entities having the same ligands can be significantly different from the equimolar mixture solution ratio by constructing the assemblies on pre-modified surfaces. The bare surfaces were modified with a template layer composed of organic or organometallic molecules. The assemblies were constructed by alternate binding of PdCl₂ and mixture of the Os and Ru entities. It is known that pyridine-derivatives bind to PdCl₂ in a trans-configuration. The binary assemblies were composed of different combination of Os and Ru polypyridyl entities, which are both redox-active and therefore allow the determination of the molecular assembly composition using electrochemistry. The ratio of the entities in the in each assembly was varied depending on the constructed template layer. Assemblies generated on template layer consisted of organometallic complexes or non-planar organic molecules displayed a constant ratio of the entities upon increasing the film thickness. In contrast, a unique behavior of the entity ratio was observed when the assemblies were constructed on a template layer composed of planar organic molecules. These assemblies exhibited an increase of Os/Ru ratio upon increasing the thickness of the assembly. The assemblies presented in this work have an advantage over other multicomponent assemblies as they composed of redox-active entities. As a result, the binding behavior of the molecular entities can be followed using a simple method such as electrochemistry. In general, assemblies with multiple entities are good candidate systems for studying the self-assembly process of molecules on surfaces due to the molecules binding competition. The competition between the entities enables us to understand better which parameters control the self-assembly process of molecules on surfaces.

In certain embodiments, the device of the present invention, in any one of the configurations defined above, comprises a substrate having an electrically conductive surface and carrying an assembly of one molecular component.

Particular such devices are those wherein said molecular component comprises two or more, preferably two, entities each independently as defined above. Specific such devices are those wherein each one of said entities independently is selected from the herein identified compounds 1, 2, 3, 4, 5 or 6, preferably wherein one of said entities is compound 1, and another one of said entities is compound 2, 3, 4, 5 or 6; one of said entities is compound 2, and another of said entities is compound 3, 4, 5 or 6; one of said entities is compound 3, and another of said entities is compound 4, 5 or 6; one of said entities is compound 4, and another of said entities is compound 5 or 6; or one of said entities is compound 5, and another of said entities is compound 6. More particular such devices are those wherein the molar ratio between said entities is in a range of 1:1 to 1:10.

In other embodiments, the device of the present invention, in any one of the configurations defined above, comprises a substrate having an electrically conductive surface and carrying an assembly of more than one molecular component.

In certain particular such embodiments, the device of the present invention, in any one of the configurations defined above, comprises a substrate having an electrically conductive surface and carrying an assembly of two molecular components.

Particular such devices are those comprising a substrate having an electrically conductive surface and carrying an assembly of two molecular components, wherein each one of said molecular components comprises one entity as defined above. Specific such devices are those wherein each one of said entities independently is selected from the herein identified compounds 1, 2, 3, 4, 5 or 6, i.e., one of said entities is compound 1, and another one of said entities is compound 2, 3, 4, 5 or 6; one of said entities is compound 2, and another of said entities is compound 3, 4, 5 or 6; one of said entities is compound 3, and another of said entities is compound 4, 5 or 6; one of said entities is compound 4, and another of said entities is compound 5 or 6; or one of said entities is compound 5, and another of said entities is compound 6.

More particular such devices are those comprising a substrate having an electrically conductive surface and carrying an assembly of two molecular components each comprising one entity as defined above, wherein the two molecular components are assembled in an alternate or successive order. In certain specific such devices, each one of said entities independently is selected from the herein identified compounds 1, 2, 3, 4, 5 or 6, i.e., one of said entities is compound 1, and another one of said entities is compound 2, 3, 4, 5 or 6; one of said entities is compound 2, and another of said entities is compound 3, 4, 5 or 6; one of said entities is compound 3, and another of said entities is compound 4, 5 or 6; one of said entities is compound 4, and another of said entities is compound 5 or 6; or one of said entities is compound 5, and another of said entities is compound 6, and said two molecular components are assembled in any alternate order.

In other particular such embodiments, the device of the present invention, in any one of the configurations defined above, comprises a substrate having an electrically conductive surface and carrying an assembly of three or more molecular components.

Particular such devices are those comprising a substrate having an electrically conductive surface and carrying an assembly of three or more molecular components, wherein each one of said molecular components comprises one entity as defined above. Specific such devices are those wherein each one of said entities independently is selected from the herein identified compounds 1, 2, 3, 4, 5 or 6.

More particular such devices are those comprising a substrate having an electrically conductive surface and carrying an assembly of three or more molecular components each comprising one entity as defined above, wherein the three or more molecular components are assembled in any random, alternate or successive order.

Devices according to the present invention, when comprising a substrate having an electrically conductive surface and carrying an assembly of one molecular component, can be used in fabrication of a multistate memory, electrochromic window, smart window, electrochromic display, or binary memory.

Certain devices according to the present invention, when comprising a substrate having an electrically conductive surface and carrying an assembly of more than one molecular component assembled in an alternate order, can be used in fabrication of a multistate memory, electrochromic window, smart window, binary memory, electrochromic display, bulk-hetero-junction solar cell, inverted type solar cell, dye sensitized solar cell, molecular diode, charge storage device, capacitor, or transistor. Particular examples of such devices, without limiting, are those comprising a substrate having an electrically conductive surface and carrying an assembly of two molecular components assembled in an alternate order, wherein each one of the two molecular components comprises a compound independently selected from the herein identified compounds 1, 2, 3, 4, 5 or 6, and the thickness of each one of said molecular components is less than 8 nm.

Other devices according to the present invention, when comprising a substrate having an electrically conductive surface and carrying an assembly of more than one molecular component assembled in a successive order, can be used in fabrication of a smart window, electrochromic display, bulk-hetero-junction solar cell, inverted type solar cell, dye sensitized solar cell, molecular diode, charge storage devices capacitor, or transistor.

In certain embodiments, the device of the present invention, in any one of the configurations defined above, is fabricated as a solid state device and further comprises an electrolyte and an electrical conductive electrode, wherein said electrical conductive electrode is fabricated on top of said assembly of one or more molecular components. In particular such embodiments, the electrolyte is a conductive polymer, gel electrolyte, or liquid electrolyte.

The invention will now be illustrated by the following non-limiting Examples.

### Examples

### Study 1

### Sequence-Dependent Assembly (SDA) to Control Molecular Interface Properties

### Experimental

Materials and Methods.

Complexes 1, 2 and 1,3,5-tris(4-ethenylpyridyl)benzene (3) were prepared as previously described (Motiei et al., 2008; Choudhury et al., 2010; Amoroso et al., 1995). p-Chloromethyl-phenyltrichlorosilane and dry propylene carbonate (<10 ppm H₂O) were purchased from Gelest Inc. and Aldrich, respectively, and used as received. Solvents (AR grade) were purchased from Bio-Lab (Jerusalem), Frutarom (Haifa) or Mallinckrodt Baker (Phillipsburg, N.J.). Toluene was dried and purified using an M. Braun solvent purification system. Single-crystal silicon (100) substrates (2.0×1.0 cm) were purchased from Wafernet (San Jose, Calif.) and ITO-coated glass substrates (7.5×0.8 cm) were purchased from Delta Technologies (Loveland, Colo.). The ITO and silicon substrates were cleaned by sonication in DCM followed by toluene, acetone, and ethanol, and subsequently dried under an N₂ stream, after which they were cleaned for 30 min with a UVOCS cleaning system (Montgomery, Pa.). Quartz substrates (2.0×1.0 cm; Chemglass Inc.) were cleaned by immersion in a “piranha” solution (7:3 (v/v) H₂SO₄/30% H₂O₂) for 1 h. Caution: piranha solution is an extremely dangerous oxidizing agent and should be handled with care using appropriate personal protection. Subsequently, the substrates were rinsed with deionized (DI) water followed by the Radio Corporation of America (RCA) cleaning protocol: 1:5:1 (v/v) NH₄OH/H₂O/30% H₂O₂ at 80° C. for 45 min. The substrates were washed with DI water and dried under an N₂ stream. All substrates were then dried in an oven for 2 h at 130° C. The siloxane-based chemistry and the formation of the 3-based template layer were carried out in a glovebox or by using standard schlenk-cannula techniques (Kaminker et al., 2010; Yerushalmi et al., 2004; Li et al., 1993). These template layers were stored in toluene and used within 24 h. UV/vis spectra were recorded on a Cary 100 spectrophotometer. Spectroscopic ellipsometry was recorded on an M 2000V (J. A. Wollam Co. Inc.) instrument with VASE32 software. Electrochemical measurements (cyclic voltammetry, differential pulse voltammetry and chronoamperometry) were performed using a potentiostat (CHI660A). The electrochemical measurements were performed in a three-electrode cell configuration consisting of (i) a self-propagating molecule-based assembly (SPMA)-functionalized ITO substrate as the working electrode; (ii) Pt wire as the counter electrode; and (iii) Ag-wire as the reference electrode with ferrocene as the internal standard, using 0.1 M solutions of TBAPF₆ in CH₃CN as the supporting electrolyte. For spectroelectrochemistry, 0.1 M solutions of TBAPF₆ in dry propylene carbonate (to avoid evaporation of the solvent) were used. All experiments were carried out at RT, unless stated otherwise. The thicknesses of the SPMAs on ITO were estimated by spectroscopic ellipsometry measurements of SPMAs grown simultaneously on silicon substrates. One deposition step is defined as the deposition of one type of metal complex (1 or 2) and the palladium salt Pd(PhCN)₂Cl₂. FIG. 1 shows the formation of the multi-component SPMAs with complexes 1 and 2. The naming of the corresponding four SPMAs (I-IV) in consecutive order is as follows: SPMA I | Ruₓ—Os_{y}; SPMA II | Ruₓ—Os_{y}; SPMA III | Osₓ—Ru_{y}; and SPMA IV | (Ru—Os)_{x+y}, where x and y denote the number of deposition steps in which complex 1 or complex 2 was deposited.

Sequence-Dependent Assembly I: Formation of Multi-Component SPMAs by Alternating Assembly of Complexes 1, 2 and PdCl₂(PhCN)₂.

Substrates functionalized with the 3-based template layer (Kaminker et al., 2010; Yerushalmi et al., 2004; Li et al., 1993) were loaded onto a Teflon holder and immersed for 15 min in a 1.0 mM solution of PdCl₂(PhCN)₂ in THF. The samples were then sonicated twice in THF and once in acetone for 3 min each. Subsequently, the samples were immersed for 15 min in a 0.2 mM solution of compound 1 in THF/DMF (9:1, v/v). The samples were then sonicated twice in THF and once in acetone for 5 min each (=deposition step 1). Next, the samples were immersed for 15 min in a 1.0 mM solution of PdCl₂(PhCN)₂ in THF. The samples were then sonicated twice in THF and once in acetone for 3 min each. Subsequently, the samples were immersed for 15 min in a 0.2 mM solution of compound 2 in THF/DMF (9:1, v/v). Finally, the samples were sonicated twice in THF and once in acetone for 3 min each (=deposition step 2). This procedure was repeated until eight deposition steps were obtained, i.e., four for each metal. Then, the samples were rinsed in ethanol and dried under a stream of N₂. All steps of this procedure were carried out at RT. Two solutions of PdCl₂(PhCN)₂ were used with identical concentrations to rigorously exclude cross-contamination between the polypyridyl complexes 1 and 2 (FIG. 1).

Sequence-Dependent Assembly II: Formation of Multi-Component SPMAs by Successive Assembly of Complexes 1, 2 and PdCl₂(PhCN)₂.

Substrates functionalized with the 3-based template layer (Kaminker et al., 2010; Yerushalmi et al., 2004; Li et al., 1993) were loaded onto a Teflon holder and immersed for 15 min in a 1.0 mM solution of PdCl₂(PhCN)₂ in THF. The samples were then sonicated twice in THF and once in acetone for 3 min each. Subsequently, the samples were immersed for 15 min in a 0.2 mM solution of compound 1 in THF/DMF (9:1, v/v). The samples were sonicated twice in THF and once in acetone for 5 min each (=deposition step 1). This cycle (a) was repeated 1, 2, 3 or 4 times, depending on the nature of the formed molecular assembly. Hereafter, the samples were immersed for 15 min in a 1.0 mM solution of PdCl₂(PhCN)₂ in THF. The samples were then sonicated twice in THF and once in acetone for 3 min each. Subsequently, the samples were immersed for 15 min in a 0.2 mM solution of compound 2 in THF/DMF (9:1, v/v). Finally, the samples were then sonicated twice in THF and once in acetone for 3 min each. This cycle (b) was repeated 1, 2, 3 or 4 times, depending on the nature of the formed SPMA. Then, the samples were rinsed in ethanol and dried under a stream of N₂. All steps of this procedure were carried out at RT. Two solutions of PdCl₂(PhCN)₂ were used with identical concentrations to rigorously exclude crosscontamination between polypyridyl complexes 1 and 2 (FIG. 1).

Sequence-Dependent Assembly III: Formation of Multi-Component SPMAs by Successive Assembly of Complexes 1, 2 and PdCl₂(PhCN)₂.

Substrates functionalized with the 3-based template layer (Kaminker et al., 2010; Yerushalmi et al., 2004; Li et al., 1993) were loaded onto a Teflon holder and immersed for 15 min in a 1.0 mM solution of PdCl₂(PhCN)₂ in THF. The samples were then sonicated twice in THF and once in acetone for 3 min each. Subsequently, the samples were immersed for 15 min in a 0.2 mM solution of compound 2 in THF/DMF (9:1, v/v). The samples were then sonicated twice in THF and once in acetone for 5 min each (=deposition step 1). This cycle (a) was repeated 1, 2, 3 or 4 times, depending on the nature of the formed molecular assembly. Hereafter, the samples were immersed for 15 min. in a 1.0 mM solution of PdCl₂(PhCN)₂ in THF. The samples were then sonicated twice in THF and once in acetone for 3 min each. Subsequently, the samples were immersed for 15 min in a 0.2 mM solution of compound 1 in THF/DMF (9:1, v/v). Finally, the samples were sonicated twice in THF and once in acetone for 3 min each. This cycle (b) was repeated 1, 2, 3 or 4 times, depending on the nature of the formed SPMA. Then, the samples were rinsed in ethanol and dried under a stream of N2. All steps of this procedure were carried out at RT. Two solutions of PdCl₂(PhCN)₂ were used with identical concentrations to rigorously exclude cross-contamination between polypyridyl complexes 1 and 2 (FIG. 1).

Sequence-Dependent Assembly IV: Formation of Multi-Component SPMAs by Assembly from a Mixture of Complexes 1, 2 with PdCl₂(PhCN)₂.

Substrates functionalized with the 3-based template layer (Kaminker et al., 2010; Yerushalmi et al., 2004; Li et al., 1993) were loaded onto a Teflon holder and immersed for 15 min, at RT, in a 1.0 mM solution of PdCl₂(PhCN)₂ in THF. The samples were then sonicated twice in THF and once in acetone for 3 min each. Subsequently, the samples were immersed for 15 min in a 0.2 mM solution (total concentration of metal complexes) of compound 1 and 2 (50:50, 0.1 mM each) in THF/DMF (9:1, v/v). The samples were then sonicated twice in THF and once in acetone for 5 min each (=deposition step 1). This procedure was repeated until eight deposition steps were obtained. Then, the samples were rinsed in ethanol and dried under a stream of N₂. All steps of this procedure were carried out at RT (FIG. 1).

Functional molecular materials have been obtained by liquid/vapor-phase epitaxy or layer-by-layer assembly with (i) electro-optic responses sufficiently high to build high-speed electro-optical modulators (Frattarelli et al., 2009; Rashid et al., 2003); (ii) high-k dielectrics for fabricating organic field effect transistors (OFETs) (Ortiz et al., 2010; Klauk et al., 2007); and (iii) ultra-low-β materials to generate molecular wires (Terada et al., 2012; Sedghi et al., 2011; Motiei et al., 2010a; Kurita et al., 2010; Tuccitto et al., 2009; Sedghi et al., 2008). Moreover, combining metal-ligand coordination chemistry with stepwise solution-based deposition resulted in the formation of crystalline assemblies, including highly porous metal-organic frameworks (MOFs) on inorganic surfaces (Ariga et al., 2012; Makiura et al., 2010; Shekhah et al., 2009; Kanaizuka et al., 2008). The key for fabricating these and other molecular materials is frequently found in a highly conserved assembly sequence that directs them towards their unique properties and desired function. Similarly, nature dictates the function of enzymes and the genetic information encoded in DNA/RNA by means of the sequence in which the amino acids and nucleotides are arranged. Yet nature is able to create diverse functionalities with the same molecular building blocks. An intriguing question thus remains; can we harvest new and useful material properties by only changing the assembly sequence of the molecular components?

To address this challenge, the present study introduces a SDA of molecular interfaces and shows how this strategy—specific to a set of given building blocks—can be fully exploited to form SPMAs with diverse functionalities. Each SPMA (I-IV) was formed with the same molecular complexes (1, 2) that subdivides our SDA into four branches: (I) alternating assembly of 1 and 2; (II) successive assembly of molecular component 1, then complex 2; (III) successive assembly of molecular component 2, then 1; and (IV) assembly of the molecular components from a mixture of 1 and 2, i.e., SPMA I | Ruₓ—Os_{y}; SPMA II | Ruₓ—Os_{y}; SPMA III | Os_{y}—Ruₓ; and SPMA IV | (Ru—Os)_{x+y}, where x and y denote the number of deposition steps in which complex 1 and 2 was deposited, respectively. The difference between each branch of the SDA is undoubtedly reflected in the multi-faceted electrochemical properties of the corresponding SPMAs. Furthermore, for SDA II and III, we can control the pathway by which electron transfer occurs by tuning the surface-interface thickness of the molecular components (1, 2). The delicate interplay between the SDA and the surface-interface thickness resulted in four distinctly observable electrochemical signatures: 1) reversible electron transfer; 2) oxidative catalytic electron transfer with charge trapping; 3) reductive catalytic electron transfer; and 4) blocking of the electron transfer. The importance of the appropriate SDA strategy is not only paramount in forming surface-confined molecular interfaces; it might also be applied in self-sorting assemblies, molecular networking, and multi-component MOFs, in which instances of sequential order can be identified (Campbell et al., 2010; Deng et al., 2010; Northrop et al., 2009; Sknepnek et al., 2008; Lehn, 2002).

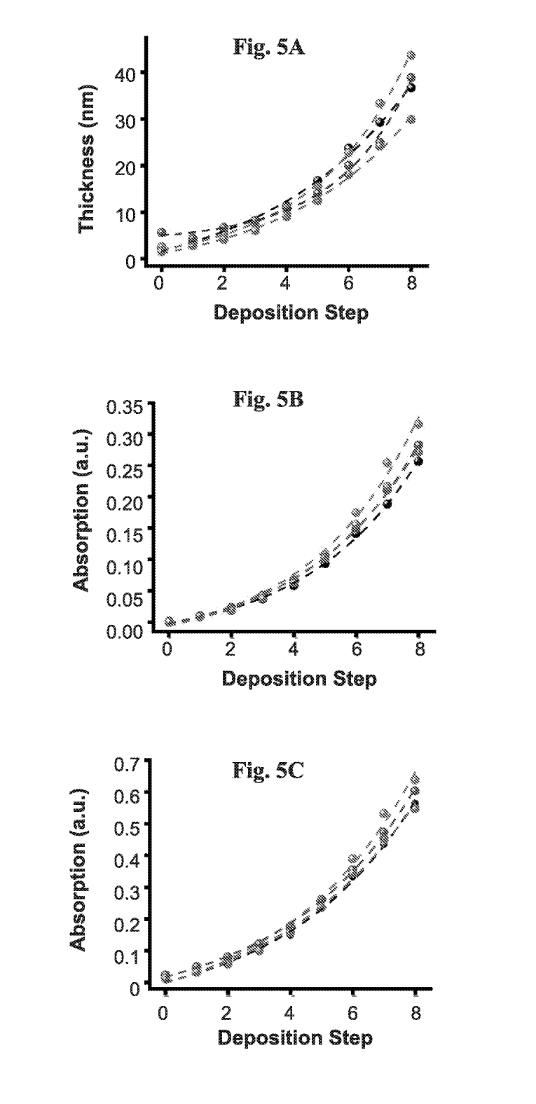

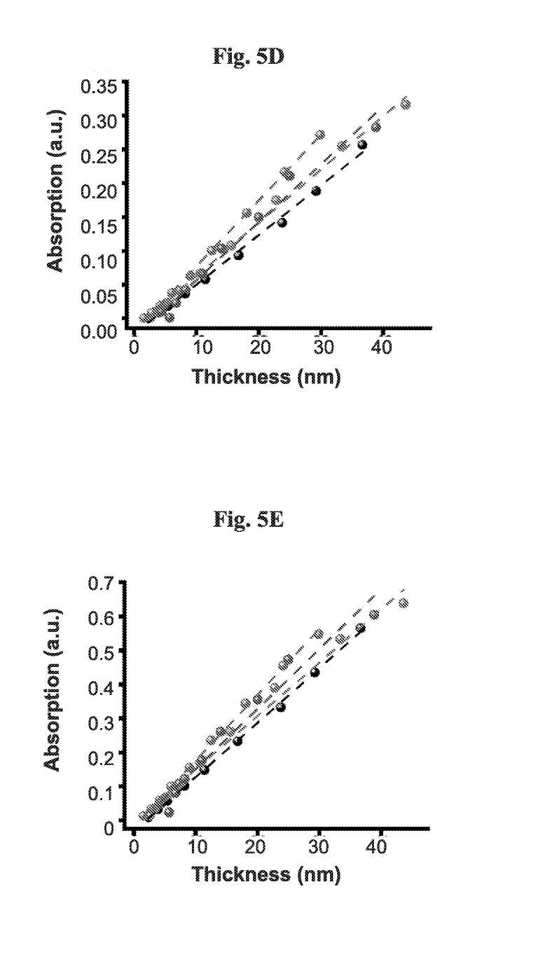

For construction of the SPMAs by our SDA strategy we relied on our recent examples of molecule-based materials that are active participants in their continuing self-propagating assembly (Motiei et al., 2012). These materials have already been applied in electrochromic materials, solar cells, and molecular data storage (de Ruiter et al., 2010a; Motiei et al., 2010b; Motiei et al., 2009). The exponential growth processes observed in these assemblies involves absorption of an excess of a palladium salt into a unimolecular network consisting of complex 2 linked by palladium dichloride (Motiei et al., 2008). For our SPMAs I-IV; numbers coincide with the SDA strategy I-IV employed in their preparation, composed of complexes 1 and 2, similar growth processes and identical optical properties have been observed (FIGS. 5A-5E).

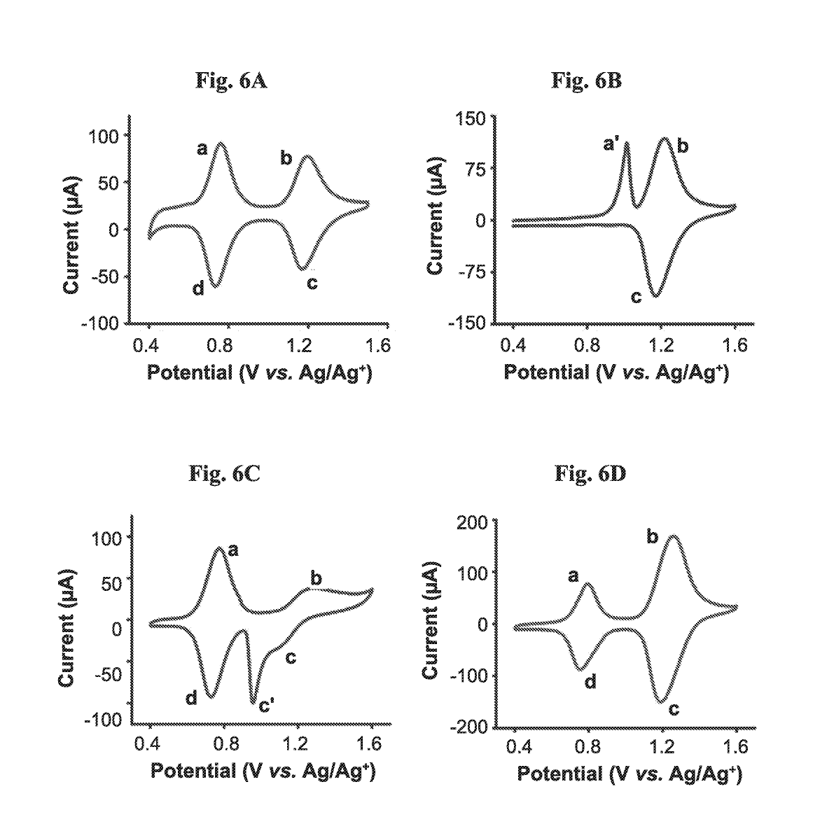

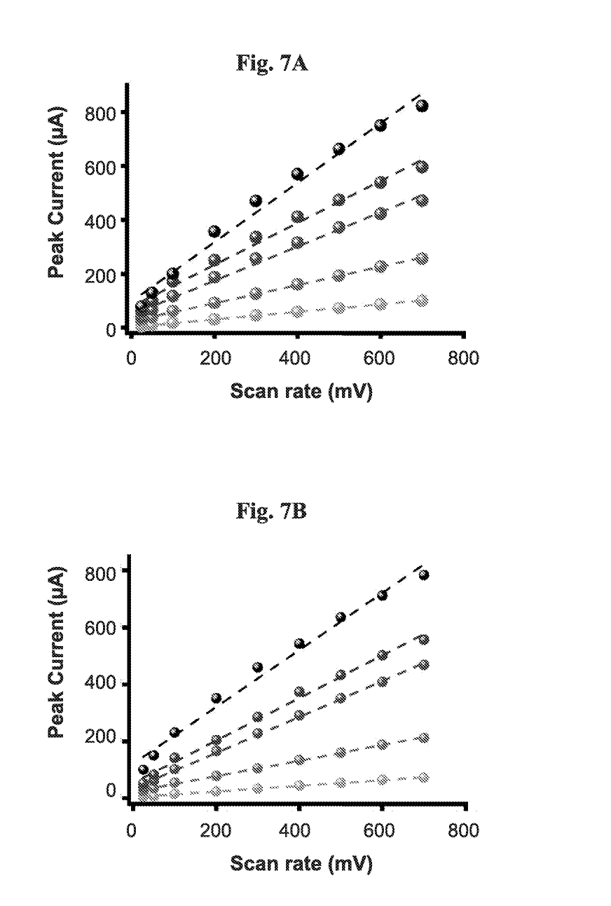

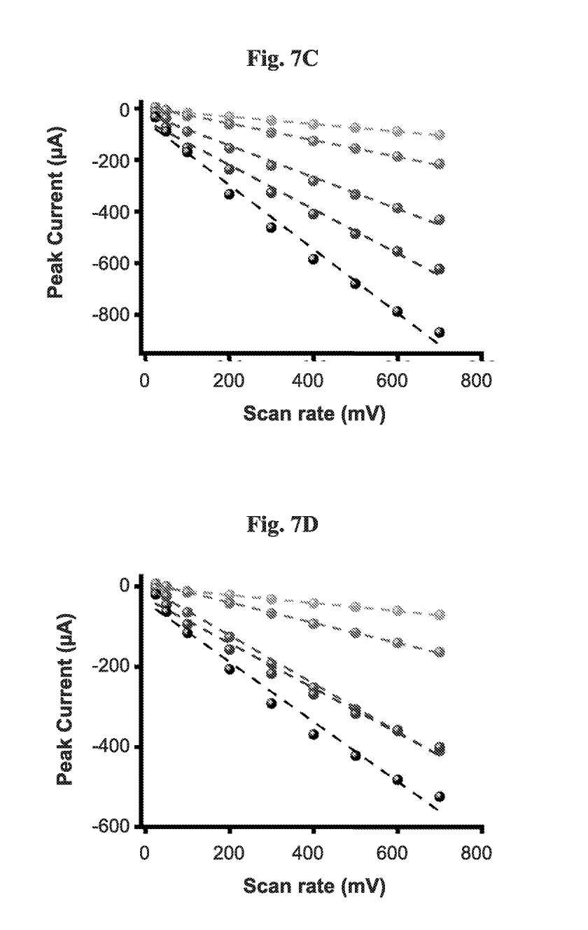

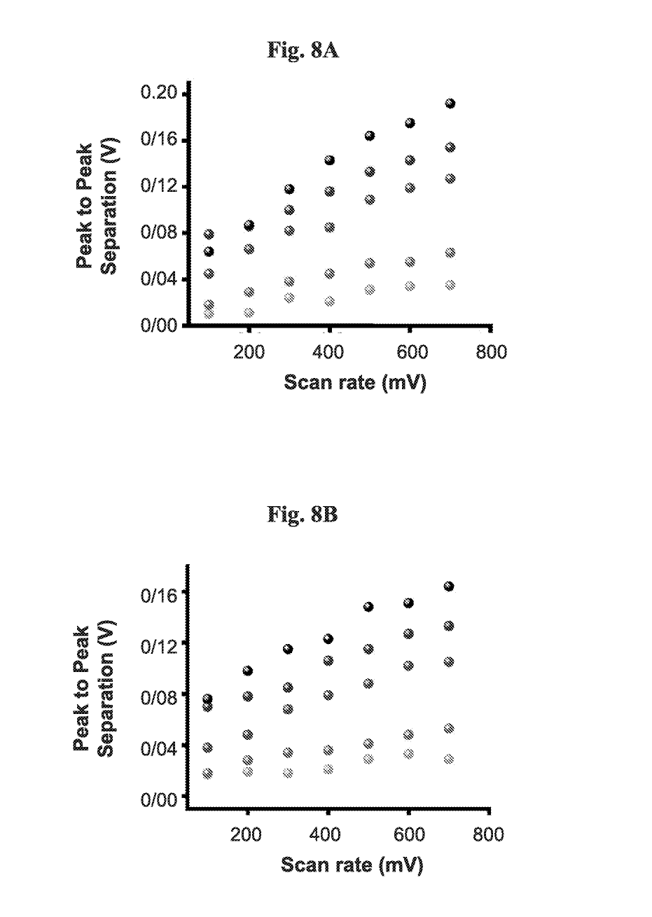

In SDA I, the molecular components (1, 2) are arranged in an alternating manner to give a SPMA that is 11.4 nm thick (SPMA I | Ru₂—Os₂). The CV of this SPMA exhibits reversible electrochemical waves for both the Os^{2+/3+} and Ru^{2+/3+} redox couples (FIG. 6A). Furthermore, the electrochemical behavior is reversible and surface-confined up to a thickness of 54 nm, although a decrease in the electron transport kinetics was observed (FIGS. 4A-4D and 5A-5B). The Os/Ru ratio does not vary significantly during SPMA assembly growth as shown by a similar total charge for both redox processes (Ru: Q=0.92×10⁻⁴ C and Os: Q=1.13×10⁻⁴ C: FIG. 9).

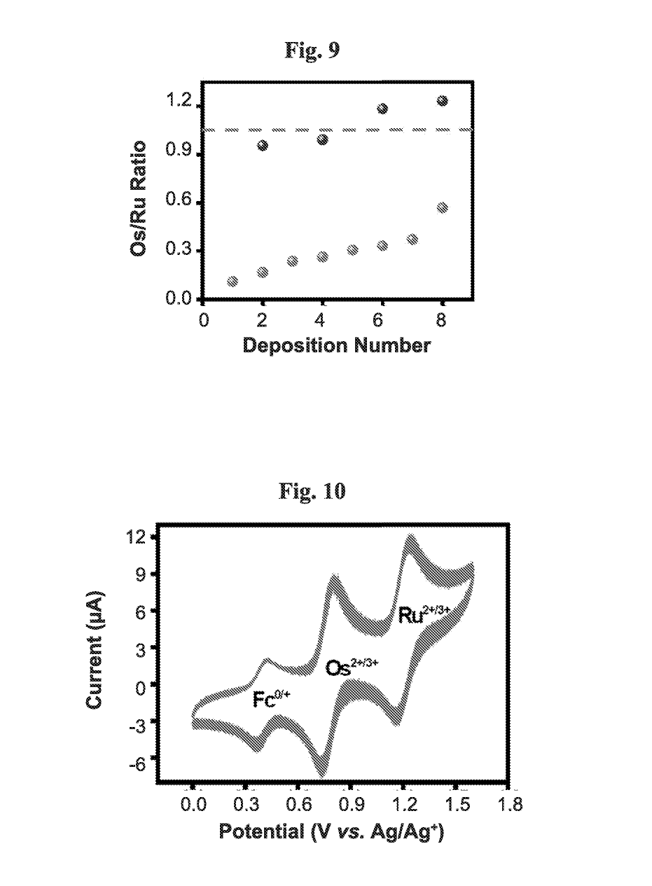

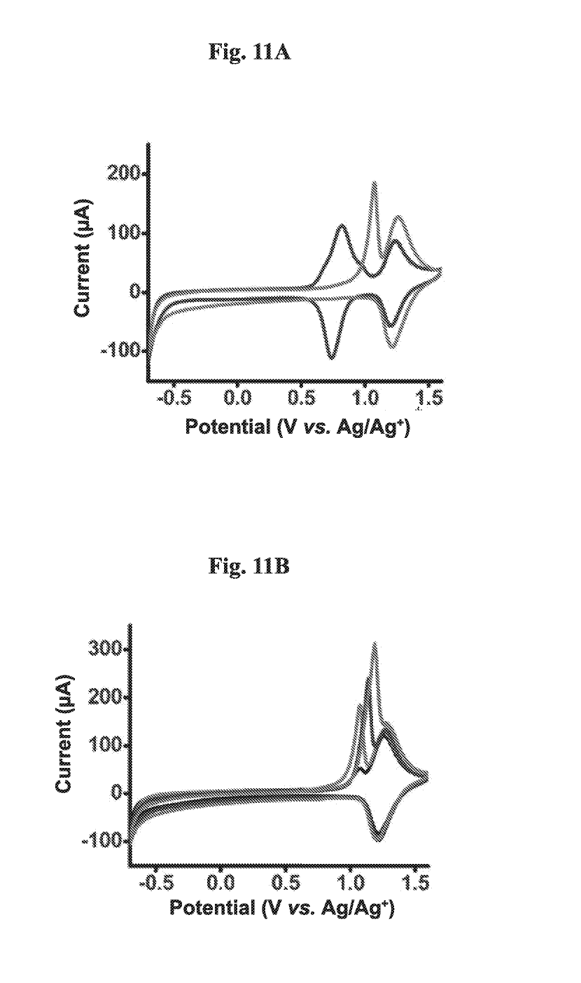

The half-wave potentials for 1 and 2 in SPMA I | Ru₂—Os₂ are similar to the ones measured in solution (2: 0.758 V and 1: 1.180 V (SPMA) vs. 2: 0.770 V and 1: 1.200 V (solution; FIG. 10) and the large separation of the half-wave potentials of ΔE₁₁₂=422 mV (ΔE_{1/2}=ΔE_{1/2}Ru-ΔE_{1/2}Os), indicates that no communication exists between the different metal-centers on the surface (FIG. 6A). This is an important characteristic that allows both types of metal-centers to be addressed individually. This feature is only displayed in products obtained by SDA strategies I and IV, whereas for the products SDA II and III metal-metal communication is observed (FIGS. 3B-3C; see below).

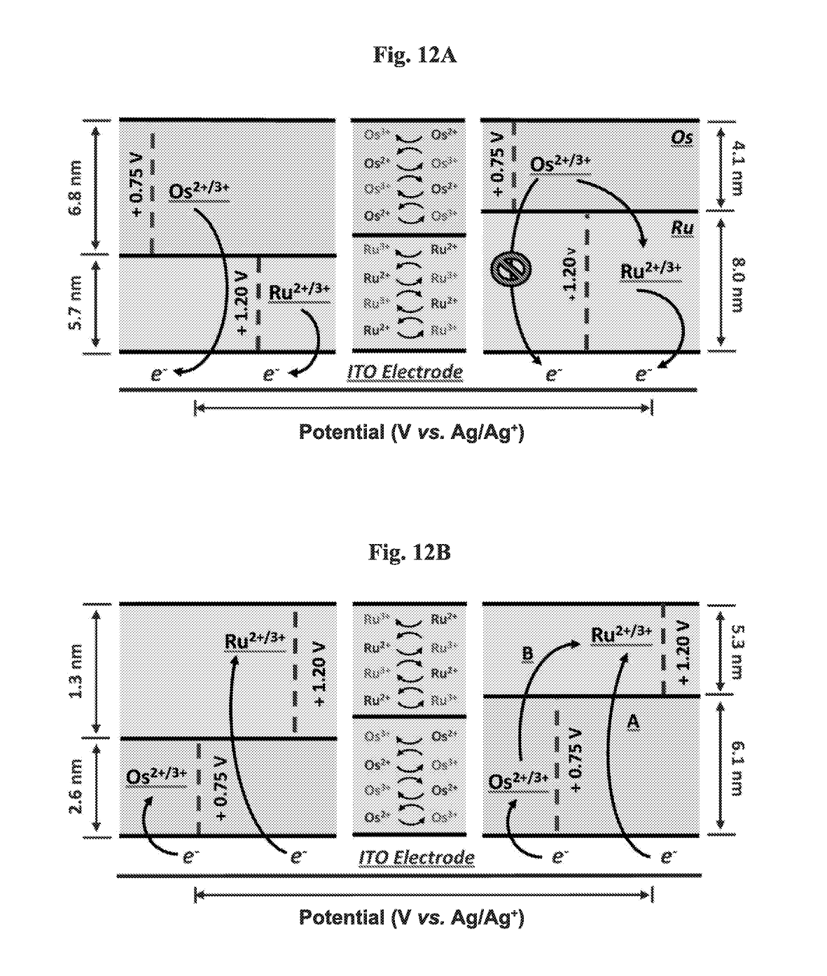

In SDA II, complexes 1 and 2 are deposited successively, the electrochemical properties are markedly affected, by the presence of the inner ruthenium layer. For a SPMA with a Ru thickness of 8.0 nm and an Os thickness of 4.1 nm (SPMA II | Ru₃—Os₁), the electrochemical behavior exhibits a sharp catalytic oxidative pre-wave at approximately 1.08 V (FIG. 6B, and FIG. 11A; red trace). Furthermore, the intensity of this catalytic pre-wave increased significantly upon increasing the surface-interface thickness of the osmium layer from 4.1 nm (FIG. 11B; red trace SPMA II | Ru₃—Os₁), to 9.3 nm (FIG. 11B; blue trace—SPMA II | Ru₃—Os₂) and finally to 17.6 nm (FIG. 11B; green trace—SPMA II | Ru₃—Os₃). Thus this sharp pre-wave at approximately 1.08 V results from catalytic oxidation of the Os metal centers in the outer layer of SPMA II | Ru₃—Os₁ (Abruna et al., 1981; Denisevich et al., 1981). This effect can be explained—similar to Murray's explanation (Abruna et al., 1981; Denisevich et al., 1981)—by assuming that the inner Ru layer (8.0 nm) isolates the Os metal centers from the ITO electrode. Therefore, at the half-wave potential of the Os^{2+/3+} redox couple no oxidation/reduction is observed. However, at the onset potential for Ru oxidation, oxidation starts to occur from Ru²⁺→Ru³⁺. Since the thermodynamic parameters are such that Ru³⁺ is able to oxidize Os²⁺, and Ru³⁺ is constantly regenerated through self-exchange with the ITO electrode, a conductive path is formed from the ITO electrode. Therefore, the sparingly formed Ru³⁺ centers, behave as a catalytic gate for electron transport from osmium to the ITO electrode. This process is graphically illustrated in FIGS. 12A-12B.

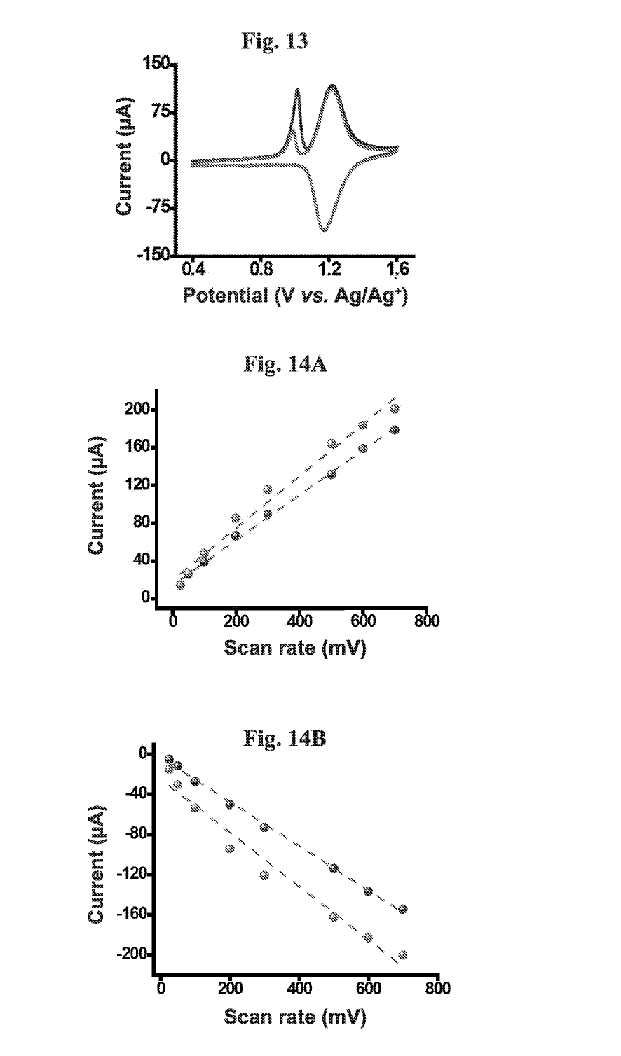

Moreover, in the negative scan direction, reduction of the Os layer from Os³⁺→Os²⁺ is absent. At the half-wave potential of the Os^{2+/3+} redox couple, all the Ru³⁺ centers have been reduced, and there is no pathway available to reduce the Os³⁺ in the outer layer, and consequently charge trapping occurs. This charge trapping is further manifested by a decrease in the intensity of the oxidative pre-wave in the 2^{nd} scan-cycle (FIG. 13). This decrease in intensity is attributed to a decrease in the available Os²⁺ metal centers in the 2^{nd} scan cycle. Overall, the electron transport is mediated only by the Ru^{2+/3+} redox couple and occurs unidirectional towards the ITO electrode, and SPMA II | Ru₃—Os₁ acts as a molecular rectifier (Abruna et al., 1981; Denisevich et al., 1981). Interestingly, below a certain threshold thickness (8.0 nm) of the ruthenium layer, the electrochemical behavior of SPMAs created by SDA II is completely reversible (FIG. 11A, and FIGS. 14A-14B). An intriguing question that arises is: would similar results be obtained if the successive arrangement of molecular components 1 and 2 is reversed, that is, deposition of complex 2 is followed by complex 1. To address this question, several SPMAs were prepared by SDA III.

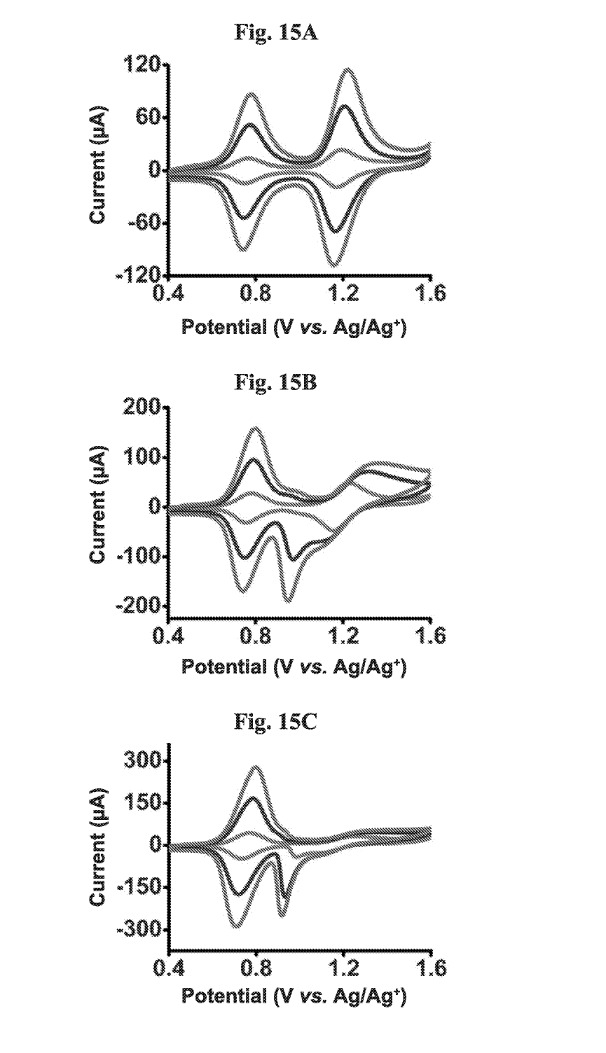

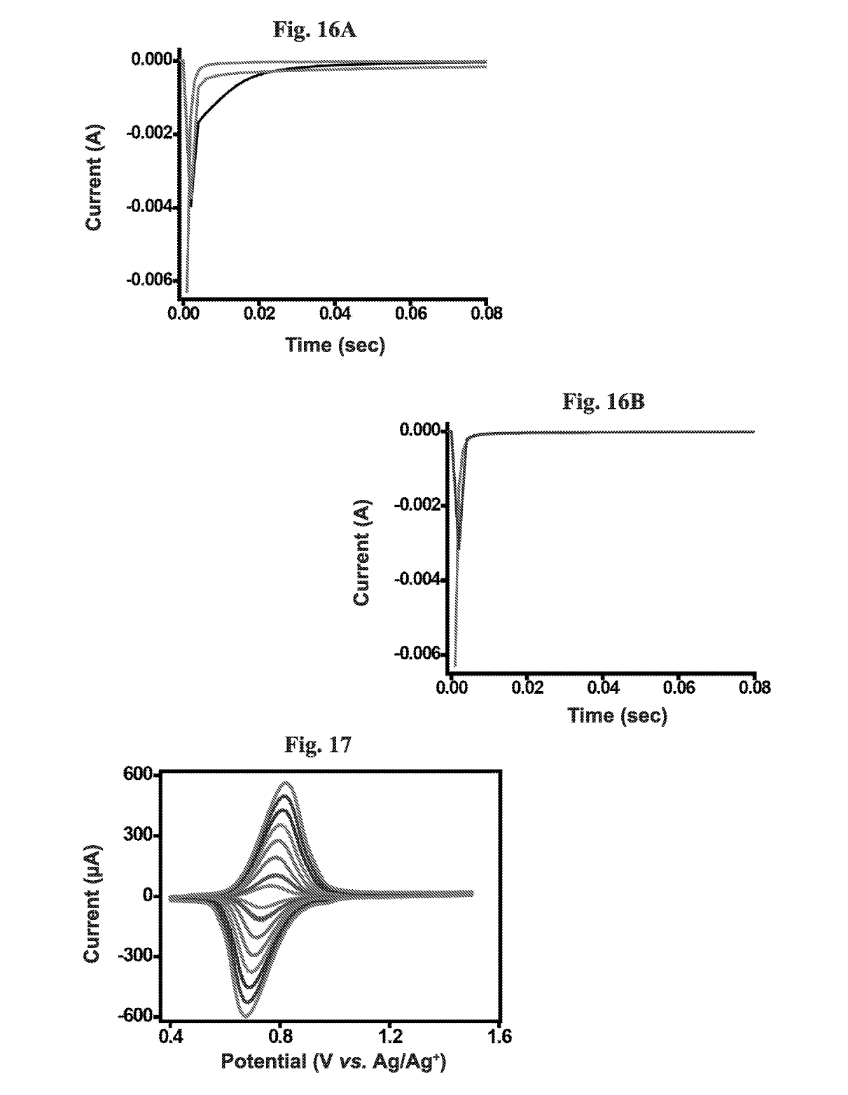

In SDA III, two electron-transfer pathways (A and B) were observed depending on the surface-interface thickness of the osmium layer and the scan rate of the electrochemical experiments (FIG. 12B). For SPMAs with a relatively small surface-interface thickness (2.6 nm; SPMA III | Os₁—Ru₁), reversible behavior of both redox couples 1 and 2 is observed at scan rates of 100, 400 and 700 mVs⁻¹, respectively (FIG. 15A). The reversible electron transfer occurs by pathway A (FIG. 12B), and is mediated by the porosity of our assemblies (Motiei et al., 2010a; Motiei et al., 2011b). Upon increasing the thickness to 3.8 nm (SPMA III | Os₂—Ru₂), reversible behavior is observed at a scan rate of 100 mVs⁻¹ (FIG. 15A; red trace), with a peak-to-peak separation of 71 mV for the Ru^{2+/3+} redox-couple. However, a new reduction wave evolves at about 1.00 V, when the scan rate is increased to 400 mVs⁻¹ and 700 mVs⁻¹ (FIG. 15A; blue and green traces, respectively). This new reduction wave is accompanied by a concurrent increase in the peak-to-peak separation from 71 mV to 254 mV of the Ru^{2+/3+} redox couple. The Os^{2+/3+} redox-couple, in contrast, only exhibits a relatively small change at higher scan rates (24 to 61 mV). The unusually large increase in peak-to-peak separation for the Ru^{2+/3+} redox couple in SPMA III | Os₂—Ru₂ is due to interference from the Os layer, in which the electron transfer at the Os³⁺/Ru²⁺ interface is thermodynamically unfavorable (Leidner and Murray, 1985), and hence becomes more difficult. Oxidation of the Ru²⁺ metal centers still occurs mainly by the large (0.4 V) over-potential that is applied, although the electron transfer through defects and pinholes cannot be excluded (Motiei et al., 2010a; Motiei et al., 2011b). The thermodynamic and kinetic effects of electron transfer at the Os/Ru interface is even more pronounced when the SPMA is reduced. Scanning in the negative direction, two distinct pathways (A and B) were observed, in which the electrode is able to reduce the outer Ru³⁺ centers (FIG. 12B). For Pathway A, at low scan rates (<100 mVs⁻¹) the electron transfer occurs similarly to the transfer that results in the oxidation, and is mediated by the porosity of our assemblies (Motiei et al., 2010a; Motiei et al., 2011b). When the scan rate is increased a second pathway (B) is preferred (Leidner and Murray, 1985). A typical characteristic of Pathway B is that the onset of the reduction from Os³⁺→Os²⁺ forms a conductive path to catalytically reduce the remaining Ru³⁺→Ru²⁺; that is, the Ru³⁺ that has not yet been reduced by means of Pathway A. Since the reduction by Pathway A occurs at 1.20 V and the reduction by means of Pathway B is at 1.00 V, there is a temporary charge trapping between 1.00 and 1.20 V. (Leidner and Murray, 1985). The increased dominance of the catalytic reduction wave is further exemplified by increasing the Os thickness to 6.1 nm (SPMA III | Os₃—Ru₂). Even at 100 mVs⁻¹ a predominant catalytic reduction peak is observed at about 1.00 V, although the original reduction is still observable (FIG. 15A; red trace). Further increasing the scan rate to 700 mVs⁻¹ decreases the original oxidation/reduction wave almost completely and only the catalytic reduction peak remains (FIG. 6C, and FIG. 15C). Moreover, the anodic peak potential (Epa) for the ruthenium reduction shifts by 80 mV, from 0.990 V to 0.910 V, owing to the more catalytic character of the electron transfer to the ITO electrode. The shift to a more catalytic nature of the ruthenium reduction—upon increasing the osmium surface-interface thickness—is also evident from the current responses of SPMA III | Os₁—Ru₁→SPMA III | Os₄—Ru₁ after applying a potential step from 1.60-1.00 V (FIGS. 16A-16B). However, when the Os thickness is further increased to 11 nm (SPMA III | Os₄—Ru₄), the oxidation/reduction processes associated with the Ru^{2+/3+} redox couple is absent in the CV (FIG. 17). At this Os thickness, the ruthenium centers are completely isolated from the surface. The mechanism underlying electron transfer in SPMAs, prepared by SDA III, with an Os thickness up to 6.1 nm is graphically illustrated in FIG. 12B.

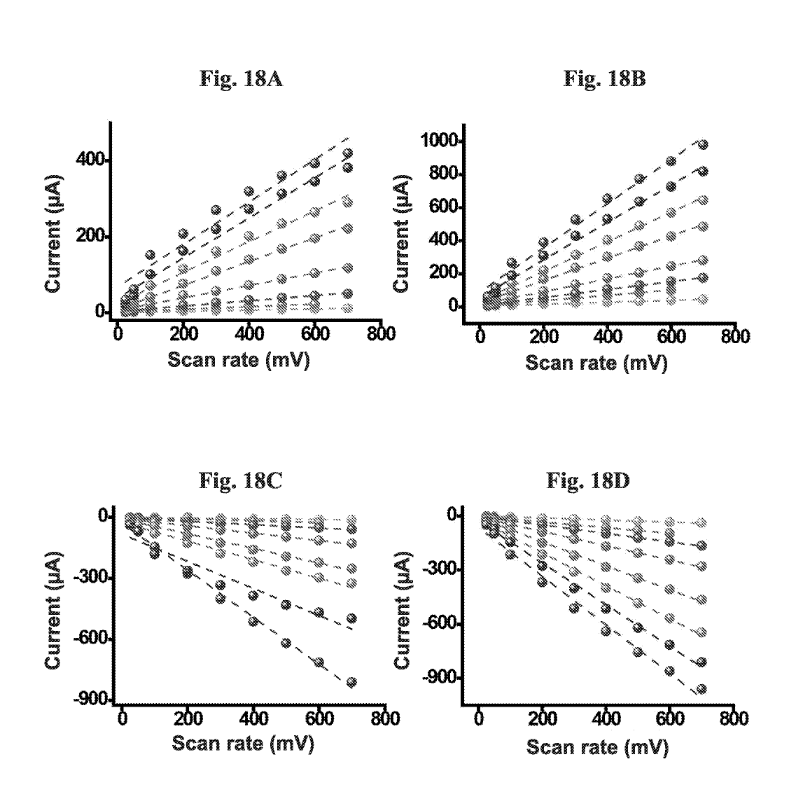

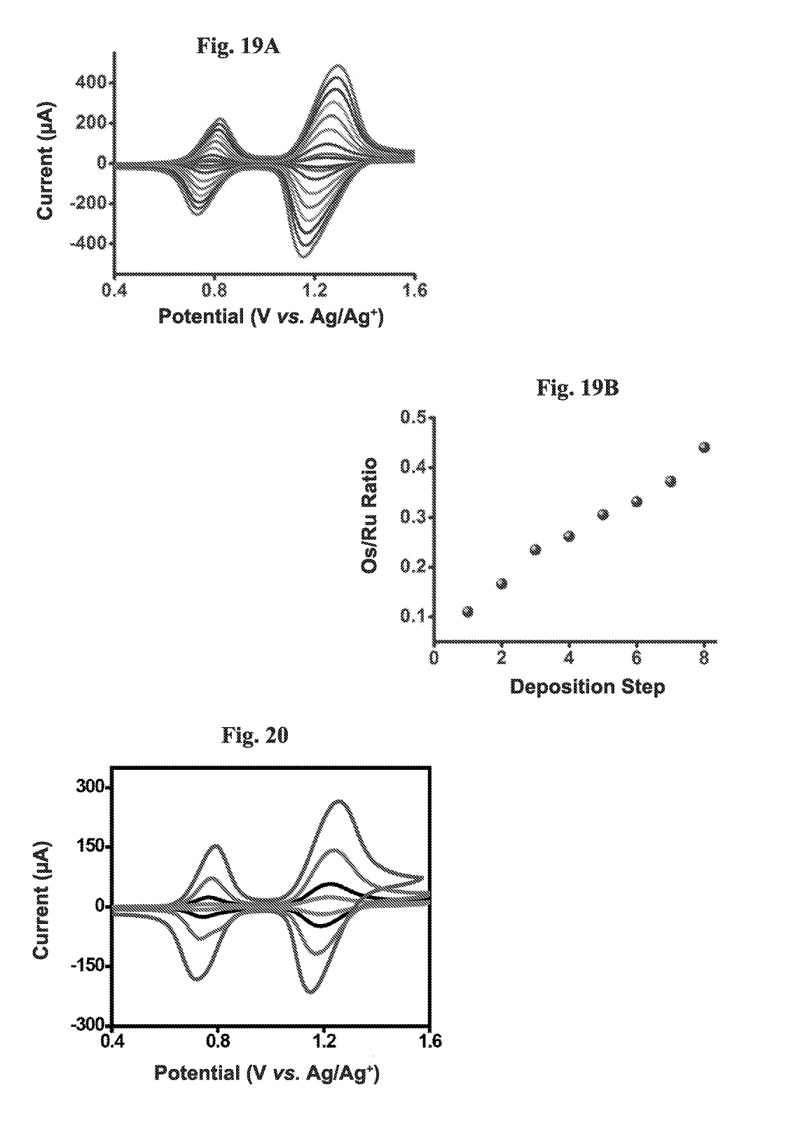

In SDA IV, the multi-component SPMAs were obtained by deposition from a solution containing an equimolar amount of complexes 1 and 2. These SPMAs exhibit reversible behavior for redox couples Os^{2+/3+} and Ru^{2+/3+} up to a thickness of 30.0 nm (FIGS. 18A-18D). For instance, a 12.5 nm thick SPMA IV | (Os—Ru)₅ displays reversible behavior between 25 and 700 mVs⁻¹ (FIG. 6D and FIG. 19A). The electrochemical behavior reflects the electrochemical characteristics obtained upon repeatedly alternating the assembly sequence of the molecular components (SDA I). Interestingly, using this assembly sequence, a change in the Os and Ru ratio is observed when moving from SPMA IV I (Os—Ru)₁→SPMA IV | (Os—Ru)₈. For very thin films (2.8 nm; SPMA IV | (Os—Ru)₁) the Os/Ru ratio is about 1:10, which increases to approximately 1:2 upon increasing the SPMA thickness to 29.8 nm (SPMA IV | (Os—Ru)₈; FIG. 19B and FIG. 20). For further data see Study 5 hereinafter.

The results presented herein demonstrate the importance of the assembly sequence and the surface-interface thickness of the molecular components 1 and 2 on the physicochemical properties, which are important for device fabrication. For instance SPMAs suitable for ternary memory devices in high-density data storage (HDDS) can be constructed by SDA I (de Ruiter et al., 2010a; de Ruiter et al., 2010b). This SDA allows the independent addressing of each type of metal-center that displays reversible, reliable, and stable electrochemical properties. The individual addressability of both molecular components in SPMA I may also be ideal for applications in three-dimensional integrated circuits (3D-ICs). Other SDA strategies result in the formation of molecular rectifiers, among others. The observed unidirectional current flow and the diverse electrochemical properties (SDA II and III) are of particular interest for fabricating solar-cells, where charge trapping and unidirectional current flows are important (Wurfel, 2009). Along with the photo-activity of Ru-polypyridyl complexes in solar cells (Reynal and Palomares, 2011), it is important to consider how to assemble those complexes in binary systems, e.g., blended or separated (McGehee and Topinka, 2006).

The electrochemical rectification of redox-active polymers in a bilayer fashion has been known since the seminal work of Murray and Wrighton (Abruna et al., 1981; Denisevich et al., 1981; Leidner and Murray, 1985; Chidsey and Murray, 1986; Smith et al., 1986). Unidirectional current flows have been subsequently reported between redox-active organic (mono/multi)-layers and ferrocyanide solutions (Berchmans et al., 2002; Oh et al., 2002), or in redox-active (ionic) polymers that might contain metal complexes (Alvarado et al., 2005; Hjelm et al., 2005; DeLongchamp et al., 2003; Cameron and Pickup, 1999; Araki et al., 1995). However, the versatility of the SDA and the resulting properties of the demonstrated interfaces are unprecedented. These films not only exhibit different electrochemical behavior upon changing the assembly sequence, they also dramatically change their behavior as a function of a controllable surface-interface thickness. This thickness in turn controls the electron transfer at the metal/metal interface. Together they determine the overall material properties in each SDA.

### Study 2

### Dual Channel Output for Ternary Data Storage Utilizing Multi-Component Self-Propagating Molecular Assemblies

### Experimental

Materials and Methods.

See Study 1 above.

Formation of Multi-Component SPMAs with Complexes 1, 2 and PdCl₂(PhCN)₂.

The procedure was identical to that described in Study 1, SDA I, except for that it was repeated until twelve deposition steps were obtained (Note: two solutions of PdCl₂(PhCN)₂ were used with identical concentrations to exclude cross-contamination between the polypyridyl complexes 1 and 2).

The fabrication of molecular memory devices for high density data storage (HDDS) is essential due to ever increasing technological demands (Lieber, 2001; Ball, 2000). For instance, 0.4-1.4 zettabytes were generated in 2010, and this is expected to grow to 35 zettabytes by 2020 (Hilbert and Lopez, 2011; Gantz et al., 2010). Moreover, since 2007 more digital information is created that can be stored (Gantz et al., 2010). These facts leave many opportunities for the development of future information storage technologies. Ternary memory is especially attractive as the data is efficiently stored in trits (3ₙ) (Knuth, 1997). In order to store multiple states one might use: (i) a combination of two, or more, redox-active molecules in a single assembly; or (ii) multiple redox-states in a single molecule (Lindsey and Bocian, 2011). However, formation of ternary memory with redox-active molecules on surfaces is rare (Lindsey and Bocian, 2011; Simao et al., 2011; Lee et al., 2011; de Ruiter et al., 2010a; de Ruiter et al., 2010b; Li et al., 2010; Fioravanti et al., 2008; Yu et al., 2008; Lauters et al., 2006; Li et al., 2004). To illustrate, porphyrin-derivatives covalently attached to silicon were used to generate electrochemically addressable and readable ternary memory (Lindsey and Bocian, 2011). More recently, Rovira and Torrent used the redox-chemistry of organic radicals for the formation of ternary memory that is readable in a dual way (Simao et al., 2011). Nevertheless, the formation of molecular platforms that exhibits several well-separated redox processes on the surface, for the formation of ternary memory is a challenging task (Lindsey and Bocian, 2011; Nishimori et al., 2009; Palomaki and Dinolfo, 2010). The use of metal complexes herein is desirable, as their redox properties might allow for such data storage (Lindsey and Bocian, 2011; Terada et al., 2011; de Ruiter et al., 2010c; Fabre, 2010).

The present study introduces a multi-component SPMA with complexes of Ru and Os (1, 2), cross-linked with a palladium salt, for multi-state data storage (for other multicomponent assemblies see: Motiei et al., 2011a; Mondal et al., 2011; Nair et al., 2011; Palomaki and Dinolfo, 2010; Gauthier et al., 2008; Miyashita and Kurth, 2008; Schiitte et al., 1998; Liang and Schmehl, 1995). The self-propagating nature of these assemblies results from the storage of excess of palladium within the assembly, which allows for the exponential increase of the SPMA after each chromophore deposition (Motiei et al., 2008). The nature of complexes 1 and 2 ensures that the geometry, size, symmetry and coordination chemistry is nearly identical, while the electrochemical properties are dissimilar. This dissimilarity is reflected in the two characteristic oxidation/reduction processes for both the Os and Ru centers in the resulting SPMAs. The separate addressability of these metal centers in a single assembly results in a solid-state platform that ensures the physical separation of the memory states. A dual optical read-out at λ=495 and 700 nm resulted in the construction of binary and ternary memory respectively, where at λ=495 nm three different states can be distinguished based on the absorbance of complex 1 or 2. In this regard our SPMAs are suitable for HDDS, under ambient conditions, in a dynamic/static random access memory (DRAM/SRAM) like fashion.

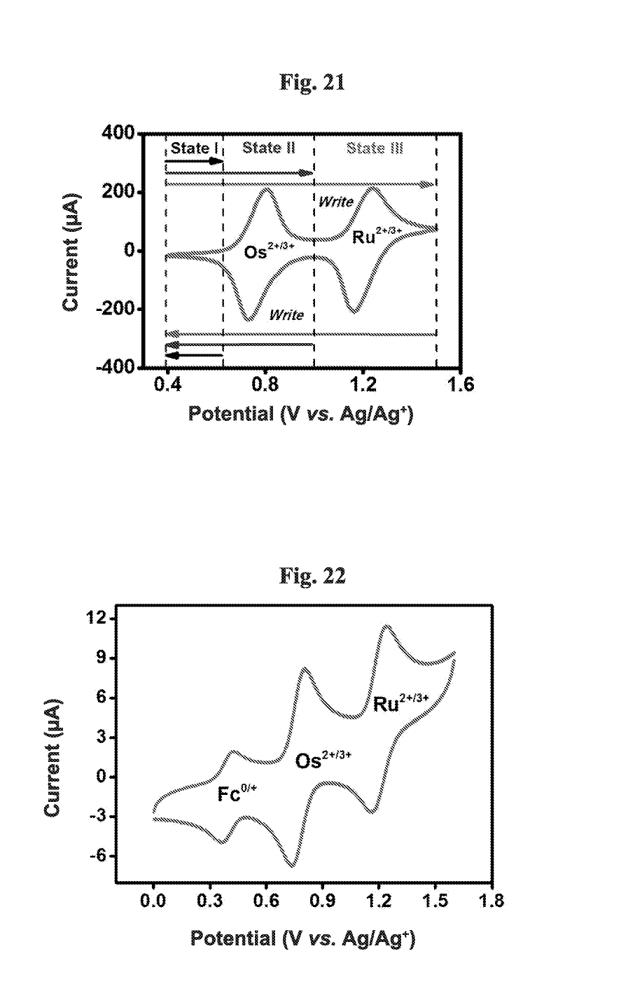

The SPMAs were generated by alternate and iterative immersion of a pyridine-terminated template layer, on silicon, ITO or quartz (Kaminker et al., 2010), in a 1.0 mM solution of Pd(PhCN)₂Cl₂ in THF, followed by immersion in 0.2 mM solutions of complexes 1 or 2 in THF/DMF, 9:1 v/v (FIG. 1). These SPMAs were characterized by cyclic voltammetry (CV), ex situ UV/Vis spectroscopy, spectroscopic ellipsometry, and spectroelectrochemistry. The CVs of the SPMAs on ITO exhibits nearly identical electrochemical behavior as a mixture of the two metal complexes (1, 2) in solution (FIGS. 14 and 22). The large separation of the half-wave potentials (0.447 V) between the surface-confined Os and Ru complexes (1, 2) is important as it allows for the selective addressing of these metal centers. Three distinct states can be written, by applying potentials of: 0.40, 0.95 or 1.60 V respectively. The resulting SPMA oxidation states: State I: Os²⁺1 Ru²⁺, State II: Os³⁺|Ru²⁺ and State III: Os³⁺|Ru³⁺ can be used for ternary data storage (FIGS. 21 and 23-25).

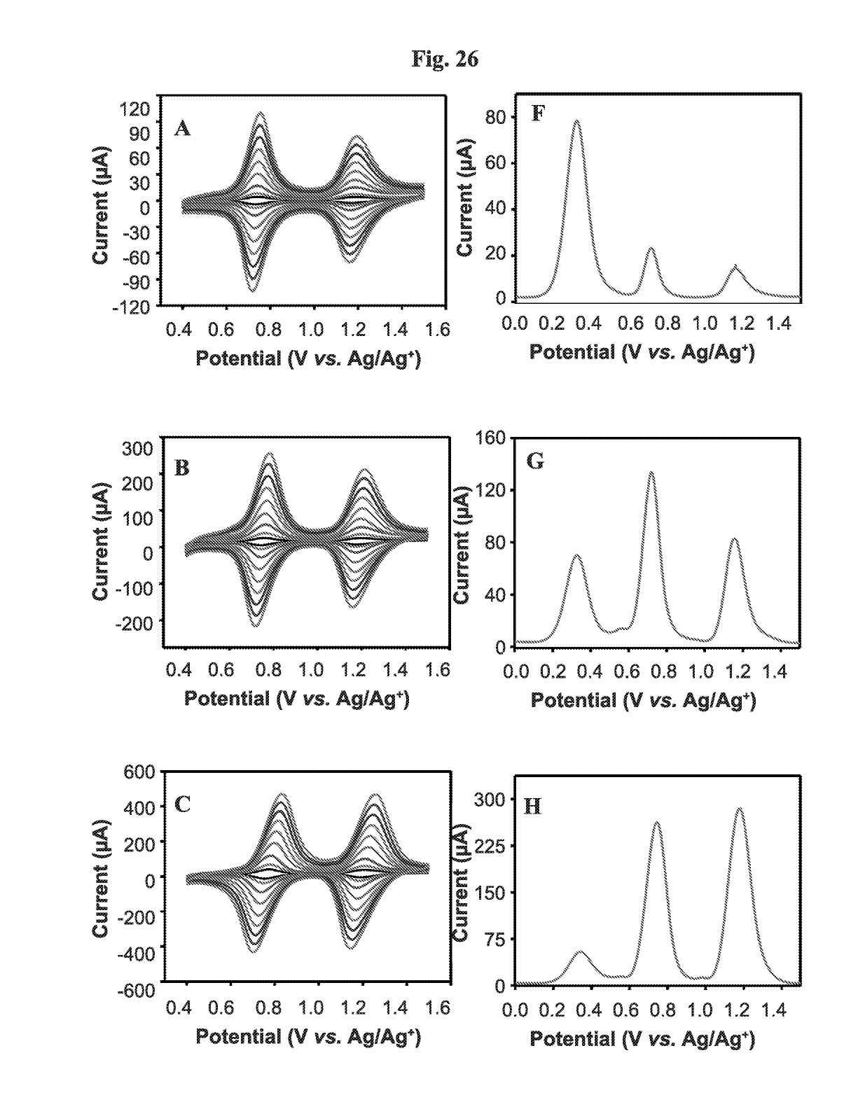

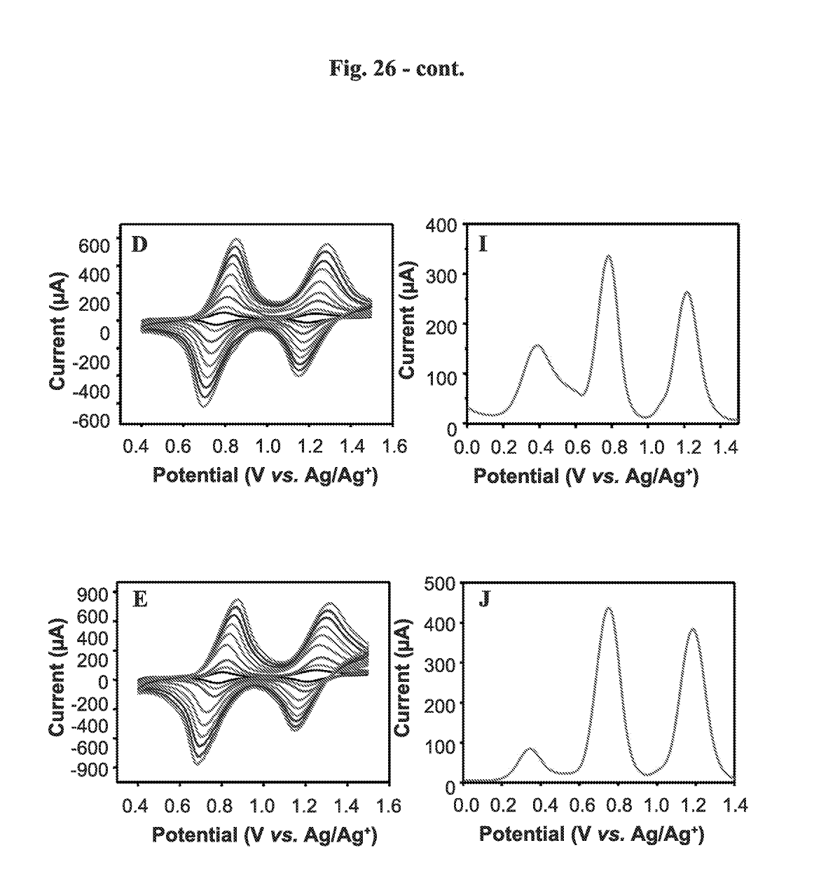

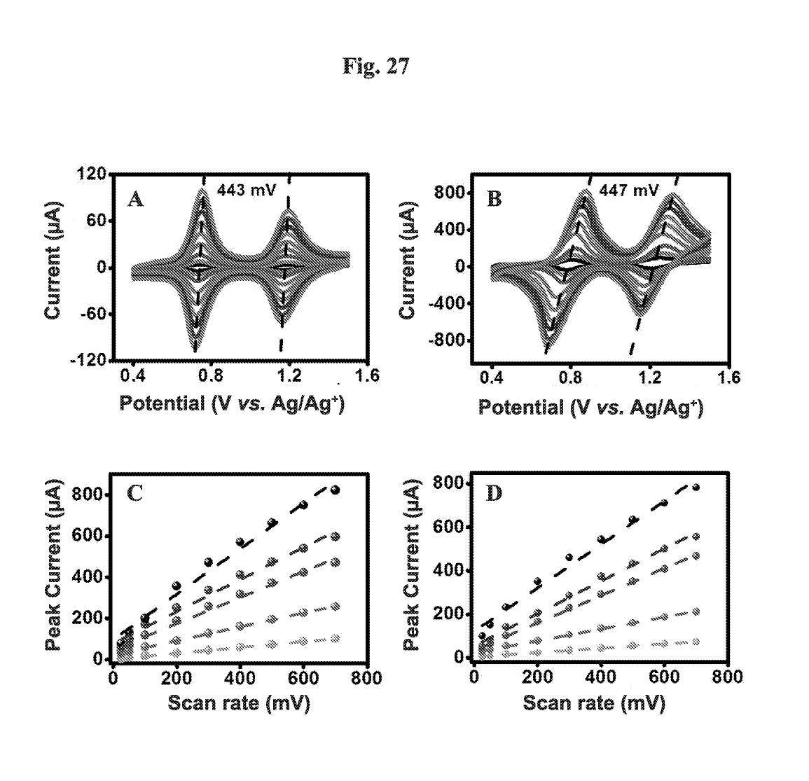

CVs and differential pulse voltammograms (DPVs) were recorded for SPMA with thicknesses up to 54 nm (FIG. 26, panels A-J). For example, the CVs for assemblies with thicknesses of 5.4 and 54.3 nm are shown in FIG. 27. The oxidative peak-current of both metal centers in the SPMAs are directly proportional to the scan rate between 25 and 700 mVs⁻¹ (FIG. 27, panels A-D). These observations indicate that the Os- and Ru-centers are surface-confined and the electron transport is not limited by diffusion (Bard and Faulkner, 2001).

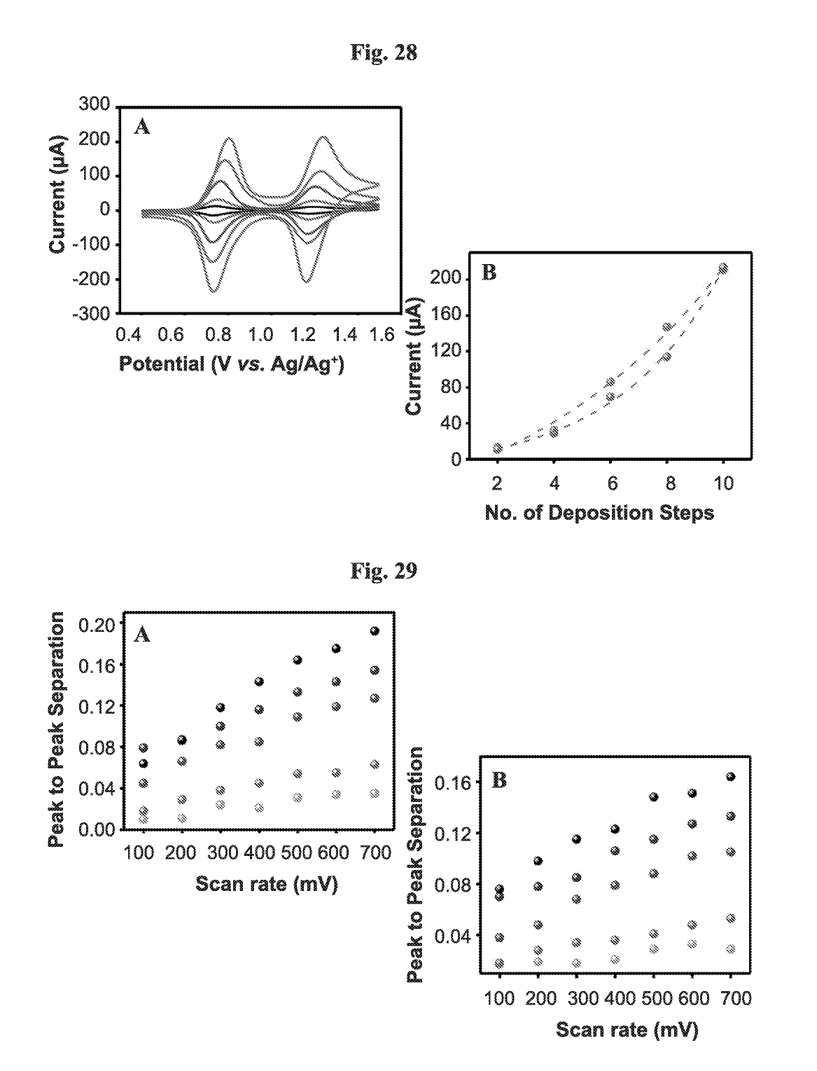

Upon increasing the assembly thickness, the peak-to-peak separation increases from 10 to 79 and from 17 to 76 mV for the Os^{2+/3+} and Ru^{2+/3+} redox-couples, respectively. The increase in the peak-to-peak separation is indicative of a decrease in the kinetics of the electron transfer, with increasing SPMA thicknesses (FIG. 28, panel A) (Ram et al., 1993). A similar effect was observed with increasing scan rates, although this effect is minimal below a thickness of −12 nm (FIG. 29) (Ram et al., 1993). Importantly, the large separation between the half-wave potentials for the Os and Ru metal centers is preserved for SPMAs with a thickness of 5.4 and 54.3 nm respectively (FIG. 27, panels A-B).

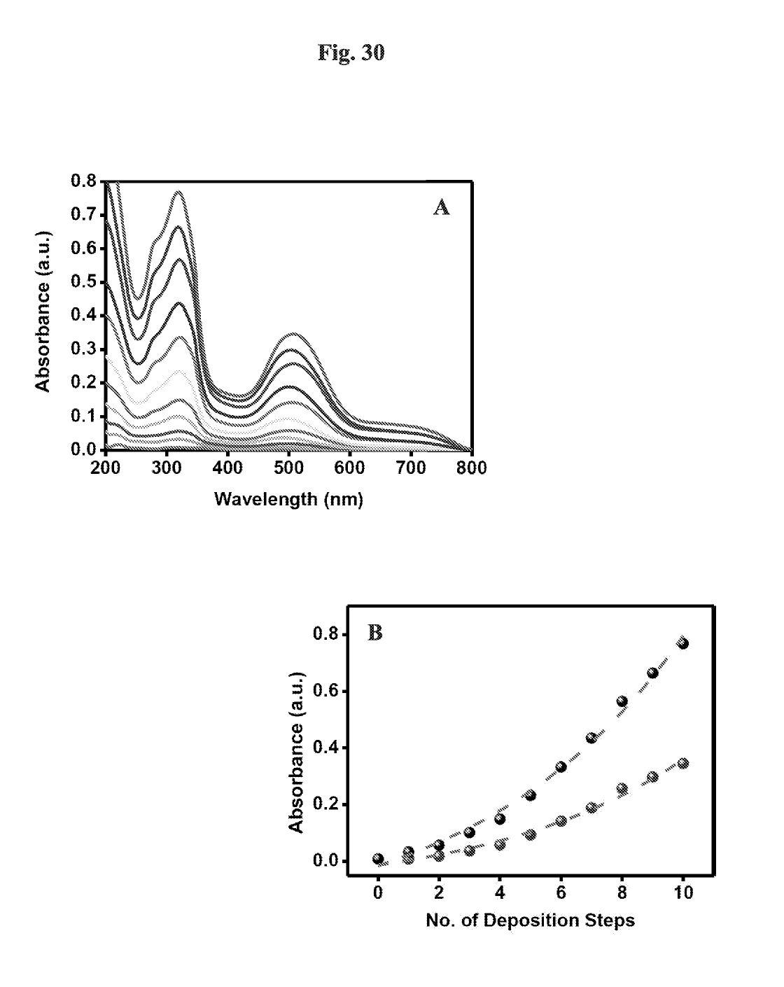

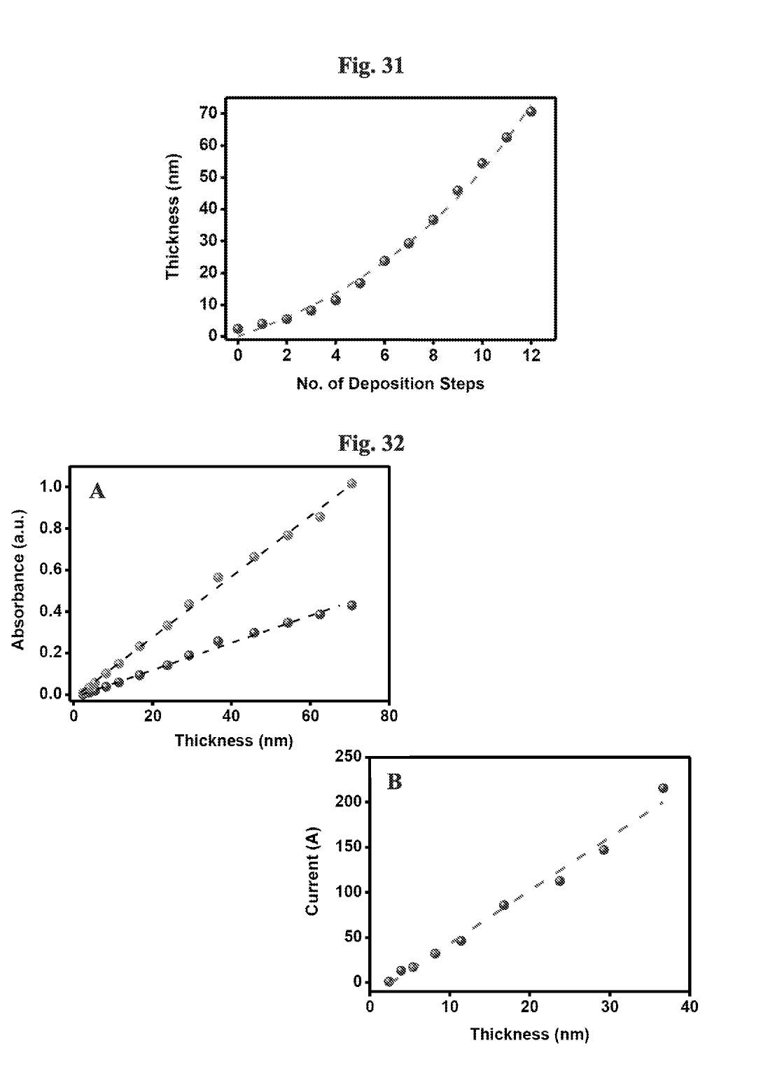

Characterization of the SPMAs by UV/Vis spectroscopy revealed that the SPMAs grow exponentially. The exponential growth results from the storage of excess palladium in the forming SPMA which is porous (Motiei et al., 2011b; Motiei et al., 2010a). Each deposition step of 1 or 2 exhibits the characteristic MLCT band of the corresponding metal center. The alternating deposition of the metal centers on the surface is evident from the variation of the λₘₐₓ of the SPMA that varies between 495 and 510 nm, which corresponds to the λₘₐₓ of the MLCT bands of the Ru and Os complexes (FIG. 30). The exponential growth of the SPMA was further confirmed by spectroscopic ellipsometry (FIG. 31) and by cyclic voltammetry (FIG. 28). The linear relationship between the SPMA thickness, absorbance and peak current indicates that there is a good correlation between the exponential growth in the thickness and the absorption, and designates a homogeneous and regular deposition of the molecular components in each deposition step (FIG. 32).

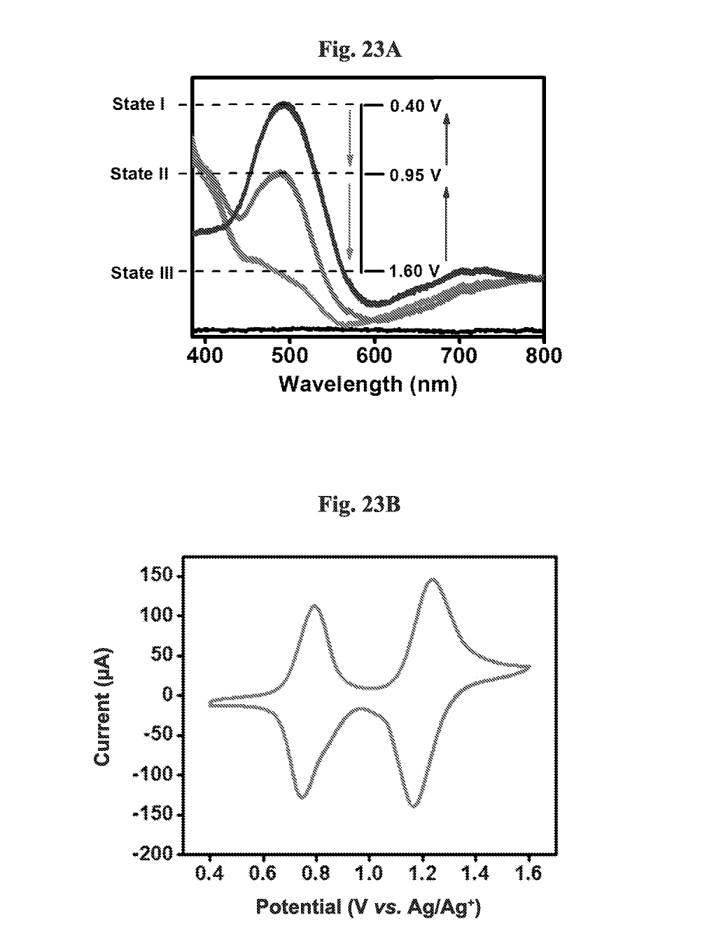

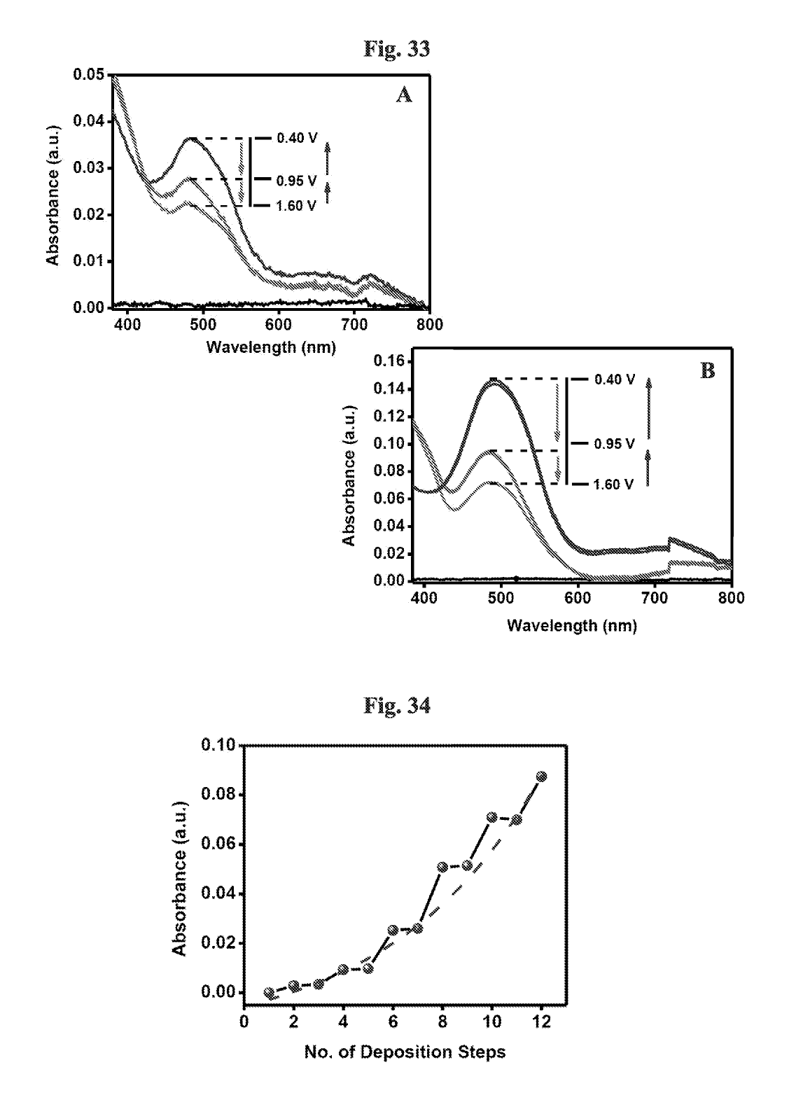

The electrochemical properties of the SPMAs permit the formation of three distinct states (FIG. 21; State I: Os²⁺|Ru²⁺, State II: Os³⁺|Ru²⁺ and State III: Os³⁺|Ru³⁺), and resembles a ternary device, in which the ternary switching is independent of the assembly thickness (11-54 nm) (vide infra). Though, the ON/OFF ratio increases with increasing film thickness, with a subsequent decrease in the signal-to-noise ratio (FIGS. 26 and 33). To demonstrate the electrochemical-based ternary data storage and optical read-out, an SPMA on ITO was used. Applying a potential of 0.40 V to the assembly ensures that both Ru and Os centers are fully reduced and the ¹MLCT at λ=495 shows an intense absorption (FIG. 23; blue trace—State I: Os²⁺|Ru²⁺). When holding the potential at 0.95 V, all the Os-based components of the assembly are oxidized (FIG. 23; green trace—State II: Os³⁺|Ru²⁺), while the Ru-based components are still in their reduced state. The oxidation of the Os metal center is indicated by a concurrent decrease of both the ¹MLCT and ³MLCT bands at λ=495 and 700 nm, respectively. Full oxidation of the assembly, as indicated by full bleaching of the ¹MLCT band, is accomplished by applying a potential of 1.60 V (FIG. 23; red trace—State III: Os³⁺|Ru³⁺).

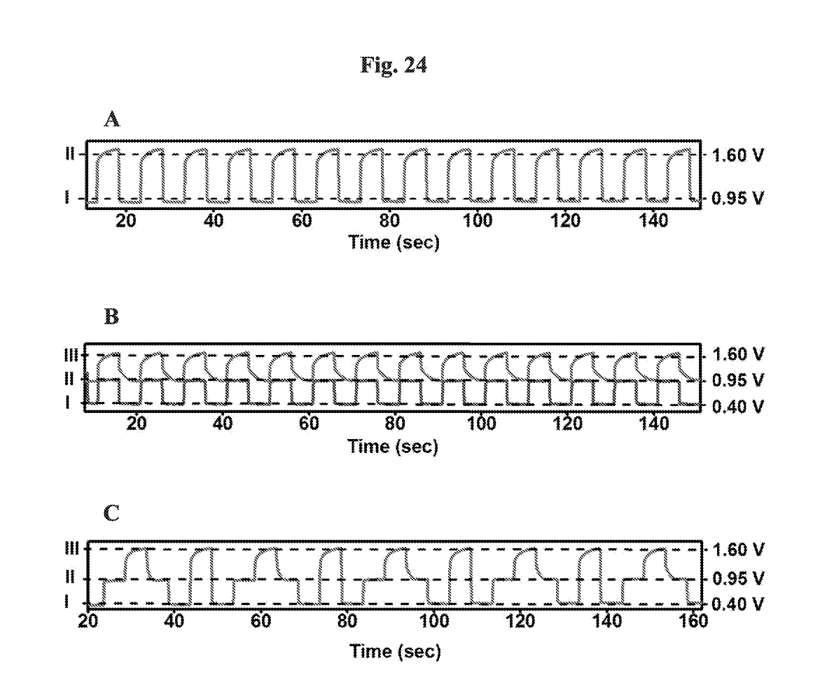

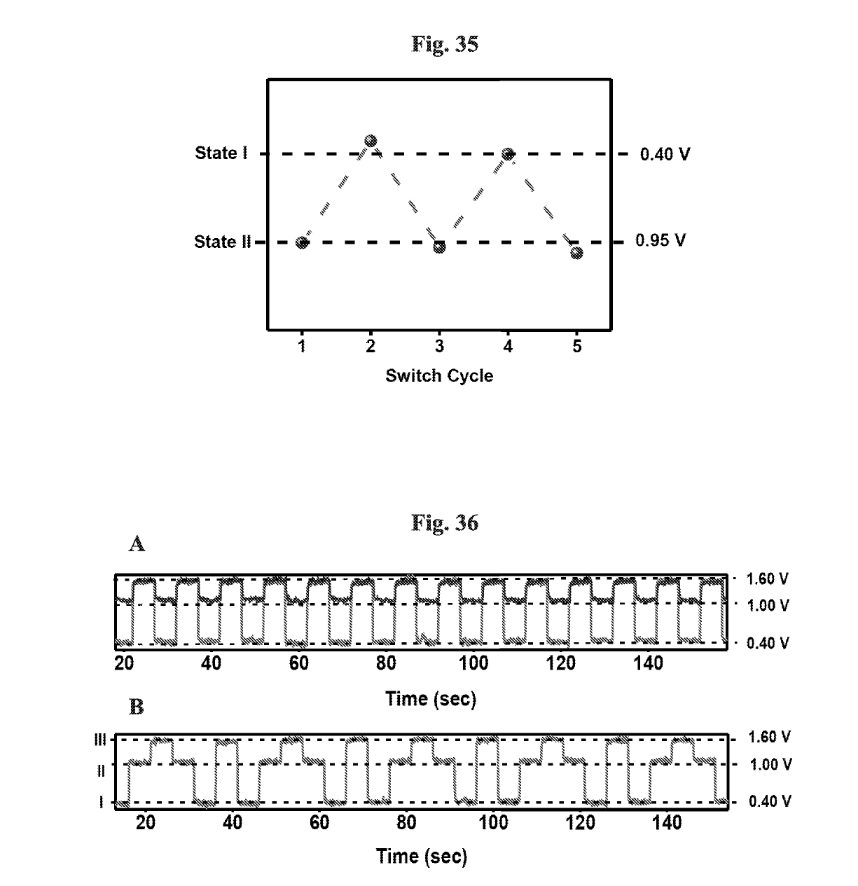

Discrimination between the Os^{2+/3+}- and Ru^{2+/3+}-based redox processes is optically possible since the Ru-based complex 1 lacks a ³MLCT band at λ≈700 nm (Campagna et al., 2007; Juris et al., 1988). As a consequence, a decrease of the ³MLCT band is only observed when a potential of 0.95 V (Os²⁺→Os³⁺) is applied, whereas such a decrease is absent when a potential of 1.60 V (Ru²⁺→Ru³⁺) is used (FIG. 23). Therefore, the ³MLCT could be used for the formation of binary memory, as it only switches between two states, i.e. only when the Os centers are oxidized (FIGS. 23 and 33-35). Consequently, our SPMA can be read-out simultaneously in a dual mode, i.e., 495 and 700 nm, for the formation of ternary and binary memory respectively. Obviously, one could also apply 5 s pulses of 0.40 V and 1.60 V to the SPMA (FIG. 24, panel A), which results in binary switching, albeit this is at the cost of the dual read-out.

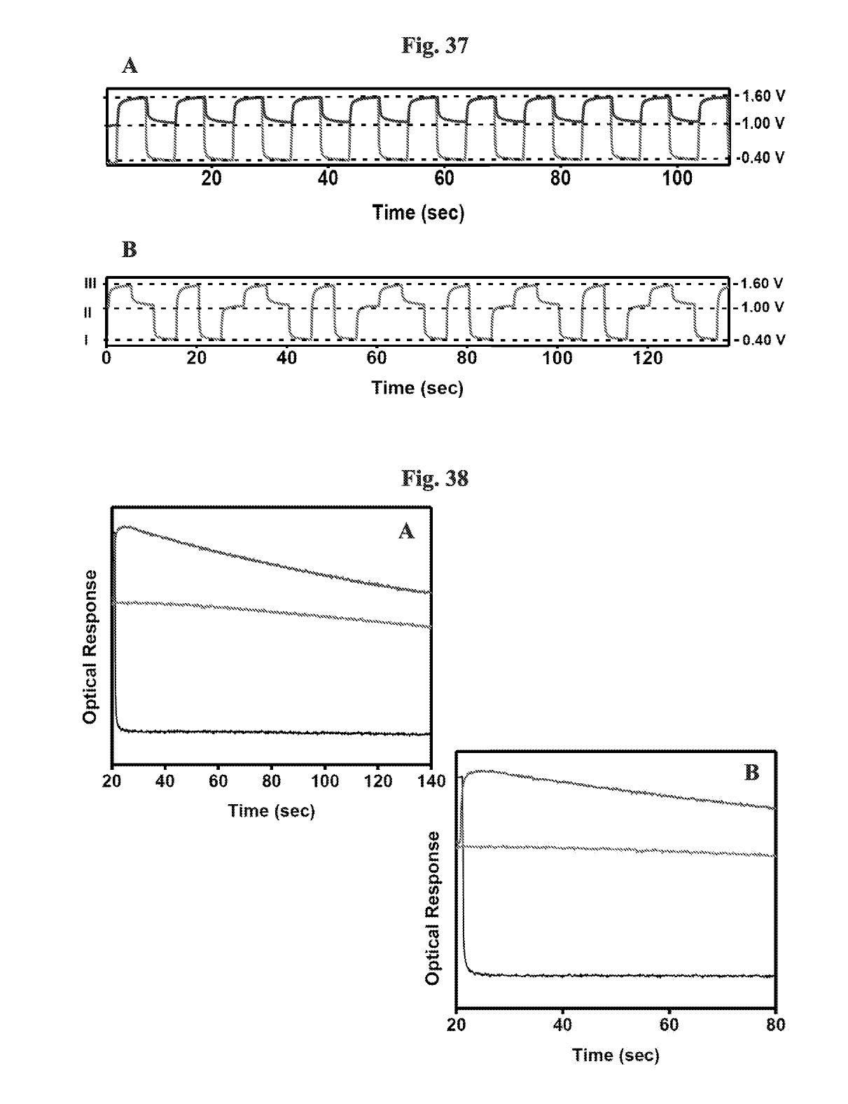

Based on the abovementioned three-state switching, the ternary memory was constructed, where the presence or absence of the applied potentials is defined as the input and the optical response of the ¹MLCT at λ=495 nm is used as the read-out (output) of the memory, e.g., applying a potential of 1.60 V is defined as write state III. Initially, the reversible separate addressing of the Ru and Os metal complexes was demonstrated for ternary applications (FIG. 24, panel B). The blue trace shows the switching of the Os metal centers upon applying a double potential step between 0.40 and 0.95 V. It was observed that the switching from Os²⁺→Os³⁺ is more efficient, than the switching from Ru²⁺→Ru³⁺ (red trace), as evidenced by a gradual increase of the optical response, upon applying a potential of 1.60 V until full oxidation of the SPMA occurs (FIG. 24, panel B; red trace). However, this observed effect is absent for the oxidation of the Os metal centers, which is nearly instantaneous. The gradual oxidation of the Ru metal centers at higher thicknesses is due to the more distant Ru centers, with respect to the ITO surface, that might become more difficult to oxidize. This effect was not observed for SPMAs having a lower thickness (e.g., 11 nm vs. 29 or 54 nm), where the oxidation of the Ru is nearly instantaneous upon applying the potential (FIGS. 36-37). The ternary memory was demonstrated by applying triple potential steps, and resulted in three clearly distinguishable absorption states (FIG. 24, panel C), with retention times up to several minutes (FIG. 38). Importantly, the ternary information is not processed by the SPMA as a whole, but rather by the individual type of polypyridyl complexes; Os or Ru, respectively. Thus, the precise optical response of a ternary component was utilized in order to achieve the multiple states, rather than relying on a binary switching mechanism. The ternary switching; thereby, is independent of the SPMA thickness. This is a clear advantage over our previously reported 2-based SPMA (de Ruiter et al., 2010a).

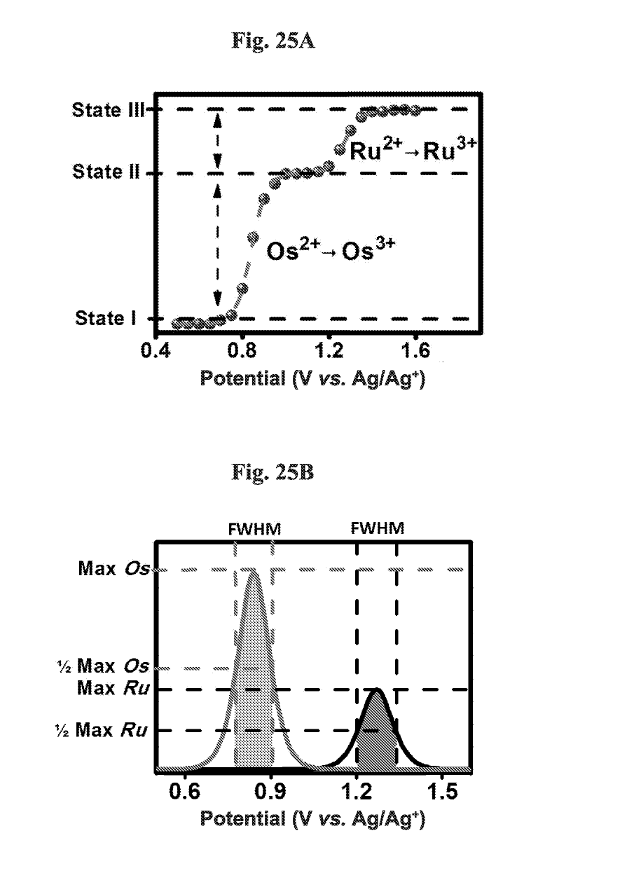

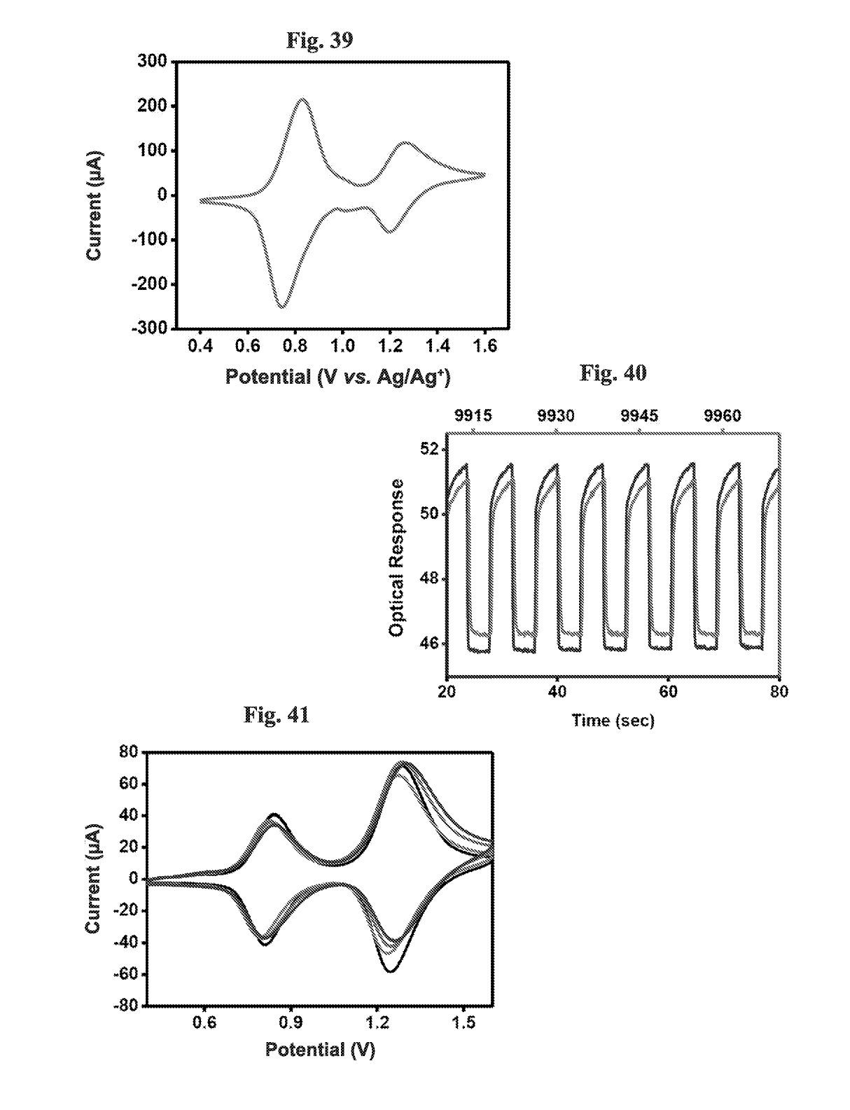

In order to assess the electrochromic properties of the SPMAs for ternary data storage in detail, the optical responses of the SPMAs were measured as a function of the potential. For instance, gradually increasing the switching potential between 0.5 and 0.5+n0.05 V, with n=0-22, in the chronoamerometric mode, results clearly in a double-step sigmoidal shape that is associated with the characteristic electrochemical properties of the redox-couples Os^{2+/3+} and Ru^{2+/3+} (FIG. 25A). This confirms the separate addressing of the Ru and Os metal-complexes in the SPMA. The double sigmoidal shape is important; differentiation of the sigmoidal fit produces a normal distribution centered on the E_{1/2} of the Os and Ru complexes (FIG. 25B and FIG. 39). Within this, the full-width at half-maximum (fwhm) is an important figure-of-merit as this value reflects the accuracy of the memory (de Ruiter et al., 2010b). The observed fwhm of 130 mv and 170 mV for the Os^{2+/3+} and Ru^{2+/3+} redox couples are comparable to the fwhm values obtained from electrochemical measurements on our previously reported SPMAs, that contain only one metal center (de Ruiter et al., 2010a; Motiei et al., 2011b; Motiei et al., 2010a). The ratio of the optical responses for the oxidation of the Os and Ru reflects the ratio between the corresponding charges in the CV (FIG. 39).

The thermal and electrochemical stability of the SPMAs were tested by cycling the potential for at least 1000 times between 0.40 and 1.60 V with 5 s intervals, and heating the SPMA to 130° C. in air for several hours. Both experiments confirmed the robust nature of the SPMA as there is no significant signal loss in the optical absorption or in the peak current of the Os^{2+/3+} and Ru^{2+/3+} redox-couples in the SPMA (FIGS. 40-41).

### Study 3

### Composite Molecular Assemblies: Nanoscale Structural Control and Spectroelectrochemical Diversity

### Experimental

General Procedures.

See Study 1 above.

XRR.

Synchrotron XRR studies were performed at beamline X6B of the National Synchrotron Light Source (NSLS; Brookhaven National Laboratory, USA), using a Huber four-circle diffractometer in the specular reflection mode (the incident angle is equal to the exit angle θ). The reflected intensity was measured as a function of the scattering vector component q_{z}=(4π/λ) sin θ, perpendicular to the reflecting surface. X-rays of energy E=10 keV (λ=1.240 Å) were used with a beam size of 0.3 mm vertically and 0.5 mm horizontally. The resolution was 3×10⁻³ Å⁻¹. The samples were placed under a slight overpressure of helium during the measurements to reduce the background scattering from the ambient gas and radiation damage. The off-specular background was measured and subtracted from the specular counts. Details of the data acquisition and analysis are given elsewhere (Evmenenko et al., 2001; Evmenenko et al., 2011). The XRR measurements were performed at 20-25° C.

XPS.

Angle-resolved (AR)-XPS were made at different takeoff angles with a PHI 5600 Multi Technique System (base pressure of the main chamber 2×10⁻¹° Torr). Resolution, corrections for satellite contributions, procedures to account for steady-state charging effects, and background removal have been described elsewhere. Experimental uncertainty in binding energies lies within ±0.4 eV.

Electrochemical measurements.

Cyclicvoltammetry and chronoamperometry were performed in a three-electrode cell configuration on a CHI 660A potentiostat. ITO electrodes functionalized with our SPMAs were used as the working electrode, whereas Pt- and Ag-wires were used as counter and references electrode, respectively. Solutions of Bu₄NPF₆ (0.1 M) in dry acetonitrile were used as the electrolyte. The Fc/Fc⁺ redox-couple, used as internal standard, was set at 0.40 V vs. SCE under these conditions (Connelly and Geiger, 1996). All electrochemical measurements were performed at RT in air.

Spectroelectrochemistry.

Spectroelectrochemical measurements were performed in a 3 ml quartz cuvette fitted in a Varian Cary 100 spectrophotometer operating in the double-beam transmission mode (200-800 nm). The potential was modulated with a CHI 660 A potentiostat operating in a three-electrode cell configuration consisting of (i) an SPMA-functionalized ITO substrate as the working electrode; (ii) a Pt wire as the counter electrode; and (iii) an Ag-wire as the reference electrode. Dry propylene carbonate containing 0.1 M Bu₄NPF₆ was used as the electrolyte solution. The UV-vis spectra were recorded in the dark, as soon as the electrochemical potential was applied. All spectroelectrochemical measurements were performed in the chronoamperometry mode at RT.

### Introduction

Understanding the many variables involved in forming supramolecular structures using metal-ligand coordination is often challenging. Factors like coordination number and geometry together with the nature of the ligand and the metal salt are but a few examples that are important in the complex niche of coordination chemistry (Ribas, 2008). Variation of the above-mentioned parameters has led to numerous fascinating structures (Ribas, 2008; Alexeev et al., 2010). Nitschke et al. demonstrated the formation of copper and zinc helicates in solution, whose stability not only depends on the ratio of the ligands, but also on the addition sequence (Campbell et al., 2010; de Hatten et al., 2012). The delicate interplay between those parameters resulted in dynamic self-assembly processes, able to cascade chemical transformations similar to signal transduction cascades in biology (Campbell et al., 2010). Stang et al., reported various well-defined shapes such as triangles, squares, rectangles, and three-dimensional structures such as cubes, by considering the geometrical constraints implied by the ligands and metal salts (Cook et al., 2009; Northrop et al., 2009; Zheng et al., 2010). In the last decade, these principles have also been extended to surface-chemistry by others (Altman et al., 2008; Doron-Mor et al., 2000; Hoertz and Mallouk, 2005; Kanaizuka et al., 2008; Katz et al., 1991; Kurita et al., 2010; Mondal et al., 2011; Motiei et al., 2008; Shekhah et al., 2009; Terada et al., 2012; Tuccitto et al., 2009; Zacher et al., 2011). The chemical modification of inorganic surfaces is an important development in the ongoing research towards hybrid functional materials. Diverse materials have been obtained that have found applications in sensors (de Ruiter et al., 2008; Gupta and van der Boom, 2006), electro-optics (Frattarelli et al., 2009; Rashid et al., 2003), photovoltaics (Motiei et al., 2010b), catalysis (Gao et al., 2010), and organic field effect transistors (OFETs) (Klauk et al., 2007; Ortiz et al., 2010) amongst others. Although there are established techniques available for surface modification (Shirman et al., 2008; Cerclier et al., 2010; Perl et al., 2009; Xia and Whitesides, 1998; Kumar et al., 1995; Piner et al., 1999; Andres and Kotov, 2010; Scheres et al., 2010), layer-by-layer assembly from solution is attractive as it offers many advantages. For instance, multiple molecular building blocks can be incorporated in a highly ordered and structured manner by utilizing directional inter-molecular forces such as hydrogen bonding, π-π stacking, and electrostatic, dipole-dipole or van der Waals interactions (Desiraju, 2007; Loi et al., 2005; Cragg, 2005; Lehn, 1995; Schneider, 1991). The information that is encoded in the molecular building blocks—by means of their geometry and inter-molecular interactions—govern the resulting supramolecular structures (Northrop et al., 2009). To demonstrate control over the sequence in which the molecules are arranged in an assembly is of critical importance for governing their material properties (de Ruiter et al., 2013). Such a molecular control can be implemented by a using SDA. Biology makes extensive use of this principle, for instance in cis-regulatory elements in DNA (Wittkopp and Kalay, 2012).

In the present study, we show how the internal composition and properties of the SPMAs (I-III) can be controlled by a SDA. For our SDA, we use polypyridyl complexes 1 and 2. These ruthenium (1) and osmium (2) complexes are highly stable, and are known to exhibit reversible electrochromic behavior by electrochemically changing their oxidation state from M²⁺→M³⁺ (M=Os, Ru) (de Ruiter et al., 2013; Motiei et al., 2009). These type of iso-structural and iso-electronic complexes are used in dye-sensitized solar cells (Wu et al., 2012; Yin et al., 2012; Freys et al., 2012) and electroluminescent devices (Buda et al., 2002; Welter et al., 2003). The SDA follows an iterative deposition procedure illustrated in FIG. 1. XPS and XRR revealed how the assembly of two metal complexes (1, 2) resulted in distinct interfaces with well-defined thicknesses and a low surface roughness. Due to the low surface roughness there is little inter-mixing of the metal complexes at the Ru|Os or Os|Ru interface. The defined interfaces combined with the use of iso-structural metal complexes allow for continuous assembly formation with a near homogeneous electron density. Although the SPMAs show nearly identical optical properties and uniformity in their electron-density, each SPMA exhibits a different distribution of oxidation potentials through-out the assembly. Reversible electrochemical behavior is observed when the interfaces are below a certain threshold thickness (>8.0 nm) regardless of the oxidation potential and composition of the interfaces. In contrast, oxidative catalytic electrochemical behavior is observed when a uniform interface is formed with a high oxidation potential, followed by an interface with a lower oxidation potential. This electrochemical behavior can be reversed, by reversing the assembly order of the interfaces, i.e., by first assembling a uniform interface with a low oxidation potential, followed by an interface with a higher oxidation potential. The relationship between the internal composition, distribution of oxidation potentials and the thickness of these interfaces is elucidated by means of differences in the electrochemistry and spectroelectrochemistry. This establishes the direct link, and importance, of the internal composition and applied SDA strategies for SPMAs.

### Results and Discussion

Molecular Assembly Formation.

The SPMAs were formed by immersing pyridine-terminated template layers in a 1.0 mM THF solution of Pd(PhCN)₂Cl₂ to allow for the coordination of PdCl₂ (Kaminker et al., 2010). This enables the first deposition of one of the metal complexes (1, 2) on ITO, quartz, or silicon. Iterative immersion in a THF solution of Pd(PhCN)₂Cl₂, followed by immersion in a THF/DMF (9:1) solution containing the metal polypyridyl complex 1 or 2 (0.2 mM) resulted in formation of SPMAs with various compositions. In this study, three possible assembly sequences were used: (i) alternating deposition of 1 and 2; (ii) successive deposition of 1, followed by 2; and (iii) successive deposition of 2, followed by 1 (de Ruiter et al., 2013). As a result, the SPMAs only differ in the internal ordering of the used metal complexes. In accordance with the assembly strategy the names of the SPMAs coincide. SPMA I | Ruₓ—Os_{y}, SPMA II | Ruₓ—Os_{y}, and SPMA III | Osₓ—Ru_{y}, refer to SDA I, II and III, where x and y denote the number of depositions steps in which complexes 1(Ru) or 2 (Os) were deposited.

UV-Vis Spectroscopy and Spectroscopic Ellipsometry.

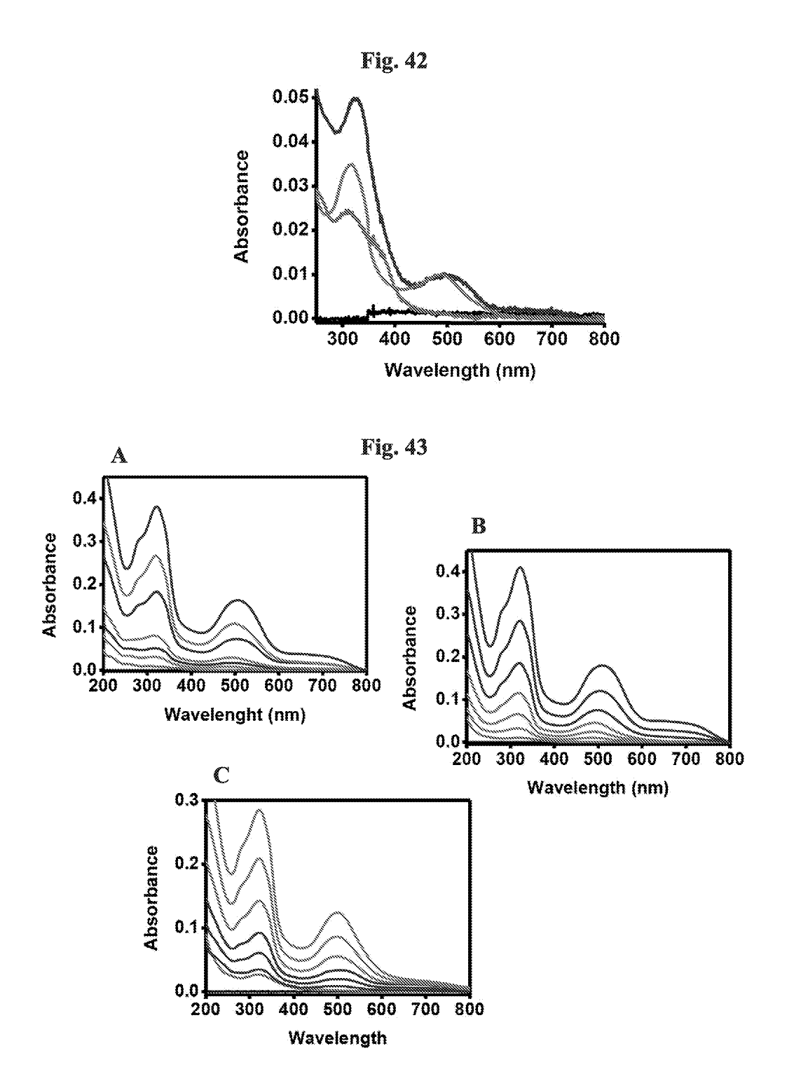

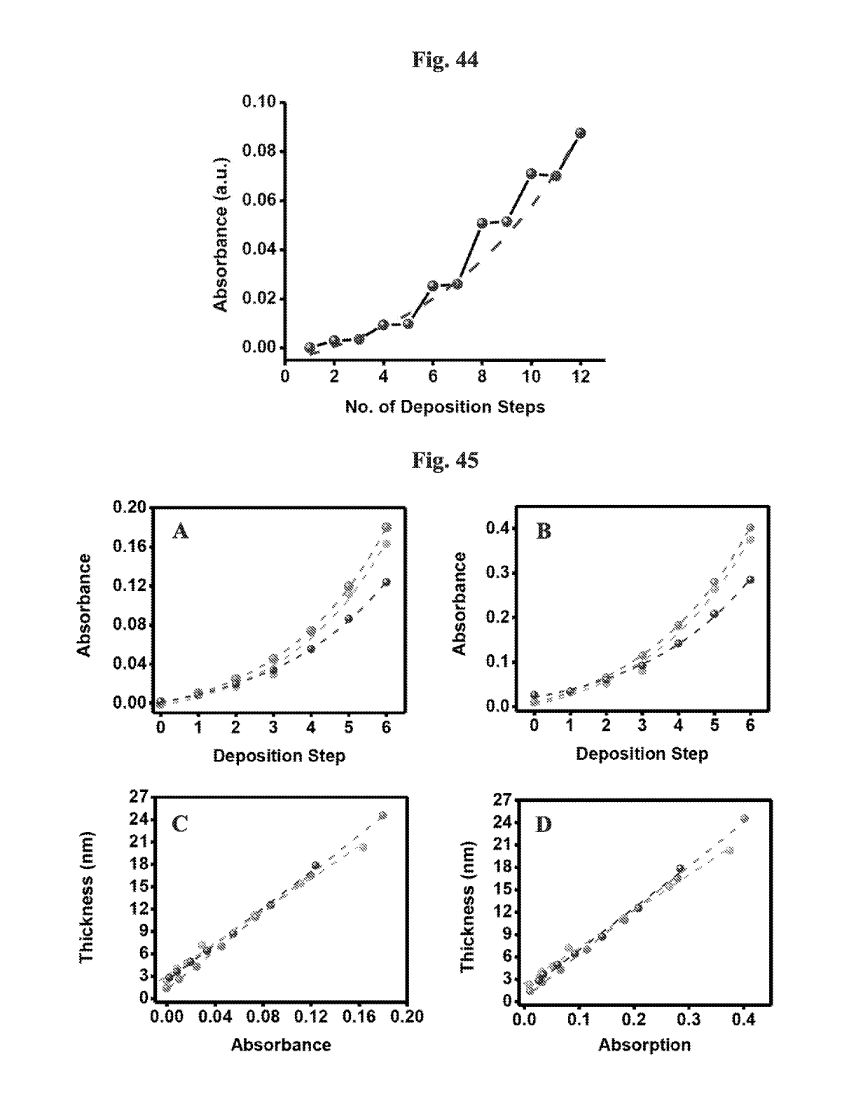

The growth of the SPMAs was followed by UV-vis spectroscopy with SPMAs formed on quartz substrates. The absorption spectra of complexes 1 and 2 are nearly identical (FIG. 42). Both exhibit a strong absorption in the UV-region, at approximately λ=320 nm. This absorption is characteristic for a ligand centered π-π* transition (Campagna et al., 2007; Kumaresan et al., 2007). A broad absorption band in the visible region is observed between λ=400-550 nm, which is the spin-allowed singlet-singlet transition from the ground state to the first excited state (Campagna et al., 2007; Kumaresan et al., 2007). This ¹MLCT band is characteristic for complexes of the type [M(bpy)₃][PF₆]₂, where M=Os, Ru or Fe (Campagna et al., 2007; Kumaresan et al., 2007; Bryant et al., 1971). For complexes 1 and 2, the maximum absorption intensity of the ¹MLCT bands are found at λ=490 and 510 nm, respectively. In addition, the absorption spectra of 2, exhibits an additional ³MLCT band between λ=600-750 nm, which is not present in the ruthenium analog 1. The appearance of the ³MLCT is due to the large spin-orbit coupling of the osmium atom that allows for the principal spin-forbidden singlet-triplet transition to occur (Crosby and Demas, 1971; Fujita and Kobayash, 1972). Since the SPMAs consist of a mixture of metal complexes 1 and 2, their optical spectra is expected to be the sum of their individual components. Indeed, the π-π*, ¹MLCT and ³MLCT band are clearly visible in the UV-vis spectra of SPMA I | Ru₃—Os₃, SPMA II | Ru₃—Os₃, and SPMA III | Os₃—Ru₃ (FIG. 43). The ³MLCT band permits us to examine the growth and the content of the osmium complex 2 in the SPMAs, without interference of complex 1. As a result, monitoring the growth of SPMA I | Ru₃—Os₃ at λ=700 nm, revealed a stepwise increase in the absorption of the ³MLCT band, which coincides with the alternating deposition of the Ru (1) and Os (2) complexes (FIG. 44).

Upon formation of SPMA I | Ru₃—Os₃, SPMA II | Ru₃—Os₃, and SPMA III | Os₃—Ru₃, the λₘₐₓ of the ¹MLCT either alternates (SPMA I) or exhibits a bathochromic (SPMA II) or hypsochromic (SPMA III) shift (FIG. 43). The change in ¹MLCT occurs according to the character of the metal complex, i.e. the λₘₐₓ of the ¹MLCT band will either shift more to 490 nm (1; Ru) or 510 nm (2; Os).

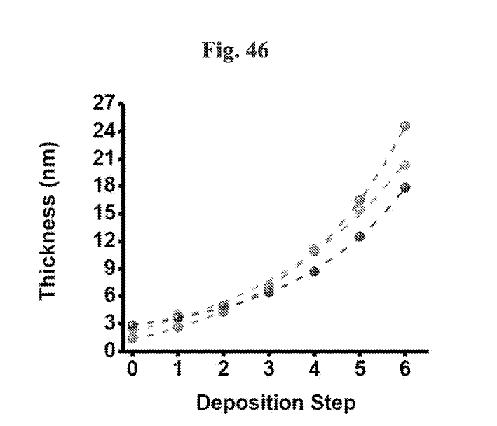

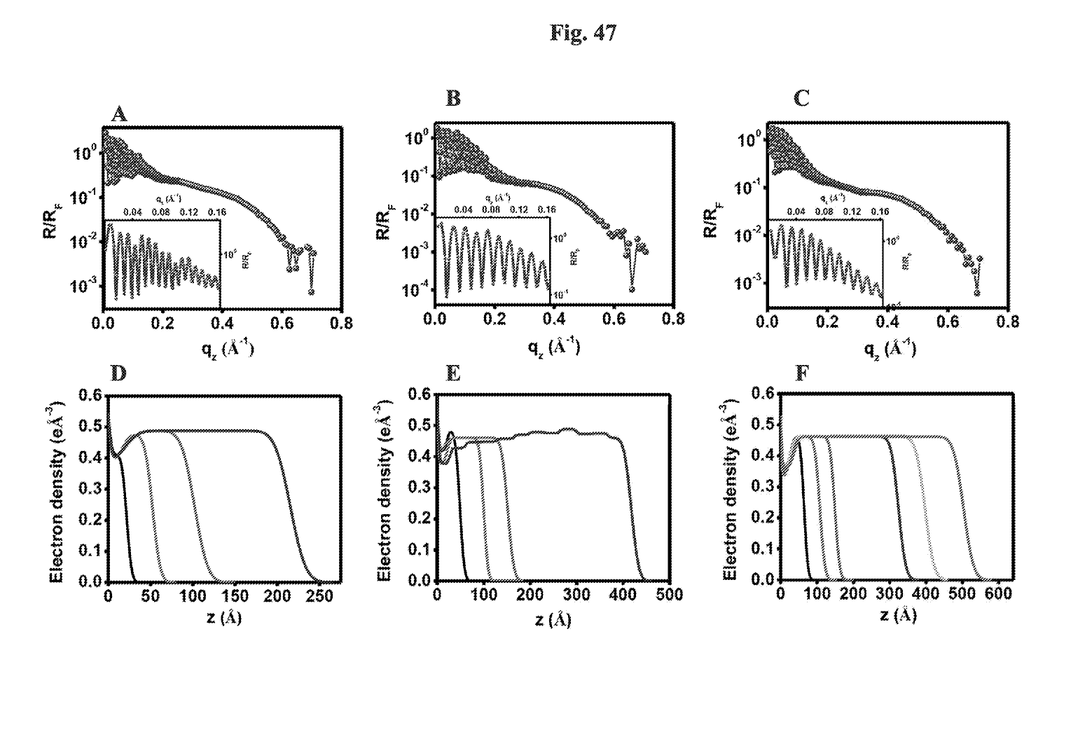

Monitoring the ¹MLCT and π-π* bands centered at λ=500 nm and λ=317 nm, respectively, revealed an exponential growth behavior for all three types of SPMAs (FIG. 45). Spectroscopic ellipsometry confirms this similarity, by a nearly identical evolution of the thicknesses for all SPMAs (FIG. 46). Exponential growth has also been observed in mono-metallic molecular assemblies by us and is caused by the porous nature of the SPMAs that allows the storage of excess of palladium (Motiei et al., 2008; Choudhury et al., 2010). For SPMAs generated by SDA I, the average increase of the thickness (ΔTₙₘ) does not exceed 7.0 nm per deposition step. This threshold is important as it shows that when the thickness of the ruthenium layer exceeds 8.0 nm in SDA II, catalytic electron transfer is observed (de Ruiter et al., 2013). For SPMAs generated by SDA I, catalytic electron transfer is not observed, since the thickness of the ruthenium layers does not exceed this threshold. The SPMAs exhibit a regular and homogeneous distribution of the metal complexes (1, 2), as shown by the linear correlation between the ¹MLCT or π-π* bands vs. thickness (FIG. 45, panels C and D). The formation of regular structures is also supported by XRR measurements, which show a constant electron density as a function of the film thickness (FIG. 47; vide infra).

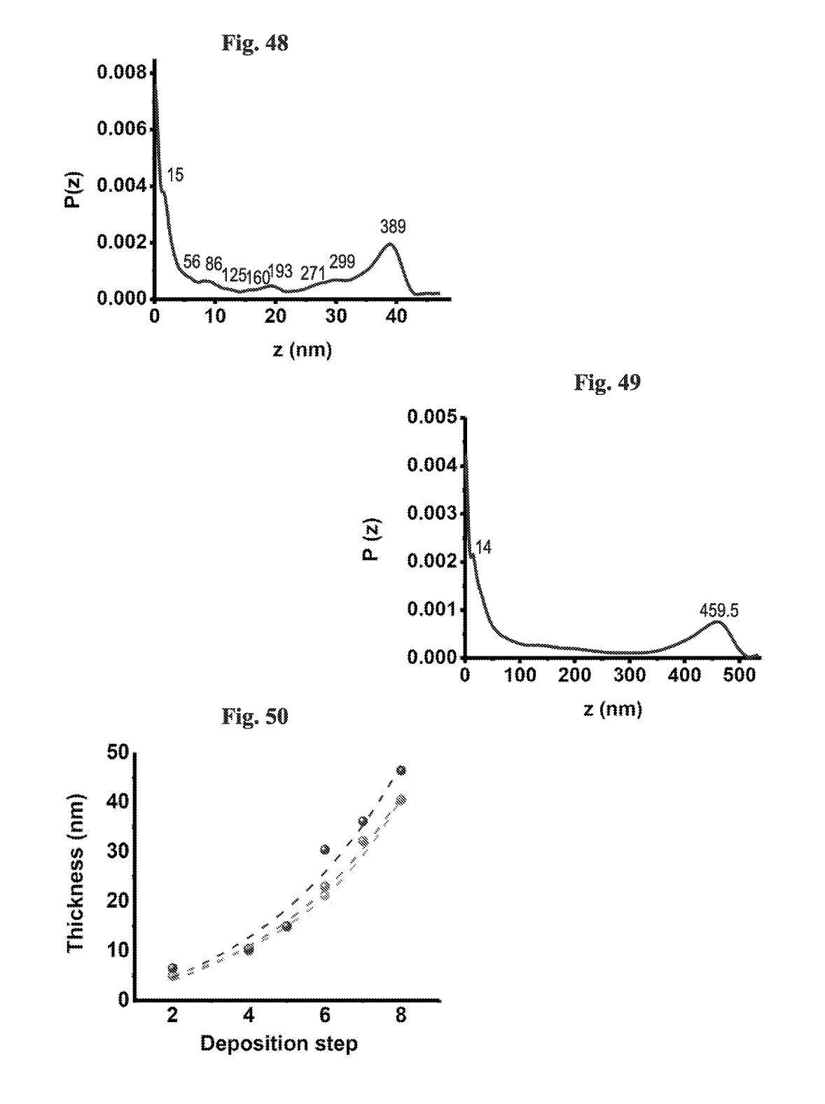

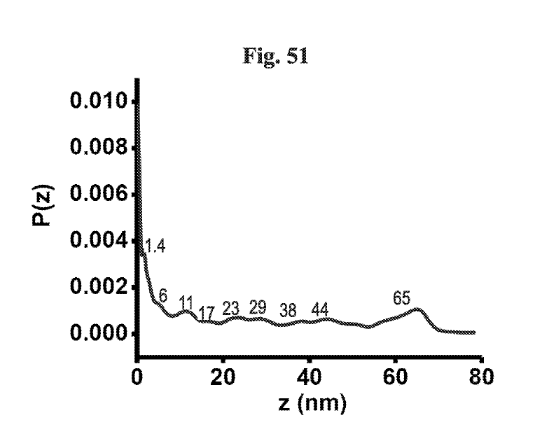

Synchrotron XRR. The XRR data demonstrates the uniformity of the SPMAs (FIG. 47). A summary of the XRR-derived structural parameters are shown in Table 1. The observed Kiessig fringes in SPMAs I-III, result from the destructive interference of reflections between substrate/film and film/air interfaces (FIG. 47, panels A-C) (Kiessig, 1931). The XRR-derived Patterson plots for SPMA I | Ru₆—Os₆, SPMA II | Ru₄—Os₄, and SPMA III | Os₄—Ru₄ are shown in FIGS. 48-50. For SPMA I | Ru₆—Os₆ and SPMA II | Ru₄—Os₄, fluctuations in the Patterson plots were observed, with local maxima at thicknesses that appear to correspond to the number of deposition steps (FIGS. 51 and 45). It is therefore plausible that in these SPMAs, the Os|Ru and Ru|Os interfaces cause minor structural perturbations, which result in slight non-uniformity of electron density profiles. In contrast, for SPMA III | Os₄—Ru₄, the Patterson plot shows a smooth interface, except for a local maxima at 1.4 nm, which correlates to the template layer (FIG. 49).

However, due to negligible changes in electron density between osmium and ruthenium layers, the small fluctuations in the Patterson functions—which usually indicate slight non-uniformity of the electron density profiles inside the SPMAs—are not reflected in the electron density profiles (FIG. 47, panels D-F). Indeed, the XRR-derived electron density profiles do not vary significantly as a function of the film thickness, and the resulting SPMAs have an average electron density of a ρ=0.46 eÅ⁻³ (Table 1). The similarity of the electron density of each layer is indicative of a homogeneous superlattice. Such a homogeneous superlattice was also confirmed by the optical data (vide supra), which showed that the molecular density (ρ) is constant, and does not vary significantly for SPMAs formed with SDA I-III (FIG. 45, panels C-D). The identical coordination chemistry of the metal complexes (1, 2), allows for maximum interaction between the two types of metal complexes is expected resulting in a continuous growth (FIGS. 40 and 42) and formation of homogeneous assemblies.

TABLE 1
Structural parameters of SPMAs created by the SDAs according to FIG. 1.
The data are obtained from XRR measurements and spectroscopic
ellipsometry.

| | | | | |
|---|---|---|---|---|
| Entry | σ_{film-air} (nm) | T_{film} (nm)^{a} | T_{film} (nm)^{b} | ρ_{film} (eÅ⁻³) |

SPMA I

| | | | | |
|---|---|---|---|---|
| Ru₁—Os₁ | 0.4 | 5.2 | 6.4 | 0.47 |
| Ru₂—Os₂ | 1.1 | 10.4 | 13.1 | 0.49 |
| Ru₃—Os₃ | 1.5 | 21.1 | 25.2 | 0.49 |
| Ru₄—Os₄ | 1.8 | 40.7 | 48.7 | 0.46 |
| Ru₆—Os₆ | 2.3 | 64.2 | 70.8 | 0.46 |

SPMA II

| | | | | |
|---|---|---|---|---|
| Ru₂—Os₀ | 0.6 | 4.9 | 5.4 | 0.48 |
| Ru₄—Os₀ | 0.7 | 10.0 | 11.3 | 0.46 |
| Ru₄—Os₁ | 0.8 | 14.8 | 17.0 | 0.46 |
| Ru₄—Os₂ | 0.9 | 23.0 | 25.3 | 0.46 |
| Ru₄—Os₃ | — | 32.1 | 38.7 | 0.46 |
| Ru₄—Os₄ | 1.5 | 40.4 | 46.8 | 0.46 |

SPMA III

| | | | | |
|---|---|---|---|---|
| Os₂—Ru₀ | 0.9 | 6.5 | 7.6 | 0.46 |
| Os₄—Ru₀ | 1.2 | 10.4 | 12.4 | 0.46 |
| Os₄—Ru₁ | 1.3 | 15.0 | 17.4 | 0.46 |
| Os₄—Ru₂ | 1.6 | 30.4 | 35.7 | 0.46 |
| Os₄—Ru₃ | 2.0 | 36.1 | 47.0 | 0.46 |
| Os₄—Ru₄ | 2.3 | 46.4 | 56.7 | 0.46 |

^{a}XRR-derived film thicknesses.
^{b}Ellipsometry-derived thicknesses for the XRR samples.

The XRR-derived thickness corresponds well with those derived from spectroscopic ellipsometry, and demonstrates and exponential growth behavior (FIG. 50). The surface roughness for all SPMAs varies between 5-10% of the film thickness. For instance, SPMAs with a film thickness of ˜40 nm display a surface roughness between 1.5-2.2 nm (Table 1). These values are comparable to previously reported values of SPMAs constructed with metal complex 2 (Motiei et al., 2008). The XRR data thus indicates the formation of homogeneous assemblies, with nearly constant electron densities with little variation among the SPMAs.

XPS (for a review of XPS on self-assembled architectures on surfaces see: Gulino, 2013). The internal composition of the SPMAs was analyzed by AR-XPS. For fully formed networks, with two pyridine groups coordinated to a palladium center, the following ratios are expected: Pd/N=0.17; Pd/M=1.5; and N/M=9 (M=Os or Ru) (Motiei et al., 2008). For all SPMAs, the XPS-derived elemental ratios are close to their expected values. However the palladium content is slightly higher than their predicted theoretical values. An higher palladium content is not uncommon, since our SPMAs are able to store excess palladium inside their porous network (Motiei et al., 2008). The ratios for SPMA I | Ru₄—Os₄, SPMA II | Ru₄—Os₄, and SPMA III | Os₄—Ru₄, are summarized in Table 2.

TABLE 2
XPS derived elemental ratios of SPMA I|Ru₄—Os₄, SPMA II|Ru₄—Os₄,
and SPMA III|Os₄—Ru₄, at various stages of the assembly formation.
The XPS spectra were recorded at a take-off angle of θ = 45°. For a more
extensive overview of the atomic concentrations for selected samples at
various take-off angles, see Tables 3-5.

| | | | | | |
|---|---|---|---|---|---|
| Entry | Pd/N^{a} | Pd/M^{a} | N/M^{a} | Os^{b} | Ru^{b} |

SPMA I

| | | | | | |
|---|---|---|---|---|---|
| Ru₁—Os₁ | 0.21 | 2.0 | 9.4 | 0.4 | 0.3 |
| Ru₂—Os₂ | 0.25 | 2.4 | 9.7 | 0.6 | 0.3 |
| Ru₃—Os₃ | 0.20 | 2.5 | 12.5 | 0.8 | — |
| Ru₄—Os₄ | 0.20 | 1.5 | 7.8 | 1.1 | — |

SPMA II

| | | | | | |
|---|---|---|---|---|---|
| Ru₂—Os₀ | 0.22 | 1.3 | 6.0 | — | 0.9 |
| Ru₄—Os₀ | 0.17 | 1.6 | 9.0 | — | 0.9 |
| Ru₄—Os₂ | 0.18 | 2.0 | 11.2 | 0.8 | — |
| Ru₄—Os₄ | 0.18 | 1.6 | 8.6 | 0.8 | — |
| Ru₄—Os₁ | 0.17 | 1.7 | 9.6 | 0.7 | 0.2 |

SPMA III

| | | | | | |
|---|---|---|---|---|---|
| Os₂—Ru₀ | 0.18 | 2.0 | 11.6 | 0.7 | — |
| Os₄—Ru₀ | 0.18 | 2.0 | 10.9 | 0.8 | — |
| Os₄—Ru₂ | 0.18 | 1.1 | 5.9 | 0.1 | 1.3 |
| Os₄—Ru₄ | 0.18 | 1.2 | 6.4 | 0.1 | 1.3 |
| Os₄—Ru₁ | 0.16 | 1 | 6 | 0.1 | 1.3 |

^{a}XPS derived elemental ratios, where M = Os and Ru.
^{b}Atomic concentration of Os or Ru.

TABLE 3
XPS derived atomic concentrations - for selected elements - of
SPMA I|Ru₁—Os₁ and SPMA I|Ru₄—Os₄. XPS spectra were
recorded at various take-off angles.

| | SPMA I\|Ru₁—Os₁ | | | | | SPMA I\|Ru₄—Os₄ | | | | |
|---|---|---|---|---|---|---|---|---|---|---|
| | 5° | 15° | 30° | 45° | 80° | 5° | 15° | 30° | 45° | 80° |
| N | 6.2 | 7.8 | 6.1 | 6.6 | 5.0 | 7.1 | 8.1 | 9.8 | 8.6 | 9.1 |
| Pd | 1.3 | 1.8 | 1.5 | 1.4 | 1.2 | 1.4 | 2.0 | 1.7 | 1.7 | 2.0 |
| Os | 0.6 | 0.7 | 0.5 | 0.4 | 0.5 | 0.8 | 1.2 | 1.1 | 1.1 | 1.2 |
| Ru | 0.5 | 0.5 | 0.3 | 0.3 | 0.3 | 0.6 | — | — | — | — |

TABLE 4
XPS derived atomic concentrations - for selected elements of
SPMA II|Ru₂—Os₀ and SPMA II|Ru₄—Os₄. XPS spectra
were recorded at various take-off angles.

| | SPMA II\|Ru₂—Os₀ | | | | | SPMA II\|Ru₄—Os₄ | | | | |
|---|---|---|---|---|---|---|---|---|---|---|
| | 5° | 15° | 30° | 45° | 80° | 5° | 15° | 30° | 45° | 80° |
| N | 6.4 | 6.7 | 6.0 | 5.4 | 4.6 | 9.7 | 9.5 | 9.1 | 10.3 | 9.4 |
| Pd | 1.1 | 1.2 | 1.2 | 1.2 | 1.0 | 1.7 | 1.7 | 1.7 | 1.9 | 2.0 |
| Os | — | — | — | — | — | 1.2 | 1.1 | 1.1 | 1.2 | 1.2 |
| Ru | 1.0 | 1.1 | 0.9 | 0.9 | 0.8 | — | — | — | — | — |

TABLE 5
XPS derived atomic concentrations - for selected elements - of
SPMA III|Os₂—Ru₀ and SPMA III|Os₄—Ru₄. XPS spectra
were recorded at various take-off angles.

| | SPMA III\|Os₂—Ru₀ | | | | | SPMA III\|Os₄—Ru₄ | | | | |
|---|---|---|---|---|---|---|---|---|---|---|
| | 5° | 15° | 30° | 45° | 80° | 5° | 15° | 30° | 45° | 80° |
| N | 8.2 | 8.5 | 8.3 | 7.7 | 7.6 | 9.2 | 9.0 | 9.4 | 9.0 | 9.7 |
| Pd | 1.4 | 1.4 | 1.5 | 1.4 | 1.4 | 1.5 | 1.5 | 1.6 | 1.6 | 1.7 |
| Os | 0.9 | 0.8 | 0.8 | 0.7 | 0.6 | 0.1 | 0.1 | 0.1 | 0.1 | 0.1 |
| Ru | — | — | — | — | — | 1.4 | 1.4 | 1.5 | 1.3 | 1.4 |

For SPMAs I and II, significant atomic concentrations of ruthenium (1) are observed, although the film is terminated with a layer of the osmium complex 2 (Table 2). For example, in SPMA I, higher ruthenium concentrations are observed for entry Ru₁—Os₁ (5.4 nm) and Ru₂—Os₂ (11.4 nm), where the thickness of the combined osmium layers is 1.5 and 3.2 nm respectively. In SPMA II for entry Ru₄—Os₁ (15.5 nm) the underlying ruthenium layer is observed as well, after a deposition of a 5.0 nm thick osmium layer. This effect might be a result of the XPS probe depth of −6.0 nm at a 45° take-off angle (Merzlikin et al., 2008). Alternatively, the pronounced presence of the ruthenium can be explained by some Ru/Os inter-mixing at the internal interfaces of the SPMA.

For higher thicknesses in SPMA I, only one of the metals is observed; entry Ru₃—Os₃ (23.8 nm) and Ru₄—Os₄ (36.7 nm), depending on which metal complex was deposited last. These results indicate that clear and distinct layers are being formed inside the SPMA that are composed of only one type of metal complex. The same effects are observed for SPMA II and III (Table 2). This layering is a direct result of the SDA and is responsible for the spectroelectrochemical properties as discussed below.

Electrochemistry.

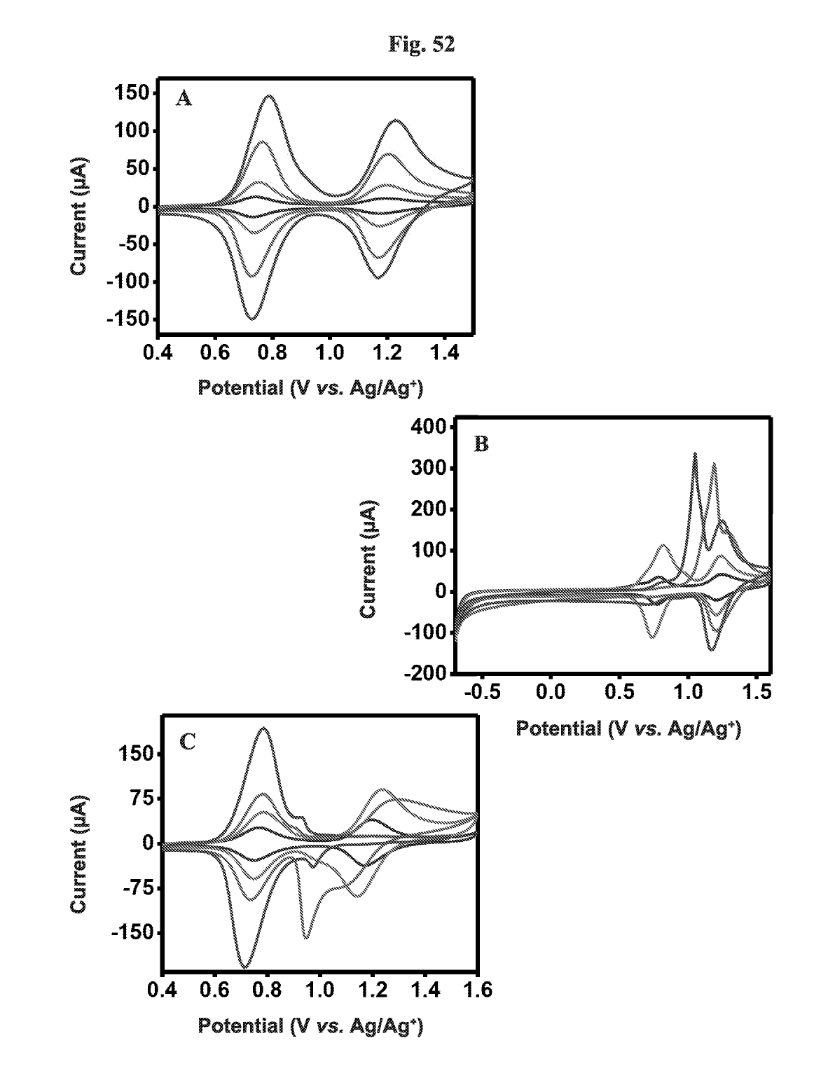

The SDA-dependent physicochemical properties (e.g., film thickness and interface formation) are expressed in the electrochemical properties of the SPMAs. For SDA I, the electron transfer is reversible for SPMA I at various thicknesses (FIG. 52, panel A).

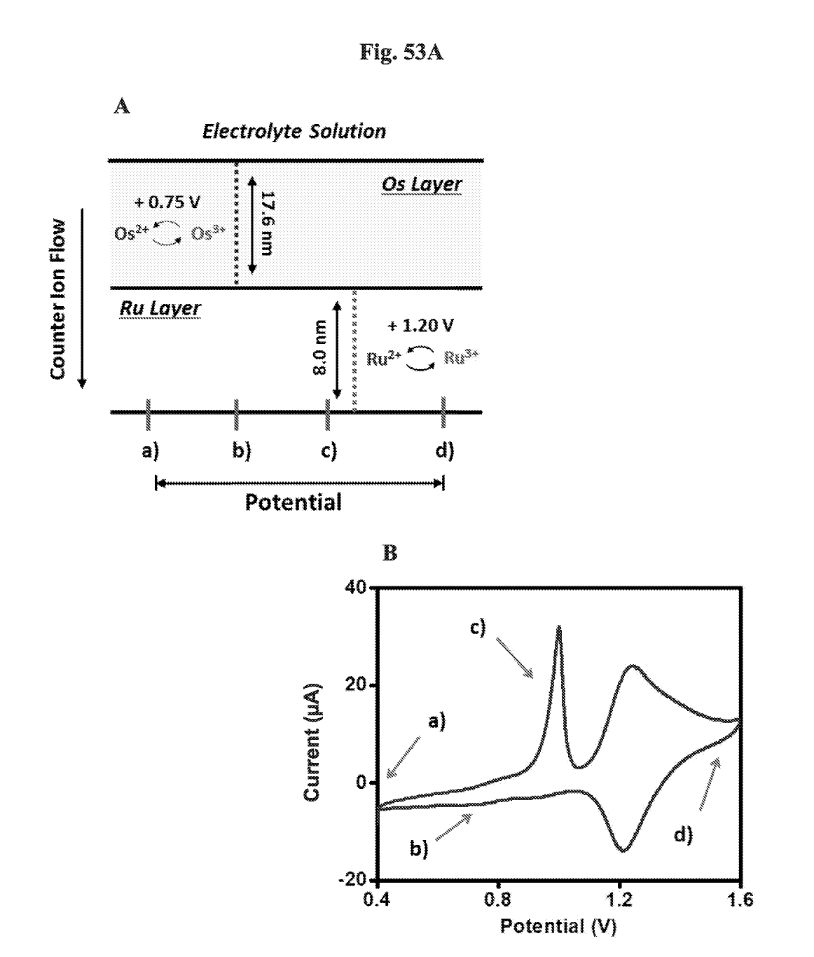

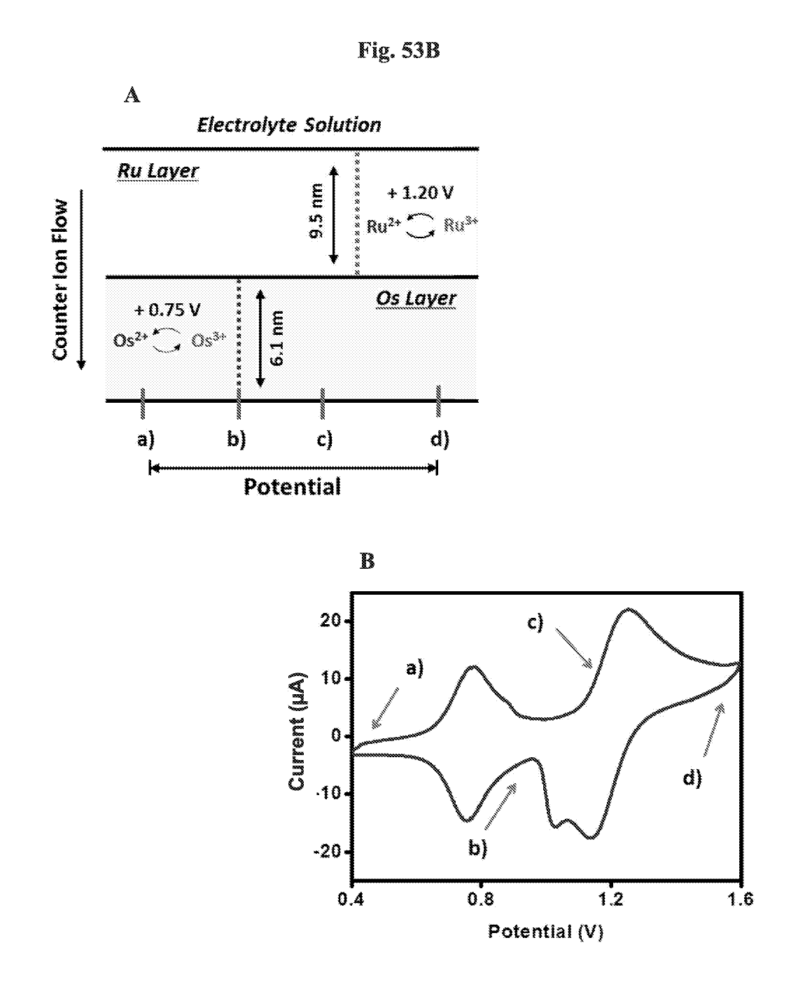

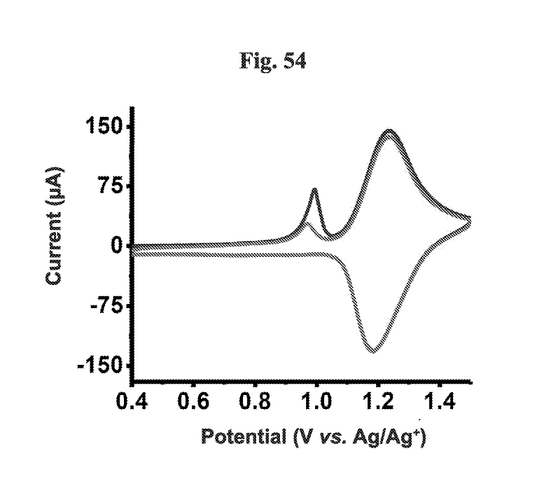

The thickness of the layers of metal complexes (1, 2) contributes to the observed reversible behavior. For SDA II similar behavior is observed for SPMA II | Ru₁—Os₁ (5.8 nm; blue trace) and SPMA II | Ru₂—Os₂ (12.4 nm; red trace), since for these SPMAs, the thickness of the ruthenium layer is below the threshold value of 8.0 nm (FIG. 52, panel B). However, for SPMA II | Ru₃—Os₃ (25.6 nm; green trace), and SPMA II | Ru₄—Os₄ (43.6 nm; purple trace), the thickness of the ruthenium layer exceeds 8.0 nm and a catalytic pre-wave is observed. Such catalytic pre-waves were first observed in the seminal work of Murray et al. on polymeric films of metal complexes (Abruna et al., 1981; Denisevich et al., 1981; Leidner and Murray, 1985). In addition, unidirectional current flows have also been observed with functionalized electrodes and ferrocyanide solutions or surface confined ionic polymers (Alvarado et al., 2005; Araki et al., 1995; Berchmans et al., 2002; Cameron and Pickup, 1999; DeLongchamp et al., 2003; Hjelm et al., 2005; Smith et al., 1986). Accordingly, the oxidative catalytic behavior above an 8.0 nm thickness of the ruthenium layer can be illustrated as follows (FIG. 53A): At potential of 0.4 V (a) the entire SPMA is reduced. Next, the potential bias is increased to the half-wave potential (0.75V) of the Os^{2+/3+} redox-couple (b). No oxidation is observed due to the insulating nature of the 8.0 nm thick ruthenium layer. However, when the potential reaches the onset-potential (1.0 V) of the ruthenium oxidation (c), small amounts of Ru²⁺ are oxidized to Ru³⁺. Since the Ru³⁺ is able to oxidize Os²⁺, a sharp increase in the current is observed in which the ruthenium layer act as a catalytic gate for the oxidation of the osmium layer. Finally when a potential of 1.60 V is reached (d), the entire SPMA is oxidized. On the other hand, when the potential is reversed, charge-trapping occurs. At 1.00 V (c), the entire ruthenium layer is reduced, therefore, when the half-wave potential of the Os^{2+|3+} redox-couple is reached (b), the electron transfer from the electrode to the osmium layer is blocked. Consequently, the second scan cycle in the CV always shows a diminished height of the catalytic pre-wave, due to the charge trapping (FIG. 54).

For SDA III, the opposite behavior is observed, since the thermodynamic driving force of the electrochemical potential is now reversed. This effect is most pronounced in SPMA III | Os₄—Ru₄ (FIG. 52; purple trace), with a thickness of the osmium layer of 11.0 nm. At these thicknesses the ruthenium complexes are isolated from the ITO-electrode (FIG. 52, panel C; purple trace). For SPMA III | Os₁—Ru₁ (FIG. 52; blue trace) in contrast, both metal complexes display reversible behavior. The catalytic electron transfer is only observed for SPMA III | Os₂—Ru₂ (FIG. 52; red trace), and SPMA III | Os₃—Ru₃ (FIG. 52; green trace). Since the electrochemical potentials distribution is reversed in SDA III, compared to SDA II, the catalytic pre-wave arises differently. According to the same principles as outlined by Murray et al. for polymeric systems (Abruna et al., 1981; Denisevich et al., 1981; Leidner and Murray, 1985); this catalytic reductive pre-wave is explained as follows (FIG. 53B): Upon increasing the potential to 1.6 V (d), the oxidation of the outer ruthenium layer is severely hampered by the presence of the osmium layer (3.0-5.0 nm), indicated by the large peak to peak separation (ΔEₚ=200 mV). Although hampered, the oxidation of the ruthenium layer still occurs. When reversing the potential, and scanning in the negative scanning direction, at 1.20 V (c), the reduction of the ruthenium layer occurs although this is difficult, hence the large peak to peak separation (vide supra). Therefore, at the onset potential (1.00 V) the Os³⁺ metal centers are being reduced to Os²⁺ (b). Since the outer ruthenium layer is not yet fully reduced, the remaining Ru³⁺ centers immediately oxidize the newly formed Os²⁺ metal centers. As a result, a reductive catalytic pre-wave at 1.00 V appears, in which the electron is transferred from the ITO electrode to the outer ruthenium layer, mediated by the osmium layer. At 0.40 V (a) the SPMA is completely reduced and charge trapping only occurs, between 1.00-1.20 V. Therefore, depending on the thickness of the osmium layer, the electron has two possibilities of reaching the outer ruthenium layer: (i) without or (ii) with the osmium metal centers as mediator. This might explain why the equilibrium between reversible electron transfer and catalytic electron transfer in SPMA III | Os₃—Ru₃ (FIG. 52; green trace) changes as a function of the scan rate. Unlike SDA II, where the oxidation of the Os²⁺ metal centers occur irrespective of the thickness of the ruthenium layer. For SDA III, the oxidation of the Ru²⁺ metal centers is dependent on the thickness of the osmium layer. Only when the thickness of the osmium layer exceeds 11.0 nm, the electron transfer is completely blocked and no electrochemical signal of the ruthenium is observed (FIG. 52, panel C; purple trace).

Spectroelectrochemistry.

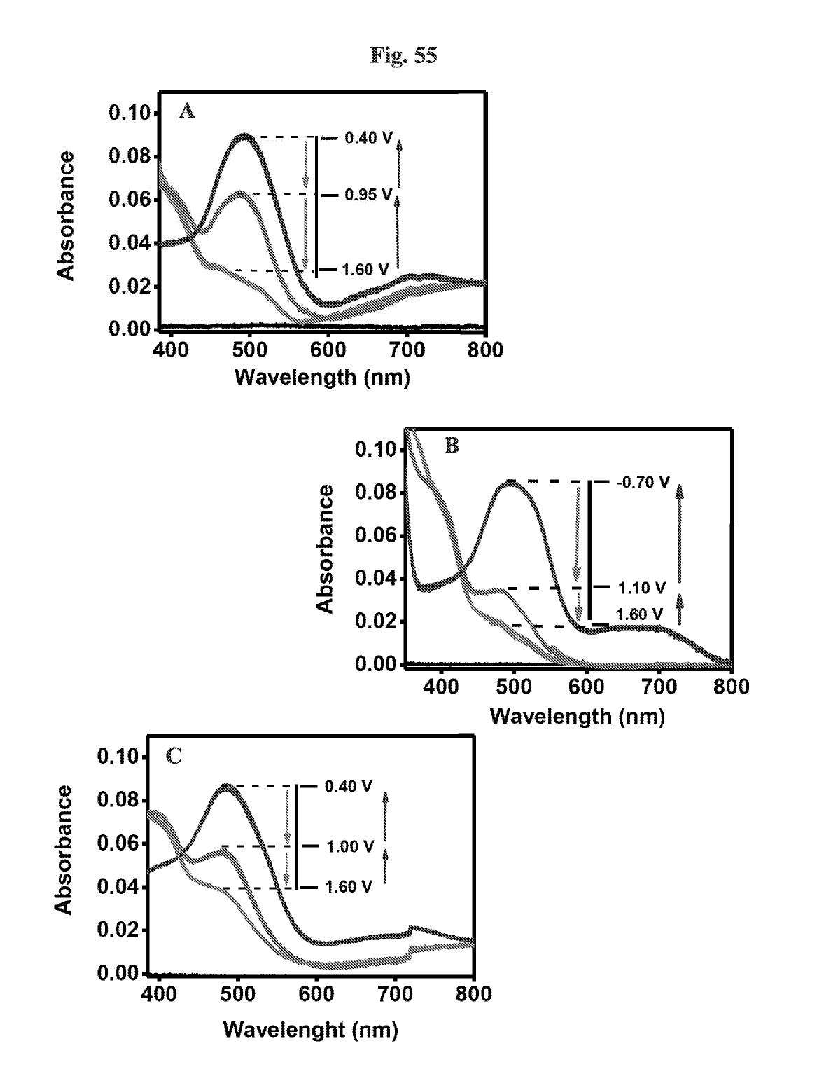

The different electrochemical behavior among the SPMAs, formed with the different SDAs I-III, is also expressed in their spectroelectrochemical properties. FIG. 55 shows the optical absorption spectra between 400-800 nm of SPMA I | Ru₄—Os₃, SPMA II | Ru₃—Os₃, and SPMA III | Os₃—Ru₃. Three distinct absorption values can be obtained upon applying three different potential biases. At a potential of 0.40 V both Ru and Os metal centers are fully reduced and the ¹MLCT at λ=495 shows an intense absorption (FIG. 55; blue traces—State I: Os²⁺|Ru²⁺). However, for SPMA II | Ru₃—Os₃, a negative potential (−0.70 V) was needed to fully reduce the SPMA and overcome the charge trapping (FIG. 55, panel B).

When holding the potential between 0.95-1.10 V, all the osmium complexes (2) of the assembly are oxidized, while the Ru-based components are still in their reduced state (FIG. 55; green trace—State II: Os³⁺|Ru²⁺). The oxidation of the Os metal centers is indicated by a concurrent decrease of both the ¹MLCT and ³MLCT bands at λ=495 and 700 nm, respectively. Full oxidation of the SPMAs, as indicated by full bleaching of the ¹MLCT band, is accomplished by applying a potential of 1.60 V (FIG. 55; red trace—State III: Os³⁺|Ru³⁺). This oxidation is incomplete for SPMA III | Os₃—Ru₃, as shown by the unusual high remaining absorption of the ¹MLCT band (FIG. 55, panel C; red trace). Discrimination between the Os^{2+/3+}- and Ru^{2+/3+}-based redox processes is optically possible since the Ru-based complex 1 lacks a ³MLCT band at λ=700 nm (Crosby and Demas, 1971; Fujita and Kobayash, 1972). As a consequence, a decrease of the ³MLCT band is only observed when a potential of 0.95-1.10 V (Os²⁺→Os³⁺) is applied, whereas such a decrease is absent when a potential of 1.60 V (Ru²⁺→Ru³⁺) is used (FIG. 55).

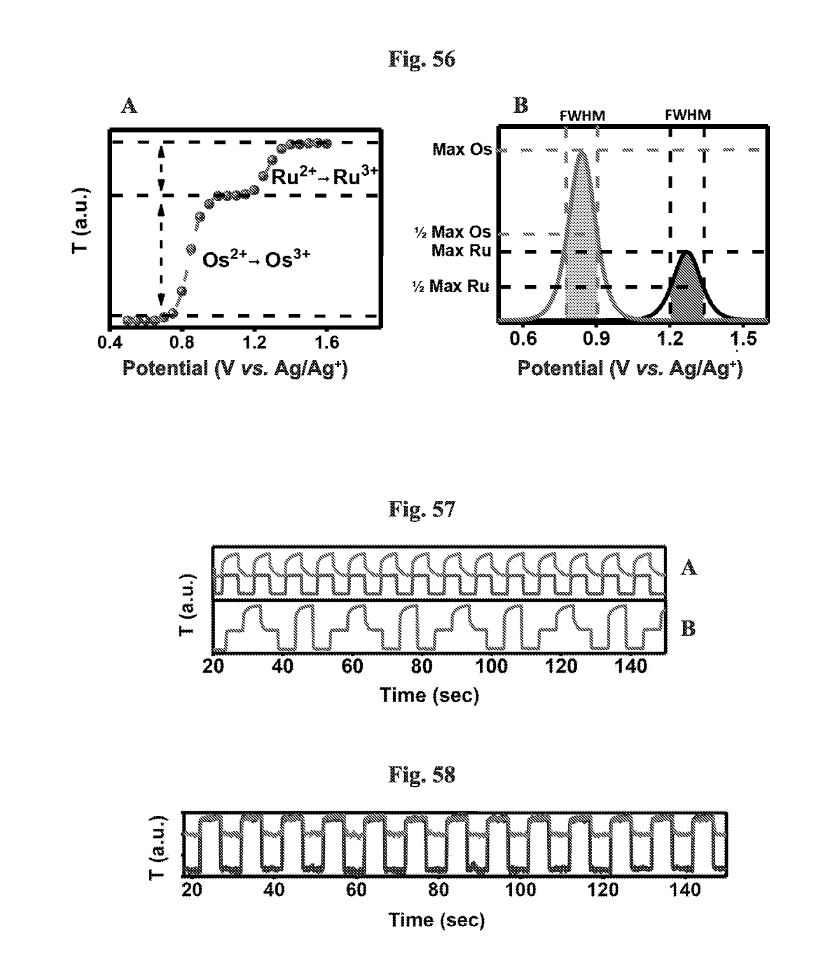

In order to further investigate the oxidation/reduction of the individual type of metal complexes; i.e. ruthenium (1) or osmium (2), SPMAs constructed according to SDA I were selected. These SPMAs are preferable since there is no interference by catalytic electron transfer, as is the case in SDA II and III. In order to assess the electrochromic properties in detail, the optical response of SPMA I | Ru₅—Os₄ was measured as a function of the potential. For instance, gradually increasing the switching potential between 0.5 and 0.5+n0.05 V, with n=0-22, in the chronoamerometric mode, results clearly in a double-step sigmoidal shape associated with the characteristic electrochemical properties of the Ru^{2+/3+} and Os^{2+/3+} redox-couples (FIG. 56, panel A). Differentiation of the sigmoidal fit produces a normal distribution centered on the E_{1/2} of the ruthenium (1) and osmium (2) complexes (FIG. 56, panel B), and demonstrates that there is no overlap in the oxidation of the individual type of metal complexes (de Ruiter et al., 2010a; de Ruiter et al., 2010b). This confirms that no metal-metal communication occurs in SPMAs created by SDA I, in contrast to SPMAs formed by SDA II and III.

The optical response of the ¹MLCT at λ=495 nm for SDA I, II, and III was further used to read-out the electronic properties of the SPMAs by applying short potential biases. For instance, for SDA I the optical response of the ¹MLCT of SPMA I | Ru₄—Os₃ is shown in FIG. 57. The blue trace in FIG. 57, panel A, shows the switching of the Os metal centers upon applying a double potential step between 0.40 and 0.95 V. It was observed that the switching from Os²⁺→Os³⁺ is more efficient, than the oxidation from Ru²⁺→Ru³⁺ (FIG. 57, panel A; red trace). The difference between the osmium (0.77 V) and ruthenium (1.20 V) oxidation is evident from the gradual increase of the optical response, after applying a potential of 1.60 V until full oxidation of the SPMA occurs. The gradual oxidation at higher thicknesses is due to the more distant ruthenium centers, with respect to the ITO surface, that are more difficult to oxidize. This effect was not observed for thinner SPMAs (e.g. 11.4 nm) where the oxidation of the ruthenium is nearly instantaneous upon applying the potential (FIG. 58). Applying triple potential steps between 0.40, 0.95, and 1.60 V resulted in three clearly distinguishable absorption states (FIG. 57, panel B). Therefore, applying the different potential biases effectively modulates the SPMA among its three different oxidation states; State 1; Os²⁺|Ru²⁺, State 2; Os³⁺|Ru²⁺, and State 3; Os³⁺|Ru³⁺ (for a recent example of electrochromic polymers with three states see: Sassi et al., 2012). It is important to realize that the three different absorption states are not the result of the SPMA as a whole, but rather from the individual type of metal complexes (1; Ru and 2; Os), that constitutes the individual layers in the SPMAs. Therefore these systems are ideal candidates for applications in electrochromic surfaces or memory devices where the information density has increased from binary to ternary (de Ruiter et al., 2010a; de Ruiter et al., 2010b).

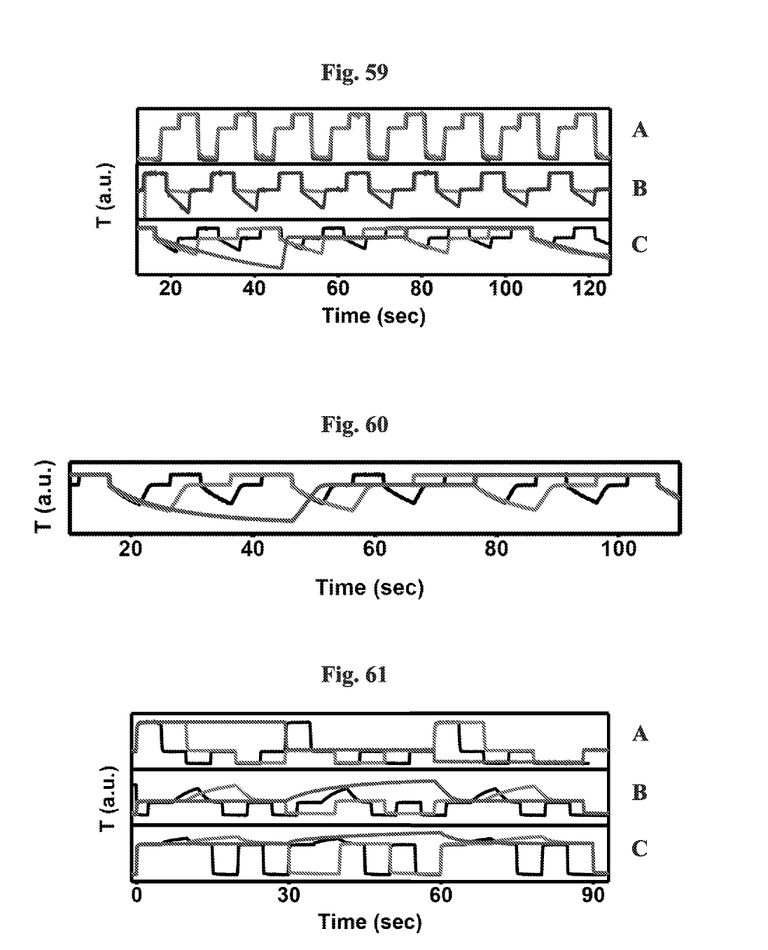

The difference between reversible and unidirectional current flow in SDA II is also manifested in the spectroelectrochemical behavior of the SPMAs. For SPMAs with a thickness of the ruthenium layer of 5.7 nm and a thickness of the osmium layer of 6.8 nm (SPMA II | Ru₂—Os₂), reversible behavior in the electro-optical properties was observed. Applying potential biases of 0.40, 1.00, and 1.60 V for 5 s (FIG. 59, panel A; red trace), shows that both metal centers 1 and 2 can be modulated reversibly between the oxidation states (M^{2+/R+}). Changing the potentials to −0.70, 1.10, and 1.60 V does not alter this behavior, and is in accordance with the CV experiments (FIG. 59, panel A; black trace). However, the spectroelectrochemical behavior is strikingly different for SPMAs with a thickness of the ruthenium layer of 8.0 nm and a thickness of the osmium layer of 17.6 nm (SPMA II | Ru₃—Os₃). When potential biases of 0.40, 1.00, and 1.60 V are applied for 5 s. (FIG. 59, panel B; red trace), the osmium in the SPMA can only be oxidized once. Thereafter, applying a potential of 0.40 V does not lead to reduction of the osmium centers. We expect the reduction to occur because the potential is 0.37 V below the E_{1/2} of Os^{2+/3+} redox couple (0.77 V; vs. Ag/Ag⁺). The charge trapping of the Os³⁺ metal centers is evident in the spectroelectrochemical properties of SPMA II | Ru₃—Os₃. The absence of reversible oxidation/reduction processes for the Os^{2+/3+} redox couple upon applying 0.40 or 1.00 V is illustrated by the flat red line in FIG. 59, panel B. Note that the oxidation/reduction of the Ru^{2+/3+} redox couple in this SPMA is reversible. When the potential biases are changed to −0.70 and 1.10 V, oxidation and reduction are observed for the Os^{2+/3+} redox couple (FIG. 59, panel B; blue trace). Although oxidation of the Os metal centers is now instant—mediated by the Ru²⁺ layer—reduction remains difficult to achieve, even at a potential that is 1.00 V below the E_{1/2} of the Os^{2+/3+} redox couple. Due to the insulating nature of the 8.0 nm thick Ru²⁺ layer, a further increase in the Os²⁺ content is only observed upon applying a potential biases of −0.70 V for 5 s (FIG. 59, panel C; black trace), 10 s (FIG. 59, panel C; red trace), and 30 s (FIG. 59, panel C; blue trace). Further increasing the thickness of the ruthenium layer to 10.7 nm (SPMA II | Ru₄—Os₄) does not alter the catalytic pre-wave (FIG. 52, panel B; purple trace) in the CV nor does it change the spectroelectrochemical properties (FIG. 60) compared to SPMA II | Ru₃—Os₃. It is captivating that by solely increasing the thickness of the ruthenium layer from 5.7 nm to 8.0 nm significant differences in the spectroelectrochemical behavior are evident.

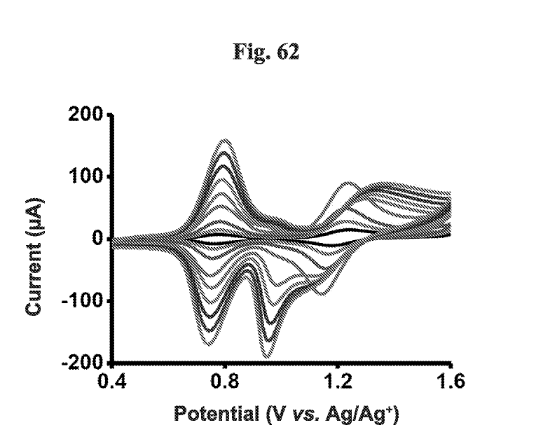

The spectroelectrochemical properties of SPMAs constructed according to SDA III are presented in FIG. 61. For SPMAs with a maximum thickness of the osmium layer of −3.8 nm, the spectroelectrochemical behavior exhibits reversible behavior. This reversible behavior illustrated by SPMA III | Os₂—Ru₂, where three clear states are observed after applying potential biases at of 0.40, 1.00, and 1.60 V, which correspond to the three different oxidation states of the SPMA (FIG. 61, panel A). Increasing the duration of the potential biases from 5 s (FIG. 61, panel A; black trace), to 10 s (FIG. 61, panel A; red trace), and 30 s (FIG. 61, panel A; blue trace), does not lead to an increase/decrease in the optical absorption of the interfaces indicating immediate oxidation of the SPMA upon applying the potential bias. This reversibility is independent of the thickness of the outer ruthenium layer, formed by complex 1. Although, the CV of SPMA III | Os₂—Ru₂ shows the evolution of a reductive catalytic pre-wave at higher scan rates (300-700 mV/s; FIG. 62), it did not affect the reversibility of the oxidation/reduction of the ruthenium redox couple.

The effect of the reductive catalytic pre-wave only becomes apparent in the spectroelectrochemical properties upon increasing the thickness of the osmium layer to 6.1 nm (SPMA III | Os₃—Ru₃). At this thickness, the insulating nature of the osmium layer becomes apparent, so oxidation of the Ru metal centers is retarded. This hampered oxidation is clearly visible optically, since the transmission slowly increases upon applying a potential bias of 1.6 V (FIG. 61, panel B). Increasing the duration of the bias to 10 s and 30 s shows that the oxidation is time dependent, as is evident from the increase in the content of the Ru³⁺ metal centers in the SPMA (FIG. 61, panel B; red and blue traces). Further increasing the thickness of the osmium layer to 11.0 nm (SPMA III | Os₄—Ru₄) did not result in any oxidation or reduction of ruthenium in the CV (FIG. 52, panel C; purple trace). However, some oxidation does occur after prolonged exposure of the SPMA to a potential bias, judging from the small increase in the transmission after applying the potential (1.60 V) for 5 s (FIG. 61, panel C; black trace), 10 s (FIG. 61, panel C; red trace), and 30 s (FIG. 61, panel C; blue trace). The above mentioned results unequivocally demonstrate that the observed metal-mediated electron transfer has significant effects on the electrochemical and spectroelectrochemical properties. These properties are not only a function of the assembly sequence, but are also dependent on the thickness of the ruthenium/osmium layers. An overview of which SPMA demonstrates a oxidative/reductive pre-wave, depending on the thickness of the ruthenium (1) and osmium (2) thickness is given in Table 6, and highlights the importance of SDA.

TABLE 6
The SPMAs formed by SDA II and III, for which a catalytic pre-wave
was observed (✓) or not (x), depending on the thickness of the
initial ruthenium (1) or osmium (2) layer, and the subsequent number
of deposition steps of the complexes 1 and 2.

| SDA II | | | | SDA III | | | |
|---|---|---|---|---|---|---|---|
| | | Oxidative | | | | Reductive | |
| | | catalytic | | | | catalytic | |
| Ru | | pre-wave | | Os | | pre-wave | |
| thickness | SPMA II | No | Yes | thickness | SPMA II | No | Yes |
| 3.3 nm | Ru₁—Os₀ | x | | 2.6 nm | Os₁—Ru₀ | x | |
| | Ru₁—Os₁ | x | | | Os₁—Ru₁ | x | |
| 5.7 nm | Ru₂—Os₀ | x | | 3.8 nm^{a} | Os₂—Ru₀ | x | ✓ |
| | Ru₂—Os₁ | x | | | Os₂—Ru₁ | x | ✓ |
| | Ru₂—Os₂ | x | | | Os₂—Ru₂ | x | ✓ |
| 8.0 nm | Ru₃—Os₀ | x | | 6.1 nm | Os₃—Ru₀ | x | |
| | Ru₃—Os₁ | | ✓ | | Os₃—Ru₁ | | ✓ |
| | Ru₃—Os₂ | | ✓ | | Os₃—Ru₂ | | ✓ |
| | Ru₃—Os₃ | | ✓ | | Os₃—Ru₃ | | ✓ |
| 10.6 nm | Ru₄—Os₀ | x | | 11.0 | Os₄—Ru₀ | x | |
| | Ru₄—Os₁ | | ✓ | | Os₄—Ru₁ | x | |
| | Ru₄—Os₂ | | ✓ | | Os₄—Ru₂ | x | |
| | Ru₄—Os₃ | | ✓ | | Os₄—Ru₃ | x | |
| | Ru₄—Os₄ | | ✓ | | Os₄—Ru₄ | x | |

^{a}The appearance of the reductive pre-wave depends on the scan rate. Only for scan rate>300 mVs⁻¹, the catalytic reductive pre-wave are clearly observed (FIG. 62).

### Study 4

### Tunable Electron Transfer Processes in Sandwich-Like Organic-Inorganic Molecular Architectures

### Experimental

Materials.

See study 1 above. BPEB and PdCl₂(PhCN)₂ were synthesized as previously described (Burdeniuk and Milstein, 1993; Anderson, 1990).

Multilayer Formation.

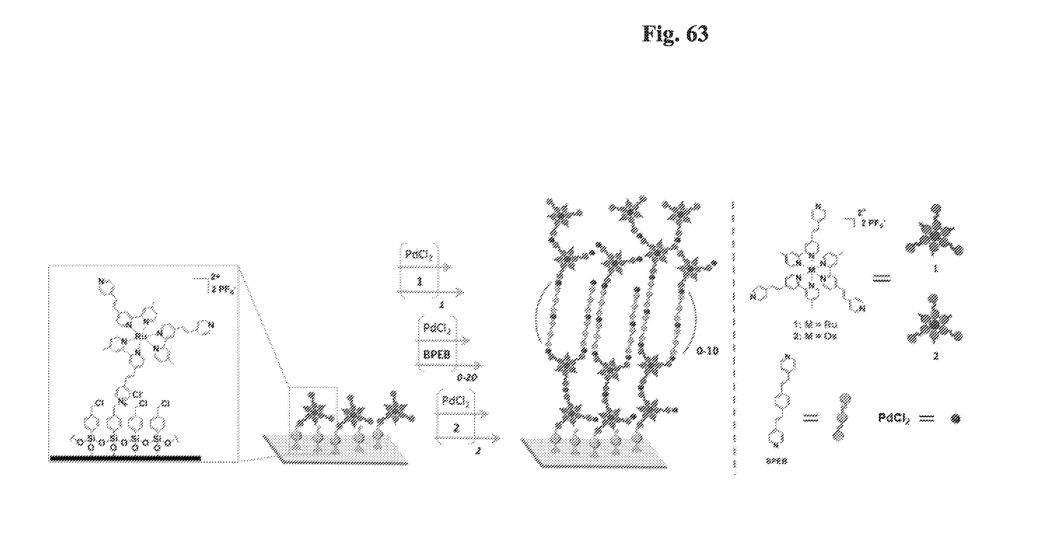

Substrates functionalized with a 1-based template layer were loaded onto a Teflon holder and immersed for 15 min in a 1.0 mM solution of PdCl₂(PhCN)₂ in THF. The samples were then sonicated twice in THF and once in acetone for 3 min each. Subsequently, the samples were immersed in a 0.2 mM solution of compound 1 in THF/DMF (9:1, v/v) for 15 min. The samples were then sonicated twice in THF and once in acetone for 5 min each (=deposition step 1). Next, the samples were immersed for 10 min in a 1.0 mM solution of PdCl₂(PhCN)₂ in THF and then sonicated twice in THF and once in acetone for 3 min each. Subsequently, the samples were immersed for 10 min in a 1.0 mM solution of BPEB in THF and sonicated twice in THF and once in acetone for 3 min each (=deposition step 2). The 2^{nd} deposition cycle procedure was repeated zero to twenty times to obtain assemblies with zero to twenty deposition cycles of BPEB (only slides with even number of BPEB deposition cycles were kept for subsequent depositions of complex 2). Then, the 1^{st} deposition cycle procedure was repeated twice using a 0.2 mM solution of compound 2 in THF/DMF (9:1, v/v). Finally, the samples were rinsed in ethanol and dried under a stream of N₂. All steps were carried out at RT. Three separate PdCl₂(PhCN)₂ solutions with identical concentrations were used to rigorously exclude possible cross contaminations between compounds 1, 2, and BPEB (FIG. 63).

Characterization Methods.

UV/vis spectroscopy was carried out using a Cary 100 spectrophotometer. Thicknesses were estimated by spectroscopic ellipsometry on an M-2000V variable angle instrument (J. A. Woollam Co., Inc.) with VASE32 software. Electrochemical measurements (i.e., cyclic voltammetry and spectroelectrochemistry) were performed using a potentiostat (CHI660A). The electrochemical measurements were performed in a three-electrode cell configuration consisting of the functionalized ITO substrate, Pt wire, and Ag wire as working, counter, and reference electrodes, respectively, using 0.1 M solutions (unless stated otherwise) of TBAPF₆ in CH₃CN as the supporting electrolyte. XRR measurements were performed at the 12-BM-B beamline of the Advanced Photon Source (APS), Argonne National Laboratory (Argonne, Ill., USA). A four-circle Huber diffractometer was used in the specular reflection mode (i.e., the incident angle was equal to the exit angle). An X-ray beam with an energy of E=10.0 keV (λ=1.24 Å) was used. The beam size was 0.40 mm vertically and 0.60 mm horizontally. The samples were held under a helium atmosphere during the measurements to reduce radiation damage and background scattering from the ambient gas. The off-specular background was measured and subtracted from the specular counts. AFM images were recorded using a Bruker multimode AFM operated in semicontact mode. Current-Voltage (I-V) measurements were performed using a Keithley 6430 subfemtoamp source meter. A thin homogeneous oxide layer was grown from an oxidizing solution on an etched surface of highly doped Si, which served as the bottom contact. The samples were contacted on the back by applying In—Ga eutectic, after scratching the surface with a diamond knife. Hanging Drop Mercury Electrode (HDME) served as the top contact (˜500 μm in diameter). Several scans from −1 to +1 V (applied to Hg) were measured for each junction with a scan rate of 20 mV/s. 4 junctions were made on each sample, and the results represent the average of the measurements. XPS measurements were carried out with Kratos AXIS ULTRA system using a monochromatized Al Kα X-ray source (hν=1486.6 eV) at 75 W and detection pass energies ranging between 20 and 80 eV. Angle-resolved spectra were recorded at 0=0° (normal) and 0=50°, where 0 is the takeoff angle with respect to the surface normal. Low-energy electron flood gun (eFG) was applied for charge neutralization. Attenuated total reflectance (ATR)-FTIR spectroscopy measurements were performed using a Bruker Equinox-55 spectrometer with a liquid N₂ cooled mercury cadmium telluride (MCT) detector. Spectra were averaged over 128 scans and referenced to freshly cleaned silicon substrate. All measurements were carried out at RT, unless stated otherwise. Temperature-dependent measurements were performed using a Varian Cary Dual Cell Peltier accessory.

### Introduction

Organizing molecular building blocks on solid surfaces has been demonstrated to be a powerful strategy to generate diverse functional interfaces, which have been used to fabricate, inter alia, nanostructures, light emitting diodes (LEDs), electro-optic modulators, photovoltaic cells, and field-effect transistors (FETs). Numerous methods for surface modification have been reported in the recent decades (Yitzchaik and Marks, 1996; Ariga et al., 2007; Kumar et al., 1995; Piner et al., 1999; Shirman et al., 2008; Cerclier et al., 2010; Palomaki and Dinolfo, 2010), including Sagiv's layer-by-layer (LbL) deposition methodology (Netzer and Sagiv, 1983; Maoz et al., 1995; Ulman, 1996; Zeira et al., 2009), which is attractive for the possibility to create composite materials by incorporating multiple molecular building blocks in an ordered and well-defined fashion. The precise control over the structure and properties of such materials is demonstrated by the linear correlation between the physicochemical properties (e.g., thickness, absorption intensity and electrochemical response) and the number of deposition steps, commonly achieved using the LbL methodology (Yitzchaik and Marks, 1996; Wanunu et al., 2005; Katz et al., 1991; Palomaki and Dinolfo, 2010, Netzer and Sagiv, 1983; Maoz et al., 1995; Ulman, 1996; Zeira et al., 2009, van der Boom et al., 2001; Evmenenko et al., 2001; Lee et al., 1988; Altman et al., 2006; Altman et al., 2008; Altman et al., 2010; Choudhury et al., 2010; Kaminker et al., 2010; Zhao et al., 2010; DeLongchamp and Hammond, 2004). Multiple components can often be combined in a manner that allows synergistic interactions between the different species and the formation of an assembly possessing complex physicochemical properties as a result of the combination (DeLongchamp et al., 2003; DeLongchamp and Hammond, 2004; Cluster et al., 2002; Motiei et al., 2011a). In such multi component assemblies, the sequence by which the components are arranged is of a great importance in determining their properties, in particular the electron transfer characteristics for electrochemically active assemblies (de Ruiter et al., 2013). Gaining a deeper understanding and achieving nano-scale control over electron transfer at interfaces has become a most relevant topic in nanotechnology and electronics for the construction of functional molecular-level systems, which are able to duplicate the functions of bulk electronic devices (Motiei et al., 2010b; Lonergan, 1997; Willner and Katz, 2005; Balzani et al., 2008; Green et al., 2007; Lezama et al., 2012). In principle, molecular electronics is based on electron transfer processes between and through molecules. Such processes are well known in biology, where they have a key role in energy conversion (Blankenship, 2002). Similarly to biology, the directionality of the electron transfer has a significant meaning for applications in electronics. Control over the directionality enables the generation of functions like current rectification across an interface (Abruna et al., 1981; Denisevich et al., 1981; Mukherjee et al., 2006). A remaining challenge in material science is related to the design and formation of specific supramolecular architectures displaying tailor-made structure and function.

In the present study, hybrid surface-confined coordination-based assemblies were formed. A precise control over the composition and the internal arrangement of the assemblies was achieved using our iterative solution-based deposition methodology (Lee et al., 1988; Altman et al., 2006; Altman et al., 2010; Choudhury et al., 2010; Motiei et al., 2011b; Mukherjee and Mohanta, 2006). Redox-active ruthenium and osmium polypyridyl complexes (1 and 2, respectively) and the organic chromophore BPEB were used as building blocks to create a well-defined model structure for studying electron-transfer phenomena across interfaces. The surface chemistry of polypyridyl complexes as well as of organic chromophores has been studied extensively (Lee et al., 1988; Altman et al., 2006; Altman et al., 2008; Altman et al., 2010; Abruna et al., 19811 Denisevich et al., 1981; Mukherjee and Mohanta, 2006; Motiei et al., 2008; Hirao, 2006; Maeda et al., 2013; Chu and Yam, 2006). We have previously utilized the reversible electrochemical behavior of complexes 1 and 2 to fabricate electrochromic thin films (Motiei et al., 2009), solar cells (Motiei et al., 2010b), molecular sensors (de Ruiter and van der Boom, 2011a), and logic gates (de Ruiter and van der Boom, 2011a; de Ruiter et al., 2010c; de Ruiter et al., 2010a; de Ruiter and van der Boom, 2012). These components have been incorporated in the new assemblies in such a way that an appropriate potential gradient for vectorial electron transfer is created. The assemblies have been thoroughly characterized in terms of growth fashion, internal structure and dimensions, surface roughness, and electrochemical features. A gradual transition between reversible electrochemical behavior to oxidative catalytic electrochemical behavior of the osmium metal centers was observed as a function of their distance from the underlying electrode surface. As found, although the structural features of the assemblies play a vital role in determining their electrochemical properties, these properties can be tuned and adjusted after the assembly formation by various means, e.g., exposure to elevated temperatures and prolonged UV irradiation. The interplay between the structural characteristics and the post-assembly modifications allows us to understand and control the electron transfer processes across the assemblies, and thus, their resulting physicochemical properties.

### Results and Discussion

For the formation of the multi-component assemblies, silicon, quartz, and ITO-coated glass substrates functionalized with 1-based template layer (Altman et al., 2010; Motiei et al., 2012) were repeatedly immersed in a solution of PdCl₂(PhCN)₂ followed by a solution of one of the molecular components (1, 2, or BPEB) according to FIG. 63. The resulting assemblies contain an intermediate domain of lengthwise increasing thickness, consisting of BPEB molecules. The BPEB-domain is sandwiched between the surface-adjacent 1-based domain and the top 2-based domain, both having constant thicknesses. The ability to incorporate three different components into a well-defined, continuous assembly is enabled due to the presence of multiple terminal vinylpyridyl moieties in each component, which can be bridged by coordination to PdCl₂ (Cluster et al., 2002). In accordance with the assembly strategy and for convenience, the assemblies will be named as follows: Ruₓ-BPEB_{y}-Os_{z}, where x, y and z refer to the number of deposition cycles of complex 1, BPEB, and complex 2, respectively. In all cases, x and z will be constant and equal to 2 whereas y will be changed systematically from 0 to 20.

A detailed characterization of the new assemblies was carried out by UV/vis spectroscopy, ellipsometry, synchrotron XRR, AFM, electrochemistry, XPS, and FTIR spectroscopy. Electrical characterization was done using Hanging Drop Mercury Electrode (HDME). By combining such methods, we were able to gain a thorough insight about the structural features of the assemblies.

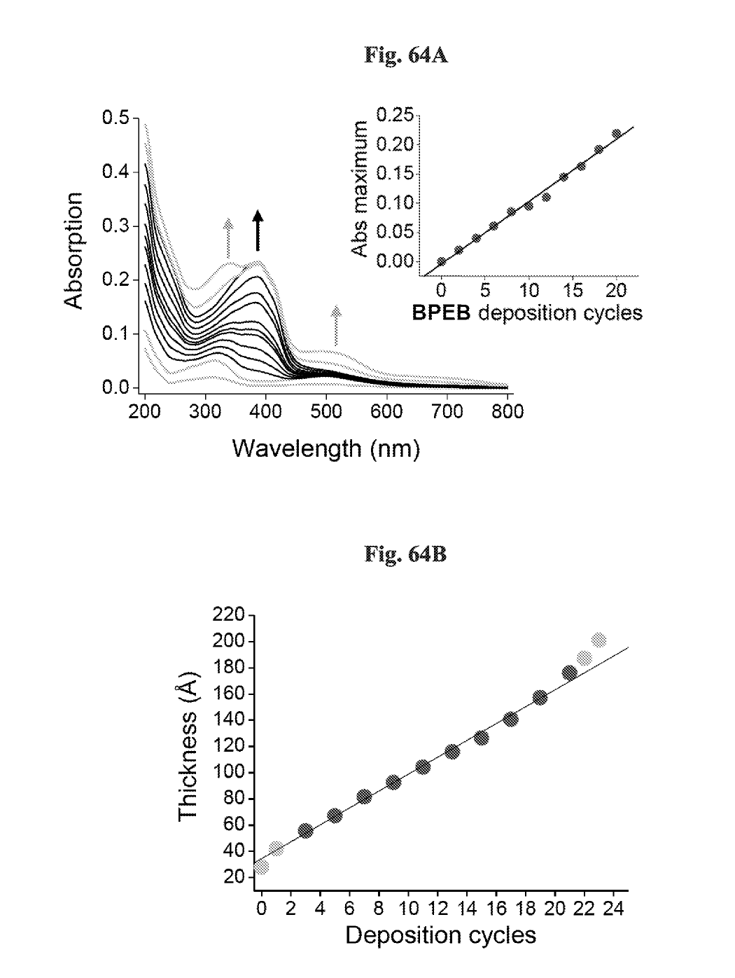

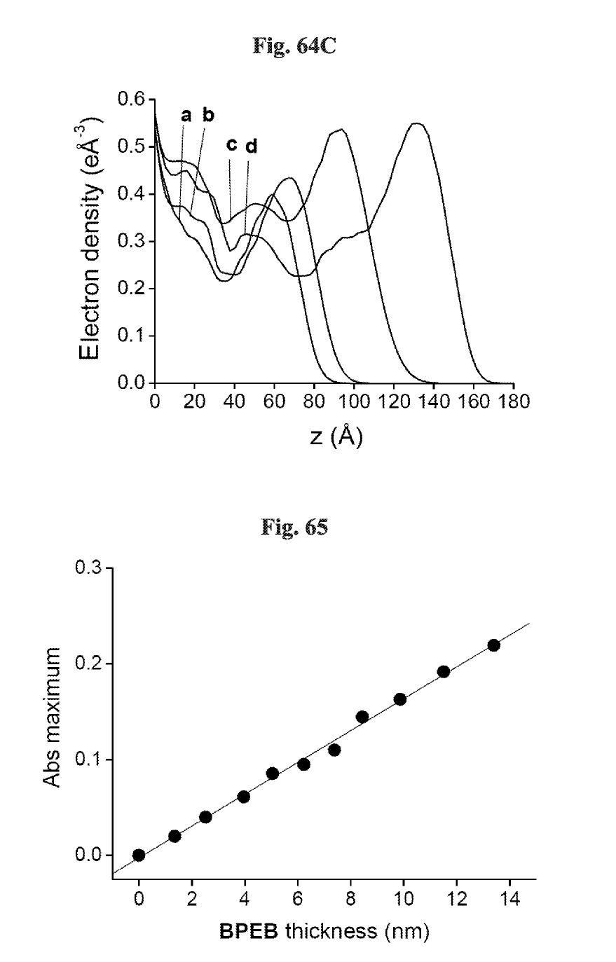

UV/vis measurements in the transmission mode of the functionalized quartz slides were performed during the film formation (FIG. 64A). Each deposition cycle of a metal complex (1 or 2) results in an apparent increase of the π-π* transition band and the MLCT band at λ≈320 and λ≈510 nm, respectively (Mukherjee and Mohanta, 2006; Motiei et al., 2009). A characteristic band at λ≈380 nm increases linearly with every even deposition cycle of BPEB (inset of FIG. 64A). A linear growth fashion of BPEB has been reported previously (Altman et al., 2006; Altman et al., 2010; Motiei et al., 2012).

Ellipsometry-derived thickness of the silicon-bound assemblies was monitored as well during the film formation. The BPEB-domain exhibits a linear increase in thickness with every even deposition cycle (FIG. 64B), which is in agreement with the optical data. The metal complexes deposition cycles were not included in the linear fit since they exhibit a non-linear growth fashion (Choudhury et al., 2010; Motiei et al., 2011a; Motiei et al., 2008, Motirei et al., 2012). The microstructural regularity along the assemblies is demonstrated by the linear relationship between the absorption at λ≈380 nm and the BPEB-domain thickness (FIG. 65). The linear dependence implies that approximately equal amounts of BPEB are being deposited in each deposition cycle.

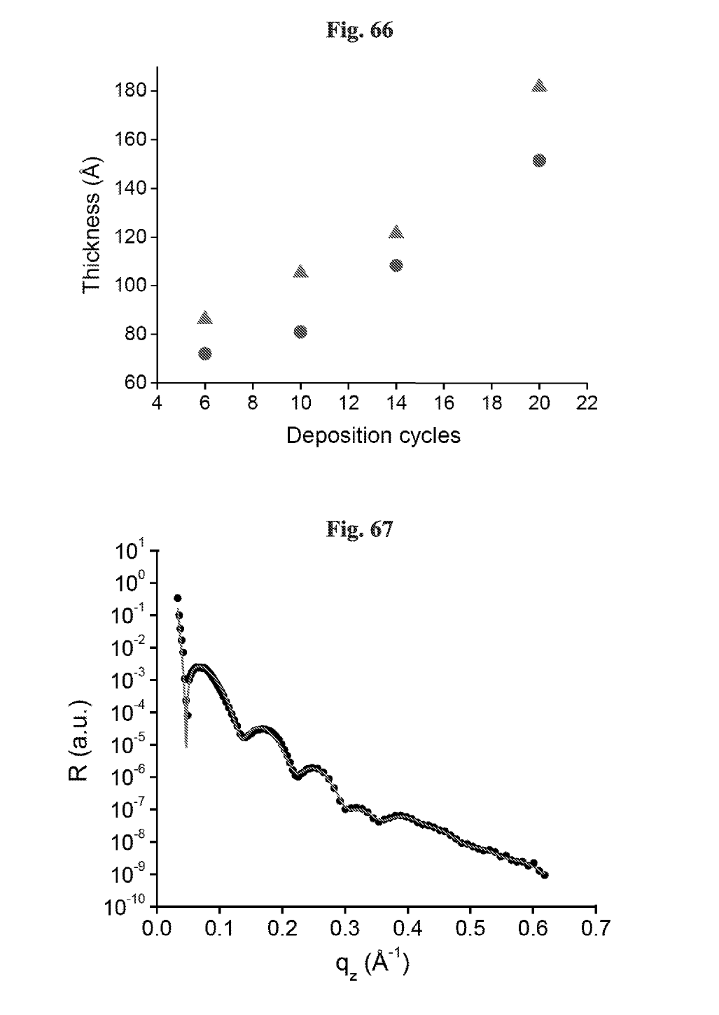

Synchrotron XRR measurements were performed on four selected assemblies with increasing thickness of the BPEB-domain in order to obtain a representative structural characterization including thickness, roughness, and electron density (ED) profile. The XRR-derived thickness is in a good agreement with the ellipsometric data (FIG. 66). The surface-roughness values of the assemblies are in the range of 0.6-0.9 nm, which are in between 5-10% of the total film thickness, with no particular trend. This result may suggest that the surface roughness is not affected by the changing BPEB intermediate domain and is determined by the constant 2-based top domain.

The thickness, surface roughness, and the ED profile of the assemblies were estimated from the Kiessig fringes in the specular reflectivity spectra (a representative spectrum of the Ru₂-BPEB₄-Os₂ assembly is shown in FIG. 67). The data was fitted according to Parratt's procedure. While the ED plots of single-component assemblies are uniform (Altman et al., 2006; Motiei et al., 2008; Motiei et al., 2012), the multi-component assemblies exhibit fluctuations in the ED profile (FIG. 64C). The sandwich-like structure of these assemblies is well demonstrated by the ED fluctuations, having high ED regions at the 1- and 2-based edge domains and low ED region at the BPEB intermediate domain. Moreover, the ED distribution in each domain is not uniform, indicating a gradual transition between the three domains rather than defined interfaces.

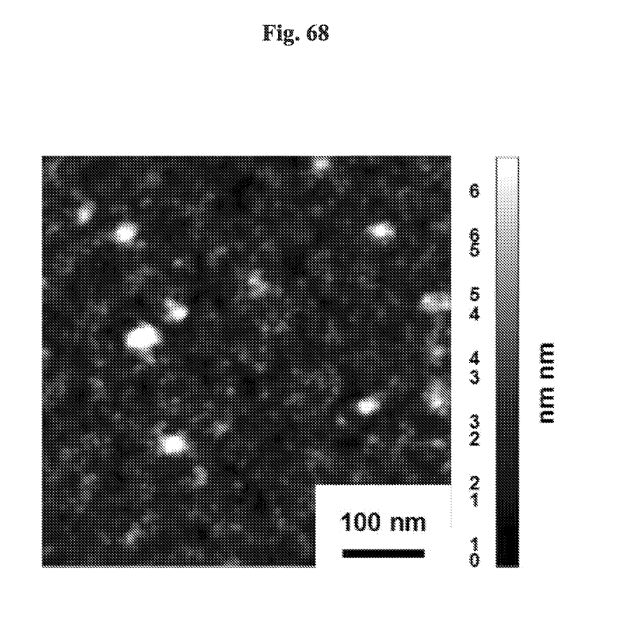

A representative AFM image of the Ru₂-BPEB₁₈-Os₂ assembly on silicon is shown in FIG. 68. The film exhibits a smooth and continuous topology with no apparent island-like domains. The surface root-mean-square roughness (Rᵣₘₛ) for a 500×500 nm² scan area is approximately 0.8 nm, which is in good agreement with the XRR data.

After obtaining a detailed structural characterization of the new multi-component assemblies, their electrical properties were examined. Solid-state semiconductor devices are typically characterized by current-voltage (I-V) curves in order to determine their diode characteristics. As a first step towards such devices we probed the conductivity of the multi-component assemblies. This is achieved by immobilizing the assemblies between two electrodes, similar to multilayer structures of redox polymers acting as electrochemical diodes (Zhao et al., 1994).

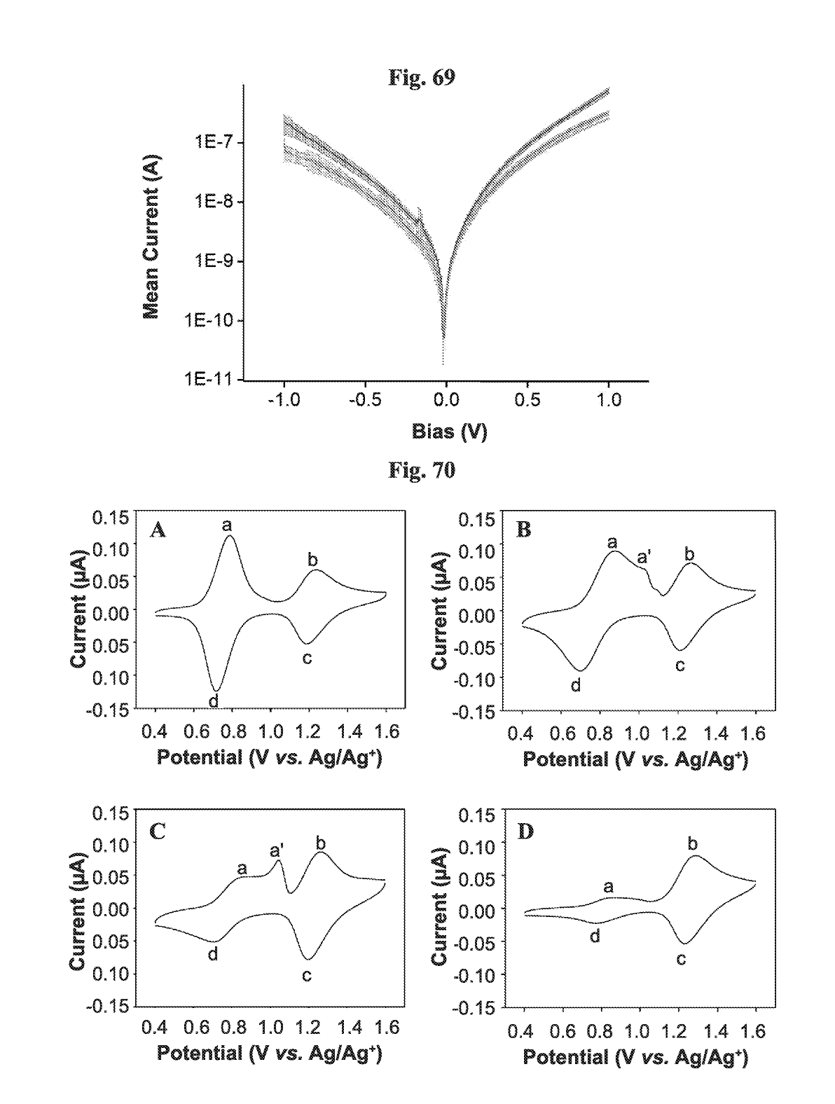

I-V measurements were carried out on a highly doped silicon substrate with a homogeneous, 8.6 Å-thick oxide layer. Highly doped p-Si electrode was chosen for its minimal semiconductor-related effects. Liquid Hg was used to form a soft, non-destructive top contact, following the roughness of the surface (Haag et al., 1999; Holmlin et al., 2001; Selzer et al., 2002; Nesher et al., 2007). Typical I-V curves of Hg/film/SiOx-p-Si junctions are shown in FIG. 69. The magnitude of the mean current depends on the thickness of the films. The decrease in the mean current with increasing distance separating the two electrodes is expected because of the increased film resistance (Rampi and Whitesides, 2002). The asymmetry in the I-V curves reflects the inherent structural asymmetry of the junctions.

We have reported that coordination-based surface-confined assemblies, based on one of the metal complexes (1 or 2) or a combination of both, are electrochemically active (de Ruiter et al., 2013; Motiei et al., 2009; Motiei et al., 2010a). Likewise, the new multi-component assemblies formed on ITO are redox-active, with changeable electrochemical characteristics as a function of the internal structure of the assemblies. By fine-tuning the distance between the 1- and 2-based redox-active domains, we were able to control the pathway by which electron transfer occurs during a redox cycle. CV measurements revealed that molecular-scale modifications in the thickness of the intermediating BPEB-domain result in a gradual transition between three distinctive electrochemical signatures, which correspond to two possible pathways for the oxidation of the outer Os metal centers.

When the BPEB-domain thickness is <2.4 nm, the assemblies exhibit reversible electrochemical waves for both Os^{2+/3+} and Ru^{2+/3+} redox couples at the half-wave potentials similar to the ones measured in solution (1: 1.194-1.212 V and 2: 0.742−0.753 V for the surface-confined assemblies vs. 1: 1.200 V and 2: 0.770 V in solution). A representative voltammogram of the Ru₂-BPEB₂-Os₂ assembly, having a total thickness of 4.8 nm and a BPEB-domain thickness of 1.4 nm, is shown in FIG. 70, panel A. The half-wave redox potentials (E_{1/2}) of 1 and 2 are 1.212 V and 0.753 V (versus Ag/AgCl), respectively. The large half-wave potentials separation of ΔE_{1/2}=0.459 V indicates that there is no communication between the Os and Ru metal centers in the assembly. Such behavior indicates that both types of metal centers can be addressed individually by the underlying ITO electrode.

As the BPEB-domain thickness increases, the peak-to-peak separation (ΔEₚ) of the Os^{2+/3+} redox couple increases and its current magnitude decreases. The redox-inactive BPEB-domain partially insulates the outer Os metal centers from the electrode, interfering with the electron-transfer process under these conditions. At the same time, a catalytic oxidative pre-wave appears. As the BPEB-domain thickness increases from 2.4 nm up to 6.6 nm, the catalytic oxidative pre-wave appears at higher potentials, starting from approximately 1.03 V to 1.13 V (versus Ag/AgCl). The voltammograms of the 5.9 nm-thick Ru₂-BPEB₄-Os₂ and the 7.0 nm-thick Ru₂-BPEB₆-Os₂ assemblies, having 2.4 and 3.5 nm-thick BPEB-domains, respectively (FIG. 70, panels B and C), demonstrate the described trend. This pre-wave results from the catalytic oxidation of the outer Os metal centers by the inner Ru metal centers and can be explained as follows: as the distance between the electrode interface and the 2-based domain increases, there will be an increasing amount of Os metal centers that are not accessible to the electrode, which explains the current decrease at the E_{1/2} of the Os^{2+/3+} redox couple. When reaching the onset potential for Ru oxidation, small amounts of Ru²⁺ are being oxidized to Ru³⁺. Since the reduction potential of Ru is higher than that of Os, the sparingly formed Ru³⁺ centers, which are closer to the 2-based domain, are able to accept electrons from the Os²⁺ centers, and subsequently transfer them to the ITO electrode, regenerating the Ru³⁺ centers which are again available to accept electrons from more Os²⁺ centers. By the constant regeneration of the Ru²⁺ centers through self-exchange at a given onset potential, an alternative electron-transfer pathway from the Os centers to the ITO electrode, with the mediation of Ru centers, is generated (de Ruiter et al., 2013; Abruna et al., 1981; Denisevich et al., 1981).

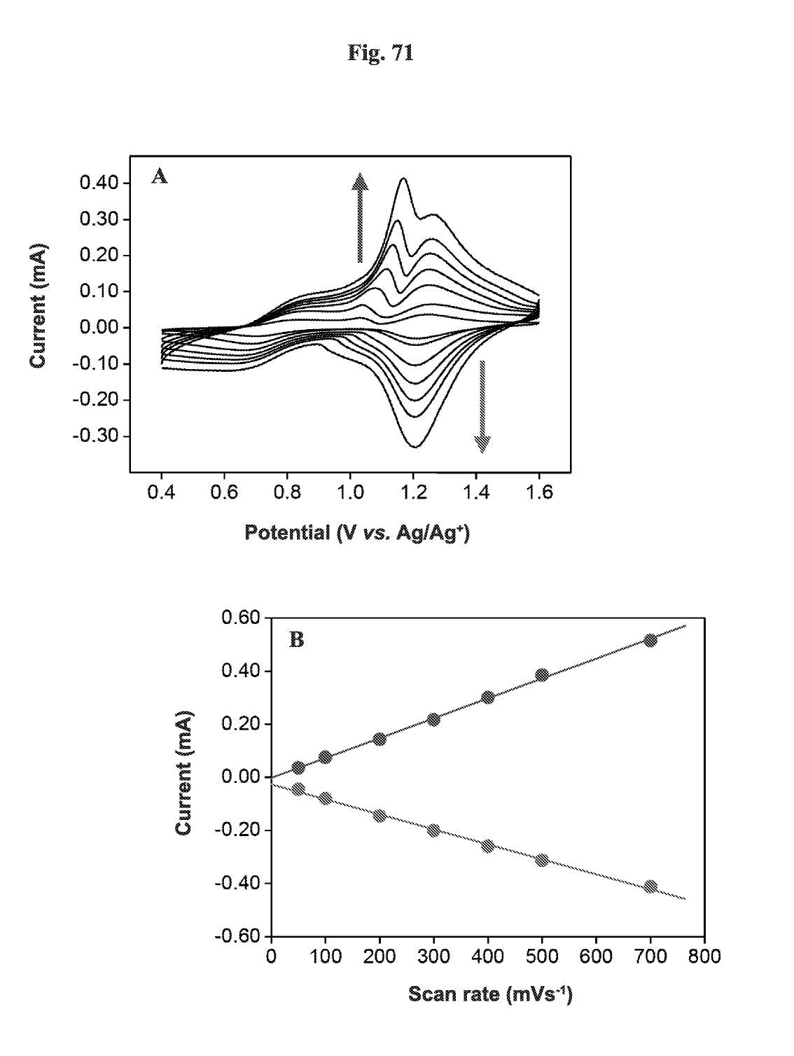

For the 7.0 nm-thick Ru₂-BPEB₆-Os₂ assembly, the Os pre-wave current and the Ru cathodic wave current are proportional to the scan rate within the range of 50-700 mVs⁻¹, indicating a surface-confined process that is not limited by diffusion (FIG. 71).

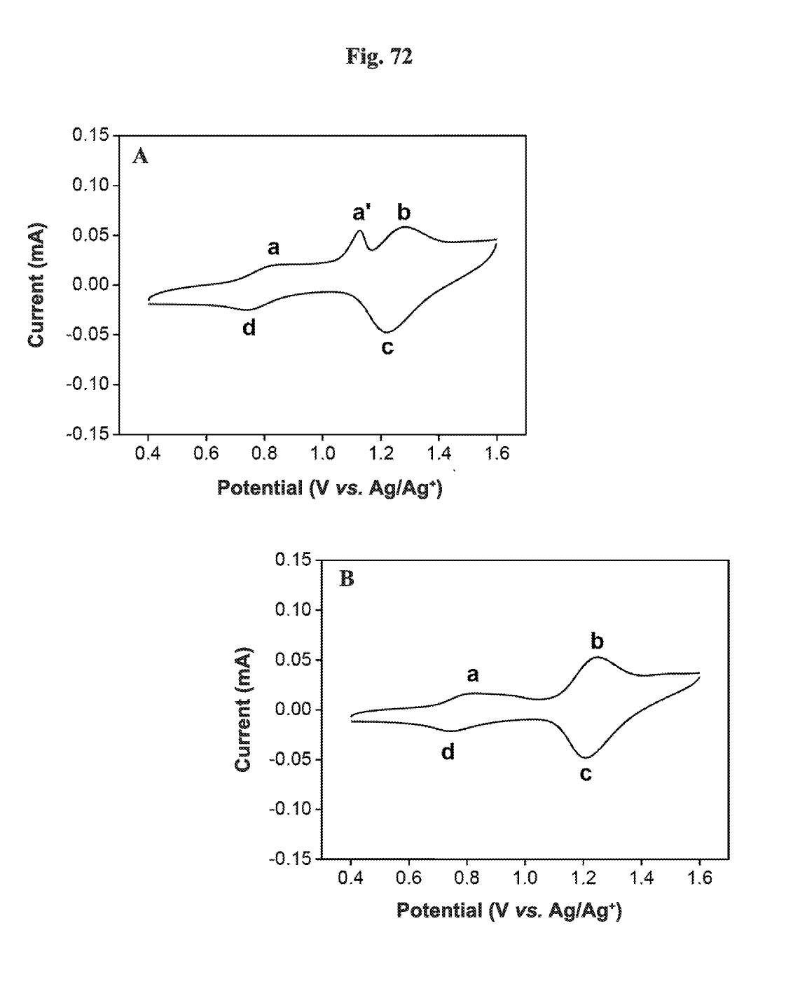

Assemblies having BPEB-domain thicknesses in the range of 4.8-6.6 nm (see FIG. 72 for a representative assembly) exhibit Os oxidation almost exclusively through the alternative pathway, which involves Ru catalytic centers. This is manifested in the CV by the presence of the pre-wave and the absence of the Os^{2+/3+} redox waves at the E_{1/2} of Os. Moreover, at this thickness range there is no pathway available for the reduction of Os³⁺ back to Os²⁺ in the negative scan direction: the direct electron-transfer pathway from the electrode to the Os centers is not available because of the large distance between them and the alternative pathway through the Ru centers is not available because the thermodynamic parameters do not permit the reduction of Os by Ru. The result of such redox cycle, in which the electron-transfer from the Os metal centers is unidirectional towards the electrode, is charge trapping (de Ruiter et al., 2013; Abruna et al., 1981; Denisevich et al., 1981).

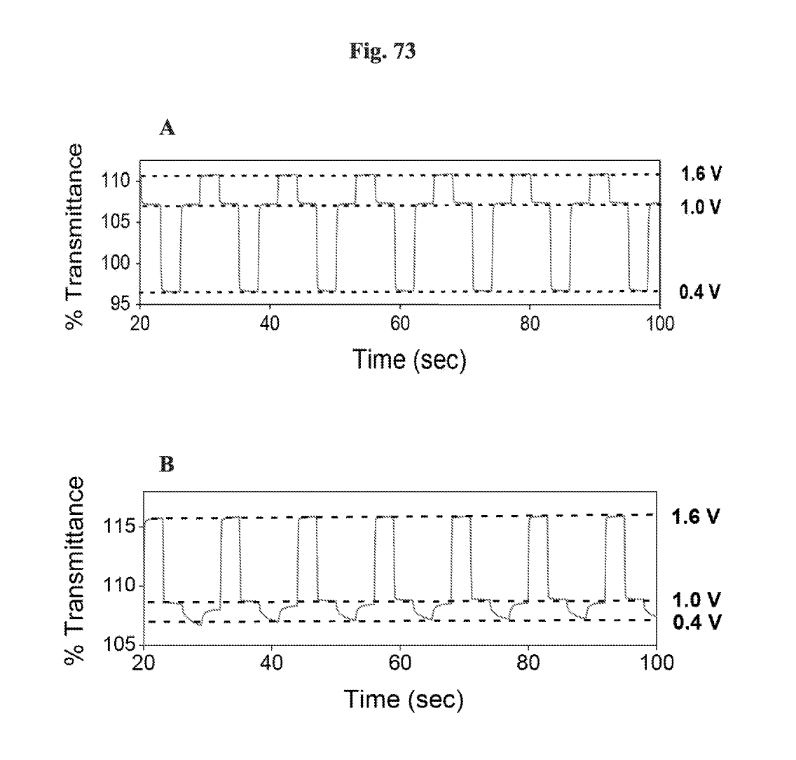

Electrochemical isolation of the Os metal centers occurs at BPEB-domain thicknesses of >6.6 nm, in which the Os metal centers are not accessible both to the electrode and the Ru metal centers. This is demonstrated, for instance, by the 10.0 nm-thick Ru₂-BPEB₁₀-Os₂ assembly, having a 6.6 nm-thick BPEB-domain (FIG. 70, panel D). At these conditions there is still a minor degree of electrochemical activity of the Os metal centers as the E_{1/2} region of the Os^{2+/3+} redox couple is not completely flat (FIG. 2D and S7B). This occurs mainly due to the large applied over potential, although electron-transfer through defects and pinholes in the assembly cannot be excluded (de Ruiter et al., 2013; Motiei et al., 2010a; Motiei et al., 2011b). In order to estimate the percentage of the accessible Os metal centers at these conditions and compare it to the most Os-accessible assembly, Ru₂-BPEB₀-Os₂, spectroelectrochemical measurements of the ITO-functionalized slides were performed (FIG. 73). The assemblies were subjected to multiple triple-potential steps (0.4, 1.0, and 1.6 V) and the MLCT band at λ≈510 nm was monitored over time. When moving up in the potential steps, the absorption band at λ≈510 nm is first partially bleached due to Os metal centers oxidation (at 1.0 V) and then totally bleached due to the oxidation of both metal centers (at 1.6 V). This corresponds to the increase in the transmittance seen in Figure S8. The percentage of accessible Os metal centers in the Ru₂-BPEB₁₂-Os₂ assembly compared to the Ru₂-BPEB₀-Os₂ assembly, after normalizing according to the 1.0-1.6 V potential step (as the Ru accessibility stays constant), is approximately 6%. These 6% are responsible for the small redox waves seen in FIG. 70, panel D, and FIG. 72 (areas a and d).

The present study demonstrates a gradual transition between three distinct electrochemical states of the multi-component assemblies, which are characterized by (i) reversible electron transfer; (ii) catalytic electron transfer; and (iii) blockage of electron transfer. In the first state, the metal centers of 1 and 2 are independently addressable, whereas in the second state 1-2 metal centers communication is observed, resulting in unidirectional current flow accompanied by charge trapping.

To further examine the charge transfer properties of the new multi-component assemblies, the influence of the environmental temperature on the electrochemical behavior has been investigated. The structural stability of the assemblies is governed by a competition between the disordering effect of entropy and the ordering effect of the coordination-based interactions among the different molecular components. An increase in the environmental temperature enhances the role of entropy, making the structure looser. Looser structure and elevated temperatures permit an enhanced diffusion of the supporting electrolyte charge carriers through the assemblies in order to maintain electro-neutrality during electron-transfer between fixed sites. In addition, electron-transfer rate constants are temperature dependent according to Arrhenius law (Smalley et al., 1995; Boiko et al., 2013; Smalley et al., 2003; Park and Hong, 2006). The combination of enhanced mobility of the charge carriers and enhanced electron-transfer rate constant results in a more reversible electrochemical profile at elevated temperatures. This is expressed in the CV by decreased peak-to-peak separation values and increased peak currents due to the thermally facilitated interfacial electron-transfer processes.

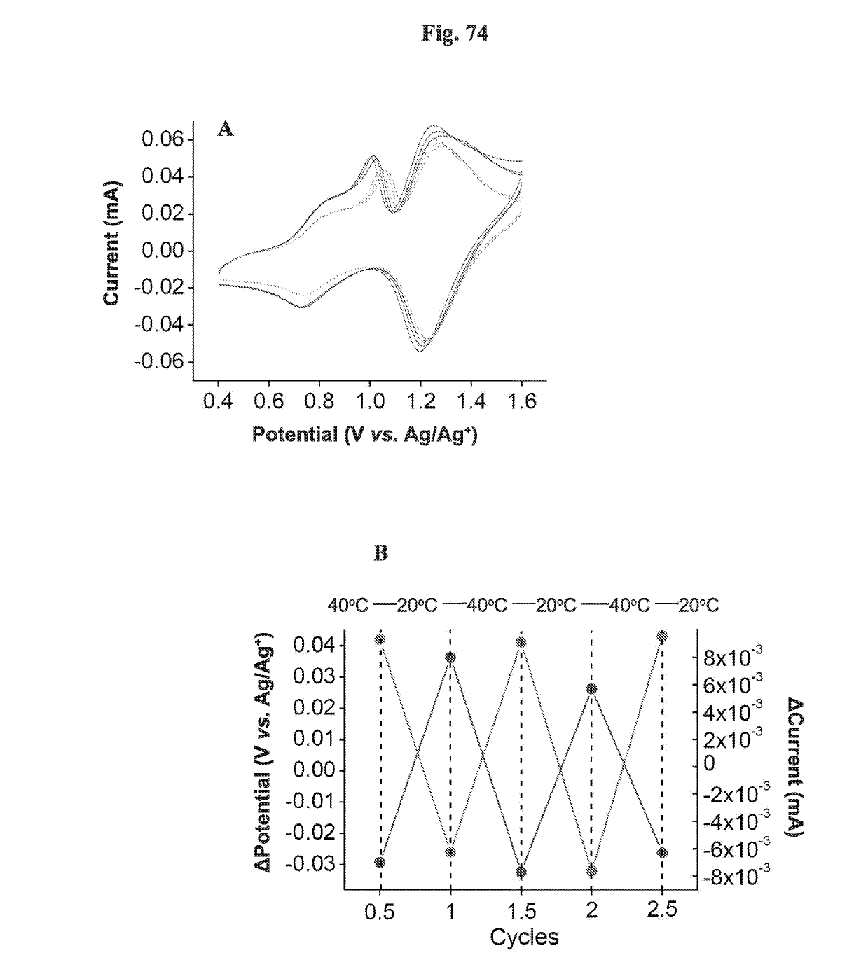

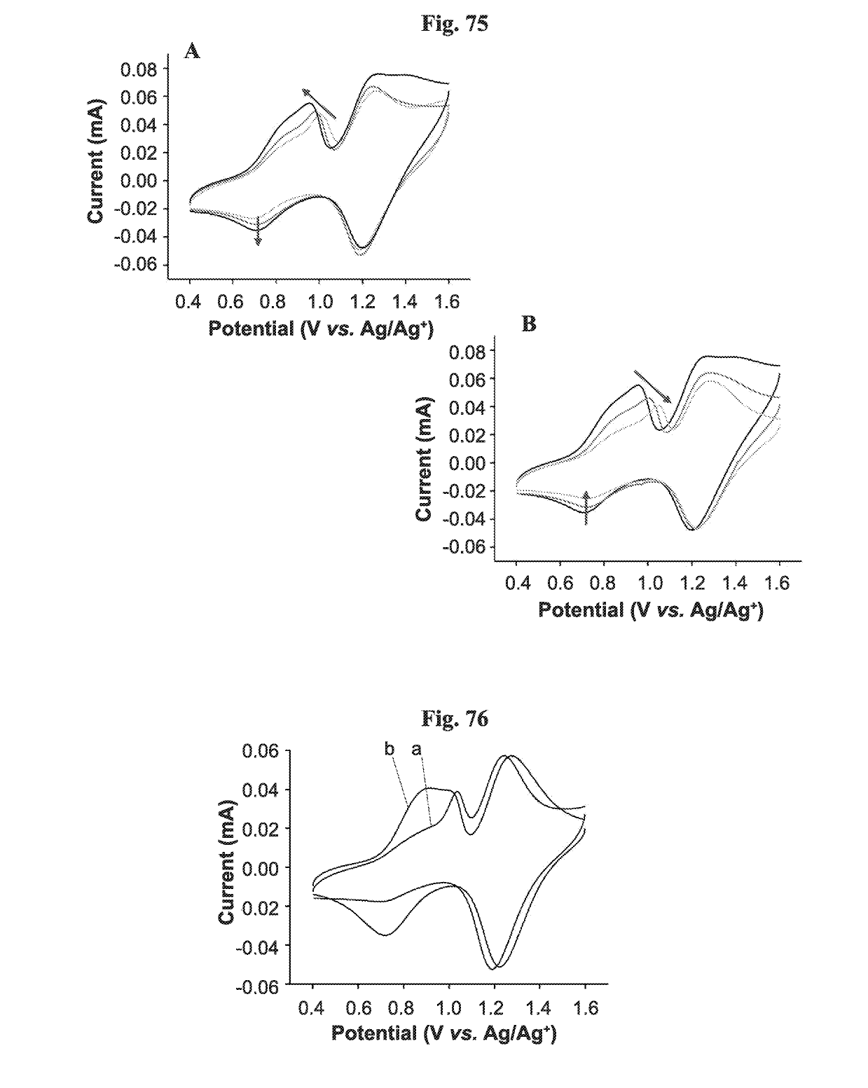

A representative assembly, Ru₂-BPEB₆-Os₂, exhibiting both reversible Os^{2+/3+} redox waves and oxidative catalytic pre-wave (FIG. 70, panel C) was chosen to demonstrate the temperature response. The chosen assembly was subjected to heating-cooling cycles using a temperature controller. CV was measured at the moment the desired temperature was reached and afterwards the temperature was immediately altered. Two-point heating-cooling cycles (20° C. and 40° C.) are presented in FIG. 74. The CVs at 40° C. exhibit increasing peak currents of the Os^{2+/3+} reversible redox waves as well as the catalytic pre-wave. In addition, because of the thermally facilitated electron-transport, the pre-wave appears at a lower potential. The difference in the pre-wave potential and current at each temperature transition is almost constant during a few heating-cooling cycles, indicating a reversible behavior of the assemblies. The reversibility was demonstrated in a three-point heating-cooling cycles (20° C., 40° C., and 60° C.) as well (FIG. 75).

Interestingly, after a prolonged heating of the assemblies the electrochemical behavior changes significantly, displaying higher reversibility. As opposed to the heating-cooling cycles, the change in this case is irreversible, implying a possible structural reorganization of the assemblies. FIG. 76 shows two voltammograms of the same assembly, taken at 20° C. before and after a heating treatment, as described in the figure caption. The major increase in the Os^{2+/3+} redox waves indicates that more Os metal centers became accessible to the ITO electrode after the heating treatment. This observation can be explained by a diffusional penetration of some of the Os complexes (2) through the assemblies and towards the electrode upon prolonged heating. Diffusion can occur through defects and pinholes in the structure as well as through the generally looser structure achieved by heating. It should be noted that similar results were obtained after 10 min of the heating treatment. As for the nature of the diffusing complexes: it cannot be excluded that during the layer-by-layer assembly, some of the complexes were incorporated not through the vinylpyridyl-Pd coordination chemistry and were stored inside available voids. While at RT the assemblies are rigid enough to keep such components in place, heating can induce internal fluctuations that will allow their movement. Although such explanation is reasonable, a dynamic coordination network as an explanation to our observations cannot be excluded (Beck and Rowan, 2003; Bodenthin et al., 2005; Friese and Kurth, 2008; Vermonden et al., 2004; Kitagawa and Uemura, 2005).

In order to confirm our hypothesis regarding the penetration of Os complexes into the assemblies upon a prolonged heating, AR-XPS measurements were performed. The data for the Ru₂-BPEB₆-Os₂ assembly is summarized in Table 7.

At the standard takeoff angle of θ=0°, the majority of the experimental elemental ratios are close to the theoretical ones. The slightly larger ratios observed between Pd and other elements are not uncommon and are due to storage of excess of the Pd precursor inside the assemblies. This phenomenon was observed previously for assemblies consisting of the metal complexes (1, 2) (Choudhury et al., 2010; Motiei et al., 2008). The Os/Ru ratio, on the other hand, is smaller than the theoretical value by a factor of 2. A combination of two factors is responsible for this result: 1) The excess of the Pd precursor being stored by the porous 1-based template layer is used for depositing more Ru complexes than expected at the first deposition cycle (which is also the reason for the non-linear growth fashion of the 1- and 2-based domains). This is confirmed by the smaller than expected Pd/Ru and N/Ru ratios. 2) Because of the highly branched nature of our assemblies and the bulkiness of the metal complexes, it is expected that the assemblies will not be fully formed. This effect will be more pronounced at the upper region of the assemblies, reducing the amount of the incorporated Os complexes. This explanation is confirmed by the larger than expected Pd/Os and N/Os ratios.

TABLE 7
XPS derived elemental ratios and atomic concentrations of a
representative assembly, Ru₂-BPEB₆-Os₂, on quartz before
and after the heating treatment. The XPS spectra were recorded at
takeoff angles of θ = 0° and θ = 50°.

| | | | | | Theoretical |
|---|---|---|---|---|---|
| | Before heating | | After heating | | elemental |
| Entry | θ = 0° | θ = 50° | θ = 0° | θ = 50° | ratio |
| Os/Ru^{a} | 2.11 | 4.67 | 1.75 | 2.80 | 4.00 |
| Pd/Os^{a} | 4.59 | 3.16 | 4.22 | 3.56 | 3.17 |
| Pd/Ru^{a} | 9.94 | 14.75 | 7.40 | 10.00 | 12.67 |
| N/Pd^{a} | 4.30 | 4.78 | 4.37 | 4.82 | 4.82 |
| N/Os^{a} | 20.17 | 15.11 | 18.48 | 17.13 | 15.25 |
| N/Ru^{a} | 42.71 | 70.50 | 32.35 | 48 | 61.00 |
| Os^{b} | 0.36 | 0.56 | 0.35 | 0.45 | |
| Ru^{b} | 0.17 | 0.12 | 0.20 | 0.16 | |

^{a}Elemental ratios.
^{b}Atomic concentrations

In order to examine the effect of the heating treatment, additional measurements at a takeoff angle of θ=50° were performed. At this takeoff angle the XPS probing depth is lower than at θ=0° and the signal intensities of elements located at the outermost region of the assembly are higher than of the ones located at its depth (Merzlikin et al., 2008). As a consequence, the outcome of a diffusion of Os complexes inwards upon the heating treatment will be a decrease in the atomic concentration of Os at θ=50°. For a normalized comparison, we examined the ratio between the atomic concentration of Os at θ=50° and at θ=0°. This ratio before the heating treatment is 1.56 and after the treatment is 1.29. The same trend is apparent when comparing the elemental ratios of the Os/Ru, Pd/Os, and N/Os pairs at the two takeoff angles (i.e. the ratio between the elemental ratios) before and after the heating treatment, but is absent for all other elements and pairs.

The combination of the AR-XPS results, which demonstrate the penetration of Os complexes into the assembly upon heating, and the electrochemical findings, that show a more reversible behavior of the Os metal centers after heating, supports the dynamic nature of our new assemblies.

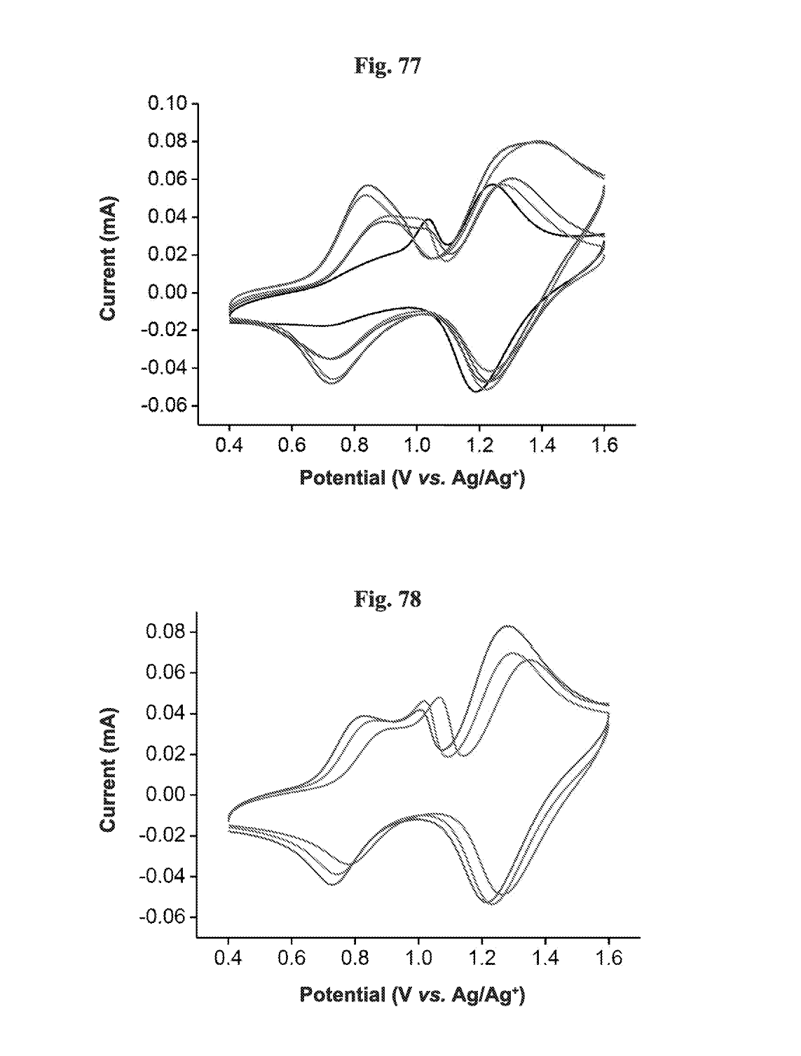

The thermally modified assembly was then electrochemically probed at 60° C. and afterwards again at 20° C. This was repeated twice and the results are shown in FIG. 77. At 60° C. the Os^{2+/3+} redox waves are much more pronounced for the thermally modified assembly compared to the untreated assembly (FIG. 75). Additionally, the modified assembly exhibits a reversible behavior during heating-cooling cycles with the electrochemical signature of the modified state at 20° C. This result further supports the proposed structural modification and the formation of a new stable structure by supplying thermal energy to the system.

Next, the influence of the supporting electrolyte concentration was examined. CVs of the representative Ru₂-BPEB₆-Os₂ assembly in three different concentrations of TBAPF₆ in acetonitrile are shown in FIG. 78. An increase of ten-fold in the electrolyte concentration improves the electrochemical reversibility of the Os^{2+/3+} redox couple, as seen by the increased peak current and decreased peak-to-peak separation values. Surface-confined systems having an electron donor and an electron acceptor separated by a molecular spacer are known to have a strong dependency of the electron-transfer rate on the supporting electrolyte concentration (Nishimori et al., 2007; Saveant, 1988a; Saveant, 1988b). In such systems a sequential electron-hopping mechanism, in which the electron moves from the donor to the acceptor through the energy levels of the spacer, was proposed (Hirao, 2006). This mechanism is limited by the motion of the supporting electrolyte counter-ions and the maintenance of electro-neutrality during electron-hopping between fixed sites. Improved electrochemical reversibility in our system upon heating and increasing the electrolyte concentration supports an electron-hopping-type mechanism.

The present study demonstrates the importance of the internal molecular structure of our assemblies in determining their physicochemical properties. To further test this hypothesis, we have chosen to address the intermediate BPEB-domain and alter its molecular structure.

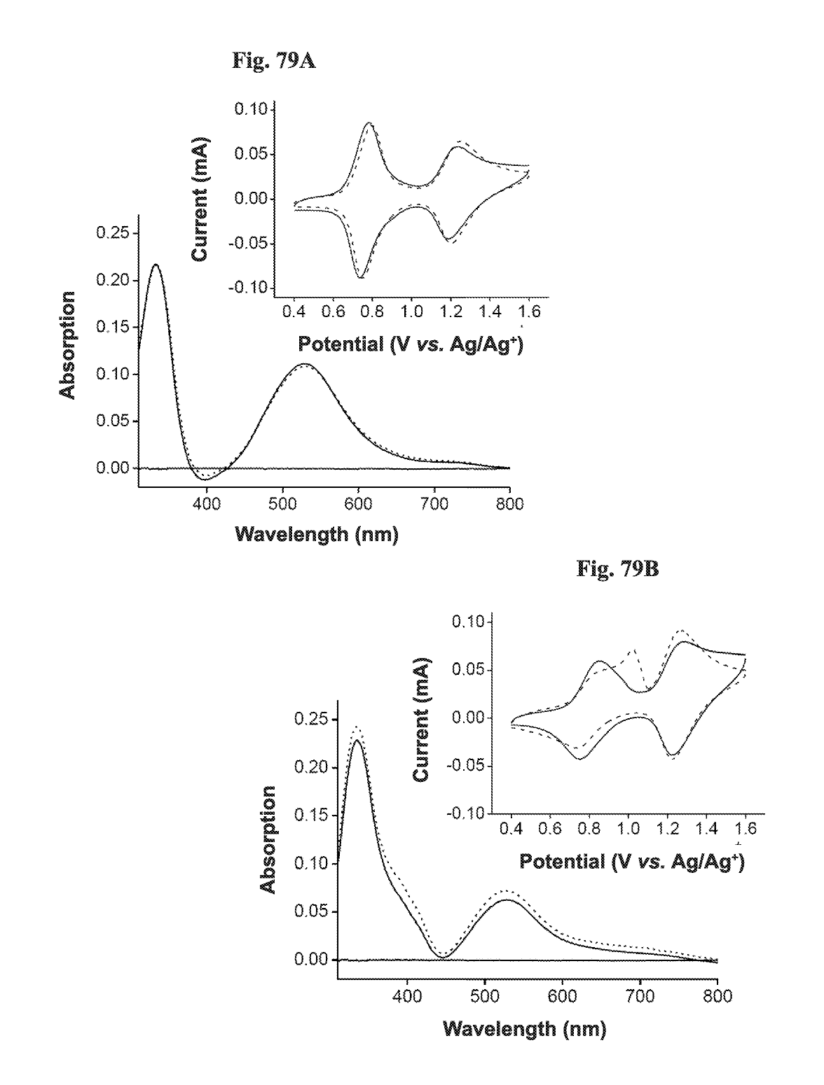

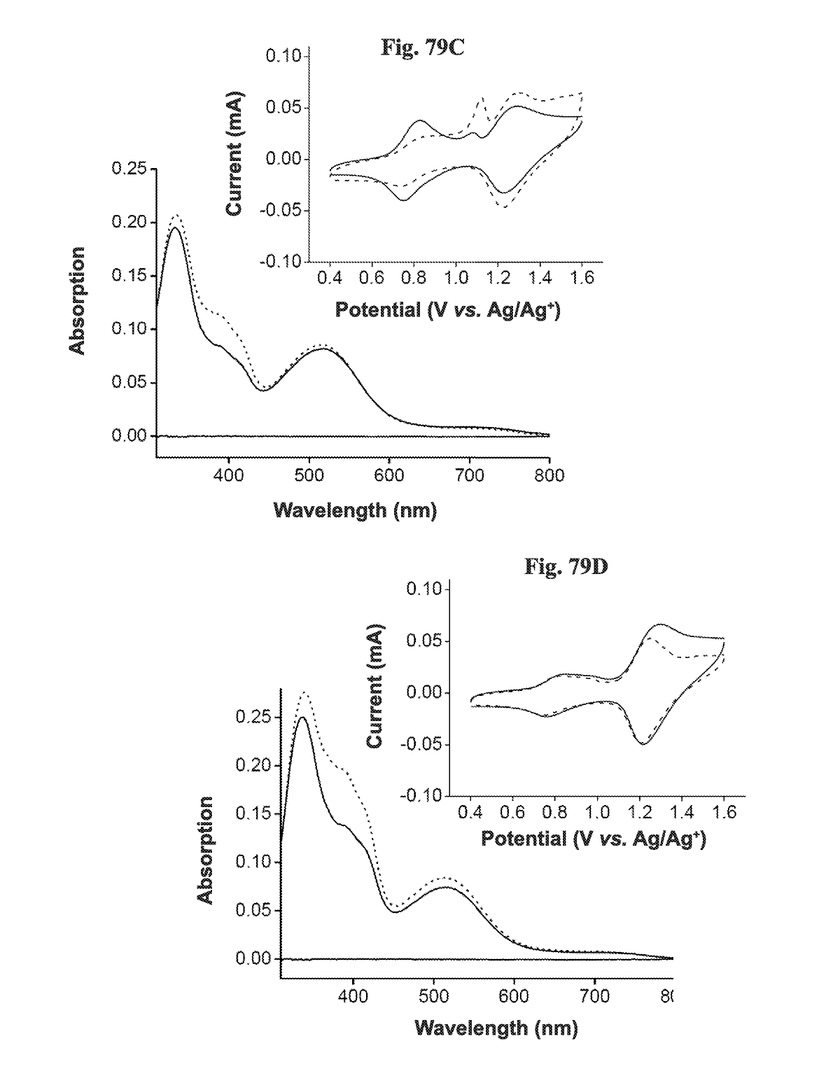

Conjugated olefins and in particular the BPEB molecule, are known to undergo a [2+2] photoreaction in the solid state, as crystalline materials or as monolayers bound to a solid surface, to produce cyclobutanes (Schmidt, 1971; MacGillivray et al., 2000; McMahon et al., 1985; Naciri et al., 2000; Fang et al., 2001; Yang et al., 2003; Li et al., 1997). We have irradiated functionalized ITO slides with UV light at 254 nm and followed the changes by UV/vis spectrometry and electrochemistry (FIGS. 79A-76D). According to the UV/vis data only the BPEB absorption band (λ≈390 nm) decreases after the irradiation while the bands associated with the metal complexes 1 and 2 (λ≈338 and 513 nm) stay unchanged (FIGS. 79B-76D) the band at λ≈338 nm slightly decreases due to the partial overlap with the BPEB band). We have found that above 40 min of irradiation the change in the BPEB absorption band is not significant while the other two bands show reduced intensities. We suspect that beyond the mentioned time the metal complexes are being damaged (and possibly also the unreacted BPEB molecules, which can be the reason for the reduction in the intensity of their absorption band) and the remaining BPEB molecules are not properly aligned to undergo a cyclization. The reduction in the BPEB absorption band indicates the loss of conjugation that occurs during the photoreaction. It should be noted that according to the ellipsometric data of the same assemblies on silicon, the thickness does not change after the irradiation, which means that the assemblies stay intact during the photoreaction.

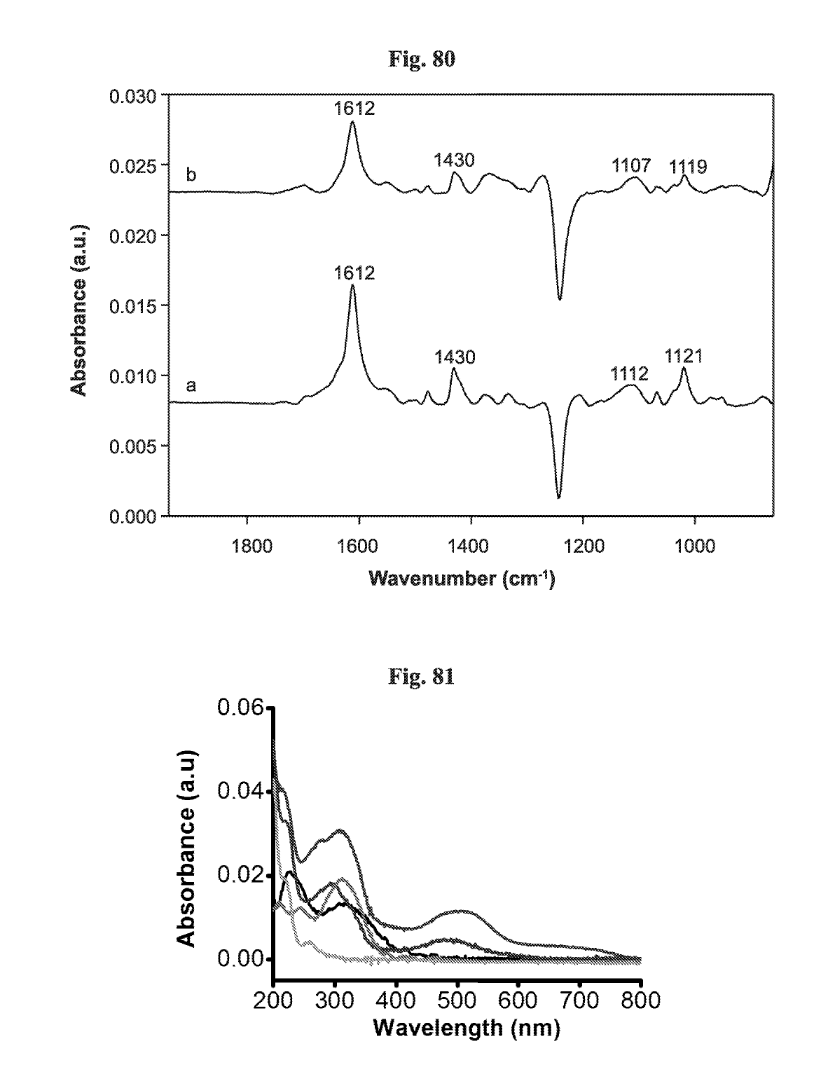

To further characterize the resulting product, FTIR was performed (FIG. 80). The most pronounced support for the cyclization reaction is the decrease of 40% in the intensity of the peak at 1612 cm⁻¹, which corresponds to a trans-disubstituted, conjugated double bond streaching (Lin-Vien et al., 1991). This band coincide with one of the pyridine ring bands and additionally, according to the UV/vis data not all of the BPEB molecules have reacted during the irradiation, which is the reason why this band didn't disappear completely. The small hill at around 930 cm⁻¹ is an indication of a cyclobutyl ring breathing (Lin-Vien et al., 1991), though a firmer support for the proposed product could not be found and a different dimerization product cannot be excluded (McMahon et al., 1985).

UV irradiation has a pronounced effect on the electron transfer ability and thus, on the electrochemical profile of the assemblies (insets of FIGS. 79A-79D). Assemblies in which the BPEB-domain partially inhibits electron transfer from the outer Os metal centers to the ITO electrode show a more reversible electrochemical behavior after being irradiated: the peak currents of the reversible Os^{2+/3+} redox waves increase at the expense of the catalytic wave and the peak-to-peak separation values of these waves decrease (FIGS. 79B-79C), which indicates a facilitated electron transfer from the 2-based domain to the underlying electrode. The irradiation does not have an effect on the electrochemistry of the assemblies in the two extreme cases: 1) when the BPEB-domain thickness is low enough so that the Os metal centers can be addressed independently by the electrode and 2) when the BPEB-domain is above a threshold thickness after which the Os metal centers are not accessible any more (FIGS. 79A and 79C).

The photoreaction couples each two BPEB molecules, leaving a larger unoccupied space, and in addition, their movement is even more restricted. This results in a higher porosity, which facilitates the electrolyte charge carriers movement throughout the assemblies.

These results also imply that the effect of conjugation in the BPEB molecules is of minor importance in the electron-transfer processes.

The results presented herein unequivocally demonstrate the ability to control and manipulate the electron transfer properties of surface-confined, multi-component assemblies. The extend of electrochemical reversibility, catalytic redox processes, unidirectional current flow, and electrochemical isolation are all fundamentally different states that can be achieved using the same molecular building block.

### Study 5

### Molecular Gradients and Template Layer Effects in the Self-Assembly of Metal Organics

### Introduction

Self-assembly of molecules on surfaces provides highly ordered three dimensional systems. The ability to incorporate a wide range of molecules on different surfaces leads to generation of a variety of solid state constructions. Surface modification can be obtained using different techniques such as Langmuir-Blodgett and Layer-by-Layer deposition. Layer by layer deposition is an attractive technique as it can offer incorporation of multiple components in one assembly by depositing different type of molecules in each deposition step. Moreover, it can offer the generation of new materials by altering the components order within the assembly. Study 1 above demonstrates direct relationship between compositional sequence of surface-confined assemblies and their electrochemical behavior. These assemblies were consisted of ruthenium and osmium redox-active polypyridyl complexes. Changing the complexes order within these surface-confined assemblies lead to charge trapping and electrochemical isolation of one of the components. Assemblies consisting of electro-active complexes such as polypyridyl complexes are ideal candidates for molecular memory applications and electrooptic devices. Another way to incorporate multiple components into one assembly is by simultaneous adsorption of different kinds of molecules on the surface. Such systems are termed “mixed assemblies”. So far, the most frequently studied mixed assemblies are binary monolayers composed of alkanethiols deposited on gold surfaces. These monolayers were composed of alkanethiols with different chain lengths, different terminal groups or a mixture of aromatic and long chain mercaptans. Studies have been done to investigate binary monolayers properties such as phase separation, wettability and structural properties. Binary monolayers can also be composed of one or two redox-active components. Li et al. (2004) demonstrated the formation of redox-active two-component monolayers in order to achieve multibit functionality for hybrid memory devices. Incorporation of two redox-active components allows increasing memory density, particularly if one of the components exhibits multiple redox states. Their monolayers were consisted of ferrocene-based molecule and zinc porphyrin derivative molecule on silicon surfaces. Since both components were electro-active, they were able to determine the binary monolayer composition using electrochemistry. They revealed that although the molecules were deposited from a solution mixture of 1:1 ratio, surface coverage of ferrocene-based molecule was higher than that of zinc-porpherin derivative molecule. The difference in the coverage of both molecules was attributed to the smaller size of ferrocene-based molecule comparing to zinc-porpherin derivative molecule. Binary monolayers composed of similar sized complexes were demonstrated by Forster and Faulkner (1995). Their mixed monolayers were consisted of osmium and ruthenium complexes having the same ligands structure. The complexes were deposited on platinum surfaces from an equimolar mixture solution. The surface coverage ratio of the complexes was similar to the complexes ratio in the mixture solution.

### Experimental

Materials and Methods.

Solvents (AR grade) were purchased from Bio-lab (Jerusalem), Frutarom (Haifa) or Mallinckrodt Baker (Phillipsburg, N.J.). Anhydrous acetonitrile was purchased from Sigma Aldrich. Toluene was dried and purified using a M. Braun solvent purification system. ITO coated glass substrates (0.7×5 cm) were purchased from Delta Technologies. Single-crystal silicon (100) substrates were purchased from Wafernet (San Jose, Calif.). All glassware and Teflon holders for SMPA formation were cleaned by immersion in a piranha solution (7:3 v/v, H₂SO₄/30% H₂O₂) for 10 min and DI water. ITO and silicon substrates were cleaned by sonication in DCM, toluene, acetone and ethanol, successively, 8 min in each solvent. Subsequently, they were dried under a N₂ stream and cleaned for 20 min using the UVOCS cleaning system (Montgomery, Pa.), then sonicated in ethanol and placed in the oven (130° C.) for 2 hours. Quarts (Chemglass, Inc.) substrates (2×1 cm) were rinsed several times with DI water and cleaned by immersion in a piranha solution for 1 h. The substrates were then rinsed with deionized water followed by sonication in RCA solution (1:5:1 (v/v) NH₄.OH/H₂O/30% H₂O₂) at 80° C. for 45 min. After RCA treatment, the substrates were washed with deionized water, sonicated in ethanol, dried under a N₂ stream, and placed in the oven (130° C.) for 2 hours. UV/vis spectra were recorded using a Cary 100 spectrophotometer on quartz slides using double beam mode in a range of 200-800 nm. Baseline measurements were recorded using bare quartz slides. Thicknesses measurements were performed on silicon by using a J. A. Woollam (Lincoln, Neb.) model M-2000V spectroscopic ellipsometer with VASE32 software (for each 2 degree at a range of 65-75° over wavelengths of 399-1000 nm). Electrochemical measurements were carried out using a CHI660A potentiostat with platinum as the counter electrode, Ag/AgCl as the reference electrode, and ITO substrate (single or double side coated glass) as the working electrode in a solution of 0.1M TBAPF₆ in CH₃CN. Ferrocene was used as the internal standard. All measurements were carried out under inert atmosphere at 298 K unless stated otherwise. Multilayer formation was carried out under air at RT.

XRR measurements were performed on silicon (100) substrates, at the 12-BM-B beamline at the Advanced Photon Source (APS) in the Argonne National Laboratory (Argonne, Ill., USA). A four-circle Huber diffractometer was used in the specular reflection mode (i.e., the incident angle θᵢₙ was equal to the exit angle θₑₓ and the wave vector transfer |q|=q_{z}=(4π/λ) sin θ is along the surface normal). X-rays of energy of E=10.0 keV (λ=1.24 Å) were used for these measurements. The beam size was 0.40 mm vertically and 0.60 mm horizontally. The samples were held under a helium atmosphere during the measurements to reduce radiation damage and background scattering from the ambient gas. The off-specular background was measured and subtracted from the specular counts. XRR measurements were performed at ambient laboratory temperatures, which ranged from 20 to 25° C.

AR-XPS measurements were performed. Films on quartz substrates were measured at five different take-off angles, relative to the surface plane (5°, 15°, 30°, 45°, 80°) with a PHI 5600 MultiTechnique System (base pressure of the main chamber 2×10⁻¹⁰ Torr). The acceptance angle of the analyzer and the precision of the sample holder concerning the takeoff angle are ±3° and ±1°, respectively. The quartz slides were radiated using a monochromator that allowed a resolution of 0.25 eV. Samples were mounted on Mo stubs. Spectra were excited with Al Kα radiation. The structure due to satellite radiation has been subtracted from the spectra before the data processing. High-resolution spectra of C(1s), O(1s), Si(2p), N(1s), Pd(3d), Cl(2p), Os(4f) Ru(3p3) and Fe(2p) were collected with 5 eV pass energy and a resolution of 0.45 eV. The XPS peak intensities were obtained after Shirley background removal and Gaussian line shapes were used for the curve fitting in the data analysis. The C(1s) line at 285.0 eV was used for calibration.

¹H NMR spectra was obtained using a Bruker AMX 400 NMR spectrometer or a Bruker DPX 250 NMR spectrometer. Mass spectrometry was performed using a Micromass Platform LCZ 4000 mass spectrometer.

Synthesis.

Compounds 1-5 were prepared according to literature procedures.

Coupling Layer Formation.

Under inert conditions, ITO, silicon and quartz substrates were loaded onto a holder and immersed in a beaker with dry toluene and para-chloromethyl-phenyl trichlorosilane (0.5 mM) for 45 min; afterwards the holder was immersed into three toluene beakers, iteratively. The substrates were then sonicated for 8 min in toluene (×2) and in hexane, and dried under a stream of N₂.

Organic Template Layer (TL) Formation.

Under inert conditions, 3 or 5 (0.5 mM) were dissolved in a solution of dry toluene in a reactor. A holder with ITO, silicon and quartz substrates coated with coupling layer was immersed in the solution and the reactor was sealed. The sealed reactor was kept at 95° C. for 3 days. The slides were then sonicated in DCM (×2) and in THF for 8 min in each solvent, and were subsequently dried under a stream of N₂ The substrates were stored under ambient conditions with the exclusion of light.

Organometallic Template Layer (TL) Formation.

Under inert conditions, 1, 2 or 4 (0.2 mM) were dissolved in a solution of dry toluene/acetonitrile (1:1 v/v) in a reactor. A holder with ITO, silicon and quartz substrates coated with coupling layer was immersed in the solution and the reactor was sealed. The sealed reactor was kept at 95° C. for 4 days. The slides were then sonicated in acetonitrile (×2) and in acetone for 8 min in each solvent, and were subsequently dried under a stream of N₂. The substrates were stored under ambient conditions with the exclusion of light.

Formation of Binary SPMAs TL-[Os/Ru] Consisting of Complexes 1 and 2 and PdCl₂.

Quartz, ITO and silicon substrates, functionalized with an organic or organometallic template layer, were immersed for 15 min in a THF solution of PdCl₂(PhCN)₂ (1 mM) at RT. The samples were then sonicated in THF (×2) and in acetone for 3 min each. Subsequently, the substrates were immersed in an equimolar solution consisting of 1 and 2 (0.1 mM each, THF:DMF=9:1, v/v) for 15 min at RT. The samples were then sonicated in THF (×2) and in acetone for 5 min each. This procedure was repeated eight times. Deposition step is defined as the deposition of palladium salt and a mixture of complexes. The slides dried under a stream of N₂ prior to UV/Vis, ellipsometric and electrochemistry analyses.

Formation of monolayers consisting of complexes 1 or 2 (TL-[M], M=Fe, Os or Ru) and PdCl₂.

ITO substrates functionalized with organic or organometallic template layer were immersed for 15 min in a THF solution (2 ml) of PdCl₂(PhCN)₂ (1 mM) at RT. The samples were then sonicated in THF (×2) and in acetone for 3 min each. Subsequently, the substrates were immersed in a solution consisting of 1 or 2 (0.2 mM, THF:DMF=9:1, v/v) for 15 min at RT. The samples were then sonicated in THF (×2) and in acetone for 5 min each. The slides were dried under a stream of N₂ prior to electrochemistry analysis.

Blocking Experiments.

ITO substrates functionalized with 3 were immersed for 15 min in a THF solution of PdCl₂(PhCN)₂ (0.1 mM) at RT. The samples were then sonicated in THF (×2) and in acetone for 3 min each. Subsequently, the substrates were immersed in a solution consists of 1, 2 or 4 (0.2 mM, THF: DMF=9:1, v/v) for 15 min at RT. The samples were then sonicated in THF (×2) and in acetone for 5 min each. Next, the slides were reacted again with PdCl₂ and treated as mentioned above. After PdCl₂ treatment, the slides were immersed in an equimolar solution consists of 1 and 2 (0.1 mM each, THF:DMF=9:1, v/v) for 15 min at RT. The samples were then sonicated in THF (×2) and in acetone for 5 min each. The slides were dried under a stream of N₂ prior to electrochemistry analysis.

### Results and Discussion

Compounds Preparation.

Compounds 1-5 were synthesized according to literature procedures and were characterized by ¹H NMR, mass spectrometry and UV/Vis spectroscopy. Complexes 1 and 2 were also characterized by CVs.

Formation of Coupling Layer.

Cleaned quartz, silicon (100) and ITO substrates were functionalized with (p-chloromethyl)phenyl-trichlorosilane. Coupling layer formation was confirmed by spectroscopic ellipsometry and aqueous contact angle measurements which showed an average thickness of 8 Å and aqueous contact angle of 70°, respectively.

Formation of Organic Template Layer.

Silicon, quartz and ITO surfaces functionalized with coupling layer were reacted with chromophore 3 or 5 to generate template layer TL3 or TL5, respectively (Scheme 1). Formation of the template layer was confirmed by UV/Vis spectroscopy and spectroscopic ellipsometry measurements. UV/Vis absorption measurements on quartz modified with TL3 revealed a band at λₘₐₓ=325 nm corresponding to the 3-based template layer. UV/Vis spectrum of TL5 showed a band at λₘₐₓ=356 nm (FIGS. 81). TL3 and TL5 thicknesses were estimated to be 17 Å and 15 Å, respectively, by ellipsometry measurements using a Causey model.

Formation of Organometallic Template Layer.

Silicon, quartz and ITO surfaces functionalized with coupling layer were reacted with complex 1, 2 or 4 to generate template layer TL1, TL2 or TL4, respectively (Scheme 1). Formation of the template layer was confirmed by UV/Vis spectroscopy and spectroscopic ellipsometry measurements. UV/Vis absorption measurements on quartz of all three template layers showed a band at λₘₐₓ=317 nm which corresponds to π-π* band of the ligand. TL1 and TL2 UV/Vis spectrum showed additional characteristic MLCT bands of complex 1 and 2 respectively. Complex 1 has MLCT band at λₘₐₓ=490 nm, and complex 2 has singlet and triplet MLCT bands at λₘₐₓ=510 nm and 680-700 nm, respectively (FIGS. 81). TL1 and TL2 thicknesses were estimated to be 25 Å and 18 Å, respectively, by ellipsometry measurements using a Causey model.

Formation of SPMA TL-[Os/Ru].

SPMA TL-[Os/Ru] containing both ruthenium and osmium redox centers was formed by iterative binding of PdCl₂ and a polypyridyl complex (1 or 2). Surfaces modified with organic or organometallic template layer were immersed in PdCl₂ (1 mM, THF) solution for 15 min, followed by sonication in THF and acetone solvents. Subsequently, the substrates were immersed in an equimolar solution consisting of complexes 1 and 2 for 15 min (0.1 mM each, THF:DMF=9:1, v/v), sonicated in THF and acetone solvents. This procedure was repeated 8 times. The slides were dried under N₂ stream. One deposition step is the deposition of PdCl₂ and a mixture of complexes on the surface.

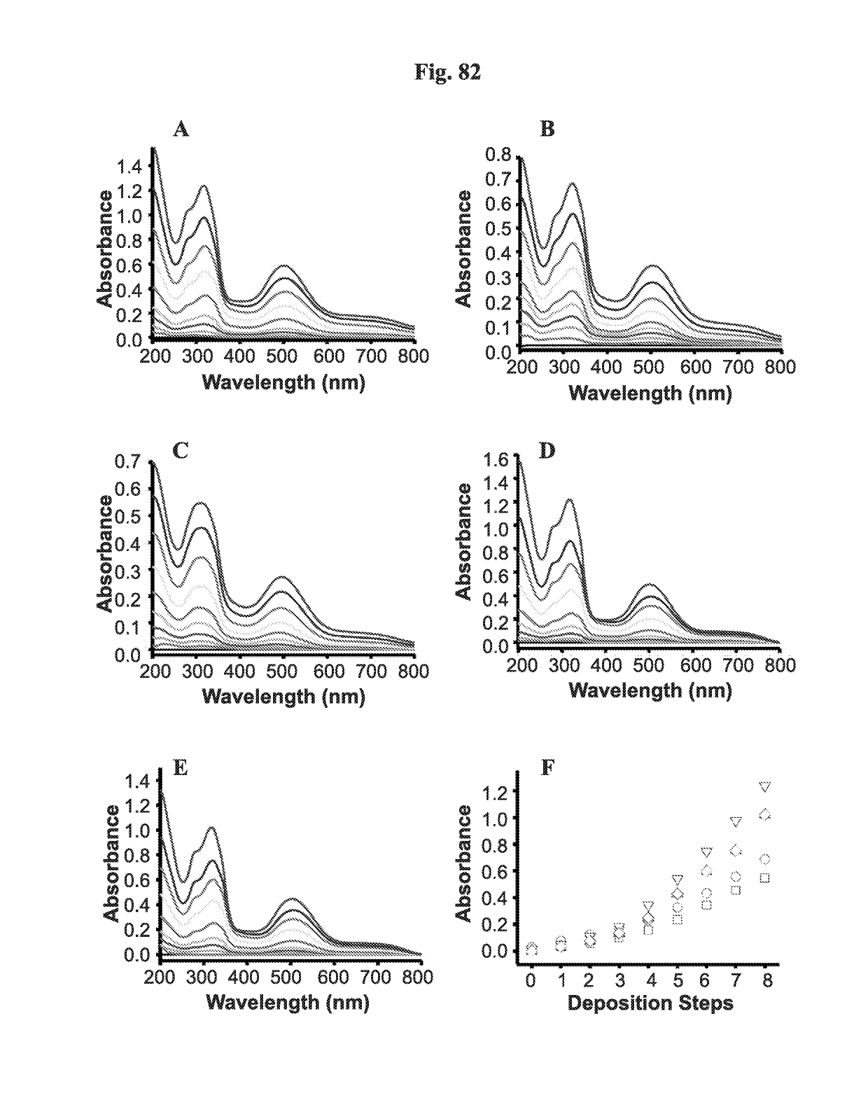

The growth of SPMA TL-[Os/Ru] on different template layers was monitored by UV/Vis spectroscopy and ellipsometry measurements on quartz and silicon substrates, respectively, after each deposition step. UV/Vis spectrum showed three bands: (i) λₘₐₓ=317 nm which corresponds to π-π* band of the ligands; (ii) λₘₐₓ=500 nm corresponds to MLCT bands of complexes 1 and 2 mixture; and (iii) λₘₐₓ=700 nm, an additional MLCT band of complex 2 (FIG. 82, panels A-E). Complex 1 has MLCT band at λₘₐₓ=490 nm, and complex 2 has singlet and triplet MLCT bands at λₘₐₓ=510 nm and 680-700 nm, respectively. The intensity of the bands increases exponentially (FIG. 82, panel F).

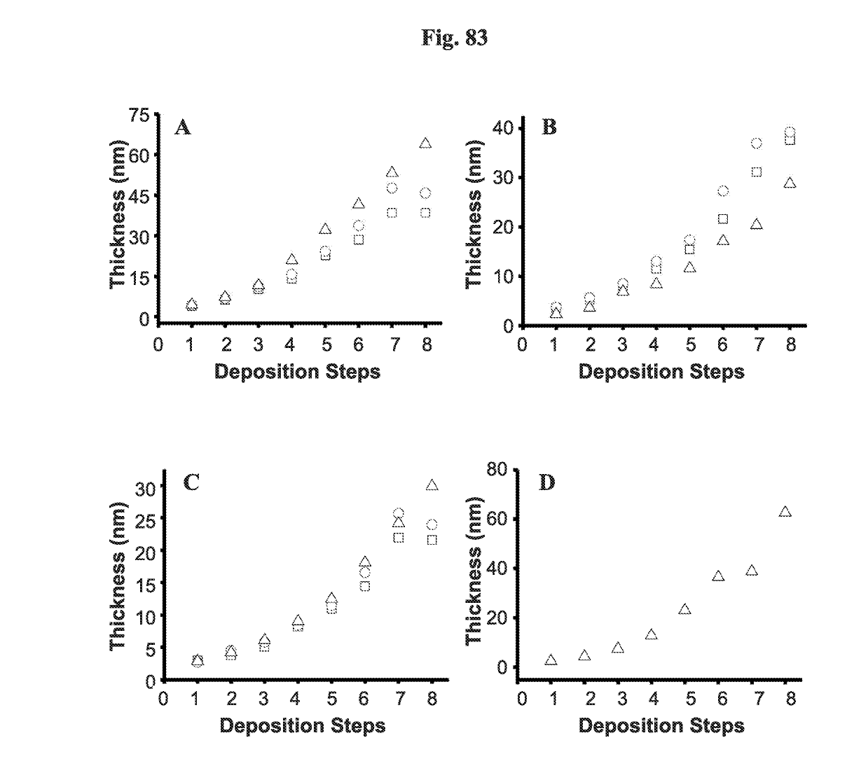

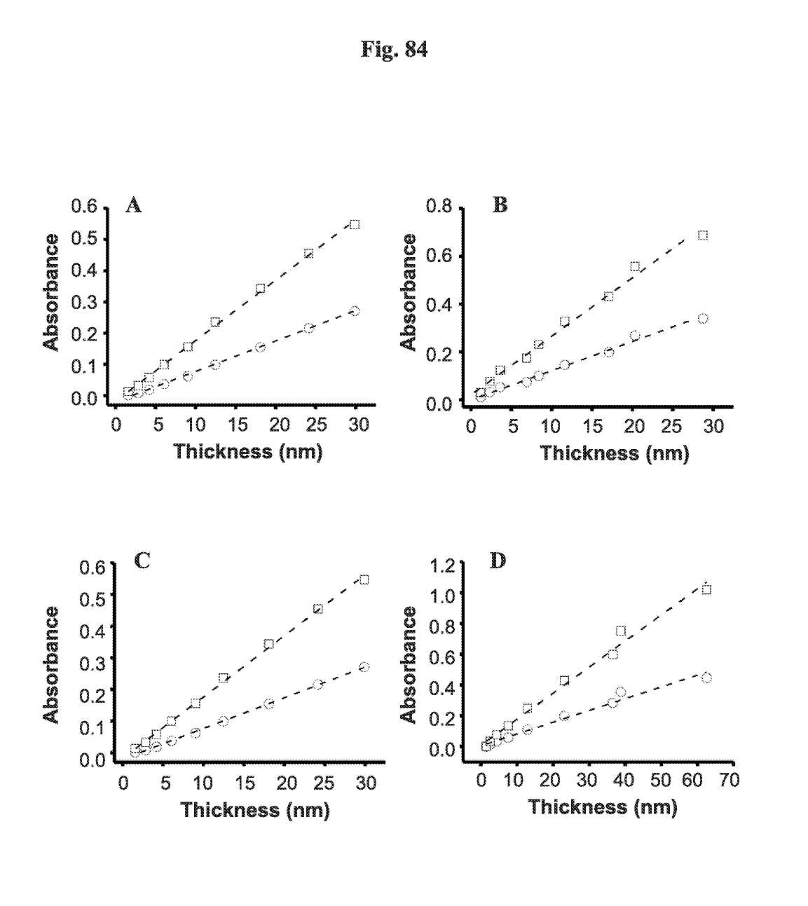

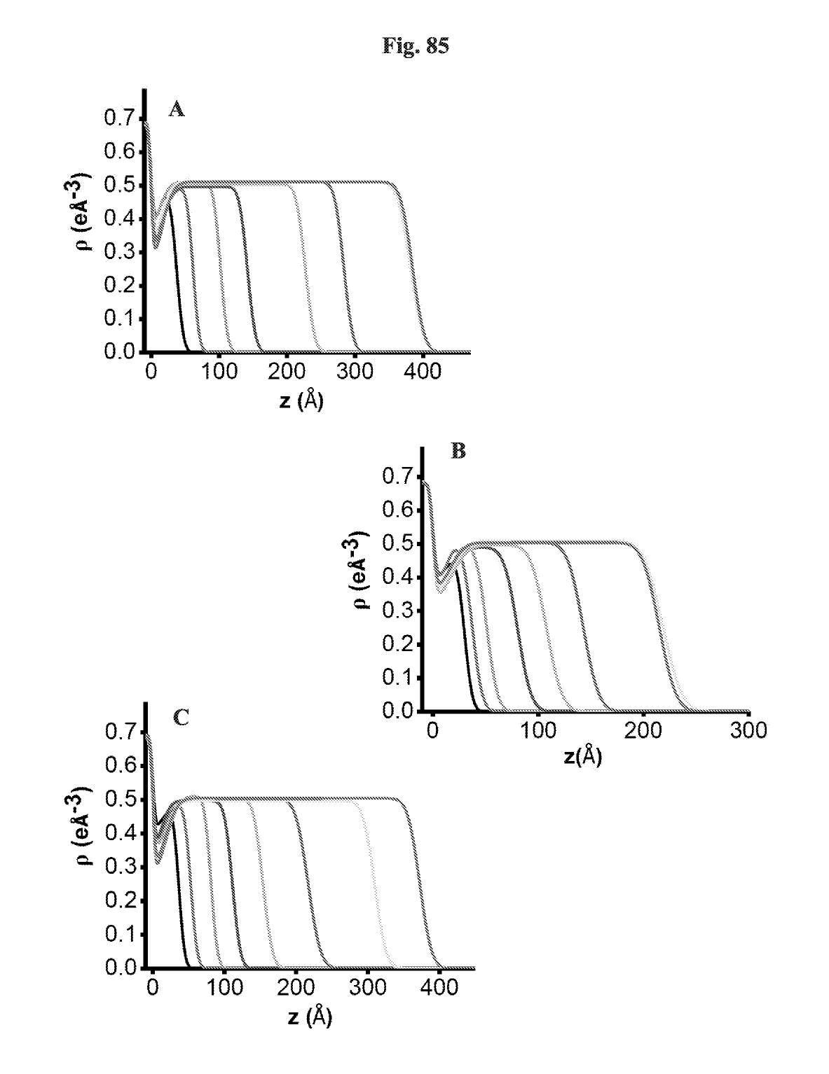

Film thicknesses of SPMA 1-[Os/Ru], SPMA 2-[Os/Ru], SPMA 3-[Os/Ru] and SPMA 5-[Os/Ru] were measured on silicon (100) after each deposition step using ellipsometry (FIG. 83); and film thicknesses of SPMA 1-[Os/Ru], SPMA 2-[Os/Ru] and SPMA 3-[Os/Ru] were further measured by XRR. The films thickness increased exponentially with the number of deposition steps. The exponential growth of the assemblies can be explained by the storage of palladium salt inside the film which diffuses out and is used in the formation of another terminal hybrid layer. XRR thickness measurements correlate well with the ellipsometry data. Absorption intensity and film thickness have a linear dependence indicating that in each deposition step the molecules density is approximately the same (FIG. 84). XRR electron density measurements support this observation since the electron density of the films remained constant (σ=0.5 e·Å⁻³) during the film formation (FIG. 85).

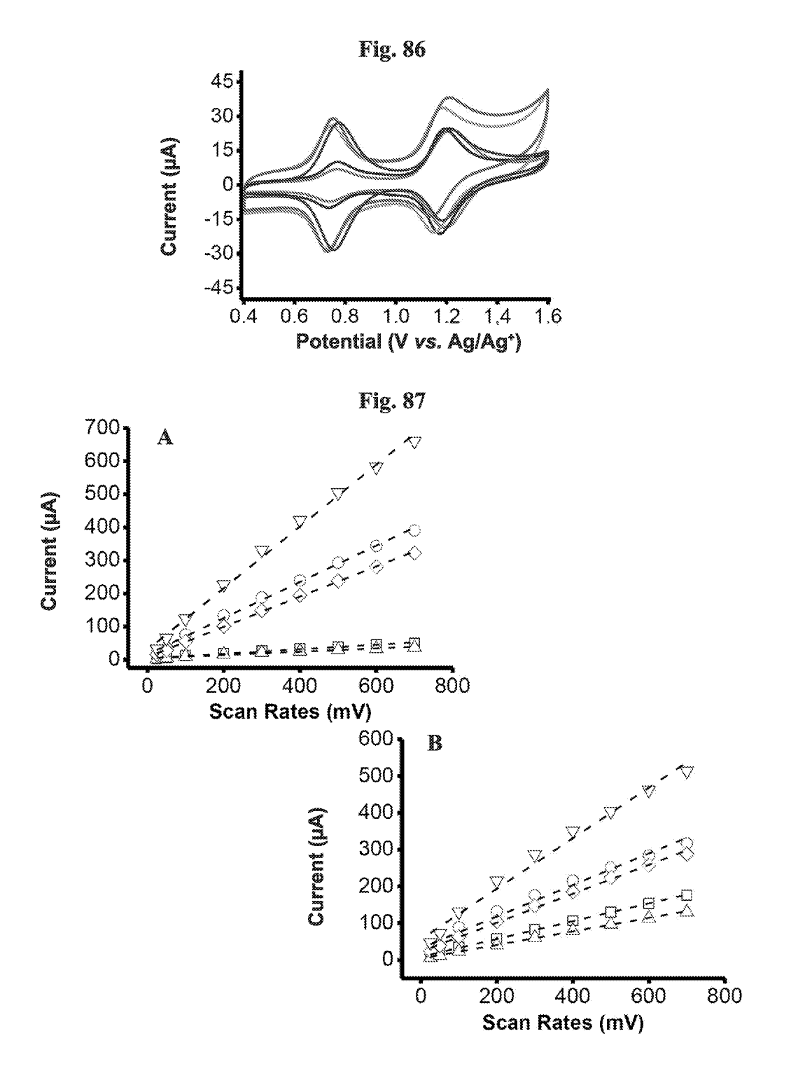

CVs of SPMA TL-[Os/Ru] measured on ITO slides showed a reversible redox process characteristic of both couples Os^{2+/3+} and Ru^{2+/3+} with a half-wave redox potential, E_{1/2}, of 0.76 V and 1.21 V (vs. Ag/AgCl), respectively (FIG. 86). Large separation of the half-wave potentials of ΔE_{1/2}=450 mV (ΔE_{1/2}=ΔE_{1/2}Ru-ΔE_{1/2}Os) allows both complexes to be addressed individually. The electrochemical behavior is surface-confined due to the linear correlation between the peaks current and scan rates within the range 0.025−0.7 Vs⁻¹ (FIG. 87).

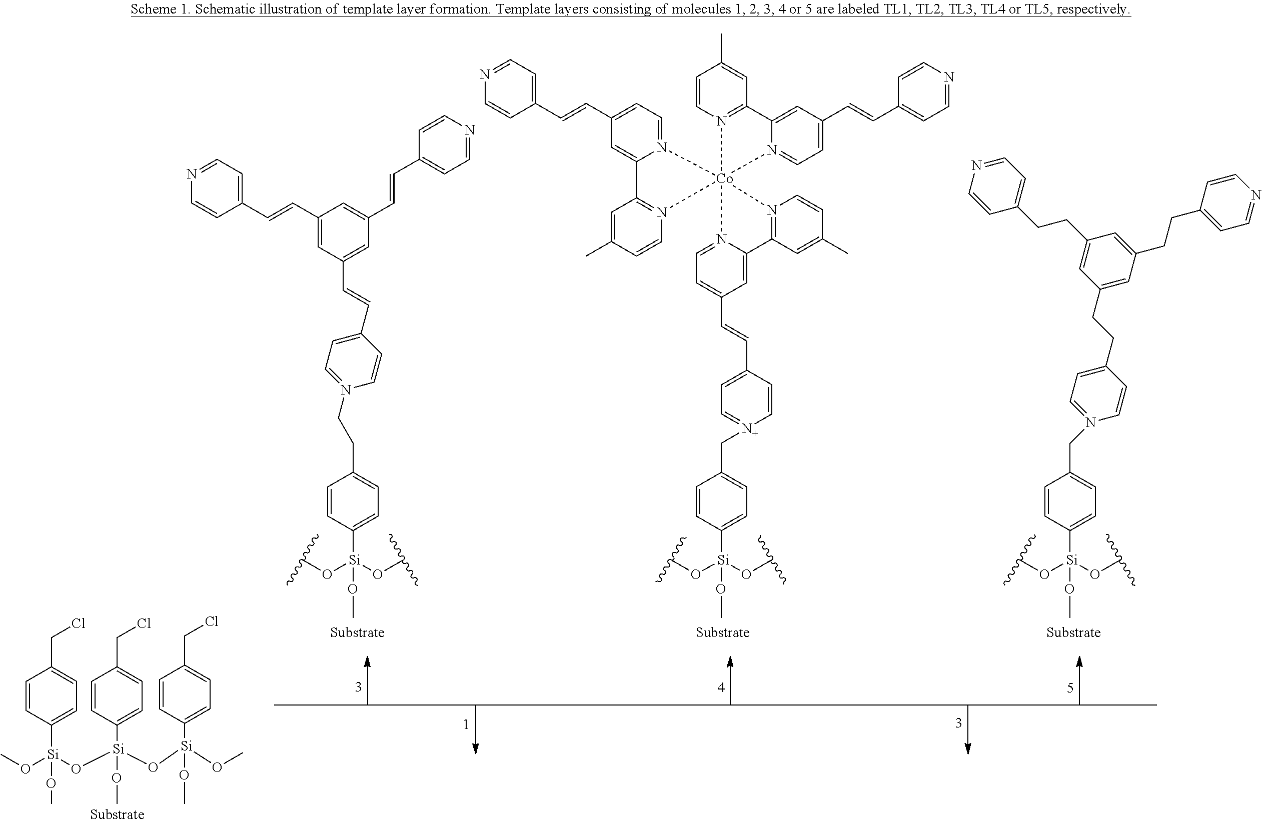

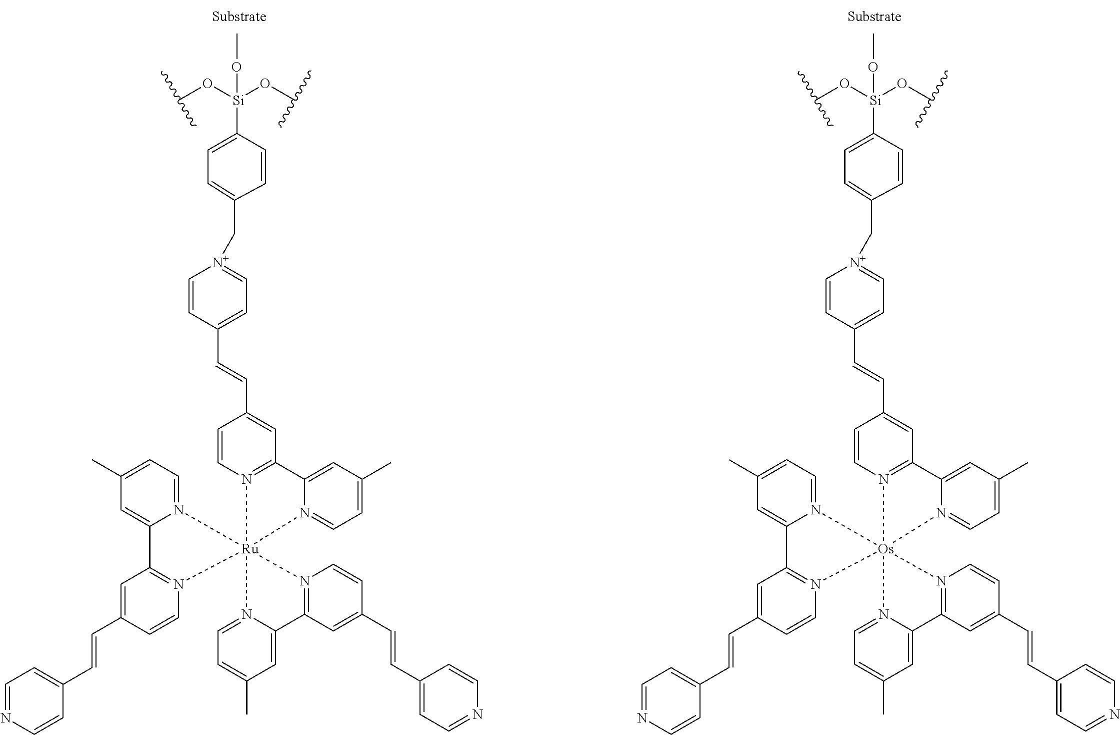

The composition of the assemblies can be determined according to the total oxidation charge value, Q, of complexes 1 and 2. Q is estimated by integration of the voltammetric oxidation peaks. The ratio between the number of osmium and ruthenium molecules on the surface is derived from Q values of 1 and 2 at a scan rate of 100 mV in accumulative manner. For example: Os:Ru ratio of deposition step number 3 is related to the number of osmium and ruthenium molecules in deposition steps 1-3. Q values for individual deposition steps were calculated by subtracting Q value of previous deposition step from the Q value of each step (Qₙ=Qₙ−Qₙ₋₁).

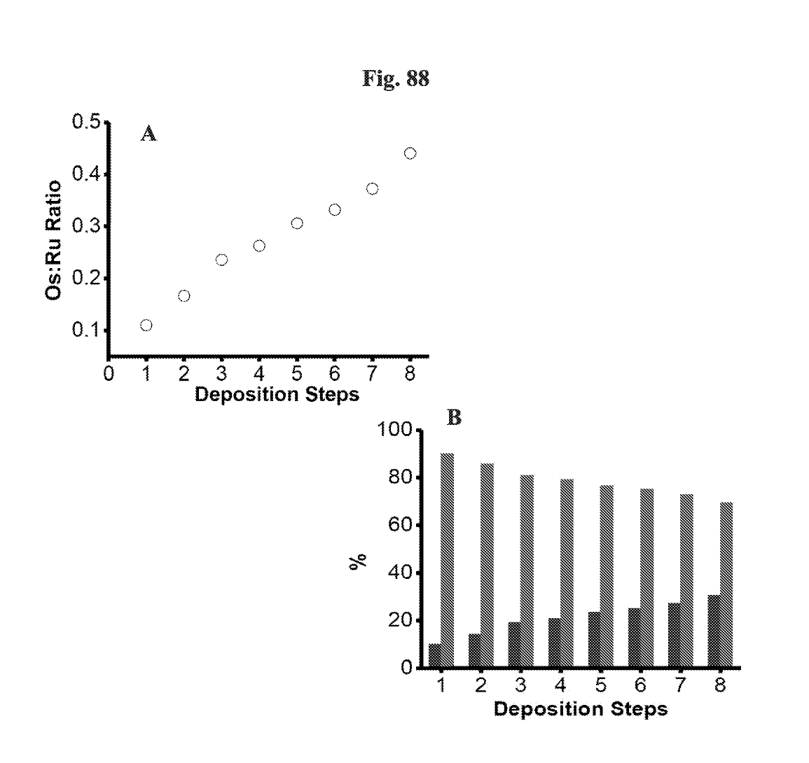

Surprisingly, the amount of 2 in SPMA 3-[Os/Ru] is significantly lower than the amount of 1 although the assembly was constructed from an equimolar solution. In the first deposition step, the ratio between 2 and 1 was about 1:10. The ratio increased with the film thickness up to about 1:2 due to growing number of bonded molecules of 2 on the surface (FIG. 88). It should further be noted that the ratio increased also while moving away from the 3-based template layer.

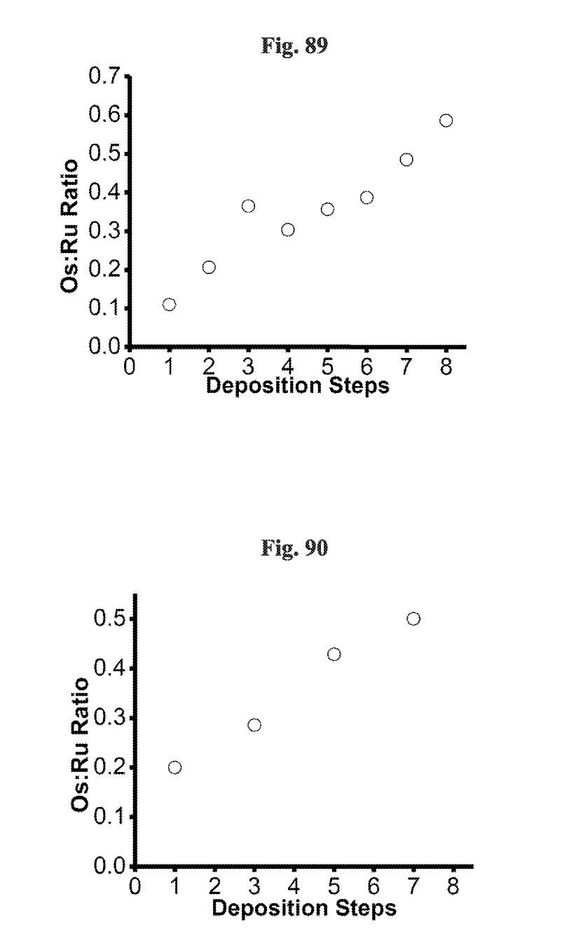

The observed increase in Os:Ru ratio is also shown for individual deposition steps suggesting that this phenomenon is not a result of the accumulative nature of the deposition steps (FIG. 89). The gradual increase in Os:Ru ratio on the surface resulted in a unique 1D vertical gradient of the assembly components (data not shown). XPS elemental analysis of SPMA 1-[Os/Ru] on quarts revealed similar increase of Os:Ru ratio as a function of deposition steps (FIG. 90). The elemental ratios of Os:Ru were recorded at a takeoff angle of 45°.

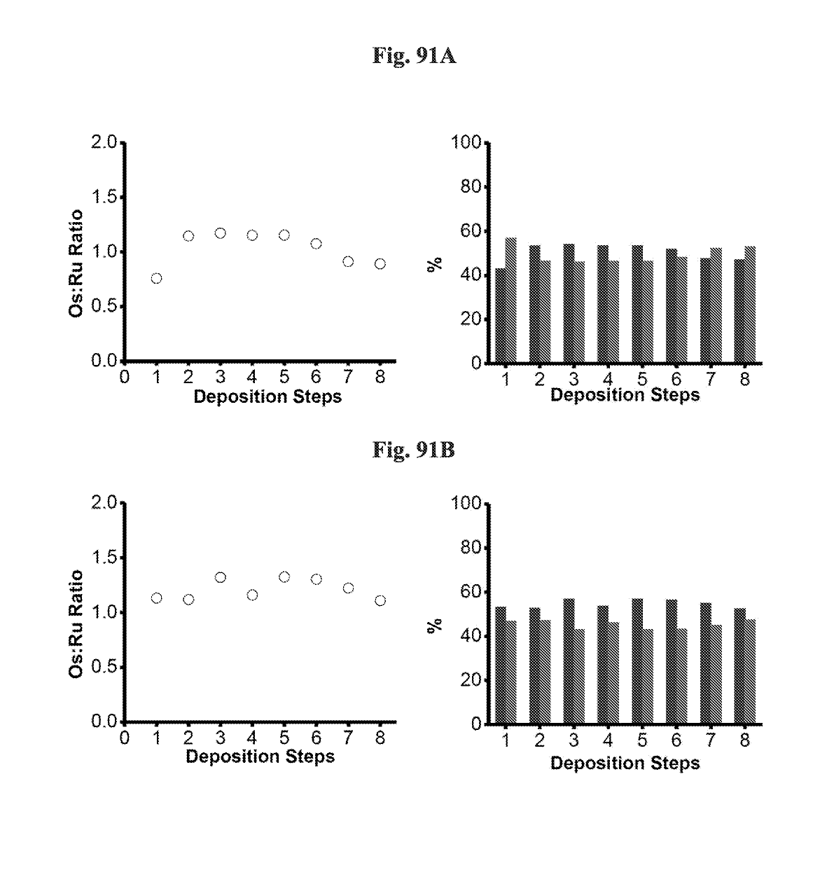

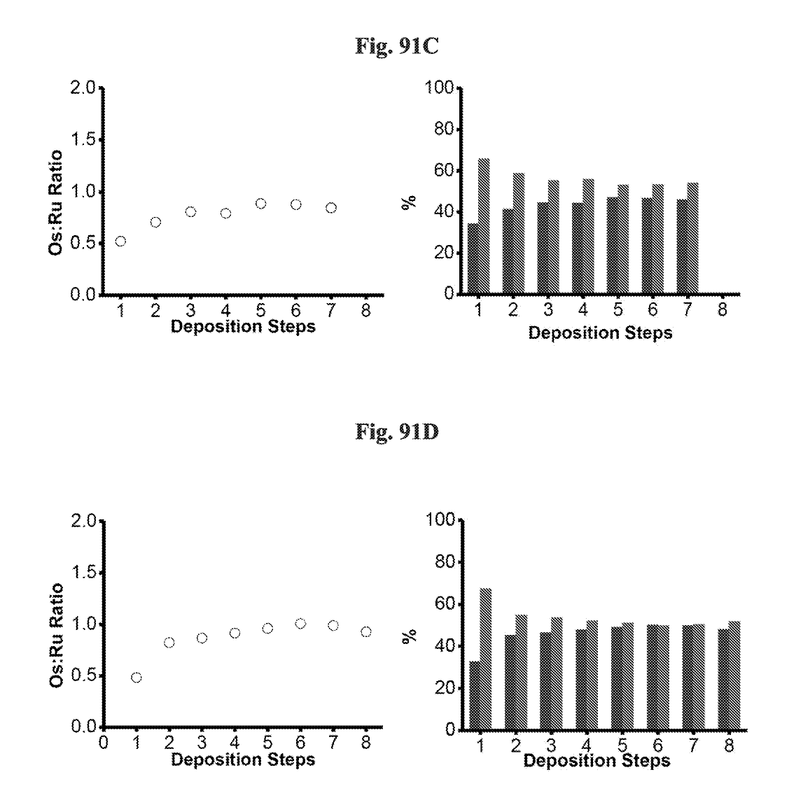

In contrast to the dynamic ratios of SPMA 3-[Os/Ru], compositional analysis of SPMA 1-[Os/Ru], SPMA 4-[Os/Ru] and SPMA 5-[Os/Ru] showed significant different trend of Os:Ru ratios as a function of the deposition steps. These assemblies displayed an increased Os:Ru ratio which leveled off at a certain value and becomes constant (FIG. 91). Complexes 1 and 2 are electroactive on ITO surface within the range 0.4 V-1.6 V while molecules 3, 4 and 5 are inactive. Therefore, Q values of SPMA 1-[Os/Ru] and SPMA 2-[Os/Ru] template layers (ruthenium (1) and osmium (2), respectively) were also summed up in the total Q values of the deposition steps. In order to avoid the template layer contribution, Q value of the template layer was subtracted from the total Q of each deposition step. SPMA 2-[Os/Ru] compositional analysis showed Os:Ru ratio of about 1:1 while SPMA 1-[Os/Ru] display Os:Ru ratio value of about 3:4 in the first deposition step which levels off to 1:1. SPMA 4-[Os/Ru] and SPMA 5-[Os/Ru] exhibited Os:Ru ratio value of about 1:2 in the first deposition steps which levels off to 4:5 and 9:10, respectively. The alteration of Os:Ru ratios in assemblies constructing on different template layers indicates a template layer effect which determines the assemblies' molecular composition.

Reactivity Evaluation of Complexes 1 and 2 on Different Template Layers.

Complexes 1 and 2 were deposited individually on ITO surfaces modified with organic or organometallic template layer to form TL-[M] monolayers. Modified ITO were immersed for 15 min in a THF solution of PdCl₂(PhCN)₂ (1 mM) at RT. The samples were then sonicated in different solvents. Subsequently, the substrates were immersed in a solution consists of 1 and 2 (0.2 mM) for 15 min at RT. The samples were then sonicated in different solvents for 5 min each.

The quantity of the individual complexes on the surface indicates their reactivity towards the surface. The amount of molecules deposited on the surface was estimated by electrochemistry according to the total oxidation charge value, Q. Q values for each complex on various template layers are summarize in Table 8. Electrochemistry measurements of 2 on TL2 gave a total Q value of both TL2 and complex 2 deposited upon TL2. Therefore, in order to derive the Q value of 2-based monolayer, TL2 was measured individually and its Q value was subtracted from the total Q value. Q value of 2 on TL2 shown in Table 8 is after subtraction.

TABLE 8
Total oxidation charge value, Q, calculated for complexes 1 and 2
on different template layers. The values are an average of
5 repeated experiments.

| | Total oxidation charge values, Q (coulomb units) | | | |
|---|---|---|---|---|
| | TL1 | TL2 | TL4 | TL5 |
| Ruthenium (1) | 2.756E⁻⁵ | 2.313E⁻⁵ | 2.26E⁻⁵ | 1.41E⁻⁵ |
| Osmium (2) | 1.142E⁻⁵ | 1.713E⁻⁵ | 8.224E⁻⁶ | 5.47E⁻⁶ |

Complexes 1 and 2 have different reactivity towards TL2, TL3, TL4 and TL5. Upon these template layers, ruthenium was deposited in higher quantity than osmium. Similar behavior of the complexes was observed in the first deposition step of SPMA 3-[Os/Ru], SPMA 4-[Os/Ru] and SPMA 5-[Os/Ru] where complex 1 was more dominant than 2 (FIG. 91). The difference in the amount of 1 and 2 upon the various template layers might be attributed to the ability of ruthenium complex to form a denser, more packed network than osmium. According to Q values of 1 and 2 on TL2, ruthenium is more reactive than osmium. However, SPMA 2-[Os/Ru] displays higher amount of osmium in the first deposition step. The variation of Os:Ru ratio between the measurements can be an outcome of subtraction the Q value of TL2. This subtraction might lead to errors in Q value of the 2-based monolayer deposited upon TL2.

Blocking the Effect of TL3.

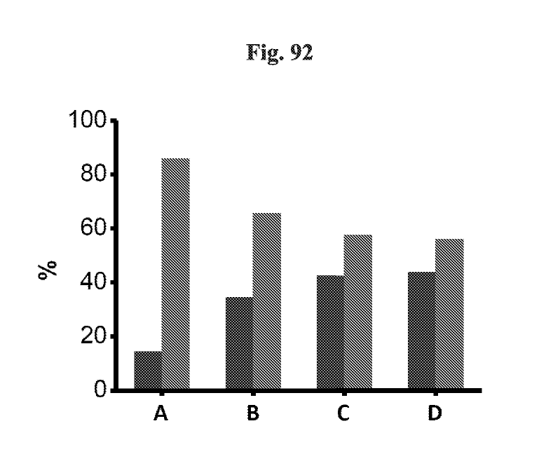

Osmium and ruthenium complexes deposited on TL3 displayed an unexpected binding behavior. The complexes are not attached to the surface equally. There is a strong preference for ruthenium molecules to be deposited on TL3. The complexes binding behavior is controlled by the template layer (TL3 in this case) specific organization and orientation on the surface. To support this assumption, a blocking experiment was performed by depositing a layer of molecules (1, 2 or 4) on TL3 before the surface was reacted with the mixture of 1 and 2. As a result, the effect of TL3 will be isolated due to the alteration in the molecules packing upon TL3. The procedure to modify the surface upon TL3 is done similarly as generating surfaces for reactivity experiment mentioned above. Complexes 1, 2 and 4 have similar structure that is different from the structure of 3. Upon TL3, Osmium-ruthenium ratio was about 0.15. Addition of the 4-based isolating layer resulted in osmium-ruthenium ratio of about 0.75 (FIG. 92). Os:Ru ratio upon 1-based and 2-based isolating layer was about 0.54 and 0.75, respectively. The change in Os:Ru ratio when a blocking layer was used indicates that the template layer effect is a result of the molecules organization within the template layer.

### REFERENCES

Abruna, H. D., Denisevich, P., Umana, M., Meyer, T. J., Murray, R. W., J. Am. Chem. Soc., 1981, 103, 1
Alexeev, Y. E., Kharisov, B. I., Garcia, T. C. H., Garnovskii, A. D., Coord. Chem. Rev., 2010, 254, 794
Altman, M., Shukla, A. D., Zubkov, T., Evmenenko, G., Dutta, P., van der Boom, M. E., J. Am. Chem. Soc., 2006, 128, 7374-7382
Altman, M., Zenkina, O., Evmenenko, G., Dutta, P., van der Boom, M. E., J. Am. Chem. Soc., 2008, 130, 5040
Altman, M., Rachamim, M., Ichiki, T., Iron, M. A., Evmenenko, G., Dutta, P., van der Boom, M. E., Chem. Eur. J., 2010, 16, 6744-6747
Alvarado, R. J., Mukherjee, J., Pacsial, E. J., Alexander, D., Raymo, F. M., J. Phys. Chem. B, 2005, 109, 6164
Amelia, M., Zou, L., Credi, A., Coord. Chem. Rev., 2010, 254, 2267
Amoroso, A. J., Thompson, A. M. W. C., Maher, J. P., McCleverty, J. A., Ward, M. D., Inorg. Chem., 1995, 34, 4828
Anderson, G. K., Lin, M., Inorg. Synth., 1990, 28, 60-63
Andreasson, J., Pischel, U., Chem. Soc. Rev., 2010, 39, 174
Andréasson, J., Pischel, U., Straight, S. D., Moore, T. A., Moore, A. L., Gust, D., J. Am. Chem. Soc., 2011, 133, 11641
Andres, C. M., Kotov, N. A., J. Am. Chem. Soc., 2010, 132, 14496
Araki, K., Angnes, L., Toma, H. E., Adv. Mater., 1995, 7, 554
Ariga, K., Hill, J. P., Ji, Q., Phys. chem. chem. phys., 2007, 9, 2319-2340
Ariga, K., Ji, Q., Hill, J. P., Bando, Y., Aono, M., NPG Asia Mater., 2012, 4, e17
Avellini, T., Li, H., Coskun, A., Barin, G., Trabolsi, A., Basuray, A. N., Dey, S. K., Credi, A., Silvi, S., Stoddart, J. F., Venturi, M., Angew. Chem. Int. Ed., 2012, DOI: 10.1002/anie.201107618
Ball, P., Nature, 2000, 406, 118
Balzani, V., Credi, A., Venturi, M., Chem. Eur. J., 2008, 14, 26-39
Bard, A. J., Faulkner, L. R., Electrochemical methods: Fundamentals and Applications, 2^{nd} Ed. Wiley, Hoboken, N.J., 2001
Beck, J. B., Rowan, S. J., J. Am. Chem. Soc., 2003, 125, 13922-13923
Berchmans, S., Ramalechume, C., Lakshmi, V., Yegnaraman, V., J. Mater. Chem., 2002, 12, 2538
Blankenship, R. E., Molecular Mechanism of Photosynthesis; Blackwell Science: Oxford, 2002
Bodenthin, Y., Pietsch, U., Möhwald, H., Kurth, D. G., J. Am. Chem. Soc., 2005, 127, 3110-31140
Boiko, Y. M., Lebedev, D. V., Myasnikova, L. P., Science, 2013, 291, 1519-1523
Bryant, G., Fergusson, J., Powell, H., Aust. J. Chem., 1971, 24, 257
Buda, M., Kalyuzhny, G., Bard, A. J., J. Am. Chem. Soc., 2002, 124, 6090
Burdeniuk, J., Milstein, D., J. Organomet. Chem., 1993, 451, 213-220
Cameron, C. G., Pickup, P. G., J. Am. Chem. Soc., 1999, 121, 11773
Campagna, S., Puntoriero, F., Nastasi, F., Bergamini, G., Balzani, V., Top. Curr. Chem., 2007, 280, 117
Campbell, V. E., de Hatten, X., Delsuc, N., Kauffmann, B., Huc, I., Nitschke, J. R., Nat. Chem., 2010, 2, 684
Cerclier, C., Cousin, F., Bizot, H., Moreau, C.l., Cathala, B., Langmuir, 2010, 26, 17248
Chidsey, C. E. D., Murray, R. W., Science, 1986, 231, 25
Choudhury, J., Kaminker, R., Motiei, L., de Ruiter, G., Morozov, M., Lupo, F., Gulino, A., van der Boom, M. E., J. Am. Chem. Soc., 2010, 132, 9295
Chu, B. W. K., Yam, V. W. W., Langmuir, 2006, 22, 7437-7443
Cluster, P., Liu, B. S., Kurth, D. G., Möhwald, H., Volkmer, D., Adv. Mater., 2002, 14, 225-228
Connelly, N. G., Geiger, W. E., Chem. Rev., 1996, 96, 877
Cook, T. R., Zheng, Y. R., Stang, P. J., Chem. Rev., 2009, 113, 734
Cragg, J. P., A Practical Guide to Supramolecular Chemistry; John Wiley & Sons, Ltd: New York, USA, 2005
Crosby, G. A., Demas, J. N., J. Am. Chem. Soc., 1971, 93, 2841
de Hatten, X., Asil, D., Friend, R. H., Nitschke, J. R., J. Am. Chem. Soc., 2012, 134, 19170
DeLongchamp, D. M., Kastantin, M., Hammond, P. T., Chem. Mater., 2003, 15, 1575
DeLongchamp, D. M., Hammond, P. T., Adv. Funct. Mater., 2004, 14, 224-232
Deng, H. X., Doonan, C. J., Furukawa, H., Ferreira, R. B., Towne, J., Knobler, C. B., Wang, B., Yaghi, O. M., Science, 2010, 327, 846
Denisevich, P., Willman, K. W., Murray, R. W., J. Am. Chem. Soc., 1981, 103, 4727
de Ruiter, G., Gupta, T., van der Boom, M. E., J. Am. Chem. Soc., 2008, 130, 2744
de Ruiter, G., Motiei, G., Choudhury, J., Oded, N., van der Boom, M. E., Angew. Chem. Int. Ed., 2010a, 49, 4780
de Ruiter, G., Wijsboom, Y. H., Oded, N., van der Boom, M. E., ACS Appl. Mater. Interfaces, 2010b, 2, 3578
de Ruiter, G., Tartakovsky, E., Oded, N., van der Boom, M. E., Angew. Chem. Int. Ed., 2010c, 49, 169
de Ruiter, G., van der Boom, M. E., Acc. Chem. Res., 2011a, 44, 563
de Ruiter, G., van der Boom, M. E., J. Mater. Chem. 2011b, 21, 17575
de Ruiter, G., van der Boom, M. E., Angew. Chem. Int. Ed., 2012, 51, 8598-8601
de Ruiter, G., Lahav, M., Keisar, H., van der Boom, M. E., Angew. Chem. Int. Ed., 2013, 52, 704
de Silva, A. P., J. Phys. Chem. Lett., 2011, 2, 2865
Desiraju, G. R., Angew. Chem. Int. Ed., 2007, 46, 8342 Doron-Mor, I., Hatzor, A., Vaskevich, A., van der Boom-Moav, T., Shanzer, A., Rubinstein, I., Cohen, H., Nature, 2000, 406, 382
Evmenenko, G., van der Boom, M. E., Kmetko, J., Dugan, S. W., Marks, T. J., Dutta, P., J. Chem. Phys., 2001, 115, 6722
Evmenenko, G., Stripe, B., Dutta, P., J. Colloid Interface Sci., 2011, 360, 793
Fabre, B., Acc. Chem. Res., 2010, 43, 1509
Fang, J., Chen, M. S., Shashidhar, R., Langmuir, 2001, 17, 1549-1551
Fioravanti, G., Haraszkiewicz, N., Kay, E. R., Mendoza, S. M., Bruno, C., Marcaccio, M., Wiering, P. G., Paolucci, F., Rudolf, P., Brouwer, A. M., Leigh, D. A., J. Am. Chem. Soc., 2008, 130, 2593
Forster, R. J., Faulkner, L. R., Anal. Chem., 1995, 67, 1232
Frattarelli, D., Schiavo, M., Facchetti, A., Ratner, M. A., Marks, T. J., J. Am. Chem. Soc., 2009, 131, 12595
Freys, J. C., Gardner, J. M., D'Amario, L., Brown, A. M., Hammarstrom, L., Dalton Trans., 2012, 41, 13105
Friese, V. A., Kurth, D. G., Coord. Chem. Rev., 2008, 252, 199-211
Fujita, I., Kobayash. H., Z. Phys. Chem. Neue Folge (Frankfurt), 1972, 79, 309
Gantz, J., Reinsel, D., The Digital Universe Decade—Are You Ready. International Data Corporation (IDC), 2010
Gao, S. Y., Zheng, Z. L., Lu, J. A., Cao, R., Chem. Comm., 2010, 46, 7584
Gauthier, N., Argouarch, G., Paul, F., Humphrey, M. G., Toupet, L., Ababou-Girard, S., Sabbah, H., Hapiot, P., Fabre, B., Adv. Mater., 2008, 20, 1952
Green, J. E., Choi, J. W., Boukai, A., Bunimovich, Y., Johnston-Halperin, E., Delonno, E., Luo, Y., Sheriff, B. A., Xu, K., Shin, Y. S., Tseng, H. R., Stoddart, J. F., Heath, J. R., Nature, 2007, 445, 414-417
Gulino, A., Anal. Bioanal. Chem., 2013, 405, 1479
Gupta, T., van der Boom, M. E., J. Am. Chem. Soc., 2006, 128, 8400
Haag, R., Rampi, M. A., Holmlin, R. E., Whitesides, G. M., J. Am. Chem. Soc., 1999, 121, 7895-7906
Hilbert, M., López, P., Science, 2011, 332, 60
Hirao, T., Redox Systems Under Nano-Space Control; Springer-Verlag: Heidelberg, 2006
Hjelm, J., Handel, R. W., Hagfeldt, A., Constable, E. C., Housecroft, C. E., Forster, R. J., Inorg. Chem., 2005, 44, 1073
Hoertz, P. G., Mallouk, T. E., Inorg. Chem., 2005, 44, 6828
Holmlin, R. E., Haag, R., Chabinyc, M. L., Ismagilov, R. F., Cohen, A. E., Terfort, A., Rampi, M. A., Whitesides, G. M., J. Am. Chem. Soc., 2001, 123, 5075-5085
Juris, A., Balzani, V., Barigelletti, F., Campagna, S., Belser, P., von Zelewsky, A., Coord. Chem. Rev., 1988, 84, 85
Kaminker, R., Motiei, L., Gulino, A., Fragalà, I., Shimon, L. J. W., Evmenenko, G., Dutta, P., Iron, M. A., van der Boom, M. E., J. Am. Chem. Soc., 2010, 132, 14554
Kanaizuka, K., Haruki, R., Sakata, 0., Yoshimoto, M., Akita, Y., Kitagawa, H., J. Am. Chem. Soc., 2008, 130, 15778
Katz, H. E., Scheller, G., Putvinski, T. M., Schilling, M. L., Wilson, W. L., Chidsey, C. E. D., Science, 1991, 254, 1485
Katz, E., Willner, I., Langmuir, 1997, 13, 3364-3373
Kiessig, H., Ann. Phys. (Leipzig), 1931, 10, 769
Kitagawa, S., Uemura, K., Chem. Soc. rev., 2005, 34, 109-119
Klauk, H., Zschieschang, U., Pflaum, J., Halik, M., Nature, 2007, 445, 745
Knuth, D. E., The Art of Computer Programming; Numerical Algorithms, 2^{nd} Ed, Addison-Wesley: Reading, Mass. 1997
Kumar, A., Abbott, N. L., Biebuyck, H., A., Kim, E., Whitesides, G. M., Acc. Chem. Res. 1995, 28, 219
Kumaresan, D., Shankar, K., Vaidya, S., Schmehl, R. H., Top. Curr. Chem., 2007, 281, 101
Kurita, T., Nishimori, Y., Toshimitsu, F., Muratsugu, S., Kume, S., Nishihara, H., J. Am. Chem. Soc., 2010, 132, 4524
Lauters, M., McCarthy, B., Sarid, D., Jabbour, G. E., Appl. Phys. Lett., 2006, 89, 013507
Lee, H., Kepley, L. J., Hong, H. G., Akhter, S., Mallouk, T. E., J. Phys. Chem., 1988, 92, 2597-2601
Lee, J. S., Kim, Y. M., Kwon, J. H., Sim, J. S., Shin, S., Sohn, B. H., Jia, Q., Adv. Mater., 2011, 23, 2064
Lehn, J. M., Supramolecular Chemistry: Concepts and Perspectives; Wiley-VCH: Weinheim, Germany, 1995
Lehn, J. M., Science, 2002, 295, 2400
Leidner, C. R., Murray, R. W., J. Am. Chem. Soc., 1985, 107, 551
Lezama, I. G., Nakano, M., Minder, N. A., Chen, Z., Di Girolamo, F. V., Facchetti, A., Morpurgo, A. F., Nature materials, 2012, 11, 788-794
Li, D. Q., Swanson, B. I., Robinson, J. M., Hoffbauer, M. A., J. Am. Chem. Soc., 1993, 115, 6975
Li, W., Lynch, V., Thompson, H., Fox, M. A., J. Am. Chem. Soc., 1997, 119, 7211-7217
Li, Q. L., Mathur, G., Gowda, S., Surthi, S., Zhao, Q., Yu, L. H., Lindsey, J. S., Bocian, D. F., Misra, V., Adv. Mater., 2004, 16, 133
Li, H., Xu, Q., Li, N., Sun, R., Ge, J., Lu, J., Gu, H., Yan, F., J. Am. Chem. Soc., 2010, 132, 5542
Liang, Y. W., Schmehl, R. H., Chem. Commun., 1995, 1007
Lieber, C. M., Sci. Am., 2001, 285, 59
Lin-Vien, D., Colthup, N. B., Fateley, W. G., Grasselli, J. G., The Handbook of Infrared and Raman Characteristic Frequencies of Organic Molecules; Academic Press: Boston, 1991
Lindsey, J. S., Bocian, D. F., Acc. Chem. Res., 2011, 44, 638
Loi, M. A., Da Como, E., Dinelli, F., Murgia, M., Zamboni, R., Biscarini, F., Muccini, M., Nat. Mater., 2005, 4, 81
Lonergan, M. C., Science, 1997, 278, 2103-2106
MacGillivray, L. R., Reid, J. L., Ripmeester, J. A., J. Am. Chem. Soc., 2000, 122, 7817-7818
Maeda, H., Sakamoto, R., Nishihara, H., Polymer, 2013, 54, 4383-4403
Makiura, R., Motoyama, S., Umemura, Y., Yamanaka, H., Sakata, 0., Kitagawa, H.,
Maoz, R., Sagiv, J., Degenhardt, D., Moehwald, H., Quint, P., Supramol. Sci., 1995, 2, 9-24
Nat. Mater., 2010, 9, 565
McGehee, M. D., Topinka, M. A., Nat. Mater., 2006, 5, 675
McMahon, J. J., Dougherty, T. P., Riley, D. J., Babcock, G. T., Carter, R. L., Surf. Sci., 1985, 158, 381-392
Mentes, A., Singh, K., Acta Cryst., 2013, E69, 58 [doi:10.1107/S1600536812050234]
Merzlikin, S. V., Tolkachev, N. N., Strunskus, T., Witte, G., Glogowski, T., Wöll, C., Grünert, W., Surf Sci., 2008, 602, 755
Miyashita, N., Kurth, D. G., J. Mater. Chem., 2008, 18, 2636
Mondal, P. C., Lakshmanan, J. Y., Hamoudi, H., Zharnikov, M., Gupta, T., J. Phys. Chem. C, 2011, 115, 16398
Motiei, L., 0, M., Gupta, T., Lupo, F., Gulino, A., Evmenenko, G., Dutta, P., van der Boom, M. E., J. Am. Chem. Soc., 2008, 130, 8913
Motiei, L., Lahav, M., Freeman, D., van der Boom, M. E., J. Am. Chem. Soc., 2009, 131, 3468
Motiei, L., Lahav, M., Gulino, A., Iron, M. A., van der Boom, M. E., J. Phys. Chem. B, 2010a, 114, 14283
Motiei, L., Yao, Y., Choudhury, J., Yan, H., Marks, T. J., van der Boom, M. E., Facchetti, A., J. Am. Chem. Soc., 2010b, 132, 12528
Motiei, L., Sassi, M., Kaminker, R., Evmenenko, G., Dutta, P., Iron, M. A., van der Boom, M. E., Langmuir, 2011a, 27, 1319
Motiei, L., Kaminker, R., Sassi, M., van der Boom, M. E., J. Am. Chem. Soc., 2011b, 133, 14264
Motiei, L., Feller, M., Evmenenko, G., Dutta, P., van der Boom, M. E., Chem. Sci., 2012, 3, 66
Mukherjee, B., Mohanta, K., Pal, A., J. Chem. Mater., 2006, 18, 3302-3307
Naciri, J., Fang, J. Y., Moore, M., Shenoy, D., Dulcey, C. S., Shashidhar, R., Chem. Mater., 2000, 12, 3288-3295
Nair, K. P., Breedveld, V., Weck, M., Macromolecules, 2011, 44, 3346
Nesher, G., Shpaisman, H., Cahen, D., J. Am. Chem. Soc., 2007, 129, 734-735
Netzer, L., Sagiv, J., J. Am. Chem. Soc., 1983, 105, 674-676
Nishimori, Y., Kanaizuka, K., Murata, M., Nishihara, H., Chem. Asian J., 2007, 2, 367-376
Nishimori, Y., Kanaizuka, K., Kurita, T., Nagatsu, T., Segawa, Y., Toshimitsu, F., Muratsugu, S., Utsuno, M., Kume, S., Murata, M., Nishihara, M., Chem. Asian J., 2009, 4, 1361
Northrop, B. H., Zheng, Y. R., Chi, K. W., Stang, P. J., Acc. Chem. Res., 2009, 42, 1554
Oh, S. K., Baker, L. A., Crooks, R. M., Langmuir, 2002, 18, 6981
Ortiz, R. P., Facchetti, A., Marks, T. J., Chem. Rev., 2010, 110, 205
Palomaki, P. K. B., Dinolfo, P. H., Langmuir, 2010, 26, 9677
Park, W., Hong, H. G., Bull. Korean Chem. Soc., 2006, 27, 381-385
Perl, A., Reinhoudt, D. N., Huskens, J., Adv. Mater. 2009, 21, 2257
Piner, R. D., Zhu, J., Xu, F., Hong, S., Mirkin, C. A., Science 1999, 283, 661
Ram, M. K., Sundaresan, N. S., Malhotra, B. D., J. Phys. Chem., 1993, 97, 11580
Rampi, M. A., Whitesides, G. M., Chem. Phys., 2002, 281, 373-391
Rashid, A. N., Erny, C., Gunter, P., Adv. Mater., 2003, 15, 2024
Remón, P., Bälter, M., Li, S., Andréasson, J., Pischel, U., J. Am. Chem. Soc., 2011, 133, 20742
Reynal, A., Palomares, E., Chem. Eur. J., 2011, 17, 4509
Ribas, J., Coordination Chemistry; Wiley-VCH Verlag: Weinheim, Germany, 2008
Sassi, M., Salamone, M. M., Ruffo, R., Mari, C. M., Pagani, G. A., Beverina, L., Adv. Mater., 2012, 24, 2004
Saveant, J. M., J. Phys. Chem., 1988a, 92, 1011-1013
Saveant, J. M., J. Phys. Chem., 1988b, 92, 4526-4532
Scheres, L., ter Maat, J., Giesbers, M., Zuilhof, H., Small, 2010, 6, 642
Schmidt, G. M., J. Pure Appl. Chem., 1971, 27, 647-678
Schneider, H. J., Angew. Chem. Int. Ed., 1991, 30, 1417
Schütte, M., Kurth, D. G., Linford, M. R., Cölfen, H., Möhwald, H., Angew. Chem. Int. Ed., 1998, 37, 2891
Sedghi, G., Sawada, K., Esdaile, L. J., Hoffmann, M., Anderson, H. L., Bethell, D., Haiss, W., Higgins, S. J., Nichols, R. J., J. Am. Chem. Soc., 2008, 130, 8582
Sedghi, G., Garcia-Suarez, V. M., Esdaile, L. J., Anderson, H. L., Lambert, C. J., Martin, S., Bethell, D., Higgins, S. J., Elliott, M., Bennett, N., Macdonald, J. E., Nichols, R. J., Nat. Nanotechnol., 2011, 6, 517
Selzer, Y., Salomon, A., Cahen, D., J. Am. Chem. Soc., 2002, 124, 2886-2887 Shekhah, O., Wang, H., Paradinas, M., Ocal, C., Schupbach, B., Terfort, A., Zacher, D., Fischer, R. A., Wöll, C., Nat. Mater., 2009, 8, 481
Shirman, T., Freeman, D., Posner, Y. D., Feldman, I., Facchetti, A., van der Boom, M. E., J. Am. Chem. Soc., 2008, 130, 8162
Simao, C., Mas-Torrent, C., Casado-Montenegro, J., Oton, F., Veciana, J., Rovira, C., J. Am. Chem. Soc., 2011, 133, 13256
Sknepnek, R., Anderson, J. A., Lamm, M. H., Schmalian, J., Travesset, A., ACS Nano, 2008, 2, 1259
Smalley, J. F., Feldberg, S. W., Chidsey, C. E. D., Linford, M. R., Newton, M. D., Liu, Y. P., J. Phys. Chem., 1995, 99, 13141-13149
Smalley, J. F., Finklea, H. O., Chidsey, C. E. D., Linford, M. R., Creager, S. E., Ferraris, J. P., Chalfant, K., Zawodzinsk, T., Feldberg, S. W., Newton, M. D., J. Am. Chem. Soc., 2003, 125, 2004-2013
Smith, D. K., Lane, G. A., Wrighton, M., S., J. Am. Chem. Soc., 1986, 108, 3522
Terada, K., Kanaizuka, K., Iyer, V. M., Sannodo, M., Saito, S., Kobayashi, K., Haga, M. A., Angew. Chem. Int. Ed., 2011, 50, 6287
Terada, K., Nakamura, H., Kanaizuka, K., Haga, M., Asai, Y., Ishida, T., ACS Nano, 2012, 6, 1988
Tuccitto, N., Ferri, V., Cavazzini, M., Quici, S., Zhavnerko, G., Licciardello, A., Rampi, M. A., Nat. Mater., 2009, 8, 41
Ulman, A., Chem. Rev., 1996, 96, 1533-1554
van der Boom, M. E., Richter, A. G., Malinsky, J. E., Lee, P. A., Armstrong, N. R., Dutta, P., Marks, T. J., Chem. Mater., 2001, 13, 15-17
Vermonden, T., de Vos, W. M., Marcelis, A. T. M., Sudhölter, E. J. R., Eur. J. Inorg. Chem., 2004, 14, 2847-2852
Wanunu, M., Vaskevich, A., Cohen, S. R., Cohen, H., Arad-Yellin, R., Shanzer, A., Rubinstein, I., J. Am. Chem. Soc., 2005, 127, 17877-17887
Welter, S., Brunner, K., Hofstraat, J. W., De Cola, L., Nature, 2003, 421, 54
Willner, I, Katz, E., Bioelectronics: From Theory to Applications; VCH-Wiley: Weinheim, 2005
Wittkopp, P. J., Kalay, G., Nat. Rev. Genet., 2012, 13, 59
Wu, K. L., Ho, S. T., Chou, C. C., Chang, Y. C., Pan, H. A., Chi, Y., Chou, P. T., Angew. Chem. Int. Ed., 2012, 51, 5642
Wurfel, P., Physics of Solar Cells: From Basic Principles to Advanced Concepts, 2^{nd} ed., Wiley-VCH, Weinheim, 2009
Xia, Y., Whitesides, G M., Angew. Chem. Int. Ed., 1998, 37, 550
Yang, G. Z., Wan, L. J., Zeng, Q. D., Bai, C. L., J. Phys. Chem. B, 2003, 107, 5116-5119
Yerushalmi, R., Scherz, A., van der Boom, M. E., J. Am. Chem. Soc., 2004, 126, 2700
Yin, J. F., Velayudham, M., Bhattacharya, D., Lin, H. C., Lu, K. L., Coord. Chem. Rev., 2012, 256, 3008
Yitzchaik, S., Marks, T., J. Acc. Chem. Res., 1996, 29, 197-202
Yu, J., Mathew, S., Flavel, B. S., Johnston, M. R., Shapter, J. G., J. Am. Chem. Soc., 2008, 130, 8788
Zacher, D., Schmid, R., Wöll, C., Fischer, R. A., Angew. Chem. Int. Ed., 2011, 50, 176
Zeira, A., Chowdhury, D., Hoeppener, S., Liu, S., Berson, J., Cohen, S. R., Maoz, R., Sagiv, J., Langmuir, 2009, 25, 13984-14001
Zhao, W., Marfurt, J., Walder, L., Helv. Chim. Acta, 1994, 77, 351-371
Zhao, W., Tong, B., Shi, J., Pan, Y., Shen, J., Zhi, J., Chan, W. K., Dong, Y., Langmuir, 2010, 26, 16084-16089
Zheng, Y. R., Zhao, Z. G., Wang, M., Ghosh, K., Pollock, J B., Cook, T. R., Stang, P. J., J. Am. Chem. Soc., 2010, 132, 16873

1. A device comprising a substrate having an electrically conductive surface and carrying an assembly of one or more molecular components, each molecular component having a thickness and an oxidative or reductive peak potential, and comprising one or more entities each independently is a redox-active compound,
provided that:
(i) wherein said device comprises one molecular component, said component comprises more than one of said entities, and the difference between the oxidative- and/or reductive peak potentials of each one of said entities is larger than 100 mV; and
(ii) wherein said device comprises more than one molecular components, said components are assembled on said electrically conductive surface in a random, alternate or successive order, each one of said components comprises one or more of said entities, and the difference between the oxidative- and/or reductive peak potentials of two of said entities comprised within said components is larger than 100 mV,
wherein exposure of said device, when comprising one molecular component, to a potential change, causes electron transfer, which results in an electrochemical signature which can be read out electrically, optically, magnetically, or by conductivity measurements;
and exposure of said device, when comprising more than one molecular components, to a potential change, causes (a) reversible electron transfer; (b) oxidative catalytic electron transfer with charge trapping; (c) reductive catalytic electron transfer; or (d) blocking of the electron transfer, dependent on the order of said components and the thickness of each one of said components, which results in an electrochemical signature which can be read out electrically, optically, magnetically, or by conductivity measurements.

2. (canceled)

3. The device of claim 1, wherein said substrate includes a material selected from glass, a doped glass, indium tin oxide (ITO)-coated glass, silicon, a doped silicon, Si(100), Si(111), SiO₂, SiH, silicon carbide mirror, quartz, a metal, metal oxide, a mixture of metal and metal oxide, group IV elements, mica, a polymer such as polyacrylamide and polystyrene, a plastic, a zeolite, a clay, wood, a membrane, an optical fiber, a ceramic, a metalized ceramic, an alumina, an electrically-conductive material, a semiconductor, steel or a stainless steel.

4. (canceled)

5. The device of claim 3, wherein said substrate is optically transparent to the ultraviolet (UV), infrared (IR), near-IR (NIR) and/or visible spectral ranges.

6. The device of claim 1, wherein said redox-active compound is a metal, modified nanoparticle or quantum dot, organometallic compound, metal-organic, organic or polymeric material, inorganic material, metal complex, organic molecule, or a mixture thereof, wherein said metal is a transition metal, lanthanide, actinide, or main group element metal.

7. (canceled)

8. The device of claim 6, wherein said transition metal is selected from Os, Ru, Fe, Pt, Pd, Ni, Ir, Rh, Co, Cu, Re, Tc, Mn, V, Nb, Ta, Hf, Zr, Cr, Mo, W, Ti, Sc, Ag, Au or Y; said lanthanide is La, Ce, Pr, Nd, Pm, Sm, Eu, Gd, Tb, Dy, Ho, Er, Tm, Yb or Lu; said actinide is Ac, Th, Pa, U, Np, Pu, Am, Cm, Bk, Cf, Es, Fm, Md, No or Lr; and said main group element metal is Zn, Ga, Ge, Al, Cd, In, Sn, Sb, Hg, Tl, Pb.

9. The device of claim 8, wherein said redox-active compound is a tris-bipyridyl complex of said transition metal, a terpyridyl complex of said transition metal, a complex of a porphyrin, corrole or chlorophyll with said transition metal.

10. The device of claim 9, wherein said redox-active compound is a tris-bipyridyl complex of ruthenium, osmium, iron or cobalt.

11. The device of claim 9, wherein said redox-active compound is a tris-bipyridyl complex of the general formula I: 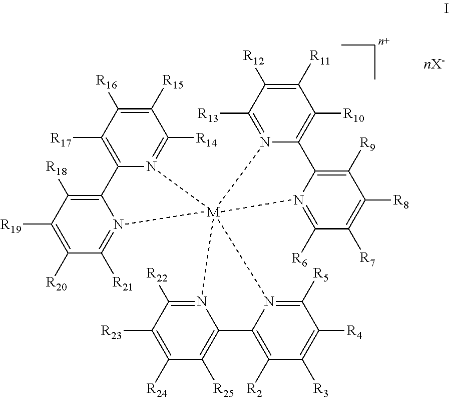
wherein
M is said transition metal;
n is the formal oxidation state of the transition metal, wherein n is 0-4;
X is a counter anion selected from the group consisting of Br⁻, Cl⁻, F⁻, PF₆⁻, BF₄⁻, OH⁻, ClO₄⁻, SO₃⁻, SO₄⁻, CF₃COO⁻, CN⁻, alkylCOO⁻, arylCOO⁻, and any combination thereof;
R₂ to R₂₅ each independently is selected from hydrogen, halogen, hydroxyl, azido, nitro, cyano, amino, substituted amino, thiol, C₁-C₁₀ alkyl, cycloalkyl, heterocycloalkyl, haloalkyl, aryl, heteroaryl, alkoxy, alkenyl, alkynyl, carboxamido, substituted carboxamido, carboxyl, protected carboxyl, protected amino, sulfonyl, substituted aryl, substituted cycloalkyl, substituted heterocycloalkyl, or group A, wherein at least two, preferably three, of said R₂ to R₂₅ each independently is a group A: 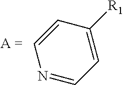
wherein A is linked to the ring structure of the compound of general formula II via R₁; and R₁ is selected from cis/trans C═C, C≡C, N═N, C═N, N═C, C—N, N—C, alkylene, arylene or a combination thereof; and any two vicinal R₂-R₂₅ substituents, together with the carbon atoms to which they are attached, may form a fused ring system selected from the group consisting of cycloalkyl, heterocycloalkyl, heteroaryl and aryl, wherein said fused system may be substituted by one or more groups selected from C₁-C₁₀ alkyl, aryl, azido, cycloalkyl, halogen, heterocycloalkyl, alkoxy, hydroxyl, haloalkyl, heteroaryl, alkenyl, alkynyl, nitro, cyano, amino, substituted amino, carboxamido, substituted carboxamido, carboxyl, protected carboxyl, protected amino, thiol, sulfonyl or substituted aryl; and said fused ring system may also contain at least one heteroatom selected from N, O or S.

12. The device of claim 11, wherein n is 2; X is PF₆⁻; R₂, R₄ to R₇, R₉, R₁₀, R₁₂ to R₁₅, R₁₇, R₁₈, R₂₀ to R₂₃ and R₂₅ each is hydrogen; R₃, R₁₁ and R₁₉ each is methyl; and R₈, R₁₆ and R₂₄ each is A, wherein R₁ is C═C.

13. The device of claim 12, wherein M is Ru, Os or Co, herein identified compounds 1, 2 and 4, respectively, of the formulas:

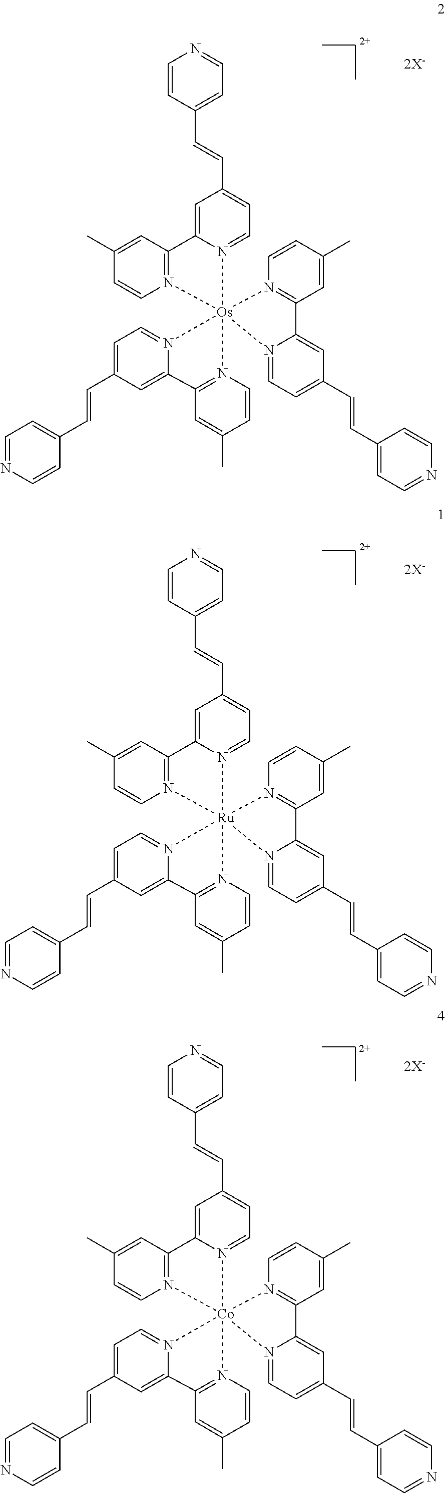

14. The device of claim 6, wherein said organic molecule is a thiophene, quinone, porphyrin, corrole, chlorophyll, a vinylpyridine derivative such as 1,3,5-tris(4-ethenylpyridyl)benzene (herein identified compound 3) and 1,4-bis[2-(4-pyridyl)ethenyl]benzene (herein identified compound 6), a pyridylethylbenzene derivative such as 1,3,5-tris(2-(pyridin-4-yl)ethyl)benzene (herein identified compound 5), or a combination thereof.

15. The device of claim 6, wherein said organic or metal-organic material is selected from (i) viologen (4,4′-bipyridylium salts) or its derivatives; (ii) azol compounds; (iii) aromatic amines; (iv) carbazoles; (v) cyanines; (vi) methoxybiphenyls; (vii) quinones; (viii) thiazines; (ix) pyrazolines; (x) tetracyanoquinodimethanes (TCNQs); (xi) tetrathiafulvalene (TTF); (xii) metal coordination complex wherein said complex is [M^{II}(2,2′-bipyridine)₃]²⁺ or [M^{II}(2,2′-bipyridine)₂(4-methyl-2,2′-bipyridine-pyridine]²⁺, wherein said M is iron, ruthenium, osmium, nickel, chromium, copper, rhodium, iridium or cobalt; or a polypyridyl metal complex selected from tris(4-[2-(4-pyridyl)ethenyl]-4′-methyl-2,2′-bipyridine osmium(II) bis(hexafluorophosphate), tris(4-[2-(4-pyridyl)ethenyl]-4′-methyl-2,2′-bipyridine cobalt(II) bis(hexafluorophosphate), tris(4-[2-(4-pyridyl)ethenyl]-4′-methyl-2,2′-bipyridine)ruthenium(II)bis-(hexafluorophosphate), bis(2,2′-bipyridine)[4′-methyl-4-(2-(4-pyridyl)ethenyl)-2,2′-bipyridine]osmium(II) [bis(hexafluorophosphate)/di-iodide], bis(2,2′-bipyridine)[4′-methyl-4-(2-(4-pyridyl)ethenyl)-2,2′-bipyridine]ruthenium(II) [bis(hexafluorophosphate)/di-iodide], bis(2,2′-bipyridine)[4′-methyl-4-(2-(4-(3-propyl trimethoxysilane)pyridinium)ethenyl)-2,2′-bipyridine]osmium(II) [tris(hexafluorophosphate)/tri-iodide], or bis(2,2′-bipyridine)[4′-methyl-4-(2-(4-(3-propyl trimethoxysilane)pyridinium) ethenyl)-2,2′-bipyridine]ruthenium(II) [tris(hexafluorophosphate)/tri-iodide]; (xiii) metallophthalocyanines or porphyrins in mono, sandwich or polymeric forms; (xiv) metal hexacyanometallates; (xv) dithiolene complexes of nickel, palladium or platinum; (xvi) dioxylene complexes of osmium or ruthenium; (xvii) mixed-valence complexes of ruthenium, osmium or iron; or (xviii) derivatives thereof.

16. The device of claim 15, wherein said viologen is methyl viologen (MV), and said azole compound is 4,4′-(1E,1′E)-4,4′-sulfonylbis(4,1-phenylene)bis(diazene-2,1-diyl)-bis(N,N-dimethylaniline).

17. The device of claim 6, wherein said inorganic material is tungsten oxide, iridium oxide, vanadium oxide, nickel oxide, molybdenum oxide, titanium oxide, manganese oxide, niobium oxide, copper oxide, tantalum oxide, rhenium oxide, rhodium oxide, ruthenium oxide, iron oxide, chromium oxide, cobalt oxide, cerium oxide, bismuth oxide, tin oxide, praseodymium, bismuth, lead, silver, lanthanide hydrides (LaH₂/LaH₃), nickel doped SrTiO₃, indium nitride, ruthenium dithiolene, phosphotungstic acid, ferrocene-naphthalimides dyads, organic ruthenium complexes or any mixture thereof.

18. The device of claim 6, wherein said polymeric material is a conducting polymer such as a polypyrrole, a polydioxypyrrole, a polythiophene, a polyselenophene, a polyfuran, poly(3,4-ethylenedioxythiophene), a polyaniline, a poly(acetylene), a poly(p-phenylene sulfide), a poly(p-phenylene vinylene) (PPV), a polyindole, a polypyrene, a polycarbazole, a polyazulene, a polyazepine, a poly(fluorene), a polynaphthalene, a polyfuran, a metallopolymeric film based on a polypyridyl complex or polymeric viologen system comprising pyrrole-substituted viologen pyrrole, a disubstituted viologen, N,N′-bis(3-pyrrol-1-ylpropyl)-4,4′-bipyridilium, or a derivative thereof.

19. The device of claim 6, wherein said redox-active compound is an electrochromic compound.

20. The device of claim 1, wherein said electrical read-out is carried out by an electrochemical technique such as cyclic voltammetry (CV), differential pulse voltammetry (DPV), current-voltage changes, and conductivity changes, and said optical read-out is carried out in the UV, IR, NIR, or visible region or by fluorescence spectroscopy.

21. The device of claim 1, comprising a substrate having an electrically conductive surface and carrying an assembly of one molecular component.

22. The device of claim 21, wherein said molecular component comprises two or more, preferably two, entities.

23. The device of claim 22, wherein each one of said entities independently is selected from the herein identified compound 1, 2, 3, 4, 5 or 6.

24. The device of claim 23, wherein the molar ratio between said entities is in a range of 1:1 to 1:10.

25. The device of claim 1, comprising a substrate having an electrically conductive surface and carrying an assembly of more than one molecular component.

26. The device of claim 25, comprising a substrate having an electrically conductive surface and carrying an assembly of two molecular components.

27. The device of claim 26, wherein each one of said molecular components comprises one entity.

28. The device of claim 27, wherein each one of said molecular components comprises a compound selected from the herein identified compound 1, 2, 3, 4, 5 or 6.

29. The device of claim 27, wherein said two molecular components are assembled in an alternate or successive order.

30. The device of claim 29, wherein each one of said molecular components comprises a compound selected from the herein identified compound 1, 2, 3, 4, 5 or 6, and said two molecular components are assembled in any alternate order, or successive order.

31. (canceled)

32. The device of claim 25, comprising a substrate having an electrically conductive surface and carrying an assembly of three or more molecular components and wherein each one of said molecular components comprises one entity.

33. (canceled)

34. The device of claim 32, wherein said three or more molecular components are assembled in any random, alternate or successive order.

35. The device of claim 21, for use in fabrication of a multistate memory, electrochromic window, smart window, electrochromic display, or binary memory.

36. The device of claim 25, comprising a substrate having an electrically conductive surface and carrying an assembly of more than one molecular component assembled in an alternate order, for use in fabrication of a multistate memory, electrochromic window, smart window, binary memory, electrochromic display, bulk-hetero-junction solar cell, inverted type solar cell, dye sensitized solar cell, molecular diode, charge storage device, capacitor, or transistor.

37. The device of claim 36, wherein each one of said molecular components comprises a compound selected from the herein identified compound 1, 2, 3, 4, 5 or 6, and the thickness of each one of said molecular components is less than 8 nm.

38. The device of claim 25, comprising a substrate having an electrically conductive surface and carrying an assembly of more than one molecular components assembled in a successive order, for use in fabrication of a smart window, electrochromic display, bulk-hetero-junction solar cell, inverted type solar cell, dye sensitized solar cell, molecular diode, charge storage devices capacitor, or transistor.

39. A device according to claim 1, fabricated as a solid state device and further comprising an electrolyte and an electrical conductive electrode, wherein said electrical conductive electrode is fabricated on top of said assembly of one or more molecular components.

40. The device of claim 39, wherein said electrolyte is a conductive polymer, gel electrolyte, or liquid electrolyte.
